(19) United States
(12) Patent Application Publication
(10) Pub. No.: US 2026/0371563 A1
(43) Pub. Date: Nov. 19, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Yasuhiro JINBO, Isehara (JP); Toshiya ENDO, Atsugi (JP); Fumito ISAKA, Zama (JP); Hironobu TAKAHASHI, Isehara (JP); Tsutomu MURAKAWA, Isehara (JP)

(21) Appl. No.: 19/515,513

(22) PCT Filed: Sep. 13, 2024
(86) PCT No.: PCT/IB2024/058906

§ 371 Date: Mar. 2, 2026

(30) Foreign Application Priority Data
Sep. 22, 2023 (JP) 2023-159064
Sep. 22, 2023 (JP) 2023-159065
Jul. 5, 2024 (JP) 2024-108958

(51) Int. Cl. H10B 12/00

(52) U.S. Cl. CPC H10B 12/33; H10B 12/05

(57) ABSTRACT

A semiconductor device including an oxide semiconductor layer, first to third conductive layers, and first to third insulating layers is provided. The first insulating layer is positioned over the first conductive layer. The second conductive layer is positioned over the first insulating layer. The first conductive layer includes a first depressed portion. The first insulating layer and the second conductive layer include a first opening portion at a position overlapping with the first depressed portion. The second insulating layer is in contact with at least the side surface of the first insulating layer in the first opening portion. The oxide semiconductor layer is in contact with the top surface of the second conductive layer and the bottom surface and the side surface of the first depressed portion and is in contact with the second insulating layer in the first opening portion.

### TECHNICAL FIELD

One embodiment of the present invention relates to a semiconductor device, a memory device, a display device, and an electronic appliance. Another embodiment of the present invention relates to a method for manufacturing a semiconductor device.

Note that one embodiment of the present invention is not limited to the above technical field. Examples of the technical field of one embodiment of the present invention include a semiconductor device, a display apparatus, a light-emitting apparatus, a power storage device, a memory device, an electronic appliance, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also refers to all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, and an electronic appliance themselves are semiconductor devices and each of them includes a semiconductor device in some cases.

### BACKGROUND ART

In recent years, semiconductor devices have been developed; an LSI, a CPU (Central Processing Unit), a memory, and the like have been mainly used for semiconductor devices. A CPU is an aggregation of semiconductor elements; the CPU includes a semiconductor integrated circuit (including at least a transistor and a memory) formed into a chip by processing a semiconductor wafer and is provided with an electrode serving as a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a semiconductor material applicable to the transistor, and an oxide semiconductor has been attracting attention as another material.

It is known that a transistor using an oxide semiconductor has extremely low leakage current in an off state. For example, Patent Document 1 discloses a low-power-consumption CPU and the like utilizing a feature of low leakage current of the transistor including an oxide semiconductor. Furthermore, for example, Patent Document 2 discloses a memory device and the like that can retain stored contents for a long period of time by utilizing a feature of low leakage current of the transistor including an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 each disclose a technique for providing an integrated circuit with higher density where a plurality of memory cells are provided to overlap with each other by stacking a first transistor using an oxide semiconductor film and a second transistor using an oxide semiconductor film. Patent Document 4 discloses a technique for providing an integrated circuit with higher density by placing a channel of a transistor using an oxide semiconductor film in the vertical direction.

### REFERENCE

### Patent Document

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et.al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a transistor with favorable electrical characteristics. Another object of one embodiment of the present invention is to provide a transistor with high on-state current. Another object of one embodiment of the present invention is to provide a transistor with low parasitic capacitance. Another object of one embodiment of the present invention is to provide a transistor, a semiconductor device, or a memory device that can be miniaturized or highly integrated. Another object of one embodiment of the present invention is to provide a display device with high resolution or a high aperture ratio. Another object of one embodiment of the present invention is to provide a highly reliable transistor, a highly reliable semiconductor device, a highly reliable display device, or a highly reliable memory device. Another object of one embodiment of the present invention is to provide a semiconductor device, a display device, or a memory device with low power consumption. Another object of one embodiment of the present invention is to provide a memory device that operates at high speed. Another object of one embodiment of the present invention is to provide a method for manufacturing any of the transistor, the semiconductor device, the display device, and the memory device that are described above.

Note that the description of these objects does not preclude the presence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device that includes an oxide semiconductor layer, a first conductive layer, a second conductive layer, a third conductive layer; a first insulating layer, a second insulating layer, and a third insulating layer. The first insulating layer is positioned over the first conductive layer. The second conductive layer is positioned over the first insulating layer. The first conductive layer includes a first depressed portion. The first insulating layer and the second conductive layer have a first opening portion at a position overlapping with the first depressed portion. The second insulating layer is in contact with at least the side surface of the first insulating layer in the first opening portion. The oxide semiconductor layer is in contact with the top surface of the second conductive layer and the bottom surface and the side surface of the first depressed portion and is in contact with the second insulating layer in the first opening portion. The third insulating layer is positioned inward from the oxide semiconductor layer in the first opening portion. The third conductive layer is positioned inward from the third insulating layer in the first opening portion. The first insulating layer has a barrier property against hydrogen. The second insulating layer has a function of capturing or fixing hydrogen.

In the semiconductor device described above, the first insulating layer preferably includes silicon and nitrogen, and the second insulating layer preferably includes oxygen and one or both of hafnium and aluminum.

In the semiconductor device described above, the second insulating layer preferably includes a first layer in contact with the first insulating layer and a second layer positioned between the first layer and the oxide semiconductor layer. The first layer preferably has a function of capturing or fixing hydrogen, and the second layer preferably includes a region containing excess oxygen.

In the semiconductor device described above, the first insulating layer preferably includes silicon and nitrogen. The first layer preferably includes oxygen and one or both of hafnium and aluminum, and the second layer preferably includes oxygen and one or both of silicon and aluminum.

The semiconductor device described above further includes a fourth insulating layer. The third insulating layer preferably covers the top surface and the side surface of the oxide semiconductor layer over the first insulating layer. The fourth insulating layer is preferably positioned over the third insulating layer and preferably includes a second opening portion at a position overlapping with the first opening portion. The third conductive layer preferably includes a portion facing the oxide semiconductor layer with the third insulating layer therebetween in the first opening portion and a portion positioned in the second opening portion.

In the semiconductor device described above, the width of the second opening portion is preferably smaller than the width of the first opening portion.

a fourth conductive layer and a fifth conductive layer over the fourth conductive layer. The fifth conductive layer preferably includes a second depressed portion. The first opening portion preferably overlaps with the second depressed portion. The second insulating layer is preferably in contact with the bottom surface and the side surface of the second depressed portion.

In the semiconductor device described above, the oxide semiconductor layer preferably includes indium, and in a cross-sectional observation with a transmission electron microscope of the oxide semiconductor layer, bright spots arranged in a layered manner in a direction parallel to the side surface of the first insulating layer in the first opening portion are preferably observed.

In the semiconductor device described above, the oxide semiconductor layer preferably includes indium. The oxide semiconductor layer preferably includes a first region, a second region in contact with the first region, and a third region in contact with the second region, and in a cross-sectional observation with a transmission electron microscope of the oxide semiconductor layer, bright spots arranged in a layered manner in a direction parallel to the side surface of the first insulating layer in the first opening portion are preferably observed in each of the first region, the second region, and the third region.

In the semiconductor device described above, a content percentage of indium in the first region is preferably higher than a content percentage of indium in the second region, and a content percentage of indium in the third region is preferably higher than the content percentage of indium in the second region.

One embodiment of the present invention is a semiconductor device including an oxide semiconductor layer, a first conductive layer, a second conductive layer, a third conductive layer, a first insulating layer, a second insulating layer, and a third insulating layer. The first insulating layer is positioned over the first conductive layer. The second conductive layer is positioned over the first insulating layer. The first conductive layer includes a first depressed portion. The first insulating layer and the second conductive layer include a first opening portion at a position overlapping with the first depressed portion. The second insulating layer is in contact with at least the side surface of the first insulating layer in the first opening portion. The oxide semiconductor layer is in contact with the top surface of the second conductive layer and the bottom surface and the side surface of the first depressed portion, and is in contact with the second insulating layer in the first opening portion. In the first opening portion, the third insulating layer is positioned inward from the oxide semiconductor layer. The third conductive layer is positioned inward from the third insulating layer in the first opening portion. The second insulating layer includes a first layer in contact with the first insulating layer and a second layer positioned between the first layer and the oxide semiconductor layer. The first insulating layer includes a third layer, a fourth layer over the third layer, and a fifth layer over the fourth layer. The first layer, the third layer, and the fifth layer each have a barrier property against hydrogen. The second layer has a function of capturing or fixing hydrogen.

In the semiconductor device described above, each of the first layer, the third layer, and the fifth layer preferably include silicon and nitrogen, and the second layer preferably includes oxygen and one or both of hafnium and aluminum.

In the semiconductor device described above, the second insulating layer preferably includes a sixth layer positioned between the second layer and the oxide semiconductor layer and the sixth layer preferably include a region containing excess oxygen.

In the semiconductor device described above, each of the first layer, the third layer, and the fifth layer preferably includes silicon and nitrogen, the second layer preferably includes oxygen and one or both of hafnium and aluminum, and the sixth layer preferably includes oxygen and one or both of silicon and aluminum.

The semiconductor device described above further includes a fourth insulating layer. The third insulating layer preferably covers the top surface and the side surface of the oxide semiconductor layer over the first insulating layer. The fourth insulating layer is preferably positioned over the third insulating layer and preferably includes a second opening portion at a position overlapping with the first opening portion. The third conductive layer preferably includes a portion facing the oxide semiconductor layer with the third insulating layer therebetween in the first opening portion and a portion positioned in the second opening portion.

In the semiconductor device described above, the width of the second opening portion is preferably smaller than the width of the first opening portion.

a fourth conductive layer and a fifth conductive layer over the fourth conductive layer. The fifth conductive layer preferably includes a second depressed portion. The first opening portion preferably overlaps with the second depressed portion. The second insulating layer is preferably in contact with the bottom surface and the side surface of the second depressed portion.

In the semiconductor device described above, the oxide semiconductor layer preferably includes indium, and in a cross-sectional observation with a transmission electron microscope of the oxide semiconductor layer, bright spots arranged in a layered manner in a direction parallel to the side surface of the first insulating layer in the first opening portion are preferably observed.

In the semiconductor device described above, the oxide semiconductor layer preferably includes indium. The oxide semiconductor layer preferably includes a first region, a second region in contact with the first region, and a third region in contact with the second region, and in a cross-sectional observation with a transmission electron microscope of the oxide semiconductor layer, bright spots arranged in a layered manner in a direction parallel to the side surface of the first insulating layer in the first opening portion are preferably observed in each of the first region, the second region, and the third region.

In the semiconductor device described above, the content percentage of indium in the first region is preferably higher than the content percentage of indium in the second region, and the content percentage of indium in the third region is preferably higher than the content percentage of indium in the second region.

### Effect of the Invention

One embodiment of the present invention can provide a transistor with favorable electrical characteristics. Another embodiment of the present invention can provide a transistor with a high on-state current. Another embodiment of the present invention can provide a transistor with low parasitic capacitance. Another embodiment of the present invention can provide a transistor, a semiconductor device, or a memory device that can be miniaturized or highly integrated. Another embodiment of the present invention can provide a display device with high resolution or a high aperture ratio. Another embodiment of the present invention can provide a highly reliable transistor, a highly reliable semiconductor device, a highly reliable display device or a highly reliable memory device. Another embodiment of the present invention can provide a semiconductor device, a display device, or a memory device with low power consumption. Another embodiment of the present invention can provide a memory device that operates at high speed. Another embodiment of the present invention can provide a method for manufacturing the transistor, the semiconductor device, the display device, or the memory device described above.

Note that the description of these effects does not preclude the presence of other effects. One embodiment of the present invention does not necessarily need to have all of these effects. Other effects can be derived from the description of the specification, the drawings, and the claims.

### BRIEF DESCRIPTION OF THE DRAWINGS

FIG. 1A and FIG. 1B are perspective views illustrating an example of a semiconductor device. FIG. 2A1 and FIG. 2A2 are plan views illustrating examples of a semiconductor device. FIG. 2B to FIG. 2E are cross-sectional views illustrating examples of the semiconductor device.

FIG. 3A and FIG. 3B are cross-sectional views illustrating examples of a semiconductor device.

FIG. 4 is a cross-sectional view illustrating an example of a semiconductor device.

FIG. 5 is a cross-sectional view illustrating an example of a semiconductor device.

FIG. 6 is a cross-sectional view illustrating an example of a semiconductor device.

FIG. 7A to FIG. 7C are cross-sectional views illustrating examples of semiconductor devices.

FIG. 8A and FIG. 8B are cross-sectional views illustrating examples of a semiconductor device.

FIG. 9A and FIG. 9B are cross-sectional views illustrating examples of a semiconductor device.

FIG. 10A and FIG. 10B are cross-sectional views illustrating examples of a semiconductor device.

FIG. 11A is a plan view illustrating an example of a semiconductor device. FIG. 11B to FIG. 11E are cross-sectional views illustrating examples of the semiconductor device.

FIG. 12A and FIG. 12B are cross-sectional views illustrating an example of a semiconductor device.

FIG. 13A is a plan view illustrating an example of a semiconductor device. FIG. 13B to FIG. 13E are cross-sectional views illustrating examples of the semiconductor device.

FIG. 14 is a cross-sectional view illustrating an example of a semiconductor device.

FIG. 15A is a plan view illustrating an example of a semiconductor device. FIG. 15B to FIG. 15E are cross-sectional views illustrating examples of the semiconductor device.

FIG. 16 is a cross-sectional view illustrating an example of a semiconductor device.

FIG. 17A to FIG. 17D are cross-sectional views illustrating an example of a method for manufacturing a semiconductor device.

FIG. 18A to FIG. 18C are cross-sectional views illustrating an example of the method for manufacturing the semiconductor device.

FIG. 19A to FIG. 19F are cross-sectional views illustrating an example of the method for manufacturing the semiconductor device.

FIG. 20A to FIG. 20F are cross-sectional views illustrating an example of the method for manufacturing the semiconductor device.

FIG. 21A1 and FIG. 21A2 are plan views illustrating examples of a semiconductor device. FIG. 21B to FIG. 21E are cross-sectional views illustrating examples of the semiconductor device.

FIG. 22A and FIG. 22B are cross-sectional views illustrating examples of a semiconductor device.

FIG. 23A and FIG. 23B are cross-sectional views illustrating examples of a semiconductor device.

FIG. 24A and FIG. 24B are cross-sectional views illustrating examples of a semiconductor device.

FIG. 25A and FIG. 25B are cross-sectional views illustrating examples of a semiconductor device.

FIG. 26 is a cross-sectional view illustrating an example of a semiconductor device.

FIG. 27A and FIG. 27B are cross-sectional views illustrating examples of a semiconductor device.

FIG. 28A and FIG. 28B are perspective views illustrating an example of a semiconductor device. FIG. 29A1 and FIG. 29A2 are plan views illustrating examples of a semiconductor device. FIG. 29B to FIG. 29E are cross-sectional views illustrating examples of the semiconductor device.

FIG. 30A and FIG. 30B are cross-sectional views illustrating examples of a semiconductor device.

FIG. 31 is a cross-sectional view illustrating an example of a semiconductor device.

FIG. 32A and FIG. 32B are cross-sectional views illustrating examples of a semiconductor device.

FIG. 33A and FIG. 33B are cross-sectional views illustrating examples of a semiconductor device.

FIG. 34A and FIG. 34B are cross-sectional views illustrating examples of a semiconductor device.

FIG. 35 is a cross-sectional view illustrating an example of a semiconductor device.

FIG. 36A to FIG. 36D are cross-sectional views illustrating a method for forming a metal oxide according to one embodiment of the present invention.

FIG. 37A to FIG. 37D are cross-sectional views illustrating the method for forming the metal oxide according to one embodiment of the present invention.

FIG. 38A is a plan view illustrating an example of a memory device. FIG. 38B and FIG. 38C are cross-sectional views illustrating examples of the memory device.

FIG. 39A and FIG. 39B are cross-sectional views illustrating structure an example of a memory device.

FIG. 40A is a plan view illustrating an example of a memory device. FIG. 40B is a cross-sectional view illustrating an example of the memory device.

FIG. 41 is a cross-sectional view illustrating an example of a memory device.

FIG. 42 is a cross-sectional view illustrating an example of a memory device.

FIG. 43 is a block diagram illustrating a structure example of a semiconductor device.

FIG. 44A to FIG. 44G are diagrams illustrating circuit structure examples of memory cells.

FIG. 45A and FIG. 45B are perspective views illustrating structure examples of a semiconductor device.

FIG. 46 is a block diagram illustrating a CPU.

FIG. 47A and FIG. 47B are perspective views of a semiconductor device.

FIG. 48A and FIG. 48B are perspective views of semiconductor devices.

FIG. 49A and FIG. 49B are diagrams each illustrating a hierarchy of a variety of memory devices.

FIG. 50A and FIG. 50B are circuit diagrams of a semiconductor device of one embodiment of the present invention, and FIG. 50C is a diagram illustrating an example of an electronic component including the semiconductor device of one embodiment of the present invention.

FIG. 51A and FIG. 51B are perspective views illustrating an example of a display device.

FIG. 52 is a cross-sectional view illustrating an example of a display device.

FIG. 53 is a cross-sectional view illustrating an example of a display device.

FIG. 54A to FIG. 54C are diagrams illustrating structure examples of a display device.

FIG. 55 is a diagram illustrating an example of an electronic component.

FIG. 56A to FIG. 56C are diagrams illustrating an example of a large computer. FIG. 56D is a diagram illustrating an example of space equipment. FIG. 56E is a diagram illustrating an example of a storage system that can be used in a data center.

FIG. 57A to FIG. 57F are diagrams illustrating examples of electronic appliances.

FIG. 58A to FIG. 58G are diagrams illustrating examples of electronic appliances.

FIG. 59A to FIG. 59F are diagrams illustrating examples of electronic appliances.

FIG. 60A to FIG. 60D show SIMS analysis results of samples fabricated in Example.

FIG. 61A to FIG. 61E show TDS analysis results of samples fabricated in Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in the drawings do not represent the actual position, size, range, and the like in some cases for easy understanding. Thus, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number assigned to a component in a certain part in this specification is not the same as an ordinal number assigned to the component in another part in this specification or the scope of claims in some cases.

A transistor is a kind of semiconductor element and can achieve a function of amplifying current or voltage, switching operation for controlling conduction or non-conduction, and the like. An IGFET (Insulated Gate Field Effect Transistor) and a thin film transistor (TFT) are in the category of a transistor in this specification.

In this specification and the like, a transistor including an oxide semiconductor or a metal oxide in its semiconductor layer and a transistor including an oxide semiconductor or a metal oxide in its channel formation region are each sometimes referred to as an OS transistor. Also, a transistor including silicon in its channel formation region is referred to as a Si transistor in some cases.

In this specification and the like, a transistor is an element having at least three terminals including a gate, a drain, and a source. In addition, the transistor includes a region where a channel is formed (also referred to as a channel formation region) between the drain (a drain terminal, a drain region, or a drain electrode) and the source (a source terminal, a source region, or a source electrode), and current can flow between the source and the drain through the channel formation region. Note that in this specification and the like, the channel formation region refers to a region through which current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of a semiconductor. For example, an element with a concentration lower than 0.1 atomic % can be regarded as an impurity. When an impurity is contained, an increase in the density of defect states or a reduction in the crystallinity of the semiconductor may occur, for example. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. In addition, oxygen vacancies (also referred to as Vo) are formed in an oxide semiconductor in some cases by entry of impurities, for example.

Note that in this specification and the like, an oxynitride refers to a material in which an oxygen content is higher than a nitrogen content. A nitride oxide refers to a material in which a nitrogen content is higher than an oxygen content.

The contents of elements such as hydrogen, oxygen, carbon, and nitrogen contained in a film can be analyzed by secondary ion mass spectrometry (SIMS) or X-ray photoelectron spectroscopy (XPS), for example. In the case where the content percentage of a target element is high (e.g., higher than or equal to 0.5 atomic % or higher than or equal to 1 atomic %), XPS is suitable. By contrast, in the case where the content percentage of a target element is low (e.g., lower than or equal to 0.5 atomic % or lower than or equal to 1 atomic %), SIMS is suitable. To compare the contents of elements, analysis with a combination of SIMS and XPS is preferably performed.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”.

In this specification and the like, “parallel” means a state where two straight lines are placed at an angle greater than or equal to −10° and less than or equal to 10°. Accordingly, the case where the angle is greater than or equal to −5° and less than or equal to 5° is also included. Furthermore, “substantially parallel” means a state where two straight lines are placed at an angle greater than or equal to −20° and less than or equal to 20°. Moreover, “perpendicular” means a state where two straight lines are placed at an angle greater than or equal to 80° and less than or equal to 100°. Accordingly, the case where the angle is greater than or equal to 85° and less than or equal to 95° is also included. Furthermore, “substantially perpendicular” means a state where two straight lines are placed at an angle greater than or equal to 70° and less than or equal to 110°.

The expression “connection” in this specification includes “electrical connection” as an example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation period of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

Unless otherwise specified, an off-state current in this specification and the like refers to a leakage current between a source and a drain of a transistor in an off state (also referred to as a non-conducting state or a cutoff state). Unless otherwise specified, an off state in an n-channel transistor refers to a state where a voltage Vgs between its gate and source is lower than a threshold voltage Vth (in a p-channel transistor, a state where a voltage Vgs is higher than Vth).

In this specification and the like, normally-on characteristics means a state where a channel is present without application of a voltage to a gate and a current flows through the transistor. Furthermore, normally-off characteristics mean a state where a current does not flow through a transistor when no potential is applied to a gate or when a ground potential is supplied to the gate.

In this specification and the like, a tapered shape refers to such a shape that at least part of a side surface of a component is inclined with respect to a substrate surface or a formation surface. For example, a tapered shape preferably includes a region where the angle formed between the inclined side surface and the substrate surface or the formation surface (such an angle is also referred to as a taper angle) is greater than 0° and less than 90°. Note that the side surface of the component, the substrate surface, and the formation surface are not necessarily completely flat, and may have a substantially planar shape with a small curvature or a substantially planar shape with slight unevenness.

In this specification and the like, when the expression “A is positioned over B” is used, at least part of A is positioned over B. In other words, A includes a region positioned over B, for example. Similarly, when the expression “A is in contact with B” or “A overlaps with B” is used, at least part of A is in contact with or overlaps with B. In other words, A includes a region in contact with B or A includes a region overlapping with B. Similarly, in this specification and the like, when the expression “A covers B” is used, at least part of A covers B. In other words, A includes a region covering B, for example.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure.

In this specification and the like, a structure where light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases. One layer may function as two or three of the carrier-injection layer, the carrier-transport layer, and the carrier-blocking layer in some cases.

In this specification and the like, a light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, one of the pair of electrodes may be referred to as a pixel electrode and the other may be referred to as a common electrode. In this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split due to the shape of the formation surface (e.g., a step or level difference).

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

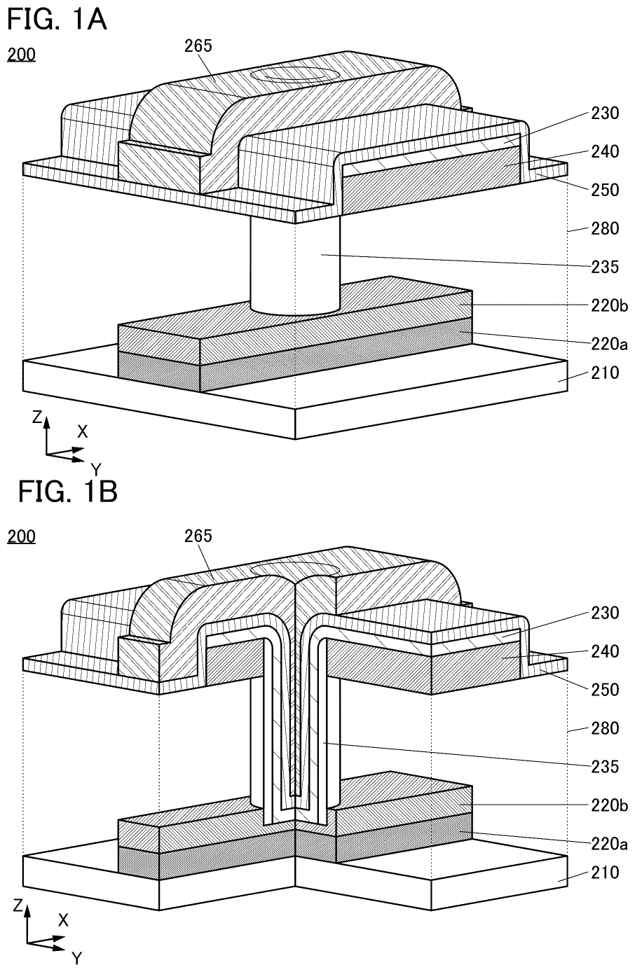

In this embodiment, a semiconductor device of one embodiment of the present invention and a method for manufacturing the semiconductor device will be described with reference to FIG. 1A to FIG. 35.

The semiconductor device of one embodiment of the present invention includes an oxide semiconductor layer, first to third conductive layers, and first to third insulating layers.

The oxide semiconductor layer functions as a semiconductor layer of a transistor, the first conductive layer functions as one of a source electrode and a drain electrode of the transistor, the second conductive layer functions as the other of the source electrode and the drain electrode of the transistor, and the third conductive layer functions as a gate electrode of the transistor. The third insulating layer functions as a gate insulating layer of the transistor.

The first insulating layer is positioned over the first conductive layer, the second conductive layer is positioned over the first insulating layer, the first conductive layer includes a first depressed portion, and the first insulating layer and the second conductive layer include a first opening portion at a position overlapping with the first depressed portion. The second insulating layer is in contact with at least the side surface of the first insulating layer in the first opening portion. The oxide semiconductor layer is in contact with the top surface of the second conductive layer and the bottom surface and the side surface of the first depressed portion, and is in contact with the second insulating layer in the first opening portion. The third insulating layer is positioned inward from the oxide semiconductor layer in the first opening portion. The third conductive layer is positioned inward from the third insulating layer in the first opening portion.

The semiconductor device of one embodiment of the present invention has a structure in which the first insulating layer encloses the periphery of the oxide semiconductor layer in a plan view. In particular, when the oxide semiconductor layer positioned in the first opening portion is circular in the plan view, the first insulating layer encloses the periphery of the oxide semiconductor layer annularly. The second insulating layer is positioned between the first insulating layer and the oxide semiconductor layer. Thus, it is preferable that the first insulating layer have a barrier property against hydrogen and the second insulating layer have a function of capturing or fixing hydrogen, for example. This can reduce impurities such as hydrogen in the oxide semiconductor layer. Accordingly, the transistors can have favorable electrical characteristics and higher reliability.

Note that the second insulating layer may be formed to have a plurality of layers. For example, the second insulating layer can have two layers: a first layer in contact with the first insulating layer and a second layer positioned between the first layer and the oxide semiconductor layer. In the case where the second insulating layer is formed to have two layers, the first layer and the second layer, the first layer preferably has a function of capturing or fixing hydrogen and the second layer preferably includes a region containing excess oxygen. This structure can reduce one or both of oxygen vacancies and impurities in the oxide semiconductor layer.

The semiconductor device of one embodiment of the present invention can have a structure in which the first layer has a barrier property against hydrogen and the second layer has a function of capturing or fixing hydrogen. With such a structure, the first layer having a barrier property against hydrogen can enclose the periphery of the oxide semiconductor layer annularly, and the second layer having a function of capturing or fixing hydrogen can be provided between the first layer and the oxide semiconductor layer. In that case, there is no particular limitation on a material used for the first insulating layer. For example, the first insulating layer can have a stacked-layer structure of a third layer, a fourth layer over the third layer, and a fifth layer over the fourth layer. In that case, the third layer and the fifth layer preferably each have a barrier property against hydrogen.

In the transistor of one embodiment of the present invention, the first depressed portion is provided in the first conductive layer. Accordingly, as compared with the case where the first depressed portion is not provided, the level of the bottom surface of the third insulating layer and the level of the bottom surface of the third conductive layer in the first opening portion can be made low. Accordingly, a gate electric field is easily applied to the oxide semiconductor layer, leading to favorable electrical characteristics of the transistor. Here, the levels of the surfaces can be determined using a formation surface of the transistor as a reference, for example.

Here, high parasitic capacitance generated between a gate wiring and the source electrode or the drain electrode may slow the transistor operation and degrade the frequency characteristics of a circuit including the transistor.

In view of the above, the transistor of one embodiment of the present invention preferably has a structure in which parasitic capacitance generated between the second conductive layer and the third conductive layer is reduced. This enables high-speed operation of the transistor. Furthermore, a semiconductor device having favorable electrical characteristics can be provided.

For example, the semiconductor device of one embodiment of the present invention preferably further includes a fourth insulating layer. In that case, it is preferable that the third insulating layer cover the top surface and the side surface of the oxide semiconductor layer over the first insulating layer, the fourth insulating layer be positioned over the third insulating layer and include a second opening portion at a position overlapping with the first opening portion, and the third conductive layer include a portion facing the oxide semiconductor layer with the third insulating layer therebetween in the first opening portion and a portion positioned in the second opening portion. Alternatively, it is preferable that the fourth insulating layer be positioned over the first insulating layer, cover the top surface and the side surface of the oxide semiconductor layer over the first insulating layer, and have the second opening portion at a position overlapping with the first opening portion, the third insulating layer include a portion positioned in the second opening portion, and the third conductive layer be positioned inward from the third insulating layer in the second opening portion.

The third conductive layer includes a portion facing the oxide semiconductor layer with the third insulating layer therebetween in the first opening portion and a portion positioned in the second opening portion. In this case, a gate wiring is placed over the fourth insulating layer, so that a physical distance between the second conductive layer and the gate wiring can be increased. Thus, parasitic capacitance generated between the second conductive layer and the gate wiring can be reduced. Note that part of the third conductive layer (a portion positioned over the fourth insulating layer) may function as the gate wiring, and another gate wiring may be provided over the fourth insulating layer separately from the third conductive layer.

In a transistor of one embodiment of the present invention, a source electrode and a drain electrode are positioned at different levels, and current flowing in a semiconductor layer flows in the height direction. In other words, the channel length direction includes a component of the height direction (vertical direction); accordingly, the transistor of one embodiment of the present invention can also be referred to as a VFET (Vertical Field Effect Transistor), a vertical transistor, a vertical-channel transistor, a vertical-channel-type transistor, or the like.

In the transistor of one embodiment of the present invention, the source electrode, the semiconductor layer, and the drain electrode can be provided to overlap with each other; thus, the area occupied by the transistor can be significantly smaller than the area occupied by what is called a planar transistor in which a semiconductor layer is provided in a planar shape.

The channel length of the transistor of one embodiment of the present invention can be controlled by the thicknesses of the first insulating layer, the second conductive layer, and the like. Thus, a transistor with an extremely small channel length, which is difficult to achieve in a planar transistor, can be achieved. Accordingly, a transistor with a small occupation area and a high on-state current can be provided.

In addition, since the off-state current of a transistor including an oxide semiconductor is extremely low, stored data can be retained for an extremely long period of time by using the transistor in the memory device, for example. In other words, such a memory device does not require refresh operation or has extremely low frequency of the refresh operation, which leads to a sufficient reduction in power consumption of the memory device. When the transistor of one embodiment of the present invention is used for a memory device, high integration and low power consumption of the memory device can be achieved.

<Structure example 1 of semiconductor device>

A structure of a semiconductor device of one embodiment of the present invention is described with reference to FIG. 1A to FIG. 5.

FIG. 1A and FIG. 1B are schematic perspective views of a semiconductor device including a transistor 200. FIG. 1B is a perspective view of FIG. 1A part of which is cut out. In FIG. 1A and FIG. 1B, only the outlines of some components (e.g., interlayer insulating layers) are indicated by dashed lines.

In FIG. 1A and FIG. 1B, the X direction, the Y direction, and the Z direction are indicated by arrows. Although the same reference signs X, Y, and Z are used in FIG. 1A and FIG. 1B, the directions in these drawings are not necessarily the same.

FIG. 2A1 is a plan view of the semiconductor device including the transistor 200. FIG. 2A2 is a plan view illustrating an example where a plurality of transistors 200 are arranged. FIG. 2B is a cross-sectional view along the dashed-dotted line A1-A2 in FIG. 2A1. FIG. 2C is a cross-sectional view taken along the dashed-dotted line A3-A4 in FIG. 2A1. FIG. 2D and FIG. 2E are cross-sectional views taken along dashed-dotted line A5-A6 in FIG. 2B. FIG. 2E corresponds to an example of an enlarged view of FIG. 2D. FIG. 2D and FIG. 2E can also be regarded as a cross-sectional view along an XY plane including an insulating layer 280. Note that for the sake of clarity of the drawing, some components are not illustrated in the plan views of FIG. 2A1 and FIG. 2A2. Some components are omitted also in the following plan views in some cases.

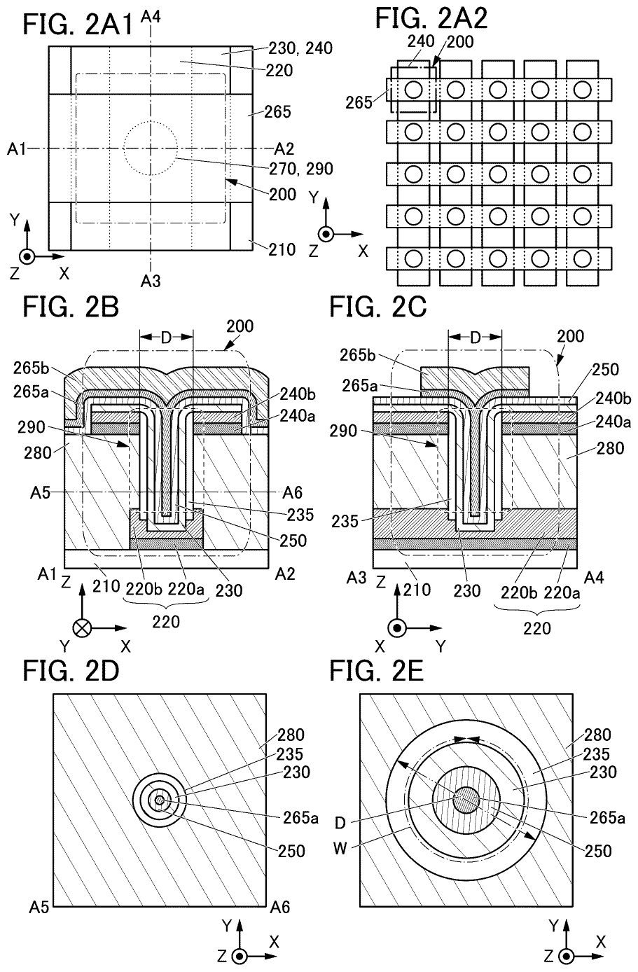

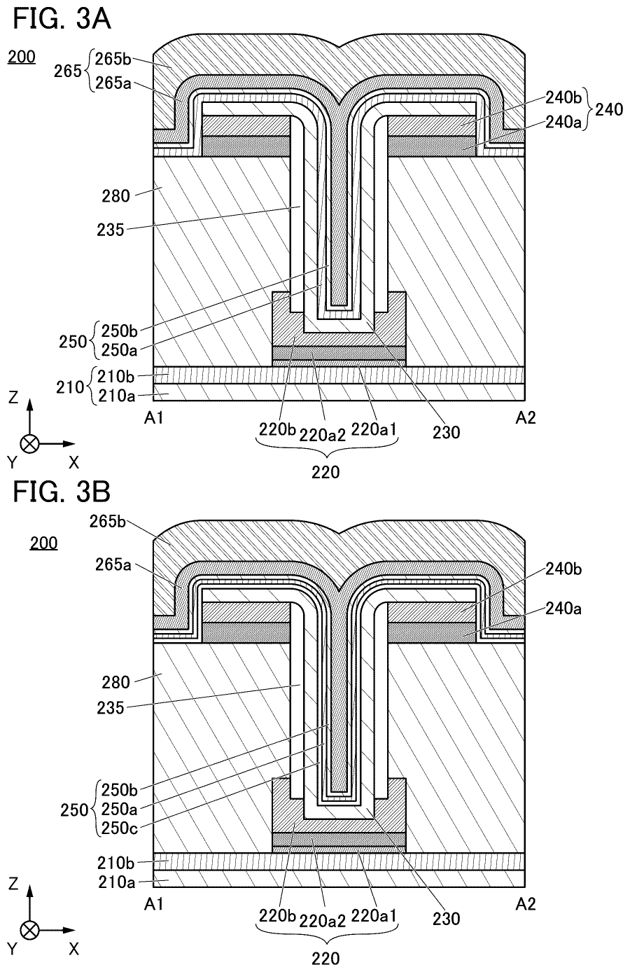

FIG. 3A to FIG. 5 are each a cross-sectional view taken along the dashed-dotted line A1-A2 in FIG. 2A1. FIG. 3A to FIG. 5 each correspond to an example of an enlarged view of FIG. 2B, and illustrate a structure example of each layer in more detail.

The semiconductor device illustrated in FIG. 1A to FIG. 2E includes an insulating layer 210 over a substrate (not illustrated), the transistor 200 over the insulating layer 210, and the insulating layer 280 over the insulating layer 210. The insulating layer 210 and the insulating layer 280 each function as an interlayer film. [Transistor 200]

The transistor 200 includes a conductive layer 220a, a conductive layer 220b over the conductive layer 220a, a conductive layer 240a over the insulating layer 280, a conductive layer 240b over the conductive layer 240a, an insulating layer 235, an oxide semiconductor layer 230, an insulating layer 250 over the oxide semiconductor layer 230, a conductive layer 265a over the insulating layer 250, and a conductive layer 265b over the conductive layer 265a.

Note that the conductive layer 220a and the conductive layer 220b are sometimes collectively referred to as a conductive layer 220 hereinafter. The conductive layer 240a and the conductive layer 240b are sometimes collectively referred to as a conductive layer 240. In addition, the conductive layer 265a and the conductive layer 265b are sometimes collectively referred to as a conductive layer 265. FIG. 2B and FIG. 2C each illustrate an example where the conductive layer 220 has a two-layer structure of the conductive layer 220a and the conductive layer 220b over the conductive layer 220a.

In the transistor 200, the oxide semiconductor layer 230 functions as a semiconductor layer, the conductive layer 265 functions as a gate electrode, the insulating layer 250 functions as a gate insulating layer, the conductive layer 220 functions as one of a source electrode and a drain electrode, and the conductive layer 240 functions as the other of the source electrode and the drain electrode. The conductive layer 265 also functions as a gate wiring.

The oxide semiconductor layer 230 includes a region overlapping with a conductive layer 260 with the insulating layer 250 therebetween. At least part of the region functions as the channel formation region of the transistor 200. One of the region of the oxide semiconductor layer 230 that is in contact with the conductive layer 220 and the region of the oxide semiconductor layer 230 that is in contact with the conductive layer 240 functions as a source region, and the other functions as a drain region. That is, the channel formation region is sandwiched between the source region and the drain region.

As illustrated in FIG. 2B and FIG. 2C, the opening portion 290 reaching the conductive layer 220 is provided in the insulating layer 280, the conductive layer 240a, and the conductive layer 240b.

The opening portion 290 includes an opening portion in the insulating layer 280, an opening portion in the conductive layer 240a, and an opening portion in the conductive layer 240b. In other words, the opening portion included in a region where the insulating layer 280 overlaps with the conductive layer 220a is part of the opening portion 290, the opening portion included in a region where the conductive layer 240a overlaps with the conductive layer 220a is another part of the opening portion 290, and the opening portion included in a region where the conductive layer 240b overlaps with the conductive layer 220a is another part of the opening portion 290. Note that the shape and the size of the opening portion 290 in the plan view may differ from layer to layer. When the opening portion 290 has a circular top-view shape, the opening portions of the layers may be, but not necessarily, concentrically arranged.

At least part of the components of the transistor 200 is placed in the opening portion 290. Specifically, at least part of each of the insulating layer 235, the oxide semiconductor layer 230, the insulating layer 250, and the conductive layer 265 is placed to be positioned inside the opening portion 290.

The insulating layer 235 is provided along at least part of the sidewall of the opening portion 290. The insulating layer 235 includes at least a region positioned between the oxide semiconductor layer 230 and the insulating layer 280. The insulating layer 235 can be referred to as a sidewall, a sidewall insulating layer, a sidewall protective layer, or the like.

Portions of the oxide semiconductor layer 230 and the insulating layer 250 that are placed inside the opening portion 290 reflect the shape of the opening portion 290. Specifically, the oxide semiconductor layer 230 is provided to cover the bottom portion and the sidewall of the opening portion 290 with the insulating layer 235 therebetween. In other words, the oxide semiconductor layer 230 is in contact with the insulating layer 235 inside the opening portion 290. The insulating layer 250 is provided to cover the oxide semiconductor layer 230. Then, the conductive layer 265a is provided to fill at least part of the depressed portion of the insulating layer 250 that reflects the shape of the opening portion 290.

In the transistor 200, the oxide semiconductor layer 230 including a channel formation region includes a metal oxide functioning as a semiconductor (also referred to as an oxide semiconductor). That is, the transistor 200 can be regarded as an OS transistor.

The electrical characteristics of an OS transistor are likely to change in the case where oxygen vacancies (Vo) and impurities are present in a channel formation region in an oxide semiconductor, which may result in degradation of the reliability. A defect that is an oxygen vacancy into which hydrogen enters (hereinafter sometimes referred to as VoH) generates an electron serving as a carrier in some cases. Thus, when the channel formation region in the oxide semiconductor includes oxygen vacancies, the OS transistor is likely to have normally-on characteristics. Therefore, oxygen vacancies and impurities are preferably reduced as much as possible in the channel formation region in the oxide semiconductor. In other words, the carrier concentration is preferably reduced in the channel formation region in the oxide semiconductor, and the channel formation region is preferably i-type (intrinsic) or substantially i-type.

Meanwhile, it is preferable that a source region and a drain region of the OS transistor include more oxygen vacancies, include more VoH, or have a higher concentration of an impurity such as hydrogen, nitrogen, or a metal element than the channel formation region, and thus be low-resistance regions with high carrier concentrations. In other words, the source region and the drain region of the OS transistor are each preferably an n-type region that has a higher carrier concentration and a lower resistance than the channel formation region.

As described above, the oxide semiconductor layer 230 is provided inside the opening portion 290. The transistor 200 has a structure in which current flows in the vertical direction since one of the source electrode and the drain electrode (here, the conductive layer 220) is positioned below and the other of the source electrode and the drain electrode (here, the conductive layer 240) is positioned above. That is, a channel is formed along the side surface of the opening portion 290.

The positional relationship of the layers in the opening portion 290 is described with reference to FIG. 2D and FIG. 2E. The insulating layer 235 is in contact with an outer surface of the oxide semiconductor layer 230. The insulating layer 250 is in contact with an outer surface of the conductive layer 265a. In addition, the oxide semiconductor layer 230 surround the whole outer circumference of the conductive layer 265a with the insulating layer 250 therebetween. Thus, the channel formation region of the transistor 200 can be formed in the entire outer surface (the entire region in contact with the insulating layer 235) of the oxide semiconductor layer 230 in the opening portion 290.

As illustrated in FIG. 2D and FIG. 2E, the semiconductor device of this embodiment has a structure in which the insulating layer 280 encloses the periphery of the oxide semiconductor layer 230 annularly in the plan view. In the semiconductor device of this embodiment, the insulating layer 235 is positioned between the insulating layer 280 and the oxide semiconductor layer 230 in the plan view.

As described above, oxygen vacancies and impurities are preferably reduced as much as possible in the channel formation region in the oxide semiconductor. In particular, hydrogen in the channel formation region of the oxide semiconductor is preferably reduced as much as possible.

In view of this, a barrier insulator against hydrogen is preferably used as the insulating layer 280 provided outside the oxide semiconductor layer 230. When the insulating layer 280 has a barrier property against hydrogen, diffusion of hydrogen into the oxide semiconductor layer 230 can be inhibited. For example, as the insulating layer 280, a silicon nitride film, a silicon nitride oxide film, or an aluminum oxide film is preferably used, and a silicon nitride film is further preferably used.

When diffusion of hydrogen into the oxide semiconductor layer 230 is inhibited, the hydrogen concentration in the oxide semiconductor can be reduced and a negative shift in the initial characteristics of the transistor 200 can be inhibited, so that the transistor 200 can have normally-off characteristics. In addition, negative drift degradation in a +GBT (Gate Bias-Temperature) stress test can also be inhibited.

Note that silicon nitride also has a barrier property against oxygen. Thus, using silicon nitride for the insulating layer 280 can inhibit extraction of oxygen from the oxide semiconductor layer 230, and accordingly can inhibit formation of an excess amount of oxygen vacancies in the oxide semiconductor layer 230.

Furthermore, when silicon nitride is used for the insulating layer 280, excess oxygen can be prevented from being supplied to the oxide semiconductor layer 230. Thus, the channel formation region of the oxide semiconductor layer 230 can be prevented from containing excess oxygen, whereby the reliability of the transistor 200 can be improved.

The insulating layer 235 provided in contact with the oxide semiconductor layer 230 is preferably formed using an insulator having a function of capturing or fixing hydrogen. When the insulating layer 235 has a function of capturing or fixing hydrogen, hydrogen in the oxide semiconductor layer 230 can be diffused into the insulating layer 235 and the hydrogen can be captured or fixed. Thus, the hydrogen concentration in the oxide semiconductor layer 230 (in particular, the hydrogen concentration in the channel formation region of the transistor) can be reduced. For example, a hafnium oxide film, a hafnium aluminate film, or an aluminum oxide film is preferably used as the insulating layer 235. The insulating layer 235 includes oxygen and one or both of hafnium and aluminum. For example, a hafnium silicate film is preferably used as the insulating layer 235.

Note that a hafnium oxide film, a hafnium silicate film, or an aluminum oxide film has a barrier property against oxygen. Thus, the insulating layer 235 in contact with the conductive layer 240 is preferably formed using any of these materials, in which case oxidation of the conductive layer 240 can be inhibited.

The insulating layer 235 is preferably an insulating layer including a region containing oxygen that is released by heating (hereinafter, sometimes referred to as excess oxygen), for example. Accordingly, oxygen can be supplied to the oxide semiconductor layer 230 from the insulating layer 235, so that oxygen vacancies in the oxide semiconductor layer 230 can be reduced. For example, it is preferable that a silicon oxide film, a silicon oxynitride film, or an aluminum oxide film be used as the insulating layer 235.

As described above, the barrier insulating layer against hydrogen encloses the periphery of the oxide semiconductor layer 230 annularly, and an insulating layer having a function of capturing or fixing hydrogen or an insulating layer including a region containing excess oxygen is provided in the vicinity of the oxide semiconductor layer 230, in which case one or both of oxygen vacancies and impurities in the oxide semiconductor layer 230 can be reduced. Thus, the transistors can have favorable electrical characteristics and higher reliability.

Note that in the case where an oxide insulating film such as a silicon oxide film is used as the insulating layer 235 that is the formation surface of the oxide semiconductor layer 230, the oxide semiconductor layer 230 is preferably formed by an ALD method. In the case where the oxide semiconductor layer 230 has a stacked-layer structure, a layer of the oxide semiconductor layer 230 that is in contact with the insulating layer 235 is preferably formed by an ALD method. When the oxide semiconductor layer 230 is formed by an ALD method, ozone (O₃) is preferably used as an oxidizer. With such a structure, oxygen can be injected into the insulating layer 235 that is the formation surface of the oxide semiconductor layer 230. Thus, excess oxygen in the insulating layer 235 can be increased.

The semiconductor device of this embodiment has a structure in which insulating layers are provided above and below the oxide semiconductor layer 230. Examples of the insulating layers provided above or below the oxide semiconductor layer 230 include the insulating layer 210 and the insulating layer 250.

A barrier insulator against hydrogen is preferably used as the insulating layer 210 positioned below the oxide semiconductor layer 230. When the insulating layer 210 has a barrier property against hydrogen, diffusion of hydrogen into the oxide semiconductor layer 230 can be inhibited. For example, silicon nitride is preferably used for the insulating layer 210.

As the insulating layer 210, an insulator having a function of capturing or fixing hydrogen is preferably used. When the insulating layer 210 has a function of capturing or fixing hydrogen, hydrogen in the oxide semiconductor layer 230 can diffuse into the insulating layer 210 through the conductive layer 220 and the hydrogen can be captured or fixed. Thus, the hydrogen concentration in the oxide semiconductor layer 230 can be reduced.

FIG. 2B and FIG. 2C illustrate an example where the insulating layer 210 has a single-layer structure. The insulating layer 210 can have a stacked-layer structure of two or more layers. FIG. 3A illustrates an example where the insulating layer 210 has a two-layer structure of an insulating layer 210a and an insulating layer 210b over the insulating layer 210a. In that case, a barrier insulator against hydrogen is preferably used as the insulating layer 210a, and an insulator having a function of capturing or fixing hydrogen is preferably used as the insulating layer 210b, for example. Specifically, a silicon nitride film is preferably used as the insulating layer 210a, and a hafnium oxide film, a hafnium silicate film, or an aluminum oxide film is preferably used as the insulating layer 210b.

The insulating layer 250 covers the top surface and the side surface of the oxide semiconductor layer 230 over the insulating layer 280. A barrier insulator against hydrogen is preferably used as the insulating layer 250 positioned above the oxide semiconductor layer 230.

When the insulating layer 250 has a barrier property against hydrogen, diffusion of hydrogen contained in the conductive layer 265 into the oxide semiconductor layer 230 can be inhibited. For example, a silicon nitride film is suitable for the insulating layer 250 because of its high barrier property against hydrogen.

Since the insulating layer 250 is in contact with the oxide semiconductor layer 230, an insulator having a function of capturing or fixing hydrogen is preferably used. Thus, hydrogen contained in the oxide semiconductor layer 230 can be captured or fixed more effectively. Accordingly, the hydrogen concentration in the oxide semiconductor layer 230 (in particular, the hydrogen concentration in the channel formation region of the transistor) can be reduced. Therefore, VoH in the channel formation region can be reduced, so that the channel formation region can be i-type or substantially i-type.

The insulating layer 250 is preferably an insulating layer including an excess-oxygen region. Accordingly, oxygen can be supplied to the oxide semiconductor layer 230 from the insulating layer 250, so that oxygen vacancies in the oxide semiconductor layer 230 can be reduced. A silicon oxide film, a silicon oxynitride film, or the like has a thermally stable structure and thus is suitably used for the insulating layer 250.

FIG. 2B and FIG. 2C illustrate an example in which the insulating layer 250 has a single-layer structure. The insulating layer 250 can have a stacked-layer structure of two or more layers.

FIG. 3A illustrates an example where the insulating layer 250 has a two-layer structure of an insulating layer 250a and an insulating layer 250b over the insulating layer 250a. In this case, the insulating layer 250a is in contact with the oxide semiconductor layer 230. For example, an insulator having a function of capturing or fixing hydrogen is preferably used as the insulating layer 250a, and a barrier insulator against hydrogen is preferably used as the insulating layer 250b. In this structure, the oxide semiconductor layer 230 can be sandwiched between the insulating layers each having a function of capturing or fixing hydrogen, so that the hydrogen concentration in the oxide semiconductor layer 230 can be further reduced. Furthermore, the oxide semiconductor layer 230 can be sandwiched between the barrier insulating layers against hydrogen with the insulating layers therebetween, so that diffusion of hydrogen into the oxide semiconductor layer 230 can be inhibited. Thus, the transistor can have high reliability.

Alternatively, for example, an insulating layer including a region containing excess oxygen is preferably used as the insulating layer 250a, and a barrier insulator against hydrogen is preferably used as the insulating layer 250b. Alternatively, for example, an insulating layer including a region containing excess oxygen is preferably used as the insulating layer 250a, and an insulator having a function of capturing or fixing hydrogen is preferably used as the insulating layer 250b.

FIG. 3B illustrates an example in which the insulating layer 250 has a three-layer structure of an insulating layer 250c, the insulating layer 250a over the insulating layer 250c, and the insulating layer 250b over the insulating layer 250a.

In the structure illustrated in FIG. 3B, for example, it is preferable that an insulating layer including a low-relative-permittivity material be used as the insulating layer 250c, an insulator having a function of capturing or fixing hydrogen be used as the insulating layer 250a, and an insulator having a barrier property against hydrogen and oxygen be used as the insulating layer 250b. As the low-relative-permittivity material, silicon oxide or silicon oxynitride is preferably used. The insulating layer 250c is a layer being in contact with the oxide semiconductor layer 230. When an oxide is used as the insulating layer 250c, oxygen can be supplied to the oxide semiconductor layer 230. Providing the insulating layer 250b can inhibit diffusion of oxygen contained in the insulating layer 250c into the conductive layer 265 so that the oxidation of the conductive layer 265 can be inhibited. In addition, a reduction in the amount of oxygen supplied to the oxide semiconductor layer 230 from the insulating layer 250c can be inhibited.

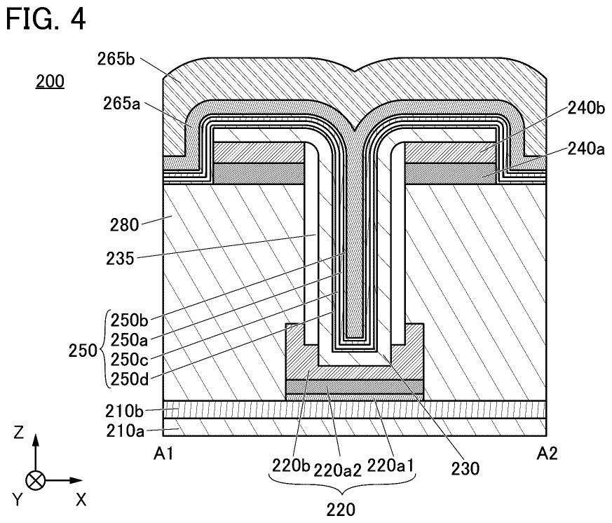

FIG. 4 illustrates an example in which the insulating layer 250 has a four-layer structure of an insulating layer 250d, the insulating layer 250c over the insulating layer 250d, the insulating layer 250a over the insulating layer 250c, and the insulating layer 250b over the insulating layer 250a.

It is preferable that an insulator having a barrier property against oxygen be used as the insulating layer 250d, an insulating layer including a low-relative-permittivity material be used as the insulating layer 250c, an insulator having a function of capturing or fixing hydrogen be used as the insulating layer 250a, and an insulator having a barrier property against hydrogen and oxygen be used as the insulating layer 250b. For the insulating layer 250a to the insulating layer 250c, structures similar to those of the layers used in the above three-layer structure can be employed. The insulating layer 250d is in contact with the oxide semiconductor layer 230. When the insulating layer 250d has a barrier property against oxygen, release of oxygen from the oxide semiconductor layer 230 can be inhibited. For the insulating layer 250d, an aluminum oxide film is preferably used, for example. Aluminum oxide has a function of capturing or fixing hydrogen and is thus suitable for the insulating layer 250d in contact with the oxide semiconductor layer 230. Specifically, it is preferable to employ a four-layer structure where an aluminum oxide film, a silicon oxide film, a hafnium oxide film, and a silicon nitride film are stacked in this order from the oxide semiconductor layer 230 side.

Each layer included in the insulating layer 250 is preferably a thin film. For example, when the insulating layer 250 is greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in the subthreshold region when the drain voltage is constant and the drain current is changed by one order of magnitude.

The thickness of each of the layers included in the insulating layer 250 (corresponding to the insulating layer 250a to the insulating layer 250d in the case of the structure illustrated in FIG. 4) is preferably larger than or equal to 0.1 nm and smaller than or equal to 10 nm, further preferably larger than or equal to 0.1 nm and smaller than or equal to 5 nm, still further preferably larger than or equal to 0.5 nm and smaller than or equal to 5 nm, yet further preferably larger than or equal to 1 nm and smaller than 5 nm, yet still further preferably larger than or equal to 1 nm and smaller than or equal to 3 nm. Note that at least part of each of the layers included in the insulating layer 250 preferably includes a region having the above-described thickness.

Typically, the thicknesses of the insulating layer 250d, the insulating layer 250c, the insulating layer 250a, and the insulating layer 250b are 1 nm, 2 nm, 2 nm, and 1 nm, respectively. This structure enables the transistor to have favorable electrical characteristics even when miniaturization or high integration of transistors is performed.

Note that the structure illustrated in FIG. 4 may be a structure without the insulating layer 250b. For example, an insulator having a barrier property against oxygen can be used as the insulating layer 250d, an insulating layer including a low-relative-permittivity material can be used as the insulating layer 250c, and an insulator having a function of capturing or fixing hydrogen can be used as the insulating layer 250a. Specifically, a three-layer structure can be used in which an aluminum oxide film, a silicon oxide film, and a hafnium oxide film are stacked in this order from the oxide semiconductor layer 230 side.

As described above, the barrier insulating layer against hydrogen encloses the periphery of the oxide semiconductor layer 230, and the insulating layer having a function of capturing or fixing hydrogen or the insulating layer including a region containing excess oxygen is provided in the vicinity of the oxide semiconductor layer 230, in which case one or both of oxygen vacancies and impurities in the oxide semiconductor layer 230 can be further reduced. Thus, the transistor can have favorable electrical characteristics and higher reliability. A semiconductor device having favorable electrical characteristics can be provided. A highly reliable semiconductor device can be provided. A semiconductor device with small variations in electrical characteristics of transistors can be provided. A semiconductor device with high on-state current can be provided.

The conductive layer 220 includes the conductive layer 220a and the conductive layer 220b over the conductive layer 220a, and a depressed portion is provided in the conductive layer 220b. In other words, the conductive layer 220 includes a depressed portion, the bottom surface of the depressed portion corresponds to the bottom surface of the depressed portion of the conductive layer 220b, and the side surface of the depressed portion corresponds to the side surface of the depressed portion of the conductive layer 220b. Specifically, the conductive layer 220b includes the first depressed portion and the second depressed portion positioned outward from the first depressed portion. The depth of the first depressed portion is greater than that of the second depressed portion. In other words, the bottom surface of the first depressed portion is positioned below the bottom surface of the second depressed portion (on the insulating layer 210 side). The second depressed portion is provided in the conductive layer 220b at the time of forming the opening portion 290, and then the first depressed portion is provided in the conductive layer 220b at the time of processing the insulating layer 235. Thus, in FIG. 2B and the like, the side surface of the first depressed portion is aligned with a surface of the insulating layer 235 on the oxide semiconductor layer 230 side, and the side surface of the second depressed portion is aligned with the side surface of the insulating layer 280 and the like on the opening portion 290 side. Hereinafter, the first depressed portion and the second depressed portion are collectively referred to as a depressed portion in some cases.

The opening portion 290 overlaps with the depressed portion of the conductive layer 220b. Here, the bottom portion of the opening portion 290 includes the bottom surface of the depressed portion of the conductive layer 220b, and the sidewall of the opening portion 290 includes the side surface of the depressed portion of the conductive layer 220b, the side surface of the insulating layer 280, the side surface of the conductive layer 240a, and the side surface of the conductive layer 240b.

In FIG. 2B and the like, the insulating layer 235 is in contact with the bottom surface and the side surface of the depressed portion (specifically, the second depressed portion) of the conductive layer 220, and is in contact with the side surface of the insulating layer 280, the side surface of the conductive layer 240a, and the side surface of the conductive layer 240b in the opening portion 290. The oxide semiconductor layer 230 is in contact with the bottom surface and the side surface of the depressed portion (specifically, the first depressed portion) of the conductive layer 220, the insulating layer 235, and the top surface of the conductive layer 240b. The insulating layer 250 is positioned inward from the oxide semiconductor layer 230 in the opening portion 290, and the conductive layer 265a is positioned inward from the insulating layer 250 in the opening portion 290.

As illustrated in FIG. 2B and the like, the first depressed portion of the conductive layer 220b preferably has a greater depth than the second depressed portion of the conductive layer 220b. Thus, the oxide semiconductor layer 230 can be in contact with the side surface of the first depressed portion of the conductive layer 220b as well as the bottom surface of the first depressed portion of the conductive layer 220b. In this structure, the contact area between the conductive layer 220b and the oxide semiconductor layer 230 can be increased, so that the contact resistance between the conductive layer 220b and the oxide semiconductor layer 230 can be reduced. Thus, a decrease in the on-state current of the transistor 200 due to the contact resistance between the conductive layer 220b and the oxide semiconductor layer 230 can be inhibited.

In the transistor of one embodiment of the present invention, at least one layer included in the conductive layer 265 is provided inside the opening portion 290. In the case where the conductive layer 265 has a stacked-layer structure, as miniaturization of the transistor 200 proceeds and the diameter of the opening portion 290 becomes smaller, it becomes difficult to arrange all the layers included in the conductive layer 265 in the opening portion 290. FIG. 2B and FIG. 2C illustrate an example where the conductive layer 265 has a two-layer structure, only the conductive layer 265a is provided in the opening portion 290, and the conductive layer 265b over the conductive layer 265a is provided at a position overlapping with the opening portion 290. In addition, both of the conductive layer 265a and the conductive layer 265b may be positioned in the opening portion 290 depending on the diameter of the opening portion 290, the thickness of the conductive layer 265a, and the like.

When the conductive layer 220b includes the depressed portion at a position overlapping with the opening portion 290, unlike in the case where the depressed portion is not provided, the level of the bottom surface of the insulating layer 250 and the level of the bottom surface of the conductive layer 265a in the opening portion 290 can be lower than the level of the top surface of the conductive layer 220b which is in contact with the insulating layer 280, with the top surface of the insulating layer 210 used as a reference. Here, the levels of the surfaces can be determined using a formation surface of the transistor as a reference, for example. Here, the top surface of the insulating layer 210 is used as the reference. The surface used as the reference is not limited to the formation surface of the transistor. For example, the top surface of the substrate where the transistor or the semiconductor device is provided may be used as the reference.

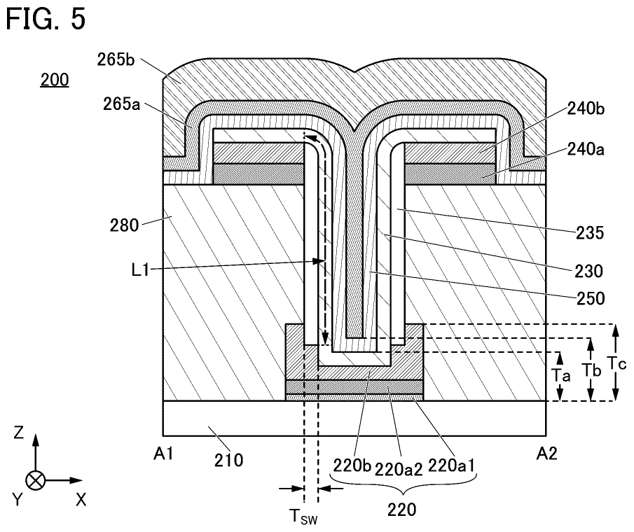

As illustrated in FIG. 5, the shortest distance Tc from the top surface of the insulating layer 210 to the top surface of the conductive layer 220b that is in contact with the insulating layer 280 is preferably longer than the shortest distance Ta from the top surface of the insulating layer 210 to the bottom surface of the insulating layer 250. Accordingly, the contact area between the side surface of the conductive layer 220b and the oxide semiconductor layer 230 can be increased, so that the contact resistance between the conductive layer 220b and the oxide semiconductor layer 230 can be reduced. This can inhibit a decrease in on-state current of the transistor 200 due to the contact resistance between the conductive layer 220b and the oxide semiconductor layer 230. Note that the shortest distance Ta can be determined on the basis of the bottom surface of the insulating layer 250 in the opening portion 290.

As illustrated in FIG. 5, the shortest distance Tc is preferably longer than or equal to the shortest distance Tb from the top surface of the insulating layer 210 to the bottom surface of the conductive layer 265a, further preferably longer than the shortest distance Tb. Accordingly, a gate electric field is easily applied to the channel formation region in the oxide semiconductor layer 230, so that the electrical characteristics of the transistor 200 can be improved. Furthermore, a gate electric field is easily applied to a region of the oxide semiconductor layer 230 which is in contact with the conductive layer 220b, so that the on-state current of the transistor 200 can be increased. The transistor 200 can have favorable electrical characteristics when either the conductive layer 220 or the conductive layer 240 is used as the drain electrode. Note that the shortest distance Tb can be determined on the basis of the bottom surface of the conductive layer 265a in the opening portion 290.

The oxide semiconductor layer 230 is in contact with the bottom surface and the side surface of the depressed portion of the conductive layer 220b and the top surface of the conductive layer 240b. When the conductive layer 220b includes a depressed portion, the contact area between the oxide semiconductor layer 230 and the conductive layer 220b can be increased. Thus, the contact resistance between the oxide semiconductor layer 230 and the conductive layer 220b can be reduced.

It is preferable to use a conductive material including oxygen for the conductive layer 220b. Accordingly, the contact resistance between the oxide semiconductor layer 230 and the conductive layer 220b can be reduced.

In the case where the conductive layer 220 and the conductive layer 240 each have a stacked-layer structure, a conductive material including oxygen is preferably used for a layer having the largest contact area with the oxide semiconductor layer 230 in the stacked-layer structure, in which case the contact resistance with the oxide semiconductor layer 230 can be reduced. Therefore, a conductive material including oxygen is preferably used for each of the conductive layer 220b and the conductive layer 240b, for example.

Alternatively, in the case where the conductive layer 220 and the conductive layer 240 each have a stacked-layer structure, the use of a conductive material including oxygen for the layer closest to the channel formation region in the stacked-layer structure can reduce the contact resistance with the oxide semiconductor layer 230, which can shorten a current path between the source and the drain and thus can increase the on-state current of the transistor. Therefore, for example, a conductive material including oxygen is preferably used for each of the conductive layer 220b and the conductive layer 240a.

As a conductive material including oxygen, a metal oxide having conductivity (also referred to as an oxide conductor) is preferably used.

FIG. 2B illustrates a structure where an end portion of the conductive layer 240a, an end portion of the conductive layer 240b, and an end portion of the oxide semiconductor layer 230 are aligned with each other outside the opening portion 290. As in a manufacturing method example described later, the conductive layer 240a, the conductive layer 240b, and the oxide semiconductor layer 230 can be formed by processing with the use of the same mask. This is preferable because the number of masks required for manufacturing the semiconductor device can be reduced. Note that the present invention is not limited thereto. For example, in the X direction or the Y direction, any of the end portion of the oxide semiconductor layer 230, the end portion of the conductive layer 240a, and the end portion of the conductive layer 240b may be positioned inward or outward from the others.

The conductive layer 240 includes the opening portion 290 in a region overlapping with the conductive layer 220. The conductive layer 240 is preferably not located inside the opening portion 290 included in the insulating layer 280 or the like. That is, the conductive layer 240 preferably does not include a region in contact with the side surface of the insulating layer 280 in the opening portion 290. With such a structure, the opening portion 290 can be formed in the conductive layer 240 and the insulating layer 280 at a time. When the side surface of the conductive layer 240 and the side surface of the insulating layer 280 are aligned with each other in the opening portion 290, the thickness distributions of the insulating layer 235, the oxide semiconductor layer 230, and the like provided inside the opening portion 290 can be uniform. In addition, the insulating layer 235, the oxide semiconductor layer 230, and the like can be inhibited from being divided by a step or the like between the conductive layer 240 and the insulating layer 280.

Although FIG. 2B and FIG. 2C illustrate the structure where the side surface of the conductive layer 240 in the opening portion 290 and the side surface of the insulating layer 280 in the opening portion 290 are flush with each other (also referred to as being aligned or substantially aligned with each other), the present invention is not limited thereto. For example, the side surface of the conductive layer 240 in the opening portion 290 and the side surface of the insulating layer 280 in the opening portion 290 may be discontinuous. The inclination of the side surface of the conductive layer 240 in the opening portion 290 and the inclination of the side surface of the insulating layer 280 in the opening portion 290 may be different from each other. At this time, for example, the taper angle of the side surface of the conductive layer 240 in the opening portion 290 is preferably smaller than that of the side surface of the insulating layer 280 in the opening portion 290. With such a structure, the coverage of the side surface of the conductive layer 240 with the oxide semiconductor layer 230 in the opening portion 290 is improved, so that defects such as voids can be reduced. In the case where the insulating layer 280 has a stacked-layer structure, the inclinations of the side surfaces of the layers in the opening portion 290 may be different from each other. Similarly, in the case where the conductive layer 240 has a stacked-layer structure, the inclinations of the side surfaces of the layers in the opening portion 290 may be different from each other.

The channel length of the transistor 200 can be regarded as a distance between the source region and the drain region. In other words, the channel length of the transistor 200 is determined by the height of the insulating layer 235. It is can be said that the channel length of the transistor 200 is determined also by the depth of the depressed portion (specifically, the second depressed portion) of the conductive layer 220, the thickness of the insulating layer 280 over the conductive layer 220, and the thickness of the conductive layer 240. In the case where the channel length of the transistor 200 is regarded as the distance between the source region and the drain region, the channel length of the transistor 200 can be a length L1 illustrated in FIG. 5.

The channel length of a planar transistor is limited by the light exposure limit of photolithography, and further miniaturization is difficult. By contrast, in one embodiment of the present invention, the channel length can be determined by the depth of the depressed portion (specifically, the second depressed portion) of the conductive layer 220, the thickness of the insulating layer 280, and the film thickness of the conductive layer 240. Thus, the transistor 200 can have an extremely small channel length that is less than or equal to the light exposure limit of photolithography (e.g., less than or equal to 60 nm, less than or equal to 50 nm, less than or equal to nm, less than or equal to 30 nm, less than or equal to 20 nm, or less than or equal to 10 nm and greater than or equal to 0.1 nm, greater than or equal to 1 nm, or greater than or equal to 5 nm).

Accordingly, the transistor 200 can have higher on-state current and improved frequency characteristics.

In addition, as described above, the channel formation region, the source region, and the drain region can be formed in the opening portion 290. Thus, the occupation area of the transistor 200 can be reduced as compared with a planar transistor in which a channel formation region, a source region, and a drain region are provided separately on the XY plane. Thus, high integration of the semiconductor device can be achieved. In the case where the semiconductor device of one embodiment of the present invention is used for a memory device, the memory capacity per unit area can be increased.

FIG. 2A2 illustrates an example where a plurality of transistors 200 are arranged in a matrix. Specifically, FIG. 2A2 illustrates an example where 5×5 transistors are arranged in the X direction and the Y direction. As illustrated in FIG. 2A2, the transistor 200 is provided at an intersection of a conductive layer 265 extending in the X direction and a conductive layer 240 extending in the Y direction. As illustrated in FIG. 2A2, the diameter of the opening portion 290 can be smaller than the width of the short side of the conductive layer 240 and the width of the short side of the conductive layer 265. Thus, it can be said that the transistor 200 can be highly integrated and miniaturized.

As illustrated in FIG. 2D and FIG. 2E, the insulating layer 235, the oxide semiconductor layer 230, the insulating layer 250, and the conductive layer 265a are provided concentrically. Thus, the side surface of the conductive layer 265a provided at the center faces the side surface of the oxide semiconductor layer 230 with the insulating layer 250 therebetween. That is, in the plan view, all the circumference of the oxide semiconductor layer 230 serves as the channel formation region. In this case, for example, the channel width of the transistor 200 is determined by the length of the outer circumference of the oxide semiconductor layer 230. In other words, the channel width of the transistor 200 is determined by the width of the opening portion 290 (the diameter in the case where the opening portion 290 is circular in the plan view). FIG. 2B, FIG. 2C and FIG. 2E each illustrate a width D of the opening portion 290, and FIG. 2E illustrates a channel width W of the transistor 200. By increasing the width D of the opening portion 290, the channel width per unit area can be increased and the on-state current can be increased.

Note that the width D of the opening portion 290 changes in the depth direction in some cases. Here, the shortest distance between two side surfaces of the conductive layer 240 on the opening portion 290 side in a cross-sectional view is particularly used as the width D. In other words, the minimum width of the opening portion 290 in the conductive layer 240 is used as the width D of the opening portion 290. The width of the opening portion 290 at the highest position, the width of the opening portion 290 at the lowest position, or the width of the opening portion 290 at the midpoint therebetween in the conductive layer 240, or the average value of these three widths may be used as the width D. Although an example in which the width D is determined using the width of the opening portion 290 of the conductive layer 240 is described here, there is no particular limitation on the method for determining the width D. For example, the shortest distance between two side surfaces of the insulating layer 280 on the opening portion 290 side can be used as the width D. The width of the opening portion 290 at the highest position, the width of the opening portion 290 at the lowest position, or the width of the opening portion 290 at the midpoint therebetween in the insulating layer 280, or the average value of these three widths may be used as the width D.

In the case where the opening portion 290 is formed by a photolithography method, the width D of the opening portion 290 is determined by the light exposure limit of photolithography. In addition, the width D of the opening portion 290 is determined by the thicknesses of the insulating layer 235, the oxide semiconductor layer 230, the insulating layer 250, and the conductive layer 265a that are provided inside the opening portion 290. The width D of the opening portion 290 is preferably, for example, greater than or equal to 5 nm, greater than or equal to 10 nm, or greater than or equal to nm and less than or equal to 100 nm, less than or equal to 60 nm, less than or equal to 50 nm, less than or equal to 40 nm, or less than or equal to 30 nm. Here, the width (thickness) of the insulating layer 235 is referred to as a width Tsw as illustrated in FIG. 5. In the case where the opening portion 290 is circular in the plan view, the width D of the opening portion 290 corresponds to the diameter of the opening portion 290, and the channel width W can be calculated to be “(D−2×Tsw)×π”.

The channel length L of the transistor 200 is preferably less than at least the channel width W of the transistor 200. The channel length L of the transistor 200 is preferably greater than or equal to 0.1 times and less than or equal to 0.99 times, further preferably greater than or equal to 0.5 times and less than or equal to 0.8 times the channel width W of the transistor 200. This structure enables a transistor with favorable electrical characteristics and high reliability.

As described above, in the case where the opening portion 290 is formed to have a circular shape in the plan view, the insulating layer 235, the oxide semiconductor layer 230, the insulating layer 250, and the conductive layer 265a are formed concentrically. This makes the distance between the conductive layer 265a and the oxide semiconductor layer 230 substantially uniform, so that a gate electric field can be substantially uniformly applied to the oxide semiconductor layer 230.

Although this embodiment describes the example where the opening portion 290 has a circular shape in the plan view, the present invention is not limited thereto. The opening portion 290 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be a concave polygonal shape (a polygonal shape at least one of the interior angles of which is greater than 180°) or a convex polygonal shape (a polygonal shape all the interior angles of which are less than or equal to) 180°. As illustrated in FIG. 2A1 and the like, the opening portion 290 in the plan view preferably has a circular shape. When the opening portion has a circular shape, processing accuracy in forming the opening portion can be high, whereby the opening portion can be formed to have a minute size. In this specification and the like, a circle is not necessarily a perfect circle.

### <Constituent Material of Semiconductor Device>

Materials that can be used for the semiconductor device of this embodiment will be described below. Note that the layers included in the semiconductor device of this embodiment may each have a single-layer structure or a stacked-layer structure.

### [Oxide Semiconductor Layer 230]

As described above, the oxide semiconductor layer 230 includes the channel formation region. The oxide semiconductor layer 230 further includes the source region and the drain region.

The source region and the drain region are each an n-type region (a low-resistance region) having a higher carrier concentration than the channel formation region. The oxide semiconductor layer 230 may have a stacked-layer structure of two or more layers.

There is no particular limitation on the crystallinity of a semiconductor material used for the oxide semiconductor layer 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The metal oxide functioning as a semiconductor preferably has a band gap larger than or equal to 2.0 eV, further preferably larger than or equal to 2.5 eV. With the use of a metal oxide having a larger band gap, the off-state current of the transistor can be reduced. The off-state current of an OS transistor is low, so that power consumption of the semiconductor device can be adequately reduced. The OS transistor has excellent frequency characteristics, which enables the semiconductor device to operate at high speed.

For the oxide semiconductor layer that can be used as the semiconductor layer of the transistor according to one embodiment of the present invention, the description in Embodiment 2 can be referred to. Here, detailed description is omitted.

Note that for the semiconductor device of this embodiment, a transistor including another semiconductor material in a channel formation region may be used. Examples of another semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. In addition, these semiconductor materials may include an impurity as a dopant.

As examples of silicon that can be used for the semiconductor material for the transistor, single crystal silicon, polycrystalline silicon, microcrystalline silicon, and amorphous silicon can be given. An example of the polycrystalline silicon is low-temperature polysilicon (LTPS).

The semiconductor layer of the transistor may include a layered substance that functions as a semiconductor. Note that the details of the layered substance will be described in Embodiment 5.

### [Insulating Layer]

An inorganic insulating film is preferably used for each of the insulating layers (the insulating layer 210, the insulating layer 250, the insulating layer 235, the insulating layer 280, and the like) included in the semiconductor device. Examples of the inorganic insulating films include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

As miniaturization and high integration of transistors progress, for example, a problem such as a leakage current may arise because of a thinner gate insulating layer. When a high-k material is used for a gate insulating layer, the voltage at the time of the operation of the transistor can be reduced with the physical thickness of the gate insulating layer maintained. In addition, the equivalent oxide thickness (EOT) of the gate insulating layer can be reduced. In contrast, when a low-relative-permittivity material is used for the insulating layer functioning as an interlayer film, the parasitic capacitance generated between wirings can be reduced. Thus, a material can be selected depending on the function of an insulating layer. Note that the low-relative-permittivity material is also a material with high dielectric strength.

Examples of a high-relative-permittivity material (high-k material) include aluminum oxide, gallium oxide, hafnium oxide, tantalum oxide, zirconium oxide, hafnium zirconium oxide, an oxide including aluminum and hafnium, an oxynitride including aluminum and hafnium, an oxide including silicon and hafnium, an oxynitride including silicon and hafnium, and a nitride including silicon and hafnium.

Examples of the low-relative-permittivity material include inorganic insulating materials such as silicon oxide, silicon oxynitride, and silicon nitride oxide, and resins such as polyester, polyolefin, polyamide (e.g., nylon and aramid), polyimide, polycarbonate, and acrylic resin. Other examples of an inorganic insulating material with low relative permittivity include silicon oxide to which fluorine is added, silicon oxide to which carbon is added, and silicon oxide to which carbon and nitrogen are added. Another example is porous silicon oxide. Note that these silicon oxides may include nitrogen.

A material that can have ferroelectricity may be used for the insulating layer included in the semiconductor device. Examples of the material that can have ferroelectricity include metal oxides such as hafnium oxide, zirconium oxide, and HfZrOx (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or an ratio in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or an ratio in the neighborhood thereof. As the material that can have ferroelectricity, a piezoelectric ceramic having a perovskite structure, such as lead titanate (PbTiOx), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride including an element M1, an element M2, and nitrogen. Here, the element M1 is one or more selected from aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide including the element M1 and nitrogen has ferroelectricity in some cases even though the metal oxide does not include the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a K-alumina-type structure, and the like.

Although metal oxides and metal nitrides are given as examples in the above description, there is not limitation thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound including a plurality of materials selected from the above-listed materials can be used, for example. Alternatively, the insulating layer 130 described in Embodiment 3 can have a stacked-layer structure of a plurality of materials selected from the above-listed materials. Note that the crystal structures (properties) of the above-listed materials and the like can be changed depending on the processes as well as the formation conditions; thus, a material that exhibits ferroelectricity is referred to not only as a ferroelectric but also as a material that can have ferroelectricity in this specification and the like.

A metal oxide including one or both of hafnium and zirconium can have ferroelectricity even when being processed into a thin film of several nanometers. A metal oxide including one or both of hafnium and zirconium can have ferroelectricity even with a minute area. Accordingly, the use of a metal oxide containing one or both of hafnium and zirconium enables miniaturization of the semiconductor device.

Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

It is considered that ferroelectricity is exhibited by displacement of oxygen or nitrogen of a crystal included in a ferroelectric layer due to an external electric field. Ferroelectricity is presumably exhibited depending on the crystal structure of a crystal included in a ferroelectric layer. Thus, in order that the insulating layer can exhibit ferroelectricity, the insulating layer 130 needs to include a crystal. It is particularly preferable that the insulating layer include a crystal having an orthorhombic crystal structure to exhibit ferroelectricity. Note that a crystal structure of a crystal included in the insulating layer may be one or more selected from a cubic crystal structure, a tetragonal crystal structure, an orthorhombic crystal structure, a monoclinic crystal structure, and a hexagonal crystal structure. Alternatively, the insulating layer may have an amorphous structure. In that case, the insulating layer may have a composite structure including an amorphous structure and a crystal structure.

Addition of a Group 3 element (also referred to as a IIIa element) in the periodic table of the elements to an oxide including one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide including one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of Group 3 element atoms in the total number of atoms of all the metal elements included in the layer. The Group 3 element is preferably one or more selected from scandium, lanthanum, and yttrium, further preferably one or both of lanthanum and yttrium.

When a transistor using a metal oxide is surrounded by an insulating layer having a function of inhibiting passage of impurities and oxygen, the transistor can have stable electrical characteristics. As the insulating layer having a function of inhibiting passage of impurities and oxygen, a single layer or stacked layers of insulating layers including one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used, for example. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

Specific examples of the insulating layer having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulating layer having a function of inhibiting the passage of oxygen and impurities such as water and hydrogen include oxides including aluminum and hafnium (hafnium aluminate). Other examples of the insulating layer having a function of inhibiting the passage of oxygen and impurities such as water and hydrogen include nitrides such as aluminum nitride, aluminum titanium nitride, silicon nitride oxide, and silicon nitride.

An insulating layer in contact with an oxide semiconductor layer, such as a gate insulating layer, or an insulating layer provided in the vicinity of the oxide semiconductor layer is preferably an insulating layer including a region including oxygen that is released by heating. For example, when an insulating layer including a region containing excess oxygen is in contact with an oxide semiconductor layer or positioned in the vicinity of the oxide semiconductor layer, oxygen vacancies included in the oxide semiconductor layer can be reduced. Examples of an insulating layer in which a region containing excess oxygen is easily formed include silicon oxide, silicon oxynitride, and porous silicon oxide.

Examples of a material for an insulating layer having a function of capturing or fixing hydrogen include metal oxides such as an oxide including hafnium, an oxide including magnesium, an oxide including aluminum, and an oxide including aluminum and hafnium (hafnium aluminate). These metal oxides may further include zirconium, and an oxide including hafnium and zirconium is given as an example. In a metal oxide having an amorphous structure, some oxygen atoms have a dangling bond, which allows the metal oxide to have a high capability of capturing or fixing hydrogen. Thus, these metal oxides preferably have an amorphous structure. For example, these oxides may have an amorphous structure by including silicon. For example, an oxide including hafnium and silicon (hafnium silicate) is preferably used. Note that part of the metal oxide includes one or both of a crystal region and a crystal grain boundary in some cases.

Note that a function of capturing or fixing a target substance can also be referred to as a property that does not easily allow diffusion of a target substance. Thus, a function of capturing or fixing a target substance can be rephrased as a barrier property.

Examples of a material for the barrier insulating layer against hydrogen include aluminum oxide, magnesium oxide, hafnium oxide, gallium oxide, silicon nitride, and silicon nitride oxide.

Note that in this specification and the like, a barrier insulating layer refers to an insulating layer having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). In addition, hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

The insulating layer 210 functions as an interlayer film and thus can be formed using a low-relative-permittivity material. When a low-relative-permittivity material is used for an interlayer film, the parasitic capacitance generated between wirings can be reduced.

The concentration of impurities such as water and hydrogen in the insulating layer 210 is preferably reduced. This can inhibit entry of impurities such as water and hydrogen into the channel formation region of the oxide semiconductor layer 230.

The insulating layer 280 can include any of the oxide insulating film, the oxynitride insulating film, and the insulating layer including a region containing excess oxygen, which are described above.

For example, the insulating layer including a region containing excess oxygen can be formed by a sputtering method in an oxygen-containing atmosphere. With the use of a sputtering method, which does not need to use a molecule containing hydrogen for a film formation gas, the hydrogen concentration in the insulating layer 280 can be reduced. When at least part of the layers included in the insulating layer 280 is formed by a sputtering method in this manner, oxygen can be supplied from the insulating layer 280 to the channel formation region of the oxide semiconductor layer 230, so that oxygen vacancies and VoH can be reduced.

The concentration of impurities such as water and hydrogen in the insulating layer 280 is preferably reduced. This can inhibit entry of impurities such as water and hydrogen into the channel formation region of the oxide semiconductor layer 230.

Note that since the thickness of the insulating layer 280 over the conductive layer 220 affects the channel length of the transistor 200, the thickness of the insulating layer 280 can be set as appropriate depending on the design value of the channel length of the transistor 200.

For the insulating layer having a function of capturing and fixing hydrogen, hafnium silicate is preferably used, for example. The insulating layer preferably has an amorphous structure.

The above insulating layer having an amorphous structure can inhibit formation of a crystal grain boundary. Inhibiting the formation of a crystal grain boundary can increase the planarity of the insulating layer. This makes the thickness distribution of the insulating layer uniform, enabling the number of extremely thin portions to be reduced, and thus the breakdown voltage of the insulating layer can be improved. In addition, the thickness distribution of a film provided on the insulating layer can be uniform.

Moreover, inhibiting the formation of a crystal grain boundary in the insulating layer can reduce leakage current due to the defect states in the crystal grain boundary. Thus, the insulating layer can function as an insulating film with little leakage current.

Since hafnium oxide is a high permittivity (high-k) material, hafnium silicate becomes a high permittivity (high-k) material depending on the content of silicon. Accordingly, in the case of using hafnium oxide or hafnium silicate for the gate insulating layer, a gate potential applied during operation of the transistor can be reduced with the physical thickness of the gate insulating layer maintained. In addition, the equivalent oxide thickness (EOT) of the gate insulating layer can be reduced.

As described above, for the above insulating layer, an oxide including one or both of aluminum and hafnium is preferably used, an oxide having an amorphous structure and including one or both of aluminum and hafnium is further preferably used, and an aluminum oxide having an amorphous structure is still further preferably used.

The insulating layer 250 may include, between a pair of insulating layers having a function of capturing hydrogen and fixing hydrogen, an insulating layer with a thermally stable structure.

The insulating layer 250 preferably includes a barrier insulating layer against oxygen. This can inhibit oxidation of the conductive layer 240, the conductive layer 265, and the like. In the case where the insulating layer 250 has a stacked-layer structure, a layer in contact with the conductive layer 240 is preferably a barrier insulating layer against oxygen. In particular, among layers included in the insulating layer 250, a layer in contact with the conductive layer 240 and a layer in contact with the conductive layer 265 are each preferably a barrier insulating layer against oxygen. When a barrier insulating layer against hydrogen and oxygen is used as the layer of the insulating layer 250 that is in contact with the conductive layer 265, oxidation of the conductive layer 265 can be inhibited. Moreover, diffusion of oxygen included in the oxide semiconductor layer 230 into the conductive layer 265 and formation of oxygen vacancies in the oxide semiconductor layer 230 can be inhibited.

Examples of the barrier insulating layer against oxygen include an oxide including one or both of aluminum and hafnium, magnesium oxide, gallium oxide, gallium zinc oxide, silicon nitride, and silicon nitride oxide. Examples of the oxide including one or both of aluminum and hafnium include aluminum oxide, hafnium oxide, an oxide including aluminum and hafnium (hafnium aluminate), and an oxide including hafnium and silicon (hafnium silicate).

The layer in the insulating layer 250 that is in contact with the conductive layer 240 is preferably less likely to transmit oxygen. When the layer has a barrier property against oxygen, oxidation of the side surface of the conductive layer 240 and formation of an oxide film on the side surface can be inhibited. Accordingly, a decrease in the on-state current or field-effect mobility of the transistor 200 can be inhibited.

The silicon oxide film included in the insulating layer 250 is preferably formed by a PEALD method. The thickness of the silicon oxide film included in the insulating layer 250 is preferably greater than or equal to 0.7 nm and less than or equal to 3 nm. An ALD method enables atomic layers to be deposited one by one, and has advantages such as deposition of an extremely thin film, deposition of a film on a component with a high aspect ratio or on a surface with a large step, deposition of a film with few defects such as pinholes, deposition of a film with excellent coverage, and low-temperature deposition. Thus, by an ALD method, the coverage of the sidewall and bottom surface of the opening portion 290 with the insulating layer 250 can be increased in the transistor of one embodiment of the present invention, so that the insulating layer 250 with a uniform thickness can be formed. The use of plasma in a PEALD method enables deposition at a lower temperature. Furthermore, when plasma is utilized, the deposition rate can be increased and the productivity can be increased.

The insulating layer 250 is preferably formed with two or more kinds of films. When the insulating layer 250 includes two or more kinds of films, the insulating layer 250 can have a plurality of functions. Examples of the functions of the insulating layer 250 include a function of extracting hydrogen from the oxide semiconductor layer 230 and a function of inhibiting diffusion of hydrogen into the oxide semiconductor layer 230. Note that in the formation of the insulating layer 250, an ALD process is preferably used twice or more. For example, the insulating layer 250 preferably has a stacked-layer structure of a plurality of insulating films, and two or more of the plurality of insulating films are preferably formed by an ALD process. When at least two insulating films are formed by an ALD process, the coverage with the insulating layer 250 and the thickness uniformity of the insulating layer 250 can be improved. When two or more kinds of films, e.g., two or more kinds of insulating films are successively formed by an ALD process, the productivity can be increased.

The insulating layer 235 preferably includes a barrier insulating layer against hydrogen. Accordingly, diffusion of hydrogen into the oxide semiconductor layer 230 can be inhibited, and the reliability of the transistor 200 can be improved. For example, aluminum oxide, hafnium oxide, silicon nitride, or silicon nitride oxide is preferably used for the insulating layer 235.

A silicon nitride film included in the insulating layer 235 is preferably formed by a PEALD method. This can improve the coverage of the sidewall of the opening portion 290 with the insulating layer 235, so that the insulating layer 235 with a uniform thickness can be formed.

The above-described material that can have ferroelectricity can also be used for the insulating layer 235.

For example, the insulating layer 235 can have a single-layer structure of a silicon oxide film, a single-layer structure of a silicon nitride film, a two-layer structure of a silicon oxide film and a silicon nitride film, a three-layer structure of a silicon oxide film, a silicon nitride film, and a silicon oxide film, and a three-layer structure of a silicon nitride film, a silicon oxide film, and a silicon nitride film. In the case of the two-layer structure of a silicon oxide film and a silicon nitride film, for example, it is preferable that the silicon oxide film be provided on the oxide semiconductor layer 230 side and the silicon nitride film be provided on the insulating layer 280 side. Accordingly, oxygen can be efficiently supplied to the oxide semiconductor layer 230, and diffusion of impurities such as hydrogen into the oxide semiconductor layer 230 can be inhibited. Alternatively, the silicon nitride film may be provided on the oxide semiconductor layer 230 side, and the silicon oxide film may be provided on the insulating layer 280 side.

[Conductive layer]

For each of the conductive layers included in the semiconductor device (e.g., the conductive layer 220, the conductive layer 240, and the conductive layer 265), it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy including any of the above metal elements, a nitride of the alloy or an oxide of the alloy may be used. For example, it is preferable to use tantalum nitride, titanium nitride, a nitride including titanium and aluminum, a nitride including tantalum and aluminum, ruthenium oxide, ruthenium nitride, an oxide including strontium and ruthenium, an oxide including lanthanum and nickel, or the like. Alternatively, a semiconductor having high electrical conductivity, typified by polycrystalline silicon including an impurity element such as phosphorus, or silicide such as nickel silicide may be used.

A conductive material including nitrogen, such as a nitride including tantalum, a nitride including titanium, a nitride including molybdenum, a nitride including tungsten, a nitride including ruthenium, a nitride including tantalum and aluminum, or a nitride including titanium and aluminum; a conductive material including oxygen, such as ruthenium oxide, an oxide including strontium and ruthenium, or an oxide including lanthanum and nickel; or a material including a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include an indium oxide containing tungsten oxide, an indium oxide containing titanium oxide, an indium tin oxide (also referred to as ITO), an indium tin oxide containing titanium oxide, an indium tin oxide containing silicon (also referred to as ITSO), an indium zinc oxide (also referred to as IZO (a registered trademark)), and an indium zinc oxide containing tungsten oxide. In this specification and the like, a conductive film formed using the conductive material including oxygen may be referred to as an oxide conductive film.

A conductive material including tungsten, copper, or aluminum as its main component is preferable because it has high conductivity.

A stack of a plurality of conductive layers formed of the above-described materials may be used. For example, a stacked-layer structure combining a material including the above metal element and a conductive material including oxygen may be employed. In addition, a stacked-layer structure combining a material including the above metal element and a conductive material including nitrogen may be employed. Furthermore, a stacked-layer structure combining a material including the above metal element, a conductive material including oxygen, and a conductive material including nitrogen may be employed.

In the case where a metal oxide is used for the channel formation region of the transistor, the conductive layer functioning as the gate electrode preferably employs a stacked-layer structure combining a material including the above metal element and a conductive material including oxygen. In that case, the conductive material including oxygen is preferably provided on the channel formation region side. When the conductive material including oxygen is provided on the channel formation region side, oxygen released from the conductive material is easily supplied to the channel formation region.

Each of the conductive layer 220 and the conductive layer 240 are in contact with the oxide semiconductor layer 230, and is thus preferably formed using a conductive material that is not easily oxidized, a conductive material that maintains its low electrical resistance even after being oxidized, a metal oxide having conductivity (also referred to as an oxide conductor), or a conductive material that has a function of inhibiting diffusion of oxygen. Examples of the conductive material include a conductive material including nitrogen and a conductive material including oxygen. This can inhibit a decrease in the conductivity of the conductive layer 220 and the conductive layer 240.

When a conductive material containing oxygen is used for the conductive layer 220 or the conductive layer 240, the conductive layer 220 or the conductive layer 240 can maintain its conductivity even after absorbing oxygen. In addition, also in the case of using an insulating layer containing oxygen, e.g., hafnium oxide, as the insulating layer 210, the conductive layer 220 can maintain its conductivity, which is preferable. For each of the conductive layer 220 and the conductive layer 240, ITO, ITSO, IZO (registered trademark), or the like is preferably used, for example.

FIG. 3A illustrates an example where the conductive layer 220 has a three-layer structure of a conductive layer 220al, a conductive layer 220a2 over the conductive layer 220al, and the conductive layer 220b over the conductive layer 220a2. In other words, FIG. 3A illustrates an example where the conductive layer 220a has a two-layer structure of the conductive layer 220al and the conductive layer 220a2 over the conductive layer 220al. In that case, for example, a conductive material that is not easily oxidized or a conductive material that has a function of inhibiting diffusion of oxygen is preferably used for the conductive layer 220al, a conductive material that has high conductivity is preferably used for the conductive layer 220a2, and a conductive material that includes oxygen (further preferably an oxide conductor) is preferably used for the conductive layer 220b. Specifically, for example, titanium nitride is preferably used for the conductive layer 220a1, tungsten is preferably used for the conductive layer 220a2, and an oxide conductor (e.g., ITO, ITSO, or IZO (registered trademark)) is preferably used for the conductive layer 220b. In that case, titanium nitride is in contact with the insulating layer 210 and the oxide conductor is in contact with the oxide semiconductor layer 230. In addition, the oxide conductor is used for the layer closest to the channel formation region of the oxide semiconductor layer 230. Since the oxide conductor has a lower contact resistance with the oxide semiconductor layer 230 than tungsten, the current path between the source and the drain can be shortened and the on-state current of the transistor can be increased. Such a structure enables the conductive layer 220 to maintain its conductivity even when the conductive layer 220 is in contact with the oxide semiconductor layer 230. In the case of using an oxide insulating layer as the insulating layer 210, excessive oxidation of the conductive layer 220 due to the insulating layer 210 can be inhibited. When a metal material (here, tungsten) having higher conductivity than an oxide conductor and titanium nitride is used for the conductive layer 220a2, the conductivity of the conductive layer 220 can be increased.

FIG. 3A illustrates an example where the conductive layer 240 has a two-layer structure of the conductive layer 240a and the conductive layer 240b over the conductive layer 240a. Here, for example, a conductive material including oxygen is preferably used for the conductive layer 240b, and a material having higher conductivity than the material for the conductive layer 240b is preferably used for the conductive layer 240a. Specifically, for example, an oxide conductor (e.g., ITO, ITSO, or IZO (registered trademark)) is preferably used for the conductive layer 240b, and tungsten is preferably used for the conductive layer 240a. Alternatively, ruthenium, titanium nitride, tantalum nitride, or the like may be used for the conductive layer 240a.

In the conductive layer 240, the conductive layer 240b is mainly in contact with the oxide semiconductor layer 230. An oxide conductor is preferably used for the conductive layer 240b, which can reduce the contact resistance with the oxide semiconductor layer 230. A material having higher conductivity than an oxide conductor is preferably used for a layer included in the conductive layer 240, in which case the conductivity of the conductive layer 240 can be increased.

Note that a conductive material including oxygen can be used for the conductive layer 240a, and a material having higher conductivity than the material for the conductive layer 240a can be used for the conductive layer 240b. In that case, an oxide conductor is used for the layer of the conductive layer 240 which is closest to the channel formation region in the oxide semiconductor layer 230. Thus, the current path between the source and the drain can be shortened, so that the amount of the on-state current of the transistor can be increased.

The conductive layer 265 is preferably formed using a material with high conductivity such as tungsten. In addition, a conductive material that is not easily oxidized, a conductive material having a function of inhibiting diffusion of oxygen, or the like is preferably used for the conductive layer 265. Examples of the conductive material include a conductive material including nitrogen (e.g., titanium nitride or tantalum nitride) and a conductive material including oxygen (e.g., ruthenium oxide), as described above. This can inhibit a decrease in the conductivity of the conductive layer 265.

It is preferable to use, for the conductive layer 265, a conductive material containing oxygen and a metal element contained in the metal oxide where the channel is formed. A conductive material including the above metal element and nitrogen (e.g., titanium nitride or tantalum nitride) may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide including nitrogen may be used. With the use of such a material, hydrogen included in the metal oxide where the channel is formed can be captured in some cases. Alternatively, hydrogen entering from an external insulating layer or the like can be captured in some cases.

FIG. 3A illustrates an example where the conductive layer 265 has a two-layer structure of the conductive layer 265a and the conductive layer 265b over the conductive layer 265a. In this case, titanium nitride is preferably used for the conductive layer 265a, and tungsten is preferably used for the conductive layer 265b, for example. Alternatively, tantalum nitride is preferably used for the conductive layer 265a, and copper is preferably used for the conductive layer 265b. Such a structure can increase the conductivity of the conductive layer 265.

The conductive layer 265 may have a stacked-layer structure of three or more layers. The conductive layer 265 may have a three-layer structure of tantalum nitride, titanium nitride over the tantalum nitride, and tungsten over the titanium nitride, for example.

The conductive layer 265 functions as the gate wiring and thus preferably has high conductivity. For the conductive layer 265, tungsten is preferably used. For example, a two-layer structure of titanium nitride and tungsten may be employed.

### [Substrate]

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, any of these substrates provided with elements may be used. Examples of the elements provided for the substrates include a capacitor element, a resistor element, a switching element, a light-emitting element, and a memory element.

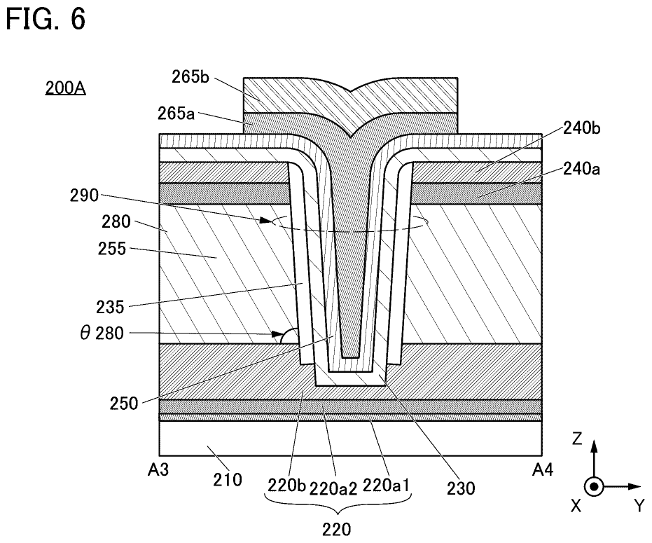

Structure examples of transistors whose structures are partly different from that of the transistor 200 will be described below with reference to FIG. 6 to FIG. 16. Note that description of the portions overlapping with the above is omitted and only different points will be described in detail. Even when positions or shapes of components are different from those in the above example, the same reference numerals are used as long as the components have the same functions as those in the above example, and description thereof is omitted in some cases.

### [Transistor 200A]

FIG. 6 is a cross-sectional view of a semiconductor device including a transistor 200A.

FIG. 6 illustrates an example where the sidewall of the opening portion 290 has a tapered shape. When the sidewall of the opening portion 290 has a tapered shape, the coverage with the insulating layer 235, the oxide semiconductor layer 230, the insulating layer 250, and the like can be improved, so that defects such as voids can be reduced. In the case where the sidewall of the opening portion 290 has a tapered shape, a taper angle θ280 of the side surface of the insulating layer 280 in the opening portion 290 is preferably greater than or equal to 45° and less than 90°, for example. Specifically, the angle is preferably greater than or equal to 80° and less than 90°, in which case the semiconductor device can be miniaturized or highly integrated as described above. Moreover, the angle is preferably greater than or equal to 45° or greater than or equal to 50° and less than 80°, less than or equal to 75°, less than or equal to 70°, less than or equal to 65°, or less than or equal to 60°, in which case the coverage with a film to be formed in the opening portion 290 is improved.

Alternatively, for example, the sidewall of the opening portion 290 may have an inverse tapered shape. In other words, the taper angle θ280 of the side surface of the insulating layer 280 in the opening portion 290 may be greater than 90°.

### [Transistor 200B]

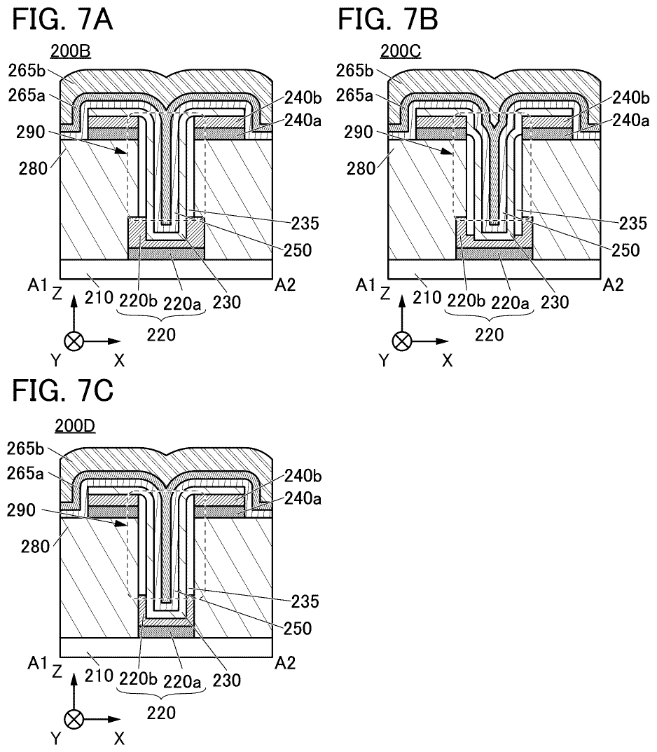

FIG. 7A is a cross-sectional view of a semiconductor device including the transistor 200B.

The transistor 200B is different from the transistor 200 mainly in that only one depressed portion is provided in the conductive layer 220b.

In the conductive layer 220b, a depressed portion can be formed in one or both of a step of forming the opening portion 290 and a step of forming the insulating layer 235. In the example of the transistor 200, a depressed portion is formed in the conductive layer 220b in both of the steps; by contrast, in the example of the transistor 200B, a depressed portion is formed in the conductive layer 220b not in the step of forming the opening portion 290 but in the step of forming the insulating layer 235.

In the transistor 200B, the insulating layer 235 is in contact with the side surface of the insulating layer 280, the side surface of the conductive layer 240a, the side surface of the conductive layer 240b, and the top surface of the conductive layer 220b in the opening portion 290. The oxide semiconductor layer 230 is in contact with the bottom surface and the side surface of the depressed portion of the conductive layer 220b.

When a depressed portion is formed in the conductive layer 220b in at least one of the step of forming the opening portion 290 and the step of forming the insulating layer 235, the height of the bottom surface of the conductive layer 265a in the opening portion 290 can be made low; accordingly, a gate electric field can be easily applied to the channel formation region of the oxide semiconductor layer 230 and the electrical characteristics of the transistor 200B can be improved.

A depressed portion is preferably formed in the conductive layer 220b in the step of forming the insulating layer 235, in which case the oxide semiconductor layer 230 can be in contact with the bottom surface and the side surface of the depressed portion of the conductive layer 220b, so that the contact area between the oxide semiconductor layer 230 and the conductive layer 220b is increased and accordingly the contact resistance between the oxide semiconductor layer 230 and the conductive layer 220 can be reduced.

### [Transistor 200C]

FIG. 7B is a cross-sectional view of a semiconductor device including the transistor 200C.

The transistor 200C is different from the transistor 200 mainly in that the insulating layer 235 does not cover the side surface of the conductive layer 240b.

The insulating layer 235 illustrated in FIG. 7B is in contact with the bottom surface and the side surface of the depressed portion of the conductive layer 220, and is in contact with the side surface of the insulating layer 280 in the opening portion 290. The insulating layer 235 is in contact with part of the side surface of the conductive layer 240a and not in contact with the side surface of the conductive layer 240b. The insulating layer 235 may be in contact with one or more of the side surface of the insulating layer 280, the side surface of the conductive layer 240a, and the side surface of the conductive layer 240b in the opening portion 290, or may cover part or the whole of each side surface.

In the case where at least part of the side surface of the conductive layer 240b is not covered with the insulating layer 235, the uncovered part is in contact with the oxide semiconductor layer 230. Thus, the contact area between the oxide semiconductor layer 230 and the conductive layer 240 can be increased and the contact resistance between the oxide semiconductor layer 230 and the conductive layer 240 can be reduced, which is preferable. Similarly, in the case where the side surface of the conductive layer 240b and at least part of the side surface of the conductive layer 240a are not covered with the insulating layer 235, the uncovered part is in contact with the oxide semiconductor layer 230. Thus, the contact area between the oxide semiconductor layer 230 and the conductive layer 240 can be increased and the contact resistance between the oxide semiconductor layer 230 and the conductive layer 240 can be reduced, which is preferable.

### [Transistor 200D]

FIG. 7C is a cross-sectional view of a semiconductor device including the transistor 200D.

The transistor 200D is different from the transistor 200 mainly in that the side surface of the conductive layer 220 is aligned with the side surface of the conductive layer 240 and the side surface of the insulating layer 280 in the opening portion 290.

The width of the conductive layer 220 in the cross-sectional view corresponds to the width of the opening portion 290. With such a structure, the parasitic capacitance between the conductive layer 220 and the conductive layer 240 can be reduced, which is preferable.

### [Transistors 200E, 200F]

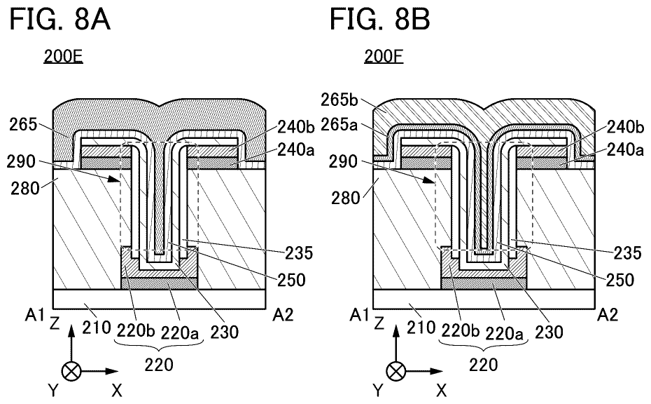

FIG. 8A is a cross-sectional view of a semiconductor device including the transistor 200E. FIG. 8B is a cross-sectional view of a semiconductor device including the transistor 200F.

The transistor 200E is different from the transistor 200 mainly in not including the conductive layer 265a nor the conductive layer 265b but including the conductive layer 265 having a single-layer structure.

Like the conductive layer 265 included in the transistor 200E, the conductive layer functioning as the gate electrode may have a single-layer structure. The conductive layer 265 is preferably provided to fill the opening portion 290.

The transistor 200F is different from the transistor 200 mainly in that both of the conductive layer 265a and the conductive layer 265b are positioned in the opening portion 290.

In the transistor 200F, the conductive layer 265b is positioned in the opening portion 290. As described above, not only the conductive layer 265a but also the conductive layer 265b is provided in the opening portion 290 in some cases depending on the diameter of the opening portion 290, the thickness of the conductive layer 265a, and the like. [Transistor 200G]

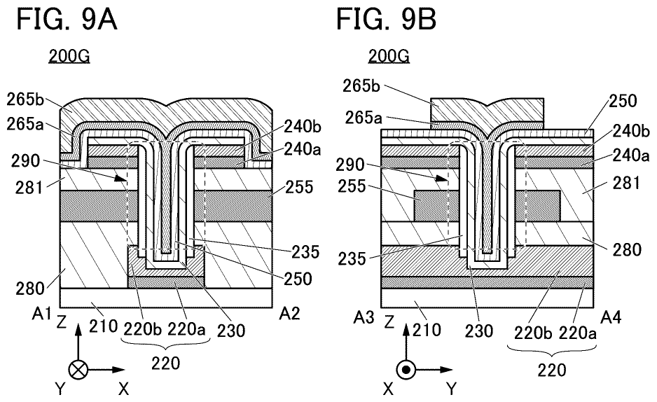

FIG. 9A and FIG. 9B are cross-sectional views of a semiconductor device including a transistor 200G.

The transistor 200G is different from the above-described transistor 200 mainly in including the conductive layer 255 and the insulating layer 281.

The conductive layer 255 is positioned over the insulating layer 280, and the insulating layer 281 is positioned over the conductive layer 255 and the insulating layer 280. The conductive layer 240a is positioned over the insulating layer 281. The insulating layer 281 functions as an interlayer film.

As illustrated in FIG. 9A and FIG. 9B, the opening portion 290 reaching the conductive layer 220 is provided in the insulating layer 280, the conductive layer 255, the insulating layer 281, the conductive layer 240a, and the conductive layer 240b.

In the transistor 200G, the oxide semiconductor layer 230 functions as a semiconductor layer, the conductive layer 265 functions as a first gate electrode, the insulating layer 250 functions as a first gate insulating layer, the conductive layer 220 functions as one of a source electrode and a drain electrode, the conductive layer 240 functions as the other of the source electrode and the drain electrode, the conductive layer 255 functions as a second gate electrode, and the insulating layer 235 functions as a second gate insulating layer.

The oxide semiconductor layer 230 includes a region overlapping with the conductive layer 255 with the insulating layer 235 therebetween and overlapping with the conductive layer 260 with the insulating layer 250 therebetween. At least part of the region functions as the channel formation region of the transistor 200G.

Since the transistor 200G includes a conductive layer functioning as a back gate, the threshold voltage of the transistor 200G can be controlled by a potential supplied to the conductive layer. Thus, by controlling the threshold voltage, a transistor having normally-off characteristics is easily achieved.

In the transistor 200G, either one of the conductive layer 255 and the conductive layer 265 may be used as a gate electrode or the other may be used as a back gate electrode. The transistor 200G has a preferable structure in which the conductive layer 265 is used as the gate electrode and the conductive layer 255 is used as the back gate electrode in some cases. When the conductive layer 265 whose region facing the oxide semiconductor layer 230 is larger than that of the conductive layer 255 is used as the gate electrode, a gate electric field is applied to the oxide semiconductor layer 230 more efficiently; thus, the electrical characteristics of the transistor can be improved in some cases.

In the case where the conductive layer 265 functions as the gate electrode and the conductive layer 255 functions as the back gate electrode, the insulating layer 250 functions as a gate insulating layer and the insulating layer 235 functions as a back gate insulating layer.

As the conductive layer 255, the conductive material that can be used for the conductive layer 265 can be used. As the insulating layer 281, the insulating material that can be used for the insulating layer 280 can be used.

### [Transistor 201]

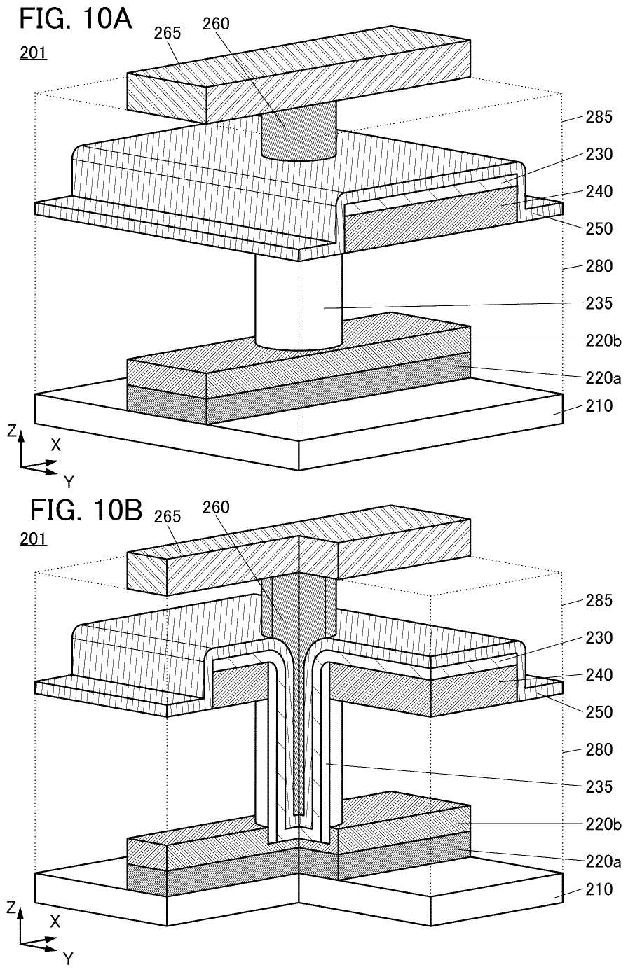

FIG. 10A and FIG. 10B are schematic perspective view of a semiconductor device including the transistor 201. FIG. 10B is a perspective view of FIG. 10A part of which is cut out. In FIG. 10A and FIG. 10B, only the outlines of some components (e.g., interlayer insulating layers) are indicated by dashed lines.

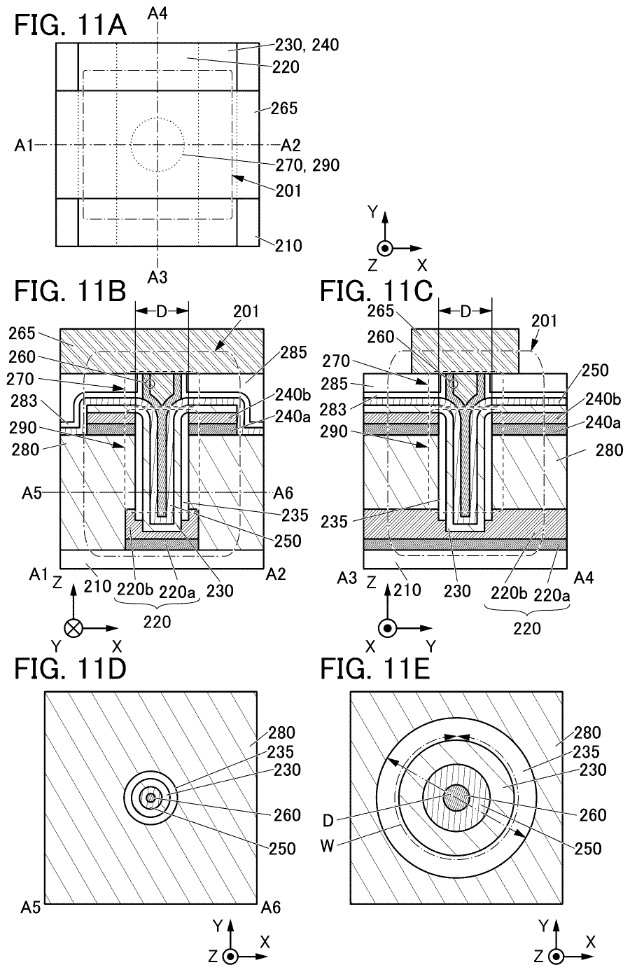

FIG. 11A is a plan view of a semiconductor device including a transistor 201. FIG. 11B is a cross-sectional view along the dashed-dotted line A1-A2 in FIG. 11A. FIG. 11C is a cross-sectional view along the dashed-dotted line A3-A4 in FIG. 11A. FIG. 11D and FIG. 11E are cross-sectional views taken along dashed-dotted line A5-A6 in FIG. 11B. FIG. 11E corresponds to an example of an enlarged view of FIG. 11D. Since the structures in FIG. 11D and FIG. 11E are similar to those in FIG. 2D and FIG. 2E except that the conductive layer 265a is not provided but the conductive layer 260 is provided, the details thereof are not described.

The semiconductor devices illustrated in FIG. 10A to FIG. 11E each include the insulating layer 210 over a substrate (not illustrated), the transistor 201 over the insulating layer 210, the insulating layer 280 over the insulating layer 210, an insulating layer 283, an insulating layer 285 over the insulating layer 283, and the conductive layer 265 over the conductive layer 260, the insulating layer 283, and the insulating layer 285. The insulating layer 210, the insulating layer 280, the insulating layer 283, and the insulating layer 285 each function as an interlayer film.

The transistor 201 includes the conductive layer 220a, the conductive layer 220b over the conductive layer 220a, the conductive layer 240a over the insulating layer 280, the conductive layer 240b over the conductive layer 240a, the insulating layer 235, the oxide semiconductor layer 230, the insulating layer 250 over the oxide semiconductor layer 230, and the conductive layer 260 over the insulating layer 250. Note that the conductive layer 265 may be regarded as a component of the transistor 201. The insulating layer 283 is provided over the insulating layer 250.

The conductive layer 260 functions as a gate electrode of the transistor 201, and the conductive layer 265 functions as a gate wiring. The conductive layer 260 can be formed using a material that can be used for the conductive layer 265.

Since the stacked-layer structure from the conductive layer 220a to the insulating layer 250 in the transistor 201 is similar to that in the transistor 200, the details thereof are not described.

As illustrated in FIG. 11B and FIG. 11C, an opening portion 270 reaching the insulating layer 250 is provided in the insulating layer 283 at a position overlapping with the opening portion 290. The conductive layer 260 is provided such that at least part of the conductive layer 260 is positioned in the opening portion 270. The conductive layer 260 is in contact with the insulating layer 250 in the opening portion 270.

The conductive layer 260 is provided to fill at least part of the opening portion 290 and the opening portion 270. The conductive layer 260 includes a portion facing the oxide semiconductor layer 230 with the insulating layer 250 therebetween in the opening portion 290 and a portion positioned in the opening portion 270.

In the transistor 201, at least one layer included in the conductive layer 260 is provided inside the opening portion 290 and the opening portion 270. In the case where the conductive layer 260 has a stacked-layer structure, as miniaturization of the transistor proceeds and the diameter of the opening portion 290 and the diameter of the opening portion 270 become smaller, it becomes difficult to arrange all the layers included in the conductive layer 260 in the opening portion 290 and the opening portion 270. FIG. 11B and FIG. 11C illustrate an example in which the conductive layer 260 has a two-layer structure, only the first conductive layer of the conductive layer 260 is provided in the opening portion 290, and the first conductive layer and the second conductive layer of the conductive layer 260 are provided in the opening portion 270. Note that both of the first conductive layer and the second conductive layer of the conductive layer 260 are positioned in the opening portion 290 in some cases depending on the diameter of the opening portion 290, the thickness of the conductive layer 260, and the like. Only the first conductive layer of the conductive layer 260 is positioned in the opening portion 270 in some cases depending on the diameter of the opening portion 270, the thickness of the conductive layer 260, and the like.

A portion of the conductive layer 265 that does not overlap with the opening portion 290 is mainly positioned over the insulating layer 285. Thus, the conductive layer 265 mainly overlaps with the conductive layer 240 with the insulating layer 283 and the insulating layer 285 therebetween. This can increase the physical distance between the conductive layer 265 and the conductive layer 240, and thus can reduce the parasitic capacitance generated between the conductive layer 265 and the conductive layer 240. Note that the conductive layer 240 and the conductive layer 265 may include a portion where they overlap with each other without the insulating layer 285 therebetween.

FIG. 11B and FIG. 11C illustrate an example where the width of the opening portion 270 is smaller than the width D of the opening portion 290. A smaller width of the opening portion 270 is preferable because the physical distance between the conductive layer 240 and the conductive layer 260 can be increased and thus the parasitic capacitance generated between the conductive layer 240 and the conductive layer 260 can be reduced. For example, the width of the opening portion 270 is preferably smaller than or equal to that of the opening portion 290.

The top surface of the conductive layer 260 is preferably level with or substantially level with the top surface of the insulating layer 285. The conductive layer 265 is provided over the insulating layer 285, the insulating layer 283, and the conductive layer 260, and is in contact with the top surface of the conductive layer 260. It can be said that the conductive layer 260 and the conductive layer 265 are connected to each other. The insulating layer 283 and the insulating layer 285 are positioned between the conductive layer 265 and the conductive layer 240. This can increase the physical distance between the conductive layer 265 and the conductive layer 240, and thus can reduce the parasitic capacitance generated between the conductive layer 265 and the conductive layer 240.

That is, the transistor 201 has a structure in which the parasitic capacitance generated between the other of the source electrode and the drain electrode and the gate wiring is reduced. Accordingly, the frequency characteristics of a circuit including the transistor can be improved.

Although this embodiment describes the example where the opening portion 270 has a circular shape in the plan view, the present invention is not limited thereto. The shape applicable to the opening portion 270 is any of the above-described shapes applicable to the opening portion 290.

In addition, the width of the opening portion 270 changes in the depth direction in some cases. Here, the maximum width of the opening portion 270 provided in the insulating layer 283 in a cross-sectional view is particularly used as the width of the opening portion 270.

As the insulating layer 283, a barrier insulating layer against hydrogen is preferably used. In that case, diffusion of hydrogen from above the insulating layer 283 into the oxide semiconductor layer 230 can be inhibited. Each of a silicon nitride film and a silicon nitride oxide film can be suitably used as the insulating layer 283 because the silicon nitride film and the silicon nitride oxide film release fewer impurities (e.g., water and hydrogen) and are less likely to transmit oxygen and hydrogen.

Silicon nitride deposited by a sputtering method is particularly preferably used as the insulating layer 283. Since a sputtering method does not need to use a molecule containing hydrogen as a deposition gas, the hydrogen concentration in the insulating layer 283 can be reduced. When the insulating layer 283 is formed by a sputtering method, high-density silicon nitride can be formed.

As the insulating layer 283, an insulating layer having a function of capturing or fixing hydrogen may be used. With such a structure, diffusion of hydrogen from above the insulating layer 283 into the oxide semiconductor layer 230 can be inhibited, and hydrogen contained in the oxide semiconductor layer 230 can be captured or fixed. Thus, the hydrogen concentration in the oxide semiconductor layer 230 can be reduced. For the insulating layer 283, aluminum oxide, hafnium oxide, hafnium silicate, or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

The insulating layer 285 functions as an interlayer film and thus is preferably formed using any of the above-described low-relative-permittivity materials. For example, the insulating layer 285 preferably includes a silicon oxide film.

### [Transistor 201A]

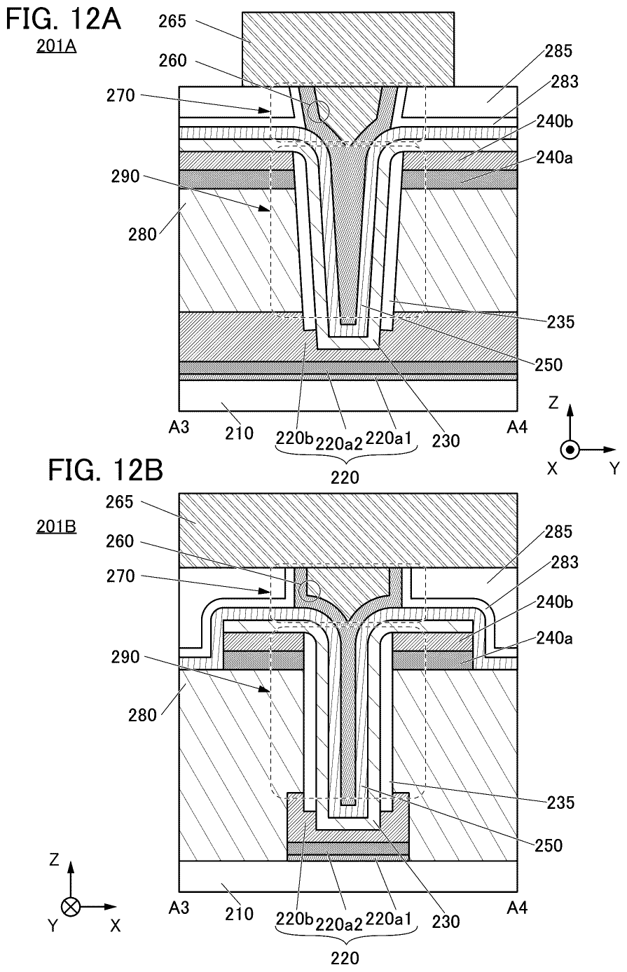

FIG. 12A is a cross-sectional view of the semiconductor device including the transistor 201A.

FIG. 12A illustrates an example where the sidewall of the opening portion 290 has a tapered shape. For the details of the case where the sidewall of the opening portion 290 has a tapered shape, the description of the transistor 200A illustrated in FIG. 6 can be referred to. [Transistor 201B] FIG. 12B is a cross-sectional view of the semiconductor device including the transistor 201B.

As illustrated in FIG. 12B, the width of the opening portion 270 can be larger than the width of the opening portion 290. Accordingly, the area of the conductive layer 260 in a plan view can be increased, so that the contact area between the conductive layer 260 and the conductive layer 265 can be increased.

The mode and details of the transistor 201 can be modified as in the case of the transistor 200. Specifically, the transistor 201 can have a structure similar to that of any of the transistor 200A to the transistor 200G.

### [Transistor 202]

FIG. 13A is a plan view of a semiconductor device including a transistor 202. FIG. 13B is a cross-sectional view along dashed-dotted line A1-A2 in FIG. 13A. FIG. 13C is a cross-sectional view taken along the dashed-dotted line A3-A4 in FIG. 13A. FIG. 13D and FIG. 13E are cross-sectional views taken along dashed-dotted line A5-A6 in FIG. 13B. FIG. 13E corresponds to an example of an enlarged view of FIG. 13D. Since the structures in FIG. 13D and FIG. 13E are similar to those in FIG. 2D and FIG. 2E, the details thereof are not described.

The semiconductor device illustrated in FIG. 13A to FIG. 13E includes the insulating layer 210 over a substrate (not illustrated), the transistor 202 over the insulating layer 210, the insulating layer 280 over the insulating layer 210, the insulating layer 283, and the insulating layer 285 over the insulating layer 283. The insulating layer 210, the insulating layer 280, the insulating layer 283, and the insulating layer 285 each function as an interlayer film.

The transistor 202 includes the conductive layer 220a, the conductive layer 220b over the conductive layer 220a, the conductive layer 240a over the insulating layer 280, the conductive layer 240b over the conductive layer 240a, the insulating layer 235, the oxide semiconductor layer 230, the insulating layer 250 over the oxide semiconductor layer 230, the conductive layer 265a over the insulating layer 250 and the insulating layer 285, and the conductive layer 265b over the conductive layer 265a.

Since the stacked-layer structure from the conductive layer 220a to the insulating layer 250 in the transistor 202 is similar to that in the transistor 200, the details thereof are not described.

As illustrated in FIG. 13B and FIG. 13C, the opening portion 270 reaching the insulating layer 250 is provided in the insulating layer 283 at a position overlapping with the opening portion 290. The conductive layer 265a is provided such that at least part of the conductive layer 265a is positioned in the opening portion 270. Furthermore, the conductive layer 265b is also provided such that at least part of the conductive layer 265b is positioned in the opening portion 270. The conductive layer 265a is in contact with the insulating layer 250 in the opening portion 270.

The conductive layer 265a is provided to fill at least part of the opening portion 290 and the opening portion 270.

In the transistor 202, at least one layer included in the conductive layer 265 is provided inside the opening portion 290 and the opening portion 270. In the case where the conductive layer 265 has a stacked-layer structure, as miniaturization of the transistor proceeds and the diameter of the opening portion 290 and the diameter of the opening portion 270 become smaller, it becomes difficult to place all the layers included in the conductive layer 265 in the opening portion 290 and the opening portion 270. FIG. 13B and FIG. 13C illustrate an example where the conductive layer 265 has a two-layer structure, only the conductive layer 265a is provided in the opening portion 290, and the conductive layer 265a and the conductive layer 265b are provided in the opening portion 270. Note that both of the conductive layer 265a and the conductive layer 265b are positioned in the opening portion 290 in some cases depending on the diameter of the opening portion 290, the thickness of the conductive layer 265a, and the like. Only the conductive layer 265a is positioned in the opening portion 270 in some cases depending on the diameter of the opening portion 270, the thickness of the conductive layer 265a, the thickness of the conductive layer 265b, and the like.

Portions of the conductive layer 265a and the conductive layer 265b which do not overlap with the opening portion 290 are mainly positioned over the insulating layer 285. Thus, the conductive layer 265 mainly overlaps with the conductive layer 240 with the insulating layer 283 and the insulating layer 285 therebetween. This can increase the physical distance between the conductive layer 265 and the conductive layer 240, and thus can reduce the parasitic capacitance generated between the conductive layer 265 and the conductive layer 240. Note that the conductive layer 240 and the conductive layer 265 may include a portion where they overlap with each other without the insulating layer 285 therebetween.

FIG. 13B and FIG. 13C illustrate an example where the width of the opening portion 270 is smaller than the width D of the opening portion 290. The width of the opening portion 270 is preferably made smaller so that the region where the conductive layer 240 and the conductive layer 265 overlap with each other without the insulating layer 285 therebetween can be narrowed and parasitic capacitance generated between the conductive layer 240 and the conductive layer 265 can be reduced. For example, the width of the opening portion 270 is preferably smaller than or equal to that of the opening portion 290.

Note that the width of the opening portion 270 may be larger than that of the opening portion 290. For example, the width of the opening portion 270 is preferably smaller than the short-side width of the conductive layer 265 (the maximum width of the conductive layer 265a and the conductive layer 265b in FIG. 13C). Accordingly, the area of the portion where the conductive layer 240 and the conductive layer 265 overlap with each other without the insulating layer 285 therebetween can be sufficiently smaller than the area of the portion where the conductive layer 240 and the conductive layer 265 overlap with each other with the insulating layer 285 therebetween, so that parasitic capacitance generated between the conductive layer 240 and the conductive layer 265 can be reduced.

That is, the transistor 202 has a structure in which the parasitic capacitance generated between the other of the source electrode and the drain electrode and the gate wiring is reduced. Accordingly, the frequency characteristics of a circuit including the transistor can be improved.

### [Transistor 202A]

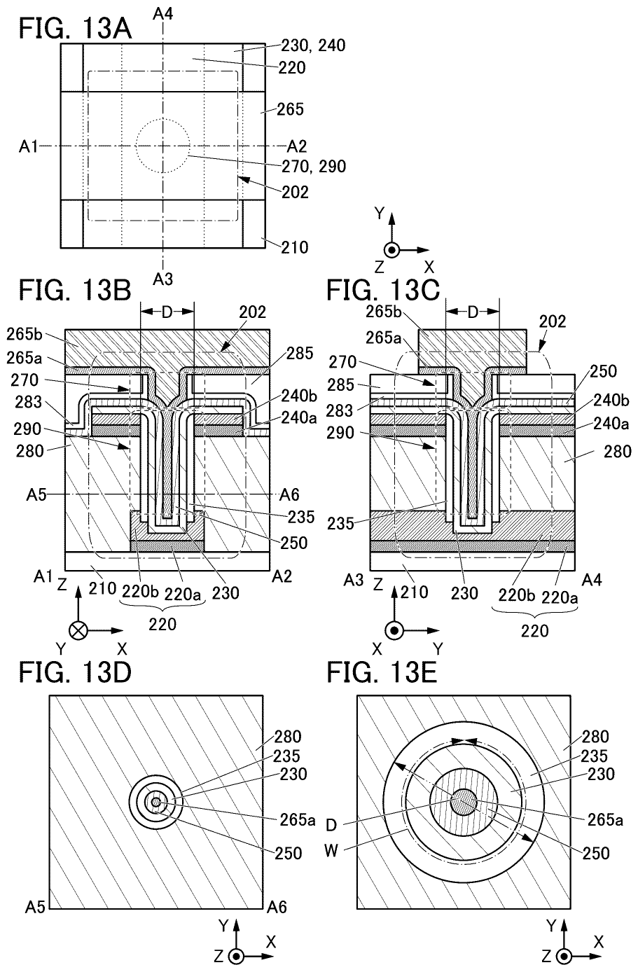

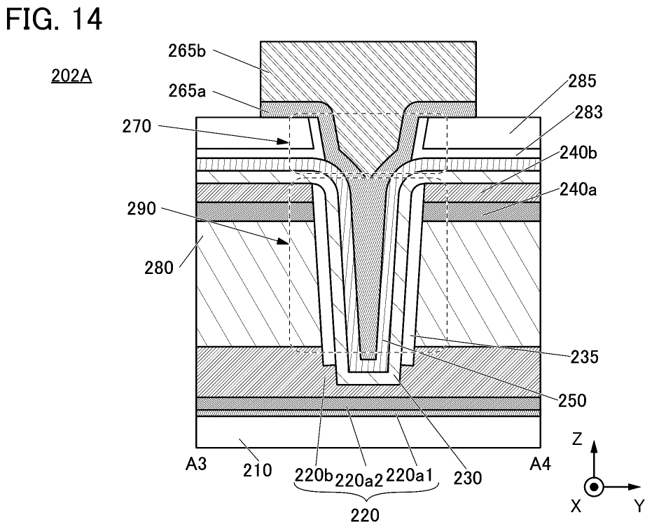

FIG. 14 is a cross-sectional view of the semiconductor device including the transistor 202A.

FIG. 14 illustrates an example where the sidewall of the opening portion 290 has a tapered shape. For the details of the case where the sidewall of the opening portion 290 has a tapered shape, the description of the transistor 200A illustrated in FIG. 6 can be referred to.

The mode and details of the transistor 202 can be modified as in the case of the transistor 200. Specifically, the transistor 202 can have a structure similar to that of any of the transistor 200A to the transistor 200G.

### [Transistor 203]

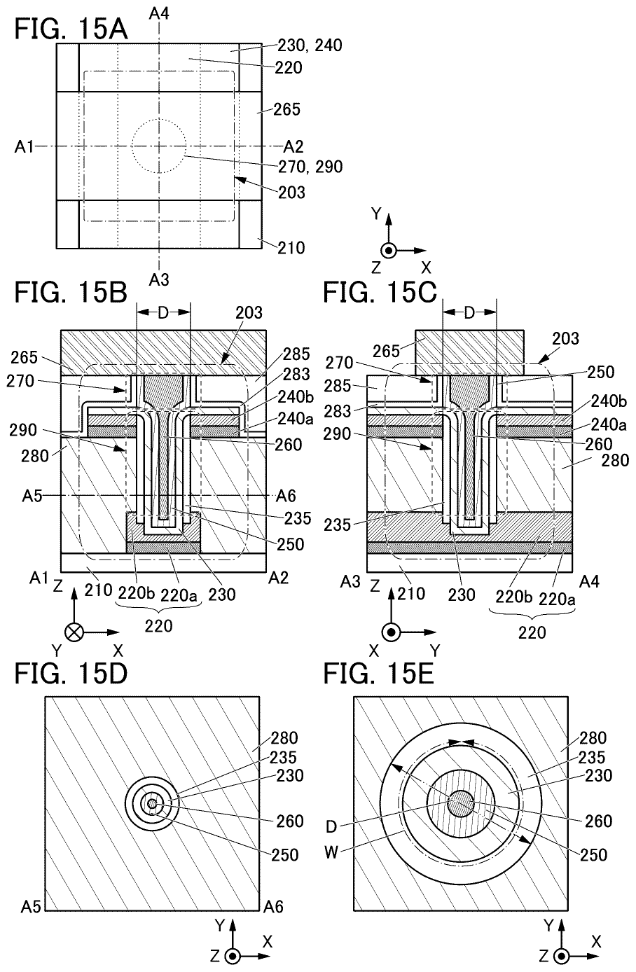

FIG. 15A is a plan view of a semiconductor device including a transistor 203. FIG. 15B is a cross-sectional view taken along the dashed-dotted line A1-A2 in FIG. 15A. FIG. 15C is a cross-sectional view taken along the dashed-dotted line A3-A4 in FIG. 15A. FIG. 15D and FIG. 15E are cross-sectional views taken along the dashed-dotted line A5-A6 in FIG. 15B. FIG. 15E corresponds to an example of an enlarged view of FIG. 15D. Since the structures in FIG. 15D and FIG. 15E are similar to those in FIG. 2D and FIG. 2E except that the conductive layer 265a is not provided but the conductive layer 260 is provided, the details thereof are not described.

The semiconductor devices illustrated in FIG. 15A to FIG. 15E each include the insulating layer 210 over a substrate (not illustrated), the transistor 203 over the insulating layer 210, the insulating layer 280 over the insulating layer 210, the insulating layer 283, the insulating layer 285 over the insulating layer 283, and the conductive layer 265 over the insulating layer 285. The insulating layer 210, the insulating layer 280, the insulating layer 283, and the insulating layer 285 each function as an interlayer film.

The transistor 203 includes the conductive layer 220a, the conductive layer 220b over the conductive layer 220a, the conductive layer 240a over the insulating layer 280, the conductive layer 240b over the conductive layer 240a, the insulating layer 235, the oxide semiconductor layer 230, the insulating layer 250 over the oxide semiconductor layer 230, and the conductive layer 260 over the insulating layer 250. Note that the conductive layer 265 may be regarded as a component of the transistor 203. The insulating layer 283 is provided over the insulating layer 250.

The conductive layer 260 functions as a gate electrode of the transistor 203, and the conductive layer 265 functions as a gate wiring. The conductive layer 260 can be formed using a material that can be used for the conductive layer 265.

Since the stacked-layer structure from the conductive layer 220a to the insulating layer 230 in the transistor 203 is similar to that in the transistor 200, the details thereof are not described.

As illustrated in FIG. 15B and FIG. 15C, the opening portion 270 reaching the oxide semiconductor layer 230 is provided in the insulating layer 283 at a position overlapping with the opening portion 290. At least parts of the components of the transistor 203 are placed in the opening portion 270. Specifically, at least parts of the insulating layer 250 and the conductive layer 260 are placed in the opening portion 270. The insulating layer 250 is in contact with the oxide semiconductor layer 230 and the insulating layer 283 in the opening portion 270.

A portion of the insulating layer 250 that is placed in the opening portion 270 reflects the shape of the opening portion 270. Specifically, the insulating layer 250 is provided to cover the sidewall of the opening portion 270 (the side surface of the insulating layer 283). Then, the conductive layer 260 is provided to fill at least part of a depressed portion that is defined by the insulating layer 250 and reflects the shape of the opening portion 270.

Since the conductive layer 260 does not overlap with the top surface of the conductive layer 240 in the transistor 203, parasitic capacitance generated between the conductive layer 240 and the conductive layer 260 can be reduced. As illustrated in FIG. 15B and FIG. 15C, the maximum width of the conductive layer 260 is smaller than the width D of the opening portion 290 in the cross-sectional view. As described above, the maximum width of the conductive layer 260 is preferably smaller than the width D of the opening portion 290, in which case the parasitic capacitance generated between the conductive layer 260 and the conductive layer 240 can be reduced. Note that, for example, as illustrated in FIG. 15B or FIG. 15C, the magnitude relation between the two widths in the semiconductor device of one embodiment of the present invention can be observed in one cross section parallel to the Z direction.

FIG. 15B and FIG. 15C illustrate an example where the width of the opening portion 270 corresponds to that of the opening portion 290 (is equal to the width D). The width of the opening portion 270 is preferably smaller than or equal to that of the opening portion 290. This is preferable because the conductive layer 260 does not overlap with the top surface of the conductive layer 240 and accordingly the parasitic capacitance generated between the conductive layer 260 and the conductive layer 240 can be reduced.

Although this embodiment mainly describes the example where the conductive layer 260 does not overlap with the top surface of the conductive layer 240, the conductive layer 260 may include a portion overlapping with the top surface of the conductive layer 240. The overlapping portion is preferably made smaller, which can reduce the parasitic capacitance generated between the conductive layer 260 and the conductive layer 240. For example, the width of the opening portion 270 is preferably smaller than the short-side width of the conductive layer 265 (the maximum width of the conductive layer 265 in FIG. 15C). For example, the maximum width of the conductive layer 265 is preferably smaller than or equal to the maximum width of the conductive layer 260.

That is, the transistor 203 has a structure where the parasitic capacitance generated between the other of the source electrode and the drain electrode and the gate electrode and the parasitic capacitance generated between the other of the source electrode and the drain electrode and the gate wiring are reduced. Accordingly, the frequency characteristics of a circuit including the transistor can be improved.

### [Transistor 203A]

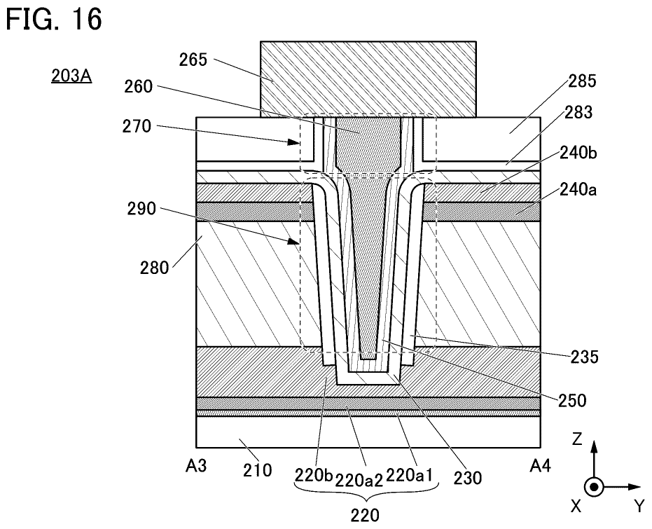

FIG. 16 is a cross-sectional view of a semiconductor device including a transistor 203A.

FIG. 16 illustrates an example where the sidewall of the opening portion 290 has a tapered shape. For the details of the case where the sidewall of the opening portion 290 has a tapered shape, the description of the transistor 200A illustrated in FIG. 6 can be referred to.

The mode and details of the transistor 203 can be modified as in the case of the transistor 200. Specifically, the transistor 203 can have a structure similar to that of any of the transistor 200A to the transistor 200G.

### [Region Containing Halogen Element and Region Containing First Element]

In the semiconductor device of one embodiment of the present invention, at least one of the side surface of the insulating layer 280 on the opening portion 290 side and the vicinity thereof, the insulating layer 235, and the oxide semiconductor layer 230 may include a region containing a halogen element.

The halogen element is preferably one or more kinds selected from chlorine, fluorine, bromine, and iodine, and further preferably chlorine or fluorine. In terms of substitution for oxygen, fluorine having higher electronegativity than oxygen is preferably used.

When the insulating layer 280 or the insulating layer 235 contains a halogen element, the halogen element can be supplied to the oxide semiconductor layer 230. The halogen element (X) has a function of generating an electron serving as a carrier by entering an oxygen vacancy (Vo) in the oxide semiconductor layer 230 to form a defect (VoX). For example, in the case where chlorine (Cl) is used as the halogen element, Cl is stably present in a state of VoCl in the oxide semiconductor layer 230 (particularly at the interface between the insulating layer 235 and the oxide semiconductor layer 230 and in the vicinity thereof). At that time, Cl can be in the state of VoCl by not only entering an existing Vo but also substituting for oxygen.

In contrast, oxygen substituted by Cl (also referred to as excess oxygen) has a function of trapping electrons. In addition, carrier trap by oxygen takes precedence over carrier generation by VoCl. Thus, a negative charge (also referred to as a negative fixed charge) is formed at the interface between the insulating layer 235 and the oxide semiconductor layer 230 and in the vicinity thereof. When a negative charge is present in the channel formation region, the threshold voltage of the transistor can be shifted positively. Thus, even when the transistor has a minute structure or an extremely small channel length, the transistor can have normally-off characteristics.

In the semiconductor device of one embodiment of the present invention, the source region and the drain region of the oxide semiconductor layer 230 preferably contain an impurity element. A first element is preferably used as the impurity element. Alternatively, both the first element and hydrogen are preferably used as the impurity element.

Note that at least one of the conductive layer 240a, the conductive layer 240b, the conductive layer 220a, and the conductive layer 220b may also contain the impurity element.

As the first element, it is preferable to use one or more kinds of boron, aluminum, indium, carbon, silicon, germanium, tin, phosphorus, arsenic, antimony, magnesium, calcium, titanium, copper, zinc, tungsten, molybdenum, tantalum, hafnium, cerium, and a noble gas (helium, neon, argon, krypton, xenon, and the like).

Note that the first element is not limited to the above elements, and one or more kinds of first transition elements (3d transition elements or 3d transition metals), second transition elements (4d transition elements or 4d transition metals), third transition elements (5d transition elements or 5d transition metals), alkaline earth metal elements, and rare earth elements can be used.

When the first element is supplied to the source region and the drain region, the first element deprives these regions of oxygen, for example, and accordingly generates an oxygen vacancy therein. Then, the oxygen vacancy is bonded to hydrogen in the film, so that a carrier is generated and the resistances of the source region and the drain region can be reduced. Accordingly, the sheet resistance of the oxide semiconductor layer 230, the contact resistance between the oxide semiconductor layer 230 and the conductive layer 220, and the contact resistance between the oxide semiconductor layer 230 and the conductive layer 240 can be reduced. Thus, the on-state current of the transistor can be increased. The increased on-state current can reduce the operation voltage of the transistor. This can reduce the power consumption of the semiconductor device.

In the case where an element that is easily bonded to oxygen is used as the first element, the first element is present in a state of being bonded to oxygen in the semiconductor layer. Furthermore, when an element that is stabilized by being bonded to oxygen is used as the first element, the first element in the semiconductor layer is present stably in an oxidized state and thus is not easily released by heat or the like applied during the manufacturing process of the semiconductor device, thereby enabling a low-resistance region that is stable in a low-electrical-resistance state. Therefore, as the first element, it is preferable to use an element an oxide of which can be present as a solid at 25 °C and 1 atmospheric pressure. Specifically, a typical non-metallic element other than hydrogen, a typical metal element, and a transition element (transition metal) are preferable as the first element, and boron, phosphorus, magnesium, aluminum, and silicon are particularly preferable as the first element.

Thus, boron, phosphorus, magnesium, aluminum, or silicon is preferably used as one first element. In particular, boron or phosphorus is preferably used as one first element.

Furthermore, hydrogen has a function of being bonded to an oxygen vacancy in addition to the above function of generating an oxygen vacancy, and thus is suitable as the impurity element.

When the first element and hydrogen are both used as the impurity element, the electrical resistances of the source region and the drain region in the oxide semiconductor layer 230 are easily reduced and a low-electrical-resistance state can be kept stably.

Both the first element and hydrogen are preferably supplied, in which case ions generated from the source gases can be added without mass separation and thus the productivity can be increased. For example, when a B₂H₆ gas is used, boron and hydrogen can be supplied as the impurity element. As another example, when a PH₃ gas is used, phosphorus and hydrogen can be supplied as the impurity element. Note that the method for supplying the impurity element is not limited thereto. For example, a specific element may be added after a source gas is ionized and then the ion is subjected to mass separation. For example, boron may be added after mass separation using a B₂H₆ gas.

Note that the impurity element is supplied also to the channel formation region of the oxide semiconductor layer 230 in some cases. Alternatively, the impurity element contained in the source region or the drain region sometimes partly diffuses to the channel formation region owing to the influence of heat applied during the manufacturing process or the like.

In manufacturing the semiconductor device of one embodiment of the present invention, an impurity element is preferably added to the source region and the drain region of the oxide semiconductor layer 230 more easily than to the channel formation region. Thus, the impurity element is preferably added from a direction perpendicular or substantially perpendicular to the top surface of the substrate. At this time, in the oxide semiconductor layer 230, the addition amount of the impurity element is smaller for a surface inclined to the top surface of the substrate than for a surface parallel or substantially parallel to the top surface of the substrate. That is, in the oxide semiconductor layer 230, the addition amount of the impurity element is larger in the source region and the drain region than in the channel formation region. Thus, the resistances of the source region and the drain region can be reduced preferentially.

### Example of Manufacturing Method of Semiconductor Device

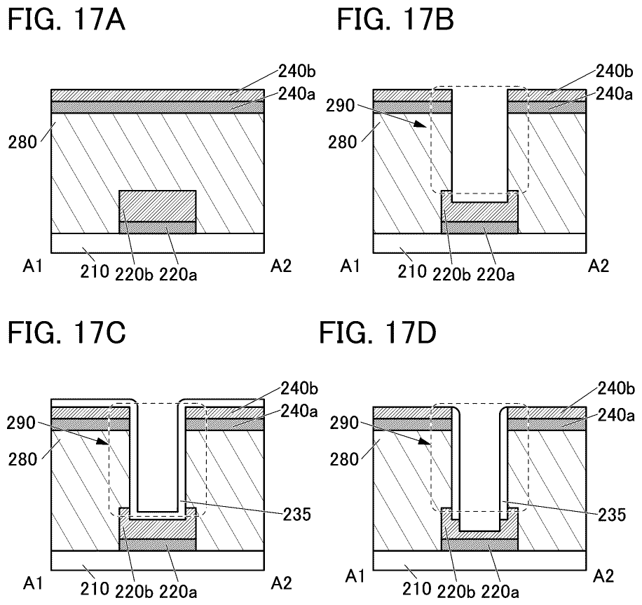

Next, a method for manufacturing a semiconductor device of one embodiment of the present invention is described with reference to FIG. 17A to FIG. 20F. Note that as for a material and a formation method of each component, portions similar to those in the above description are not described in some cases.

Thin films included in the semiconductor device (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like.

Examples of a sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. An RF sputtering method is mainly used in the case where an insulating film is formed, and a DC sputtering method is mainly used in the case where a metal conductive film is formed. The pulsed DC sputtering method is mainly used in the case where a compound such as an oxide, a nitride, or a carbide is formed by a reactive sputtering method.

CVD methods can be classified into a plasma CVD (PECVD: Plasma Enhanced CVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by a plasma CVD method. A thermal CVD method is a film formation method that does not use plasma and thus enables less plasma damage to an object. For example, a wiring, an electrode, an element (a transistor, a capacitor element, or the like), or the like included in a semiconductor device may be charged up by receiving charge from plasma. In that case, accumulated charge may break the wiring, the electrode, the element, or the like included in the semiconductor device. By contrast, a thermal CVD method, which does not use plasma, does not cause such plasma damage, and thus can increase the yield of the semiconductor device. In addition, a thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, or the like can be used.

Note that a precursor used in the ALD method sometimes includes an element such as carbon or chlorine. Thus, in some cases, a film provided by an ALD method includes a larger amount of an element such as carbon or chlorine than a film provided by another film formation method. Note that these elements can be quantified by XPS or SIMS. The film formation method of a metal oxide according to one embodiment of the present invention, which employs an ALD method and one or both of a deposition condition with a high substrate temperature and impurity removal treatment, can sometimes deposit a film with smaller amounts of carbon and chlorine than a method employing an ALD method without the deposition condition with a high substrate temperature or the impurity removal treatment.

Unlike a film formation method in which particles ejected from a target or the like are deposited, an ALD method is a film formation method in which a film is formed by reaction at a surface of an object to be processed. Thus, an ALD method is a film formation method that enables good step coverage almost regardless of the shape of an object. In particular, the ALD method enables excellent step coverage and excellent thickness uniformity and thus is suitable for covering a surface of an opening portion with a high aspect ratio, for example.

A CVD method and an ALD method are different from a sputtering method in which particles ejected from a target or the like are deposited. Thus, a CVD method and an ALD method are film formation methods that enable good step coverage almost regardless of the shape of an object. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another film formation method with a high deposition rate, such as a CVD method, in some cases.

By a CVD method, a film with a certain composition can be deposited depending on the flow rate ratio of the source gases. For example, by a CVD method, a film whose composition is continuously changed can be deposited by changing the flow rate ratio of the source gases during deposition. In the case where a film is deposited while the flow rate ratio of the source gas is changed, the time taken for transfer or pressure adjustment is saved, and thus the time taken for the deposition can be shortened as compared to the case where a film is deposited using a plurality of deposition chambers. Thus, the productivity of the semiconductor device can be increased in some cases.

In an ALD method, a film with a certain composition can be deposited by concurrently introducing different kinds of precursors. In the case where different kinds of precursors are introduced, a film with a certain composition can be deposited by controlling the number of cycles of the precursors.

Thin films included in the semiconductor device (insulating films, semiconductor films, conductive films, and the like) can be formed by a wet film-formation method such as a spin coating method, a dip coating method, a spray coating method, an inkjet method, dispensing, screen printing, offset printing, a doctor blade method, slit coating, roll coating, curtain coating, or knife coating.

In processing thin films included in the semiconductor device, a photolithography method or the like can be employed. Alternatively, the thin films may be processed by a nanoimprint method, a sandblast method, a lift-off method, or the like. Island-shaped thin films may be directly formed by a film formation method using a blocking mask such as a metal mask.

There are two typical examples of a photolithography method. In one of the methods, a resist mask is formed over a thin film that is to be processed, the thin film is processed by etching or the like, and the resist mask is removed. In the other method, a photosensitive thin film is formed and then processed into a desired shape by light exposure and development.

As light used for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. In addition, light exposure may be performed by liquid immersion exposure technique. As the light used for the light exposure, extreme ultraviolet (EUV) light or X-rays may be used. Instead of the light used for light exposure, an electron beam can be used. Extreme ultraviolet light, X-rays, or an electron beam is preferably used, in which case extremely minute processing can be performed. Note that a photomask is not needed when the light exposure is performed by scanning with a beam such as an electron beam.

For etching of thin films, a dry etching method, a wet etching method, a sandblasting method, or the like can be used.

### Example of Manufacturing Method of Transistor 200

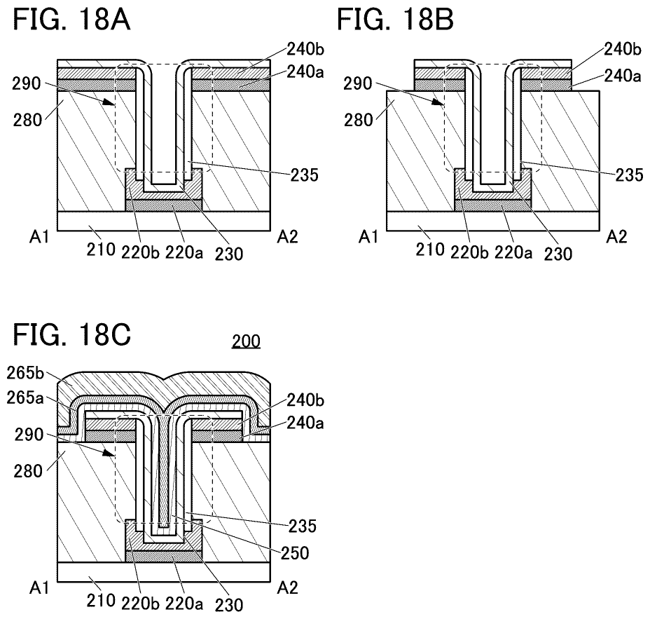

An example of a method for manufacturing the semiconductor device including the transistor 200 (see FIG. 2A1 to FIG. 2E) will be described with reference to FIG. 17A to FIG. 18C.

First, as illustrated in FIG. 17A, the insulating layer 210 is formed over a substrate (not illustrated), the conductive layer 220a is formed over the insulating layer 210, the conductive layer 220b is formed over the conductive layer 220a, and the insulating layer 280 is formed over the conductive layer 220b.

Note that the insulating layer 280 can be formed by two kinds of film formation methods. For example, as the insulating layer 280, a silicon nitride film can be formed by an ALD method, and then a silicon nitride film can be formed by a sputtering method. An ALD method provides excellent step coverage and excellent thickness uniformity and thus is suitable for forming a thin film or covering a surface of an opening portion with a high aspect ratio or a surface of a layer. The sputtering method, whose deposition rate is higher than that of the ALD method, can improve the productivity.

Note that planarization treatment is preferably performed after formation of the insulating layer 280 to planarize the top surface of the insulating layer 280. As the planarization treatment, planarization treatment using a chemical mechanical polishing (CMP) method (also referred to as CMP treatment) is suitable. Alternatively, planarization treatment using etching (also referred to as etch back treatment) may be performed. By the planarization treatment of the insulating layer 280, the formation surface of the conductive layer 240a can be made flat, whereby disconnection of the conductive layer 240a can be inhibited. Note that the planarization treatment is not necessarily performed, in which case the manufacturing cost can be reduced.

Next, as illustrated in FIG. 17A, the conductive layer 240a is formed over the insulating layer 280, and the conductive layer 240b is formed over the conductive layer 240a.

Next, as illustrated in FIG. 17B, the opening portion 290 is formed in the conductive layer 240b, the conductive layer 240a, and the insulating layer 280 at a position overlapping with the conductive layer 220a. At this time, a depressed portion is preferably provided in the conductive layer 220b at a position overlapping with the opening portion 290. By formation of the opening portion 290, the bottom surface and the side surface of the depressed portion in the conductive layer 220b are preferably exposed.

At the time of forming the opening portion 290, part of the conductive layer 220b, part of the conductive layer 240a, part of the conductive layer 240b, and part of the insulating layer 280 are preferably processed by anisotropic etching for microfabrication and a small transistor size. Processing by a dry etching method is particularly preferable because it is suitable for microfabrication. The opening portion 290 may be formed under processing conditions different between layers. Note that the side surface of the conductive layer 220b, the side surface of the conductive layer 240a, the side surface of the conductive layer 240b, and the side surface of the insulating layer 280 in the opening portion 290 may have different inclinations depending on the materials, processing conditions, and the like for the conductive layer 220b, the conductive layer 240a, the conductive layer 240b, and the insulating layer 280.

In the formation step or the like of the opening portion 290, a region containing a halogen element is sometimes provided in at least one of the bottom surface and the side surface of the depressed portion in the conductive layer 220b, the side surface of the insulating layer 280, the side surface of the conductive layer 240a, and the top surface and the side surface of the conductive layer 240b. Examples of the region include a region containing fluorine, a region containing chlorine, and a region containing fluorine and chlorine. In some cases, a halogen element derived from an etching gas used in dry etching remains in the region, for example.

Next, heat treatment may be performed. The heat treatment is performed, for example, at a temperature higher than or equal to 250 °C and lower than or equal to 650 °C, preferably higher than or equal to 300 °C and lower than or equal to 500 °C, further preferably higher than or equal to 320 °C and lower than or equal to 450 °C.

The heat treatment is performed in a nitrogen gas atmosphere or an inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, heat treatment may be performed in a nitrogen gas atmosphere or an inert gas atmosphere, and then heat treatment may be performed in an atmosphere containing an oxidizing gas at higher than or equal to 10 ppm, higher than or equal to 1%, or higher than or equal to 10% in order to compensate for released oxygen. By the above-described heat treatment, impurities such as water contained in the insulating layer 280 or the like can be reduced before formation of the oxide semiconductor layer 230.

The gas used in the above heat treatment is preferably highly purified. For example, the amount of moisture contained in the gas used in the heat treatment is preferably lower than or equal to 1 ppb, further preferably lower than or equal to 0.1 ppb, still further preferably lower than or equal to 0.05 ppb. The heat treatment using a highly purified gas can prevent entry of moisture or the like into the insulating layer 280 and the like as much as possible.

Next, as illustrated in FIG. 17C, the insulating layer 235 is formed to cover the opening portion 290. The insulating layer 235 is provided in contact with the bottom surface and the side surface of the depressed portion in the conductive layer 220b, the side surface of the insulating layer 280, the side surface of the conductive layer 240a, and the top surface and the side surface of the conductive layer 240b.

The insulating layer 235 is provided in the opening portion 290, and thus is preferably formed by a CVD method or an ALD method, further preferably formed by an ALD method. In such a case, the insulating layer 235 can be provided with good coverage.

Next, as illustrated in FIG. 17D, the insulating layer 235 is processed to expose the top surface of the conductive layer 240b and expose the conductive layer 220b in the opening portion 290. In the opening portion 290, the bottom surface of the depressed portion of the conductive layer 220b is preferably exposed.

When the insulating layer 235 is processed by anisotropic etching, a region of the insulating layer 235 which is positioned on the top surface of the conductive layer 240b and a region of the insulating layer 235 which is positioned on the bottom surface of the opening portion 290 are removed, so that the insulating layer 235 can remain only on the side surface of the opening portion 290. The insulating layer 235 is preferably processed by highly anisotropic etching using a dry etching method.

Note that as illustrated in FIG. 17D, part of the conductive layer 220b may be removed at the time of processing the insulating layer 235 to form a depressed portion in the conductive layer 220b.

Next, as illustrated in FIG. 18A, the oxide semiconductor layer 230 is formed to cover the opening portion 290. The oxide semiconductor layer 230 is in contact with the bottom surface and the side surface of the depressed portion in the conductive layer 220b, the insulating layer 235, and the top surface of the conductive layer 240b.

The oxide semiconductor layer 230 can be formed by a sputtering method, a CVD method, a molecular beam epitaxy (MBE) method, a PLD method, or an ALD method, for example.

The oxide semiconductor layer 230 is preferably formed to have as uniform a thickness as possible along the bottom surface and the side surface of the depressed portion in the conductive layer 220b, the insulating layer 235, and the top surface of the conductive layer 240b. By an ALD method, a thin film can be formed with good controllability. Thus, the oxide semiconductor layer 230 is preferably formed by an ALD method.

In addition, when the oxide semiconductor layer 230 has high crystallinity, diffusion of impurities in the oxide semiconductor layer 230 is inhibited; thus, electrical characteristics of the transistor are less likely to change and the reliability of the transistor can be improved. The oxide semiconductor layer 230 is preferably formed by a sputtering method, in which case a layer with high crystallinity can be formed easily as compared with the case of using an ALD method.

In the case where the oxide semiconductor layer 230 is formed by a sputtering method, oxygen or a mixed gas of oxygen and a noble gas is used for a sputtering gas. An increase in the proportion of oxygen in the sputtering gas can increase the amount of excess oxygen contained in the oxide film to be formed. In the case where the oxide film is formed by a sputtering method, an In-M-Zn oxide target or the like can be used.

In the formation of the oxide semiconductor layer 230 by a sputtering method, setting the proportion of oxygen contained in the sputtering gas to higher than 30% and lower than or equal to 100%, preferably higher than or equal to 70% and lower than or equal to 100% allows formation of an oxygen-excess oxide semiconductor. A transistor including an oxygen-excess oxide semiconductor in its channel formation region can have relatively high reliability. Note that one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in its channel formation region can have relatively high field-effect mobility. In addition, when the oxide semiconductor is formed while the substrate is being heated, the crystallinity of the oxide semiconductor layer can be improved.

For a formation method of the oxide semiconductor layer, description in Embodiment 2 can also be referred to.

Next, heat treatment is preferably performed. The heat treatment is preferably performed in a temperature range where the oxide semiconductor layer 230 does not become polycrystal. The heat treatment temperature is, for example, preferably higher than or equal to 100 °C and lower than or equal to 650 °C, further preferably higher than or equal to 250 °C and lower than or equal to 600 °C, still further preferably higher than or equal to 350 °C and lower than or equal to 550 °C. For the details of the heat treatment, the above description can be referred to.

The gas used in the above heat treatment is preferably highly purified. The heat treatment performed using a highly purified gas can prevent entry of moisture or the like into the oxide semiconductor layer 230 as much as possible.

In this embodiment, heat treatment is performed at 450 °C for an hour at a flow rate ratio of a nitrogen gas to an oxygen gas of 4:1. With such heat treatment using the oxygen gas, impurities such as carbon, water, and hydrogen in the oxide semiconductor layer 230 can be reduced. The reduction of impurities in the film improves the crystallinity of the oxide semiconductor layer 230, thereby offering a dense structure with higher density. Accordingly, the crystal region in the oxide semiconductor layer 230 can be expanded, and an in-plane variation in the crystal region in the oxide semiconductor layer 230 can be reduced. Thus, an in-plane variation in electrical characteristics of the transistor can be reduced.

In the case where at least one of the insulating layer 280 and the insulating layer 235 contains oxygen, oxygen is preferably supplied from the insulating layer containing the oxygen to the channel formation region of the oxide semiconductor layer 230 by the heat treatment. Accordingly, oxygen vacancies and VoH can be reduced.

In this manner, excess oxygen is supplied to the oxide semiconductor layer 230 from the insulating layer in contact with the oxide semiconductor layer 230 or the insulating layer positioned in the vicinity of the oxide semiconductor layer 230 in some cases. Since excess oxygen has a function of trapping electrons, a negative charge is likely to be formed. Accordingly, the threshold voltage of the transistor can be shifted positively to enable formation of the transistor having normally-off characteristics.

Next, as illustrated in FIG. 18B, the oxide semiconductor layer 230, the conductive layer 240a, and the conductive layer 240b are processed into island shapes so that part of the top surface of the insulating layer 280 is exposed. The oxide semiconductor layer 230, the conductive layer 240a, and the conductive layer 240b can be processed using the same mask. This is preferable because the number of masks required for manufacturing the semiconductor device can be reduced.

Next, as illustrated in FIG. 18C, the insulating layer 250 is formed to cover the opening portion 290, and the conductive layer 265a is formed over the insulating layer 250. Furthermore, the conductive layer 265b is formed over the conductive layer 265a. The insulating layer 250 is provided in contact with the oxide semiconductor layer 230. The conductive layer 265a is preferably provided to fill the opening portion 290. Note that the conductive layer 265b is also provided in the opening portion 290 in some cases depending on the diameter of the opening portion 290, the thickness of the conductive layer 265a, and the like.

The insulating layer 250 and the conductive layer 265a are each formed in the opening portion 290 with a high aspect ratio. Thus, the insulating layer 250 and the conductive layer 265a are each preferably deposited by a film formation method providing favorable coverage, and is further preferably deposited by a CVD method, an ALD method, or the like.

Through the above process, the transistor 200 can be manufactured.

### Example of Manufacturing Method of Transistor 202

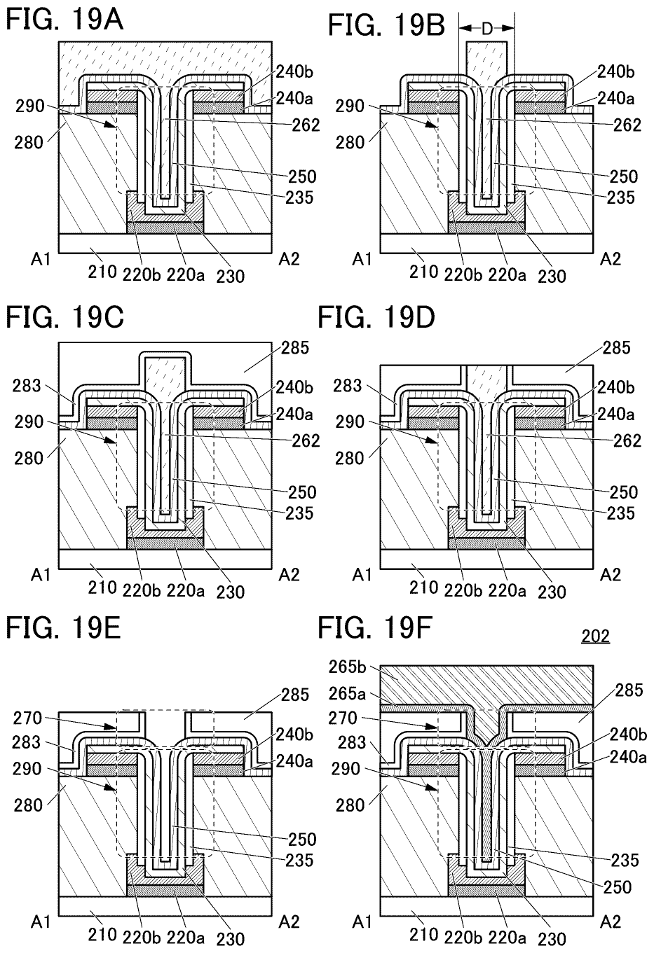

An example of a method for manufacturing the semiconductor device including the transistor 202 (see FIG. 13A to FIG. 13E) will be described with reference to FIG. 19A to FIG. 19F. Note that detailed description of portions similar to those in the example of the manufacturing method of the transistor 200 is omitted.

First, the steps of FIG. 17A to FIG. 18B are performed as in the example of manufacturing method of the transistor 200. Next, as illustrated in FIG. 19A, the insulating layer 250 is formed to cover the insulating layer 280, the conductive layer 240a, the conductive layer 240b, and the oxide semiconductor layer 230.

After that, a sacrificial layer 262 is formed over the insulating layer 250. As the sacrificial layer 262, a spin on carbon (SOC) film and a spin on glass (SOG) film are suitable. The sacrificial layer 262 preferably has a two-layer structure of an SOC film and an SOG film over the SOC film, for example.

The sacrificial layer 262 is preferably provided over and in contact with the insulating layer 250, in which case damage to the oxide semiconductor layer 230 can be reduced in the manufacturing process of the semiconductor device as compared with the case where the sacrificial layer 262 is provided over and in contact with the oxide semiconductor layer 230. Meanwhile, in the case where the sacrificial layer 262 is provided over and in contact with the oxide semiconductor layer 230 as in a manufacturing method of the transistor 202 to be described later, damage to the insulating layer 250 can be reduced in the manufacturing process of the semiconductor device, which is preferable. Note that in the case where the insulating layer 250 has a stacked-layer structure, one or some of the layers constituting the insulating layer 250 may be formed before formation of the sacrificial layer 262, and the other layer(s) may be formed after removal of the sacrificial layer 262.

Subsequentially, as illustrated in FIG. 19B, part of the sacrificial layer 262 is removed. In a region where the sacrificial layer 262 remains, a gate electrode (the conductive layer 265a and the conductive layer 265b) is provided in a later process. Thus, the sacrificial layer 262 preferably has a small portion overlapping with the top surface of the conductive layer 240b or further preferably has no portion overlapping with the top surface of the conductive layer 240b. As illustrated in FIG. 19B, the maximum width of the sacrificial layer 262 is preferably smaller than the width D of the opening portion 290 in a cross-sectional view.

Next, as illustrated in FIG. 19C, the insulating layer 283 is formed to cover the insulating layer 250 and the sacrificial layer 262, and the insulating layer 285 is formed over the insulating layer 283.

When the insulating layer 285 is made thick, the distance between the conductive layer 240b and the conductive layer 265a can be increased, so that parasitic capacitance generated between the conductive layer 240b and the gate electrode (or gate wiring) can be reduced.

A silicon oxide film is preferably formed by a sputtering method as the insulating layer 285, for example.

Here, in the case where the insulating layer 283 is not provided, the sacrificial layer 262 is exposed to plasma containing oxygen in forming a silicon oxide film by a sputtering method as the insulating layer 285, in which case part or the whole of the sacrificial layer 262 is etched in some cases. As described above, depending on the formation method of the insulating layer 285, the sacrificial layer 262 might be shrunk or disappear. For this reason, the insulating layer formed over the sacrificial layer 262 preferably has not a single-layer structure of the insulating layer 285 but a stacked-layer structure of the insulating layer 283 and the insulating layer 285. This can produce effects of widening the range of choices of the materials for the sacrificial layer 262 and the insulating layer 285, lowering the difficulty of manufacturing the semiconductor device, and the like.

In the case where an oxide film is used as the insulating layer 283, the oxide film is preferably formed by a method other than a sputtering method, e.g., an ALD method. For example, an aluminum oxide film or a hafnium oxide film is preferably formed as the insulating layer 283 by an ALD method. Alternatively, a nitride film (e.g., a silicon nitride film) is preferably used as the insulating layer 283. Thus, the sacrificial layer 262 can be inhibited from being unintentionally processed in forming the insulating layer 283 and the insulating layer 285.

The insulating layer 283 is preferably formed by a CVD method or an ALD method, further preferably formed by an ALD method. In such a case, the insulating layer 283 can be provided on the side surface or the like of the sacrificial layer 262 with good coverage.

Subsequently, as illustrated in FIG. 19D, planarization treatment is performed to expose the top surface of the sacrificial layer 262 and planarize the top surfaces of the sacrificial layer 262, the insulating layer 283, and the insulating layer 285. As the planarization treatment, CMP treatment is suitable. At least part of the insulating layer 283 and part of the insulating layer 285 are removed by the planarization treatment. In addition, part of the sacrificial layer 262 may be removed.

Next, as illustrated in FIG. 19E, the sacrificial layer 262 is removed. There is no particular limitation on the method for removing the sacrificial layer 262. For example, the sacrificial layer 262 can be removed by dry etching. Here, as illustrated in FIG. 19E, the insulating layer 283 can be regarded as including the opening portion 270 at a position overlapping with the opening portion 290.

Next, as illustrated in FIG. 19F, the conductive layer 265a is formed to cover the opening portion 270 and the opening portion 290. The conductive layer 265a is provided in contact with the insulating layer 250 and the insulating layer 283 in the opening portion 270 and the opening portion 290. The conductive layer 265a is preferably provided to fill the opening portion 290. Furthermore, the conductive layer 265b is formed over the conductive layer 265a. Here, an example where the conductive layer 265b is provided in the opening portion 270 is illustrated.

The conductive layer 265a and the conductive layer 265b are each formed in one or both of the opening portion 290 and the opening portion 270 with a high aspect ratio. Thus, the conductive layer 265a and the conductive layer 265b are each preferably formed by a film formation method providing favorable coverage, and is further preferably deposited by a CVD method, an ALD method, or the like.

Note that the conductive layer 265b is also provided in the opening portion 290 in some cases depending on the diameter of the opening portion 270, the diameter of the opening portion 290, the thickness of the conductive layer 265a, the thickness of the conductive layer 265b, and the like. In another case, the conductive layer 265a fills the opening portion 270, and the conductive layer 265b is not provided in the opening portion 270.

Through the above process, the transistor 202 can be manufactured.

### Example of Manufacturing Method of Transistor 203

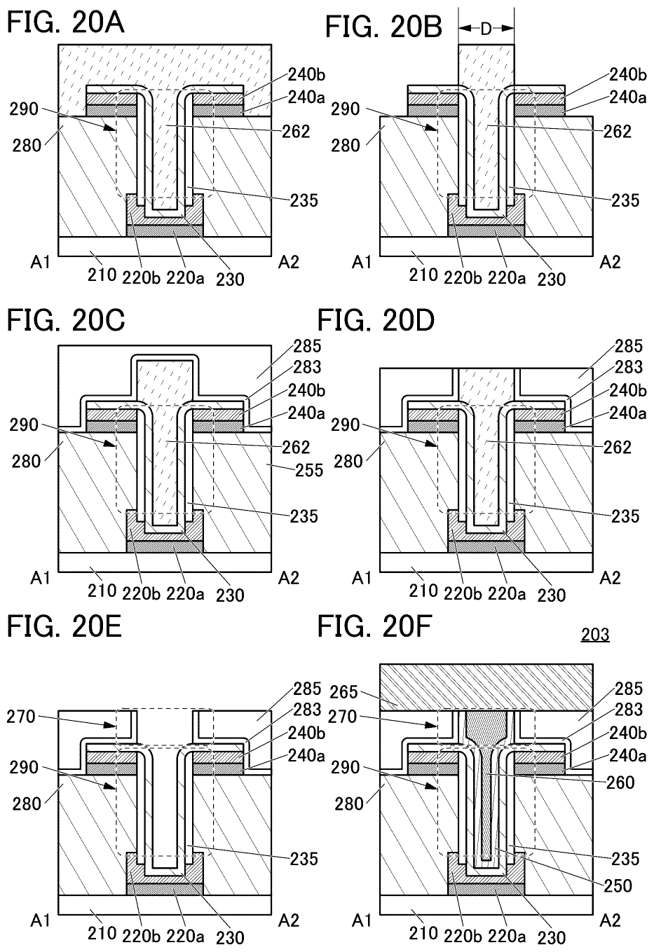

An example of a method for manufacturing the semiconductor device including the transistor 203 (see FIG. 15A to FIG. 15E) will be described with reference to FIG. 20A to FIG. 20F. Note that detailed description of portions similar to those in the examples of manufacturing methods of the transistors 200 and 202 is omitted.

First, the steps of FIG. 17A to FIG. 18B are performed as in the example of the manufacturing method of the transistor 200. Next, as illustrated in FIG. 20A, the sacrificial layer 262 is formed to cover the insulating layer 280, the conductive layer 240a, the conductive layer 240b, and the oxide semiconductor layer 230.

Subsequentially, as illustrated in FIG. 20B, part of the sacrificial layer 262 is removed. In a region where the sacrificial layer 262 remains, a gate insulating layer and a gate electrode (the insulating layer 250 and the conductive layer 260) are provided in a later process. Thus, the sacrificial layer 262 preferably has a small portion overlapping with the top surface of the conductive layer 240a or further preferably has no portion overlapping with the top surface of the conductive layer 240a. In a cross-sectional view, preferably, the width of the sacrificial layer 262 does not exceed the sum of the width D of the opening portion 290 and twice the thickness of the insulating layer 250 to be formed later. FIG. 20B illustrates an example where the width of the sacrificial layer 262 corresponds to the width D of the opening portion 290.

Next, as illustrated in FIG. 20C, the insulating layer 283 is formed to cover the insulating layer 280, the conductive layer 240a, the conductive layer 240b, the oxide semiconductor layer 230, and the sacrificial layer 262, and the insulating layer 285 is formed over the insulating layer 283.

When the insulating layer 285 is made thick, the distance between the top surface of the conductive layer 240b and the gate wiring (the conductive layer 265) can be increased, so that the parasitic capacitance between the conductive layer 240b and the gate wiring can be reduced.

Subsequently, as illustrated in FIG. 20D, planarization treatment is performed to expose the top surface of the sacrificial layer 262 and planarize the top surfaces of the sacrificial layer 262, the insulating layer 283, and the insulating layer 285.

Next, as illustrated in FIG. 20E, the sacrificial layer 262 is removed.

Next, as illustrated in FIG. 20F, the insulating layer 250 is formed to cover the opening portion 270 and the opening portion 290, and the conductive layer 260 is formed over the insulating layer 250. Next, planarization treatment is performed to expose the top surfaces of the insulating layer 283 and the insulating layer 285 and planarize the top surfaces of the conductive layer 260, the insulating layer 250, the insulating layer 283, and the insulating layer 285.

The insulating layer 250 is provided in contact with the oxide semiconductor layer 230 and the insulating layer 283.

The insulating layer 250 and the conductive layer 260 are each formed in the opening portion 290 and the opening portion 270 with a high aspect ratio. Thus, the insulating layer 250 and the conductive layer 260 are preferably formed by a film formation method providing favorable coverage, and is further preferably deposited by a CVD method, an ALD method, or the like.

As the planarization treatment, CMP treatment is suitable. In the planarization treatment, at least regions of the conductive layer 260 and the insulating layer 250 that overlap with the top surface of the insulating layer 285 are removed. Thus, a portion of the conductive layer 260 overlapping with the top surface of the conductive layer 240 can be removed, so that generation of parasitic capacitance between the conductive layer 260 and the conductive layer 240 can be inhibited.

By removing the portion of the conductive layer 260 overlapping with the top surface of the conductive layer 240 by the CMP treatment, an increase in the number of masks can be inhibited as compared with the case of using dry etching, for example.

As illustrated in FIG. 20F, the top surface of the insulating layer 285 and the top surface of the conductive layer 260 are preferably level with each other. Alternatively, one of the top surface of the insulating layer 285 and the top surface of the conductive layer 260 may be higher than the other. Owing to the difference in polishing rate between the materials for the insulating layer 285 and the conductive layer 260, the top surface levels of the two layers can be controlled.

Next, as illustrated in FIG. 20F, the conductive layer 265 is formed over the insulating layer 250, the insulating layer 283, the insulating layer 285, and the conductive layer 260.

The insulating layer 283 and the insulating layer 285 are positioned between the conductive layer 265 and the conductive layer 240b. This can increase the physical distance between the conductive layer 265 and the conductive layer 240b, and thus can reduce the parasitic capacitance generated between the conductive layer 265 and the conductive layer 240b.

Through the above steps, the semiconductor device of one embodiment of the present invention can be manufactured.

### [Method for Adding Element]

As described above, a region containing a halogen element may be provided in at least one of the insulating layer 280, the insulating layer 235, and the oxide semiconductor layer 230. A region containing the first element may be provided in the oxide semiconductor layer 230. A region containing the first element may be provided in at least one of the conductive layer 220a, the conductive layer 220b, the conductive layer 240a, and the conductive layer 240b.

For example, after the opening portion 290 illustrated in FIG. 17B is formed, a halogen element may be supplied to the side surface of the insulating layer 280 in the opening portion 290. Note that the halogen element may also be supplied to one or more of the conductive layer 240a, the conductive layer 240b, the conductive layer 220a, and the conductive layer 220b.

Here, FIG. 17B illustrates an example where the sidewall of the opening portion 290 is perpendicular to the top surface of the substrate. In the semiconductor device of one embodiment of the present invention, the sidewall of the opening portion 290 is perpendicular or substantially perpendicular to the top surface of the substrate or has a tapered shape. Accordingly, when the halogen element is added perpendicularly or substantially perpendicularly to the top surface of the substrate, it is sometimes difficult to supply the halogen element uniformly to a desired region.

Thus, the halogen element is preferably added from a direction that is inclined to the top surface of the substrate at greater than 0° and less than 90°. Thus, the halogen element can be easily supplied to the side surface of the insulating layer 280 in the opening portion 290. The adding direction is not limited to one direction; the halogen element is preferably supplied step by step at different rotation angles, in which case the halogen element can be supplied to a desired region more uniformly.

An element that can be used as the halogen element is as described above.

A plasma ion doping method or an ion implantation method can be suitably used for the supply of the halogen element. In the above methods, the concentration profile in the depth direction can be controlled with high accuracy by the acceleration voltage and the dosage of ions, for example. Note that when one or both of the substrate to be processed and the ion irradiation unit of the apparatus are inclined, for example, the angle at which the halogen element is added can be within the above range.

With the use of an ion implantation method in which a source gas is ionized and the ions are subjected to mass separation and then added, the purity of the halogen element to be supplied can be increased. Furthermore, with the use of a plasma ion doping method in which the source gas is ionized and the ions are added without mass separation, the productivity can be increased.

An ion implantation apparatus or an ion doping apparatus used for supplying the halogen element is used also for manufacturing a Si transistor such as an LTPS transistor; thus, preferably, an apparatus for an existing LTPS manufacturing line can be used, eliminating the need for additional capital investment. Thus, capital investment for manufacturing the semiconductor device can be reduced.

As the source gas of the halogen element, a gas containing the above-described halogen element can be used. As the gas, a gas of halogen alone or a halide gas can also be used. In the case where fluorine is supplied, an F₂ gas, a BF₃ gas, a C₄F₆ gas, a C₅F₆ gas, a C₄F₈ gas, a CF₄ gas, an SF₆ gas, a CHF₃ gas, a CH₂F₂ gas, a CH₃F gas, or the like can be typically used. In the case where chlorine is supplied, a Cl₂ gas, a BCl₃ gas, an SiCl₄ gas, or a CCl₄ gas can be typically used. A mixed gas in which the above source gas is diluted with hydrogen or a noble gas may be used. An ion source is not limited to a gas, and a solid or a liquid may be vaporized by being heated.

The supply of the halogen element can be controlled by setting conditions such as the acceleration voltage and the dose in consideration of the composition, density, thickness, and the like of the insulating layer 280.

Note that there is no limitation on the method for supplying the halogen element, and for example, plasma treatment, treatment using thermal diffusion by heating, or the like may be used. In the case of a plasma treatment method, a halogen element can be supplied in such a manner that plasma is generated in a gas atmosphere containing the halogen element to be supplied and plasma treatment is performed. A dry etching apparatus, an ashing apparatus, a plasma CVD apparatus, a high-density plasma CVD apparatus, or the like can be used as an apparatus for generating the plasma.

The step of supplying the halogen element may be performed while the substrate is heated. Thus, damage applied to the insulating layer 280 when the halogen element is added can be repaired. That is, the addition of the halogen element and the repair of damage due to the addition can be performed on the insulating layer 280 concurrently.

The substrate temperature in the step of supplying the halogen element is preferably higher than or equal to 150 °C and lower than the strain point of the substrate, further preferably higher than or equal to 200 °C and lower than or equal to 500 °C, still further preferably higher than or equal to 200 °C and lower than or equal to 450 °C, yet further preferably higher than or equal to 250 °C and lower than or equal to 400 °C, yet still further preferably higher than or equal to 250 °C and lower than or equal to 350 °C or higher than or equal to 300 °C and lower than or equal to 400 °C, yet still further preferably higher than or equal to 300 °C and lower than or equal to 350 °C.

Alternatively, after the insulating layer 235 illustrated in FIG. 17C or FIG. 17D is formed, the halogen element may be supplied to the insulating layer 235 positioned in the opening portion 290.

When the oxide semiconductor layer 230 is formed while the substrate is heated, the halogen element can be supplied from the insulating layer 280 or the insulating layer 235 to the oxide semiconductor layer 230 in some cases. In the heat treatment performed after formation of the oxide semiconductor layer 230, the halogen element can be supplied from the insulating layer 280 or the insulating layer 235 to the oxide semiconductor layer 230 in some cases.

As described above, the halogen element is added to the insulating layer in contact with the oxide semiconductor layer 230 or the insulating layer placed in the vicinity of the oxide semiconductor layer 230, and then supplied from the insulating layer to the oxide semiconductor layer 230; thus, damage to the channel formation region of the oxide semiconductor layer 230 due to the element addition, decrease in crystallinity of the channel formation region due to the element addition, and the like can be inhibited. As a result, the reliability of the transistor can be improved.

Alternatively, after the oxide semiconductor layer 230 illustrated in FIG. 18A or FIG. 18B is formed, the halogen element may be supplied to the side surface of the oxide semiconductor layer 230 positioned in the opening portion 290.

After the opening portion 290 illustrated in FIG. 17B is formed, an impurity element may be supplied to the top surface of the conductive layer 220b and the top surface of the conductive layer 240b.

After that, the oxide semiconductor layer 230 is formed and heat treatment or the like is performed, whereby the impurity element can be supplied from the conductive layer 220b and the conductive layer 240b to the source region and the drain region of the oxide semiconductor layer 230.

When an impurity element is supplied to the oxide semiconductor layer 230 through the conductive layer 220 or the conductive layer 240, a decrease in crystallinity of the oxide semiconductor layer 230 can be inhibited as compared with the case where an impurity element is directly added to the oxide semiconductor layer 230. Thus, an increase in electrical resistance due to the decrease in crystallinity can be inhibited.

Note that the step of supplying an impurity element is preferably performed after the step in FIG. 17B and before the step of forming the conductive layer 265a in FIG. 18C. That is, the impurity element may be supplied to the oxide semiconductor layer 230 after formation of the oxide semiconductor layer 230. In addition, an impurity element may be added to the oxide semiconductor layer 230 through the insulating layer 250.

When an impurity element is added to the oxide semiconductor layer 230, the sheet resistance of the oxide semiconductor layer 230, the contact resistance between the oxide semiconductor layer 230 and the conductive layer 220, and the contact resistance between the oxide semiconductor layer 230 and the conductive layer 240 can be reduced.

The insulating layer 250 is deposited over the oxide semiconductor layer 230 after an impurity element is directly added to the oxide semiconductor layer 230, whereby the insulating layer 250 can be inhibited from being damaged by addition of an impurity element.

Alternatively, when an impurity element is supplied to the oxide semiconductor layer 230 through the insulating layer 250, the decrease in crystallinity of the oxide semiconductor layer 230 can be inhibited as compared with the case where an impurity element is directly added to the oxide semiconductor layer 230. Thus, an increase in electrical resistance due to the decrease in crystallinity can be inhibited.

When the insulating layer 250 is deposited after the addition of an impurity element, the deposition chamber of the insulating layer 250 might be contaminated. Thus, an impurity element is preferably added after the formation of the insulating layer 250.

In that case, the thickness of the insulating layer 250 in the direction where the impurity element is added is larger in a region provided along the side surface of the insulating layer 235 than in a region provided along the top surface of the conductive layer 220b or the top surface of the conductive layer 240b. Thus, in the oxide semiconductor layer 230, the addition amount of the impurity element is larger in the region provided along the top surface of the conductive layer 220b or the top surface of the conductive layer 240b than in the region provided along the side surface of the insulating layer 235. In this manner, the impurity element can be inhibited from entering the channel formation region of the oxide semiconductor layer 230, so that the resistances of the source region and the drain region can be reduced preferentially.

Thus, the impurity element is preferably added from a direction perpendicular or substantially perpendicular to the top surface of the substrate. In this case, in the oxide semiconductor layer 230, the addition amount of the impurity element is smaller for a surface inclined to or perpendicular or substantially perpendicular to the top surface of the substrate than for a surface parallel or substantially parallel to the top surface of the substrate. That is, in the oxide semiconductor layer 230, the addition amount of the impurity element is larger in the source region and the drain region than in the channel formation region. Thus, the resistances of the source region and the drain region can be reduced preferentially.

An element that can be used as the impurity element is as described above.

A plasma ion doping method or an ion implantation method can be suitably used for the supply of the impurity element. In the above methods, the concentration profile in the depth direction can be controlled with high accuracy by the acceleration voltage and the dosage of ions, for example.

With the use of an ion implantation method in which the source gas is ionized and the ions are subjected to mass separation and then added, the purity of an impurity element to be supplied can be increased. In the case of using an ion implantation method, the above-described first element is preferably used as the impurity element, and boron or phosphorus is further preferably used. When an element that is stabilized by being bonded to oxygen is used as the impurity element, a low-resistance region that is stable in a low-electric-resistance state can be formed.

Furthermore, with the use of a plasma ion doping method in which the source gas is ionized and the ions are added without mass separation, the productivity can be increased. In the case of using a plasma ion doping method, the first element and hydrogen are both preferably used as the impurity element, and hydrogen and boron or phosphorus are further preferably used. When hydrogen and an element that is stabilized by being bonded to oxygen are both used as the impurity element, the electric resistance of the low-resistance region is easily reduced and the low-electric-resistance state can be kept stable.

An ion implantation apparatus or an ion doping apparatus used for supplying the impurity element is used also in manufacturing a Si transistor such as an LTPS transistor. Thus, an apparatus for an existing LTPS manufacturing line can be used and new capital investment is not required, which is preferable. Thus, the cost of capital investment for manufacturing the semiconductor device can be reduced.

In the treatment for supplying an impurity element, the treatment conditions are preferably controlled so that the impurity element concentration in the oxide semiconductor layer 230 can be higher in a portion overlapping with the top surface of the conductive layer 220b or the top surface of the conductive layer 240b than in the other regions. Thus, an impurity element at an optimal concentration can be supplied to the source region and the drain region of the oxide semiconductor layer 230.

As a source gas of the impurity element, a gas containing any of the above-described impurity elements can be used. In the case where boron is supplied, a B₂H₆ gas, a BF₃ gas, or the like can be typically used. In the case where phosphorus is supplied, a PH₃ gas can be typically used. A mixed gas in which the above source gas is diluted with hydrogen or a noble gas may be used.

Alternatively, as the source gas, CH₄, N₂, NH₃, AlH₃, AlCl₃, SiH₄, Si₂H₆, F₂, HF, H₂, (C₅H₅)₂Mg, a noble gas, or the like can be used. An ion source is not limited to a gas, and a solid or a liquid may be vaporized by being heated.

For example, boron and hydrogen are preferably supplied as the impurity element using a gas containing boron and hydrogen. This is preferable because the impurity element can be added without mass separation and the resistance of the oxide semiconductor layer 230 can be easily reduced, thereby improving both the productivity and characteristics of the semiconductor device.

Furthermore, the same source gas is preferably used in the step of supplying the halogen element and the step of supplying an impurity element, in which case the manufacturing cost can be reduced. For example, by ionization of a BF₃ gas and mass separation of the ion, fluorine can be supplied as the halogen element and boron can be supplied as an impurity element.

The supply of an impurity element can be controlled by setting the conditions such as an acceleration voltage and a dose in consideration of the composition, the density, the thickness, and the like of the oxide semiconductor layer 230.

Note that there is no limitation on the method for supplying an impurity element, and for example, plasma treatment, treatment using thermal diffusion by heating, or the like may be used. In the case of a plasma treatment method, an impurity element can be supplied in such a manner that plasma is generated in a gas atmosphere containing the impurity element to be supplied and plasma treatment is performed. A dry etching apparatus, an ashing apparatus, a plasma CVD apparatus, a high-density plasma CVD apparatus, or the like can be used as an apparatus for generating the plasma.

The step of supplying an impurity element is preferably performed while the substrate is heated. Thus, damage applied to the oxide semiconductor layer 230 when an impurity element is added can be repaired. That is, the addition of an impurity element and the repair of damage due to the addition can be performed on the oxide semiconductor layer 230 concurrently.

The substrate temperature in the step of supplying an impurity element is preferably higher than or equal to 150 °C and lower than the strain point of the substrate, further preferably higher than or equal to 200 °C and lower than or equal to 500 °C, still further preferably higher than or equal to 200 °C and lower than or equal to 450 °C, yet further preferably higher than or equal to 250 °C and lower than or equal to 400 °C, yet still further preferably higher than or equal to 250 °C and lower than or equal to 350 °C or higher than or equal to 300 °C and lower than or equal to 400 °C, yet still further preferably higher than or equal to 300 °C and lower than or equal to 350 °C. Heat treatment may be performed after the impurity element is supplied. By the heat treatment, damage to the oxide semiconductor layer 230 in the step of supplying an impurity element can be repaired.

When an element that is stabilized by being bonded to oxygen is used as an impurity element, the impurity element can be inhibited from being released by heat or the like applied during the manufacturing process of the semiconductor device. Thus, even when heat treatment is performed or a film formation step or the like is performed while the substrate is heated after the addition of the impurity element, the low-electric-resistance state can be maintained without release of the impurity element.

### Structure Example 2 of Semiconductor Device

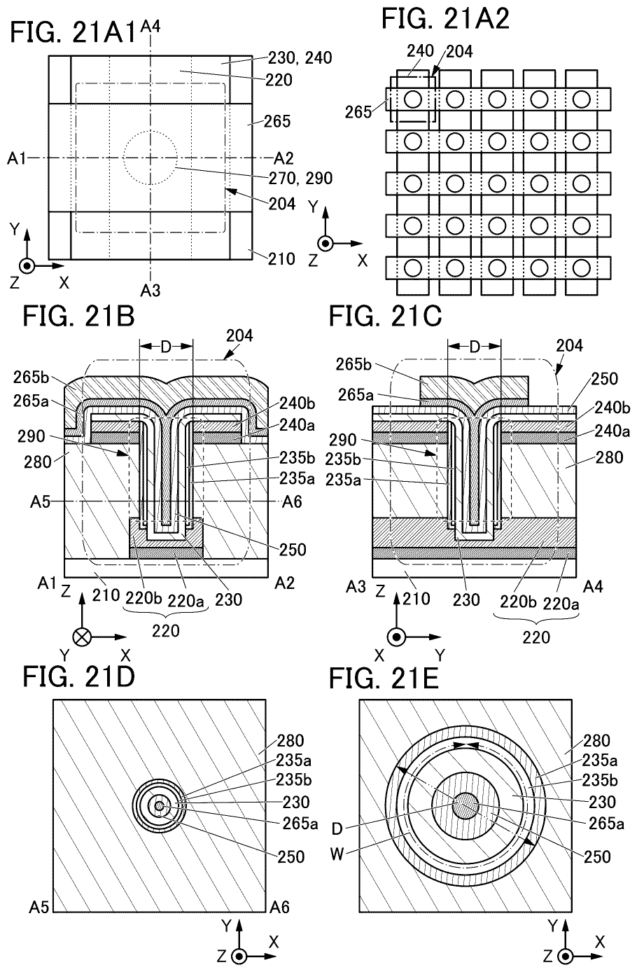

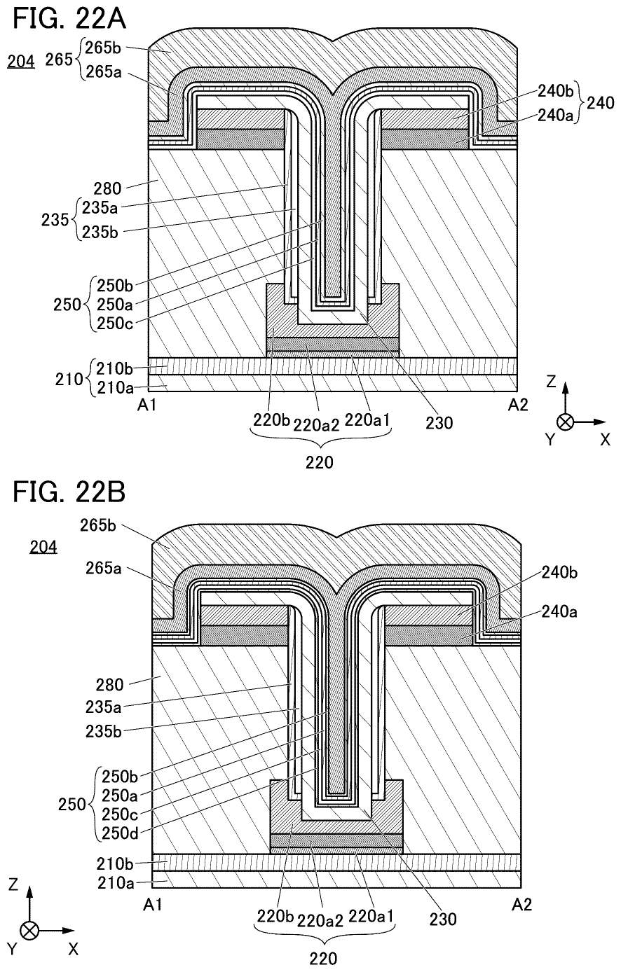

Structure examples of transistors whose structures are partly different from that of the transistor 200 will be described below with reference to FIG. 21A1 to FIG. 22B. Note that description of the portions overlapping with the above is omitted and only different points will be described in detail. Even when positions or shapes of components are different from those in the above example, the same reference numerals are used as long as the components have the same functions as those in the above example, and description thereof is omitted in some cases.

FIG. 21A1 is a plan view of a semiconductor device including a transistor 204. FIG. 21A2 is a plan view illustrating an example where a plurality of transistors 204 are arranged. FIG. 21B is a cross-sectional view along the dashed-dotted line A1-A2 in FIG. 21A1. FIG. 21C is a cross-sectional view taken along the dashed-dotted line A3-A4 in FIG. 21A1. FIG. 21D and FIG. 21E are each a cross-sectional view along the dashed-dotted line A5-A6 in FIG. 21B. FIG. 21E corresponds to an example of an enlarged view of FIG. 21D. FIG. 21D and FIG. 21E can also be regarded as a cross-sectional view along an XY plane including the insulating layer 280. Note that in the plan views of FIG. 21A1 and FIG. 21A2, some components are omitted for the sake of clarity of the drawings. Some components are omitted also in the following plan views in some cases.

FIG. 22A and FIG. 22B are each a cross-sectional view along the dashed-dotted line A1-A2 in FIG. 21A1. FIG. 22A and FIG. 22B each correspond to an example of an enlarged view of FIG. 21B, and illustrates more details of the structure example of each layer.

The semiconductor device illustrated in FIG. 21A1 to FIG. 21E includes the insulating layer 210 over a substrate (not illustrated), the transistor 204 over the insulating layer 210, and the insulating layer 280 over the insulating layer 210. The insulating layer 210 and the insulating layer 280 each function as an interlayer film.

### [Transistor 204]

The transistor 204 includes the conductive layer 220a, the conductive layer 220b over the conductive layer 220a, the conductive layer 240a over the insulating layer 280, the conductive layer 240b over the conductive layer 240a, the insulating layer 235, the oxide semiconductor layer 230, the insulating layer 250 over the oxide semiconductor layer 230, the conductive layer 265a over the insulating layer 250, and the conductive layer 265b over the conductive layer 265a. The transistor 204 is different from the transistor 200 mainly in that the insulating layer 235 has a stacked-layer structure.

FIG. 21A1 to FIG. 21E illustrate an example in which the insulating layer 235 includes two layers of an insulating layer 235a that is in contact with the insulating layer 280 and an insulating layer 235b that is positioned between the insulating layer 235a and the oxide semiconductor layer 230. It can be said that the insulating layer 235 illustrated in FIG. 21A1 to FIG. 21E has a two-layer structure of the insulating layer 235a and the insulating layer 235b over the insulating layer 235a. Here, for one of the insulating layer 235a and the insulating layer 235b, an insulator having a function of capturing or fixing hydrogen is preferably used, for example. The other of the insulating layer 235a and the insulating layer 235b is preferably an insulating layer including a region containing excess oxygen. Accordingly, the hydrogen concentration in the oxide semiconductor layer 230 can be reduced, and oxygen can be supplied from the insulating layer 235a or the insulating layer 235b to the oxide semiconductor layer 230, so that the reliability of the transistor can be improved. Typically, the insulating layer 235a can be formed using an insulator having a function of capturing or fixing hydrogen, and the insulating layer 235b can be an insulating layer including a region containing excess oxygen.

For example, it is preferable that a hafnium oxide film, a hafnium aluminate film, or an aluminum oxide film be used as the insulating layer 235a, and a silicon oxide film, a silicon oxynitride film, or an aluminum oxide film be used as the insulating layer 235b. Here, the insulating layer 235a includes oxygen and one or both of hafnium and aluminum, and the insulating layer 235b includes oxygen and one or both of silicon and aluminum. For another example, a hafnium silicate film may be used as the insulating layer 235a. Alternatively, it is preferable that a silicon oxide film, a silicon oxynitride film, or an aluminum oxide be used as the insulating layer 235a, and a hafnium oxide film, a hafnium aluminate film, or an aluminum oxide film be used as the insulating layer 235b. Here, the insulating layer 235a includes oxygen and one or both of silicon and aluminum, and the insulating layer 235b includes oxygen and one or both of hafnium and aluminum. For another example, a hafnium silicate film may be used as the insulating layer 235b.

As described above, the barrier insulating layer against hydrogen encloses the periphery of the oxide semiconductor layer 230 annularly, and an insulating layer having a function of capturing or fixing hydrogen or an insulating layer including a region containing excess oxygen is provided in the vicinity of the oxide semiconductor layer 230, in which case one or both of oxygen vacancies and impurities in the oxide semiconductor layer 230 can be reduced. Thus, the transistors can have favorable electrical characteristics and higher reliability.

As described in <Structure example 1 of semiconductor device> above, the semiconductor device of this embodiment has a structure in which insulating layers are provided above and below the oxide semiconductor layer 230. Examples of the insulating layer provided above or below the oxide semiconductor layer 230 include the insulating layer 210 and the insulating layer 250.

The above description in <Structure example 1 of semiconductor device>can be referred to for the structures of the insulating layer 210 and the insulating layer 250. For example, as illustrated in FIG. 22A, the insulating layer 210 may have a two-layer structure of the insulating layer 210a and the insulating layer 210b over the insulating layer 210a. The insulating layer 250 may have a three-layer structure of the insulating layer 250c, the insulating layer 250a over the insulating layer 250c, and the insulating layer 250b over the insulating layer 250a. Alternatively, as illustrated in FIG. 22B, the insulating layer 250 may have a four-layer structure of the insulating layer 250d, the insulating layer 250c over the insulating layer 250d, the insulating layer 250a over the insulating layer 250c, and the insulating layer 250b over the insulating layer 250a.

In the example of the transistor 204 illustrated in FIG. 22A, the insulating layer 235a is provided in contact with the bottom surface and the side surface of the depressed portion of the conductive layer 220b, and the insulating layer 235b is provided over the insulating layer 235a. For example, an insulating film to be the insulating layer 235a and an insulating film to be the insulating layer 235b are stacked, and then the two insulating films are processed, whereby the insulating layer 235a and the insulating layer 235b in the structure illustrated in FIG. 22A can be formed. Thus, it can be said that the structure can be formed relatively easily.

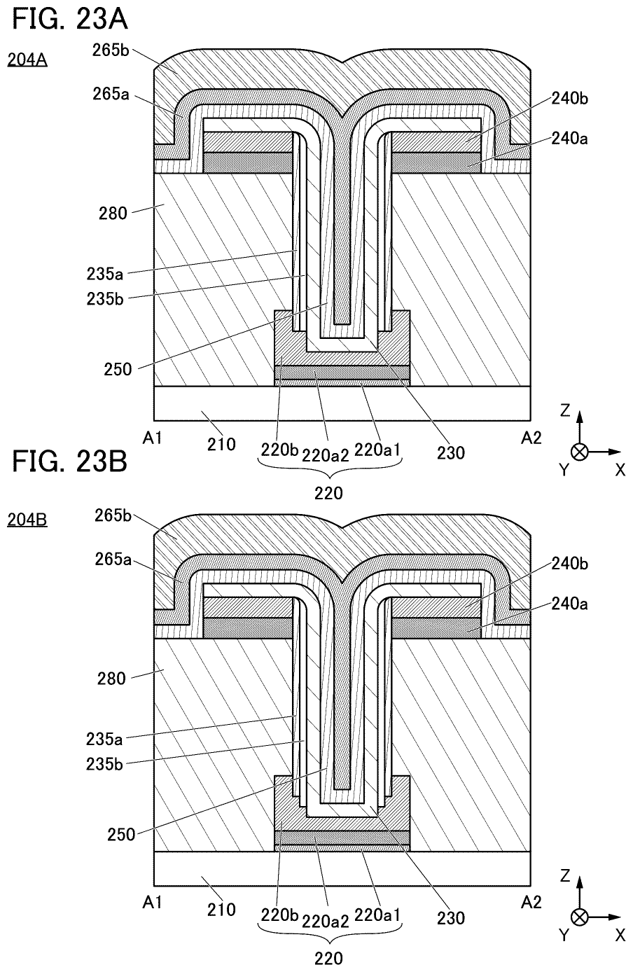

Structure examples of transistors whose structures are partly different from that of the transistor 204 will be described below with reference to FIG. 23A to FIG. 27B. Note that description of the portions overlapping with the above is omitted and only different points will be described in detail. Even when positions or shapes of components are different from those in the above example, the same reference numerals are used as long as the components have the same functions as those in the above example, and description thereof is omitted in some cases.

### [Transistors 204A, 204B]

FIG. 23A is a cross-sectional view of a semiconductor device including a transistor 204A. FIG. 23B is a cross-sectional view of a semiconductor device including a transistor 204B.

In the example of the transistor 204A, the insulating layer 235a is provided in contact with the bottom surface and the side surface of the depressed portion of the conductive layer 220b, and the insulating layer 235b is positioned inward from the insulating layer 235a and is in contact with the bottom portion of the depressed portion of the conductive layer 220b in the opening portion 290.

In the transistor 204B, the conductive layer 220b includes the first depressed portion, the second depressed portion positioned outward from the first depressed portion, and a third depressed portion positioned outward from the second depressed portion. The depth of the first depressed portion is greater than that of the second depressed portion, and the depth of the second depressed portion is greater than that of the third depressed portion. The third depressed portion is provided in the conductive layer 220b at the time of forming the opening portion 290, the second depressed portion is provided in the conductive layer 220b at the time of processing the insulating layer 235a, and then the first depressed portion is provided in the conductive layer 220b at the time of processing the insulating layer 235b. Thus, in FIG. 23B, the side surface of the first depressed portion is aligned with a surface of the insulating layer 235b on the oxide semiconductor layer 230 side, the side surface of the second depressed portion is aligned with a surface of the insulating layer 235a on the insulating layer 235b side, and the side surface of the third depressed portion is aligned with the side surface of the insulating layer 280 on the opening portion 290 side.

In the example of the transistor 204B, the insulating layer 235a is provided in contact with the bottom surface and the side surface of the third depressed portion of the conductive layer 220b, and the insulating layer 235b is provided in contact with the bottom surface and the side surface of the second depressed portion of the conductive layer 220b.

For example, after the insulating layer 235a is provided on the sidewall of the opening portion 290, an insulating film to be the insulating layer 235b is formed and processed, whereby the insulating layer 235a and the insulating layer 235b as illustrated in FIG. 23A or FIG. 23B can be formed. A structure can be obtained in which the contact area between the insulating layer 235a and the oxide semiconductor layer 230 can be smaller than that in the transistor 204, and the insulating layer 235b can be in contact with the oxide semiconductor layer 230.

### [Transistor 204C]

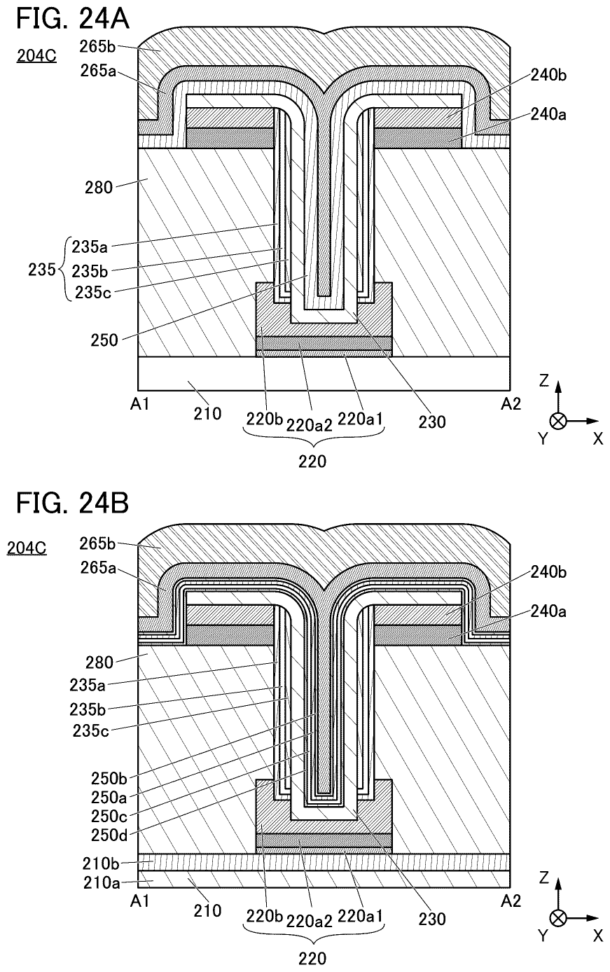

FIG. 24A is a cross-sectional view of a semiconductor device including a transistor 204C.

The transistor 204C is different from the transistor 200 mainly in that the insulating layer 235 has a three-layer structure.

The transistor 204C includes the insulating layer 235a in contact with the insulating layer 280, the insulating layer 235b positioned between the insulating layer 235a and the oxide semiconductor layer 230, and an insulating layer 235c positioned between the insulating layer 235b and the oxide semiconductor layer 230. It can also be said that the transistor 204C includes the insulating layer 235a, the insulating layer 235b over the insulating layer 235a, and the insulating layer 235c over the insulating layer 235b.

At least one of the insulating layer 235a, the insulating layer 235b, and the insulating layer 235c preferably includes an insulating layer including a region containing excess oxygen. An insulator having a function of capturing or fixing hydrogen is preferably used as at least another one of the insulating layer 235a, the insulating layer 235b, and the insulating layer 235c.

Accordingly, oxygen can be supplied from at least one of the insulating layer 235a, the insulating layer 235b, and the insulating layer 235c to the oxide semiconductor layer 230 and diffusion of hydrogen into the oxide semiconductor layer 230 can be inhibited, leading to higher reliability of the transistor.

For example, it is preferable that a hafnium oxide film or a hafnium silicate film be used as the insulating layer 235a, a silicon oxide film be used as the insulating layer 235b, and an aluminum oxide film be used as the insulating layer 235c.

The above description in <Structure example 1 of semiconductor device>can be referred to for the structures of the insulating layer 210 and the insulating layer 250. For example, as illustrated in FIG. 24B, the insulating layer 210 may have a two-layer structure of the insulating layer 210a and the insulating layer 210b over the insulating layer 210a. Moreover, the insulating layer 250 may have a four-layer structure of the insulating layer 250d, the insulating layer 250c over the insulating layer 250d, the insulating layer 250a over the insulating layer 250c, and the insulating layer 250b over the insulating layer 250a.

Note that the insulating layer 235 having a three-layer structure in the transistor 204C can be regarded as a variation example of the insulating layer 235 having a two-layer structure in the transistor 204 (FIG. 22A). In the case where the insulating layer 235 has a three-layer structure, the structure is not limited to that illustrated in the transistor 204C. For example, the insulating layer 235, which has a two-layer structure in the transistor 204A (FIG. 23A) or the transistor 204B (FIG. 23B), can have a three-layer structure.

The above description in <Structure example 1 of semiconductor device>can be referred to for the structures of the insulating layer 210 and the insulating layer 250. For example, as illustrated in FIG. 24B, the insulating layer 210 may have a two-layer structure of the insulating layer 210a and the insulating layer 210b over the insulating layer 210a. Alternatively, as illustrated in FIG. 24B, the insulating layer 250 may have a four-layer structure of the insulating layer 250d, the insulating layer 250c over the insulating layer 250d, the insulating layer 250a over the insulating layer 250c, and the insulating layer 250b over the insulating layer 250a.

### [Transistor 204D]

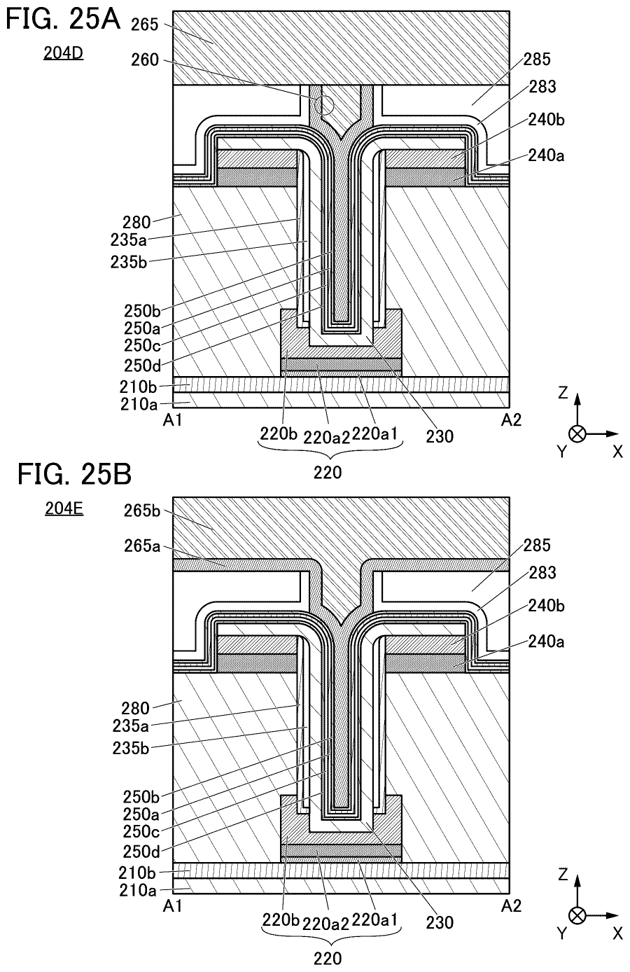

FIG. 25A is a cross-sectional view of a semiconductor device including a transistor 204D.

The transistor 204D is different from the transistor 201 mainly in that the insulating layer 235 has a two-layer structure. For the details of the insulating layer 235 having a two-layer structure, the description of the transistor 204 (FIG. 21A1 to FIG. 21E) can be referred to.

### [Transistor 204E]

FIG. 25B is a cross-sectional view of a semiconductor device including a transistor 204E.

The transistor 204E is different from the transistor 202 mainly in that the insulating layer 235 has a two-layer structure. For the details of the insulating layer 235 having a two-layer structure, the description of the transistor 204 (FIG. 21A1 to FIG. 21E) can be referred to.

### [Transistor 204F]

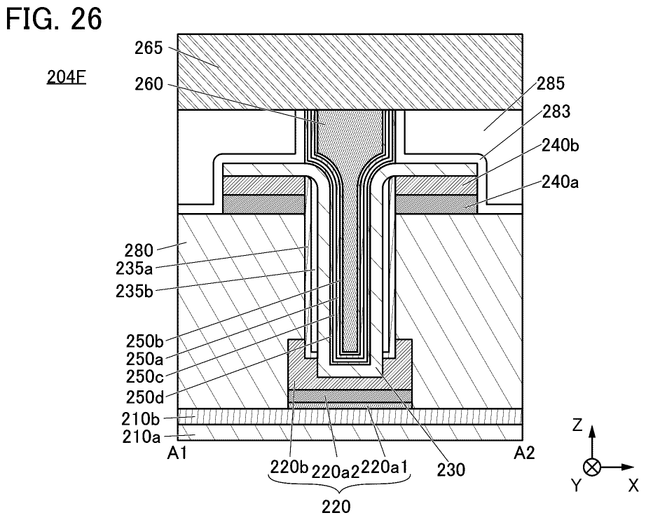

FIG. 26 is a cross-sectional view of a semiconductor device including a transistor 204F.

The transistor 204F is different from the transistor 203 mainly in that the insulating layer 235 has a two-layer structure. For the details of the insulating layer 235 having a two-layer structure, the description of the transistor 204 (FIG. 21A1 to FIG. 21E) can be referred to.

### [Transistors 204G, 204H]

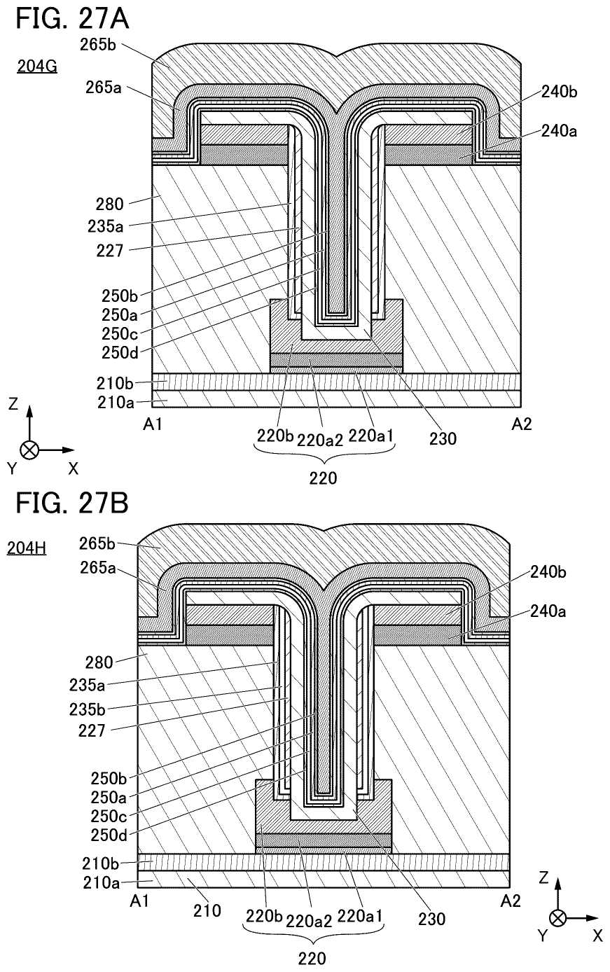

FIG. 27A is a cross-sectional view of a semiconductor device including a transistor 204G.

The transistor 204G is different from the transistor 204 mainly in including a metal oxide layer 227 instead of the insulating layer 235b.

The metal oxide layer 227 is preferably formed using a metal oxide material that can be used as the oxide semiconductor layer 230. For example, the metal oxide layer 227 preferably includes one or both of gallium and zinc. When the metal oxide layer 227 includes gallium, oxygen contained in the oxide semiconductor layer 230 can be inhibited from diffusing into the insulating layer 235a or the like, and oxygen vacancies can be inhibited from being formed in the oxide semiconductor layer 230. In addition, when the metal oxide layer 227 includes zinc, the crystallinity of the metal oxide layer 227 can be increased and the crystallinity of the oxide semiconductor layer 230 provided over the metal oxide layer 227 can be improved.

A single layer or stacked layers of gallium oxide, zinc oxide, indium gallium oxide, gallium zinc oxide, aluminum zinc oxide, indium gallium zinc oxide, or the like can be used for the metal oxide layer 227, for example. In the case of using indium gallium zinc oxide for the metal oxide layer 227, a metal oxide with a composition of In:M:Zn=1:3:2 [atomic ratio] or in the neighborhood thereof or a composition of In:M:Zn=1:3:4 [atomic ratio] or in the neighborhood thereof is specifically used.

The thickness of the metal oxide layer 227 can be smaller than that of the oxide semiconductor layer 230 and can be, for example, greater than or equal to 0.1 nm and less than or equal to 1 nm, or greater than or equal to 0.1 nm and less than or equal to 0.5 nm.

When the metal oxide layer 227 is provided between the insulating layer 235a and the oxide semiconductor layer 230, impurity components such as hydrogen contained in the insulating layer 235a can be inhibited from diffusing into the oxide semiconductor layer 230. Furthermore, the crystallinity of the oxide semiconductor layer 230 can be improved. When the metal oxide layer 227 can sufficiently inhibit diffusion of impurity components such as hydrogen contained in the insulating layer 235a, an insulating material that relatively easily transmits hydrogen, such as silicon oxide, can also be used for the insulating layer 235a.

Note that in the case where the insulating layer 235a has a function of capturing or fixing hydrogen, the thickness of the insulating layer 235a is preferably large, and for example, the insulating layer 235a is preferably thicker than the metal oxide layer 227. When the insulating layer 235a is thick, hydrogen in the oxide semiconductor layer 230 is diffused into the insulating layer 235a and the hydrogen can be captured or fixed. Note that the insulating layer 235a is preferably a thin film so that it can be provided inside the opening portion 290. For example, the thickness of the insulating layer 235a can be greater than or equal to 1 nm and less than or equal to 10 nm, greater than or equal to 1 nm and less than or equal to 5 nm, or greater than or equal to 3 nm and less than or equal to 5 nm.

Note that the transistor included in the semiconductor device of this embodiment can have a structure in which the metal oxide layer 227 is provided instead of the insulating layer 235c of the transistor 204C illustrated in FIG. 24A or the transistor 204C illustrated in FIG. 24B. FIG. 27B illustrates a transistor 204H that includes the metal oxide layer 227 instead of the insulating layer 235c of the transistor 204C illustrated in FIG. 24B.

FIG. 21B to FIG. 27B illustrate examples in which the insulating layer 235 includes two layers or three layers. Note that the insulating layer 235 may include four or more layers. The mode and details of the transistor 204 can be modified as in the case of the transistor 200. Specifically, the transistor 204 can have a structure similar to that of any of the transistor 200A to the transistor 200G.

<Structure example 3 of semiconductor device>

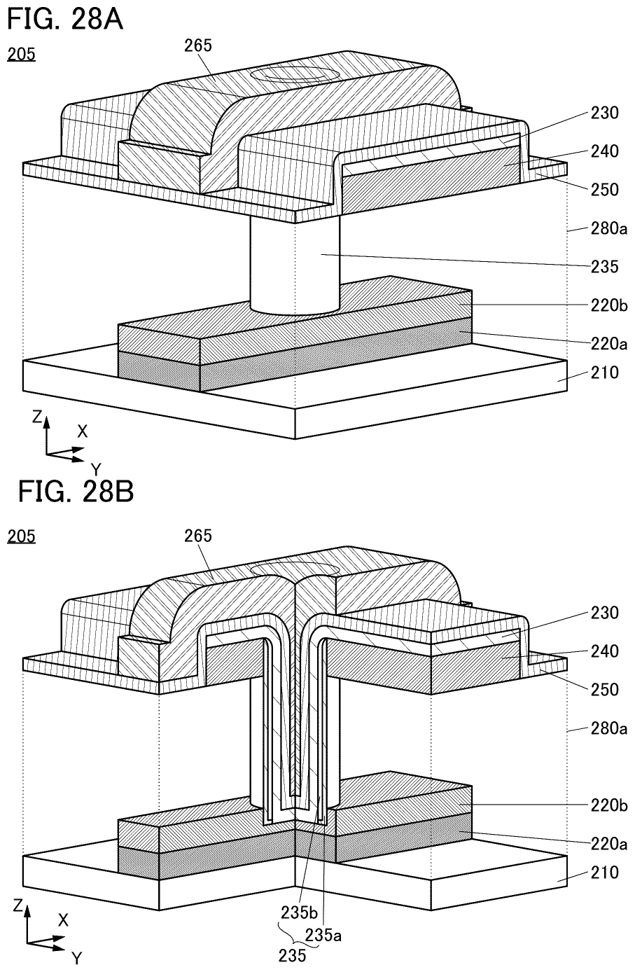

Structure examples of transistors whose structures are partly different from that of the transistor 200 will be described below with reference to FIG. 28A to FIG. 30B. Note that description of the portions overlapping with the above is omitted and only different points will be described in detail. Even when positions or shapes of components are different from those in the above example, the same reference numerals are used as long as the components have the same functions as those in the above example, and description thereof is omitted in some cases.

FIG. 28A and FIG. 28B are schematic cross-sectional views of a semiconductor device including the transistor 205. FIG. 28B is a perspective view of FIG. 28A part of which is cut out. In FIG. 28A and FIG. 28B, only the outlines of some components (e.g., interlayer insulating layers) are indicated by dashed lines.

FIG. 29A1 is a plan view of the semiconductor device including the transistor 205. FIG. 29A2 is a plan view illustrating an example where a plurality of transistors 205 are arranged. FIG. 29B is a cross-sectional view taken along the dashed-dotted line A1-A2 in FIG. 29A1. FIG. 29C is a cross-sectional view along the dashed-dotted line A3-A4 in FIG. 29A1. FIG. 29D and FIG. 29E are cross-sectional views taken along dashed-dotted line A5-A6 in FIG. 29B. FIG. 29E corresponds to an example of an enlarged view of FIG. 29D. FIG. 29D and FIG. 29E can also be regarded as a cross-sectional view along an XY plane including the insulating layer 280a. Note that in the plan views of FIG. 29A1 and FIG. 29A2, some components are omitted for the sake of clarity of the drawings. Some components are omitted also in the following plan views in some cases.

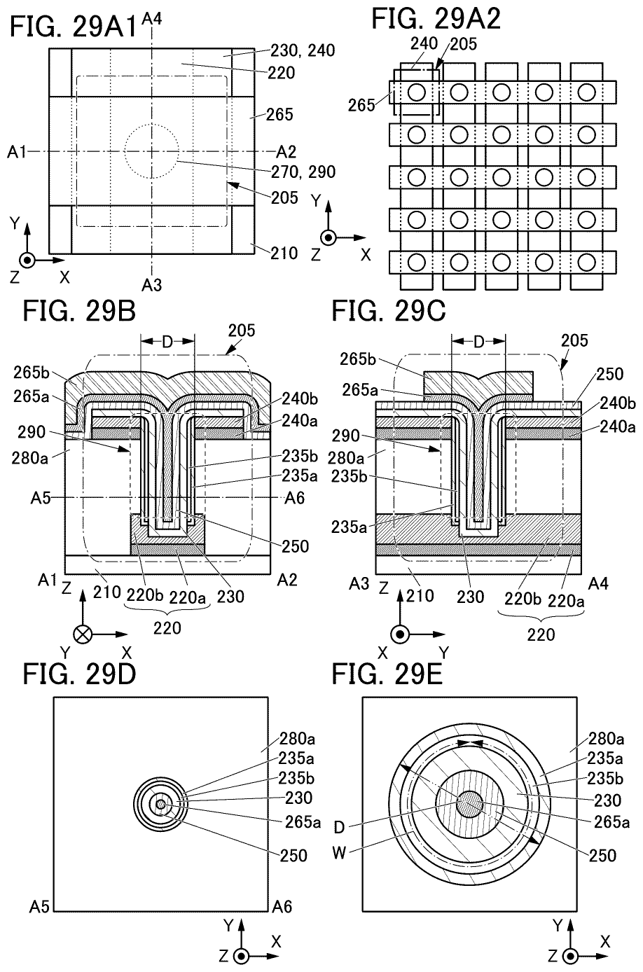

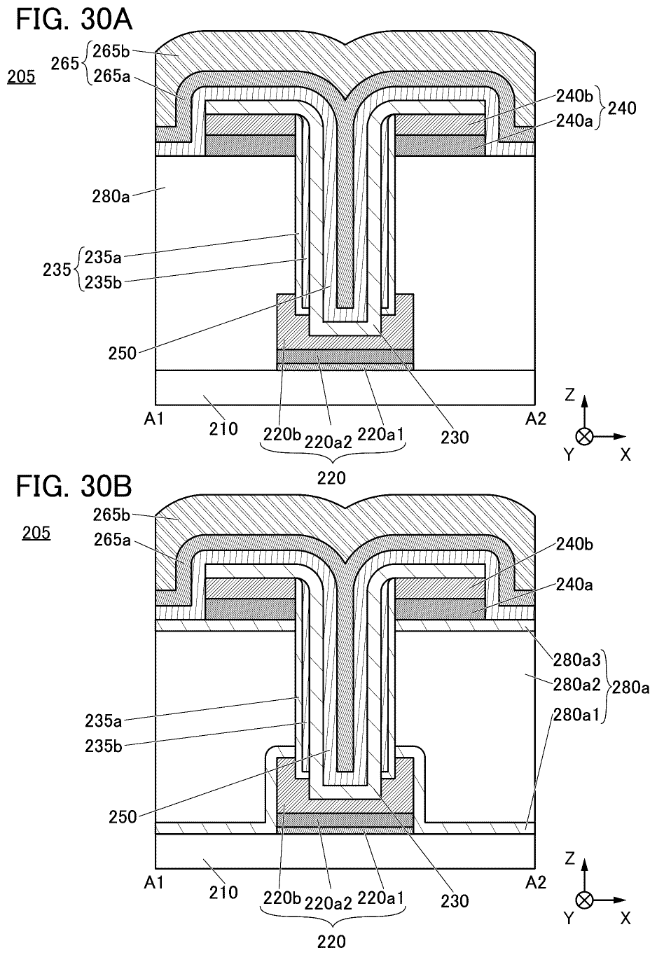

FIG. 30A and FIG. 30B are each a cross-sectional view taken along the dashed-dotted line A1-A2 illustrated in FIG. 29A1. FIG. 30A and FIG. 30B correspond to an example of an enlarged view of FIG. 30B, and illustrate the structure example of each layer in more detail.

The semiconductor device illustrated in FIG. 28A to FIG. 29E includes the insulating layer 210 over a substrate (not illustrated), the transistor 205 over the insulating layer 210, and the insulating layer 280a over the insulating layer 210. The insulating layer 210 and the insulating layer 280a each function as an interlayer film.

### [Transistor 205]

The transistor 205 includes the conductive layer 220a, the conductive layer 220b over the conductive layer 220a, the conductive layer 240a over the insulating layer 280a, the conductive layer 240b over the conductive layer 240a, the insulating layer 235, the oxide semiconductor layer 230, the insulating layer 250 over the oxide semiconductor layer 230, the conductive layer 265a over the insulating layer 250, and the conductive layer 265b over the conductive layer 265a. The transistor 205 is different from the transistor 200 mainly in that the insulating layer 235 has a two-layer structure. The transistor 205 is different from the above-described transistor 200 mainly in including the insulating layer 280a instead of the insulating layer 280.

FIG. 29D and FIG. 29E illustrates an example in which the insulating layer 235 includes two layers of the insulating layer 235a and the insulating layer 235b; the insulating layer 235a is in contact with the insulating layer 280a, and the insulating layer 235b is positioned between the insulating layer 235a and the oxide semiconductor layer 230. As illustrated in FIG. 29D and FIG. 29E, the transistor 205 has a structure in which the insulating layer 235a encloses the periphery of the oxide semiconductor layer 230 annularly in a plan view. In the semiconductor device, the insulating layer 235b is positioned between the insulating layer 235a and the oxide semiconductor layer 230 in a plan view.

In the case where the insulating layer 235 has the two-layer structure, the insulating layer 235a provided outside the oxide semiconductor layer 230 can be formed using a barrier insulator against hydrogen, and the insulating layer 235b provided in contact with the oxide semiconductor layer 230 can be formed using an insulator having a function of capturing or fixing hydrogen. This structure can reduce the hydrogen concentration in the oxide semiconductor layer 230. Thus, the transistors can have favorable electrical characteristics and higher reliability. For example, the threshold voltage Vth of the transistor can be positively shifted.

For example, a silicon nitride film is preferably used as the insulating layer 235a. In that case, the insulating layer 235a includes silicon and nitrogen. As the insulating layer 235b, a hafnium oxide film, a hafnium aluminate film, or an aluminum oxide film is preferably used. Here, the insulating layer 235b includes oxygen and one or both of hafnium and aluminum. As the insulating layer 235b, a hafnium oxide film is further preferably used. Here, the insulating layer 235b includes hafnium and oxygen.

In addition, the insulating layer 235a provided outside the oxide semiconductor layer 230 can be formed using a barrier insulator against hydrogen, and the insulating layer 235b provided in contact with the oxide semiconductor layer 230 can be an insulating layer including a region containing excess oxygen. This structure can reduce one or both of oxygen vacancies and hydrogen in the oxide semiconductor layer 230. Thus, the transistor can have favorable electrical characteristics and higher reliability.

When the insulating layer 235 has the above structure, the range of choices for the insulating material used for the insulating layer 280a can be widened, so that the yield and the reliability can be improved. For example, a low-relative-permittivity material can be used for the insulating layer 280a. In that case, the parasitic capacitance generated between wirings can be reduced. For example, silicon oxide or silicon oxynitride can be used for the insulating layer 280a. Note that the insulating layer 280a may be formed using any of the above-described insulating materials that can be used for the insulating layer 280.

For example, a silicon nitride film is preferably used as the insulating layer 235a. In that case, the insulating layer 235a includes silicon and nitrogen. As the insulating layer 235b, a silicon oxide film, a silicon oxynitride film, or an aluminum oxide film is preferably used. As the insulating layer 235b, a silicon oxide film is further preferably used. In that case, the insulating layer 235b includes silicon and oxygen.

Silicon nitride that can be used for the insulating layer 235a also has a barrier property against oxygen. The insulating layer 235a is in contact with the side surface of the conductive layer 240 in the opening portion 290. Thus, the use of silicon nitride for the insulating layer 235a in contact with the conductive layer 240 can inhibit oxidation of the conductive layer 240.

Meanwhile, the number of stacked insulating layers 235 provided in the opening portion 290 in the transistor 200 described in <Structure example 1 of semiconductor device> above can be reduced, as compared with that of the transistor 205, and the channel width per unit area can be increased. Accordingly, the transistor 200 can have higher on-state current and improved frequency characteristics.

As illustrated in FIG. 30B, the insulating layer 280a may have a three-layer structure of an insulating layer 280al, an insulating layer 280a2 over the insulating layer 280al, and an insulating layer 280a3 over the insulating layer 280a2. In that case, it is preferable that any of the above-described low-relative-permittivity materials be used for the insulating layer 280a2 and a barrier insulating layer against oxygen be used as each of the insulating layer 280al and the insulating layer 280a3. Thus, the conductive layer 220 and the conductive layer 240 can be inhibited from being oxidized and having an increased resistance.

In that case, it is preferable that any of the above-described low-relative-permittivity materials be used for the insulating layer 280a2 and a barrier insulating layer against hydrogen be used as each of the insulating layer 280al and the insulating layer 280a3. With such a structure, the insulating layer 280a2 can be surrounded by the insulating layer 280al, the insulating layer 280a3, and the insulating layer 235a. This is preferable because diffusion of impurities such as hydrogen from the insulating layer 280a2 into the oxide semiconductor layer 230 can be inhibited.

For example, it is preferable that a silicon nitride film or an aluminum oxide film be used as each of the insulating layer 280al and the insulating layer 280a3 and a silicon oxide film be used as the insulating layer 280a2.

The above description in <Structure example 1 of semiconductor device>can be referred to for the structure of the conductive layer 220. For example, as illustrated in FIG. 30A, the conductive layer 220 may have a three-layer structure of the conductive layer 220al, the conductive layer 220a2 over the conductive layer 220al, and the conductive layer 220b over the conductive layer 220a2.

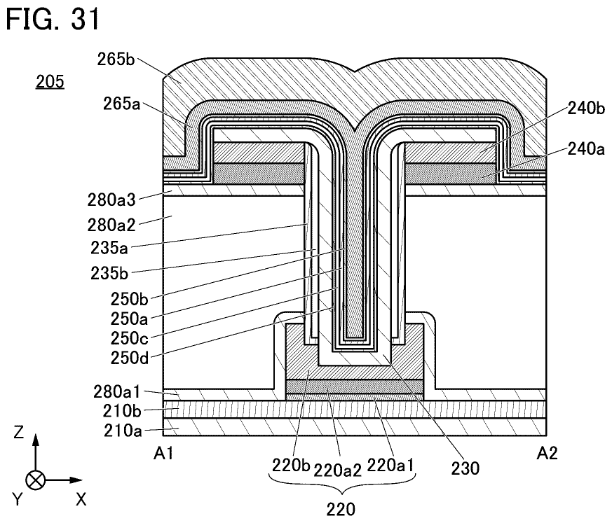

The above description in <Structure example 1 of semiconductor device>can be referred to for the structures of the insulating layer 210 and the insulating layer 250. For example, as illustrated in FIG. 31, the insulating layer 210 may have a two-layer structure of the insulating layer 210a and the insulating layer 210b over the insulating layer 210a. In addition, the insulating layer 250 may have a four-layer structure of the insulating layer 250d, the insulating layer 250c over the insulating layer 250d, the insulating layer 250a over the insulating layer 250c, and the insulating layer 250b over the insulating layer 250a.

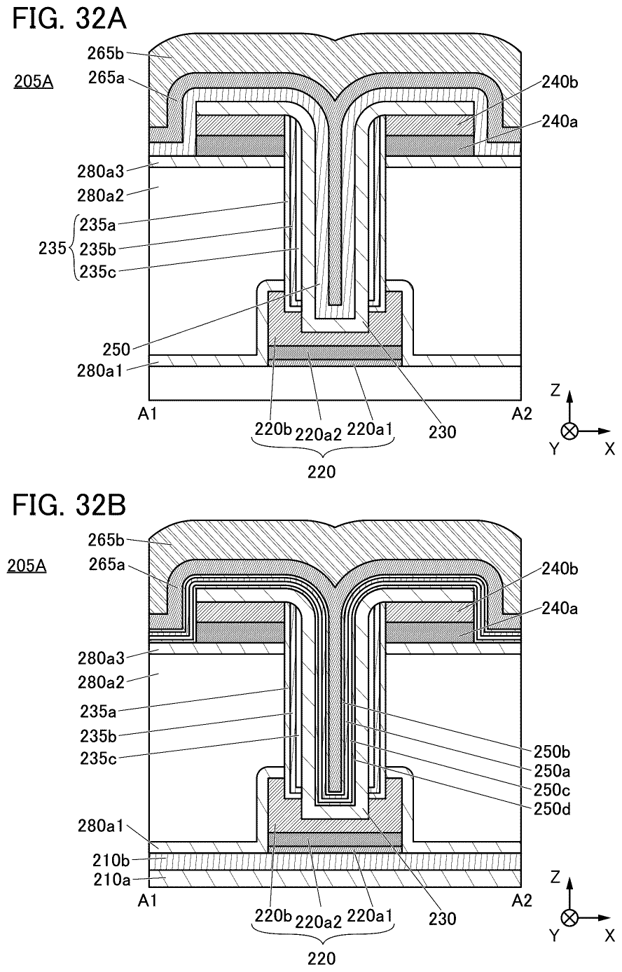

Structure examples of transistors whose structures are partly different from that of the transistor 205 will be described below with reference to FIG. 32A to FIG. 35. Note that description of the portions overlapping with the above is omitted and only different points will be described in detail. Even when positions or shapes of components are different from those in the above example, the same reference numerals are used as long as the components have the same functions as those in the above example, and description thereof is omitted in some cases.

### [Transistor 205A]

FIG. 32A is a cross-sectional view of a semiconductor device including a transistor 205A.

The transistor 205A is different from the transistor 205 mainly in that the insulating layer 235 has a three-layer structure.

The transistor 205A includes the insulating layer 235a in contact with the insulating layer 280a, the insulating layer 235b positioned between the insulating layer 235a and the oxide semiconductor layer 230, and the insulating layer 235c positioned between the insulating layer 235b and the oxide semiconductor layer 230. It can be said that the transistor 205A includes the insulating layer 235a, the insulating layer 235b over the insulating layer 235a, and the insulating layer 235c over the insulating layer 235b.

As the insulating layer 235a, a barrier insulator against hydrogen is preferably used. One of the insulating layer 235b and the insulating layer 235c preferably includes an insulating layer including a region containing excess oxygen. Furthermore, for the other of the insulating layer 235b and the insulating layer 235c, an insulator having a function of capturing or fixing hydrogen is preferably used. With such a structure, diffusion of hydrogen into the oxide semiconductor layer 230 can be inhibited and oxygen can be supplied to the oxide semiconductor layer 230, so that the reliability of the transistor can be improved.

For example, as the insulating layer 235a, a silicon nitride film or an aluminum oxide film is preferably used, and a silicon nitride film is further preferably used. As the insulating layer 235b, a hafnium oxide film, a hafnium aluminate film, or aluminum oxide is preferably used. Here, the insulating layer 235b includes oxygen and one or both of hafnium and aluminum. A hafnium silicate film is preferably used as the insulating layer 235b. As the insulating layer 235c, a silicon oxide film, a silicon oxynitride film, or an aluminum oxide film is preferably used. Here, the insulating layer 235c includes oxygen and one or both of silicon and aluminum.

Note that the transistor included in the semiconductor device of this embodiment can have a structure in which the metal oxide layer 227 is provided instead of the insulating layer 235c of the transistor 205A illustrated in FIG. 32A or the transistor 205A illustrated in FIG. 32B. The above description in <Structure example 2 of semiconductor device>can be referred to for the metal oxide material that can be used for the metal oxide layer 227.

The above description in <Structure example 1 of semiconductor device>can be referred to for the structures of the insulating layer 210 and the insulating layer 250. For example, as illustrated in FIG. 32B, the insulating layer 210 may have a two-layer structure of the insulating layer 210a and the insulating layer 210b over the insulating layer 210a. Moreover, the insulating layer 250 may have a four-layer structure of the insulating layer 250d, the insulating layer 250c over the insulating layer 250d, the insulating layer 250a over the insulating layer 250c, and the insulating layer 250b over the insulating layer 250a.

### [Transistor 205B]

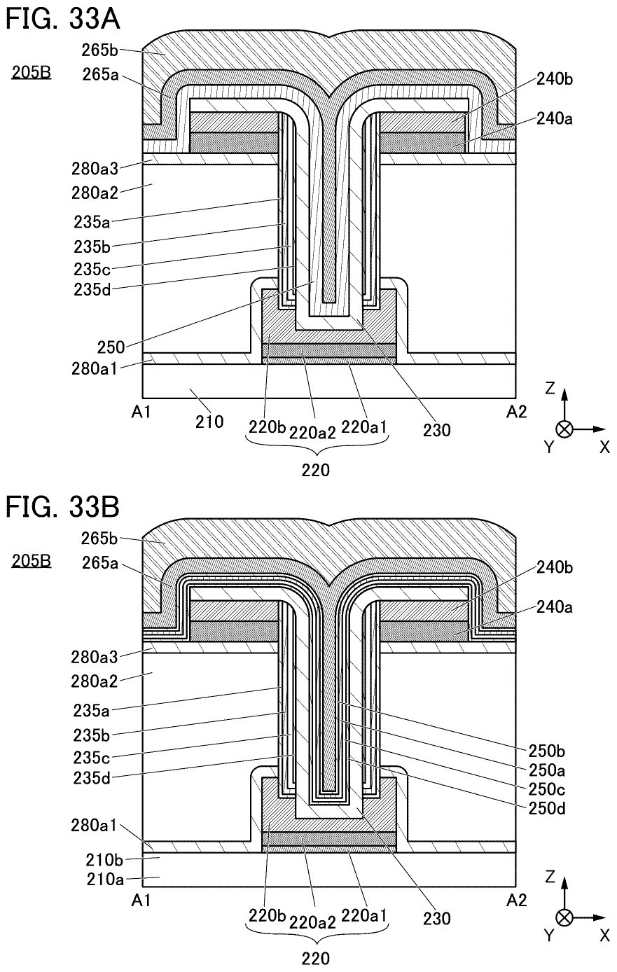

FIG. 33A is a cross-sectional view of a semiconductor device including a transistor 205B.

The transistor 205B is different from the transistor 205 mainly in that the insulating layer 235 has a four-layer structure.

The transistor 205B includes the insulating layer 235a in contact with the insulating layer 280, the insulating layer 235b positioned between the insulating layer 235a and the oxide semiconductor layer 230, the insulating layer 235c positioned between the insulating layer 235b and the oxide semiconductor layer 230, and the insulating layer 235d positioned between the insulating layer 235c and the oxide semiconductor layer 230. It can be said that the transistor 205B includes the insulating layer 235a, the insulating layer 235b over the insulating layer 235a, the insulating layer 235c over the insulating layer 235b, and the insulating layer 235d over the insulating layer 235c.

As the insulating layer 235a, a barrier insulator against hydrogen is preferably used. At least one of the insulating layer 235b to the insulating layer 235d preferably includes an insulating layer including a region containing excess oxygen. At least another one of the insulating layer 235b to the insulating layer 235d preferably includes an insulator having a function of capturing or fixing hydrogen. With such a structure, diffusion of hydrogen into the oxide semiconductor layer 230 can be inhibited and oxygen can be supplied to the oxide semiconductor layer 230, so that the reliability of the transistor can be improved.

For example, it is preferable that a silicon nitride film or an aluminum oxide film be used as the insulating layer 235a, a hafnium oxide film or a hafnium silicate film be used as the insulating layer 235b, a silicon oxide film be used as the insulating layer 235c, and an aluminum oxide film be used as the insulating layer 235d.

The layers included in the insulating layer 235 are each preferably a thin film. A smaller thinness of the insulating layer 235 can inhibit a reduction in the channel width of the transistor, thereby inhibiting a reduction in the on-state current of the transistor. Meanwhile, when the thickness of the insulating layer 235 is increased, the function of the insulating layer 235 (e.g., a barrier property against hydrogen, a function of capturing or fixing hydrogen, or the like) can be enhanced. For example, the thickness of the insulating layer 235 is preferably greater than or equal to 1 nm and less than or equal to 20 nm, further preferably greater than or equal to 2 nm and less than or equal to 15 nm, still further preferably greater than or equal to 3 nm and less than or equal to 10 nm.

The thickness of each of the layers included in the insulating layer 235 (corresponding to the insulating layer 235a to the insulating layer 235d in the case of the structure illustrated in FIG. 33A) is preferably larger than or equal to 0.1 nm and smaller than or equal to 10 nm, further preferably larger than or equal to 0.1 nm and smaller than or equal to 5 nm, still further preferably larger than or equal to 0.5 nm and smaller than or equal to 5 nm, yet further preferably larger than or equal to 1 nm and smaller than 5 nm, yet still further preferably larger than or equal to 1 nm and smaller than or equal to 3 nm. Note that at least part of each of the layers included in the insulating layer 235 preferably includes a region having the above-described thickness.

Note that the transistor included in the semiconductor device of this embodiment can have a structure in which the metal oxide layer 227 is provided instead of the insulating layer 235d of the transistor 205B illustrated in FIG. 33A or the transistor 205B illustrated in FIG. 33B. The above description in <Structure example 2 of semiconductor device>can be referred to for the metal oxide material that can be used for the metal oxide layer 227.

The above description in <Structure example 1 of semiconductor device>can be referred to for the structures of the insulating layer 210 and the insulating layer 250. For example, as illustrated in FIG. 33B, the insulating layer 210 may have a two-layer structure of the insulating layer 210a and the insulating layer 210b over the insulating layer 210a. Moreover, the insulating layer 250 may have a four-layer structure of the insulating layer 250d, the insulating layer 250c over the insulating layer 250d, the insulating layer 250a over the insulating layer 250c, and the insulating layer 250b over the insulating layer 250a.

FIG. 29B to FIG. 33B illustrate an example in which the insulating layer 235 includes two layers, three layers, or four layers. Note that the insulating layer 235 may include five or more layers.

### [Transistor 205C]

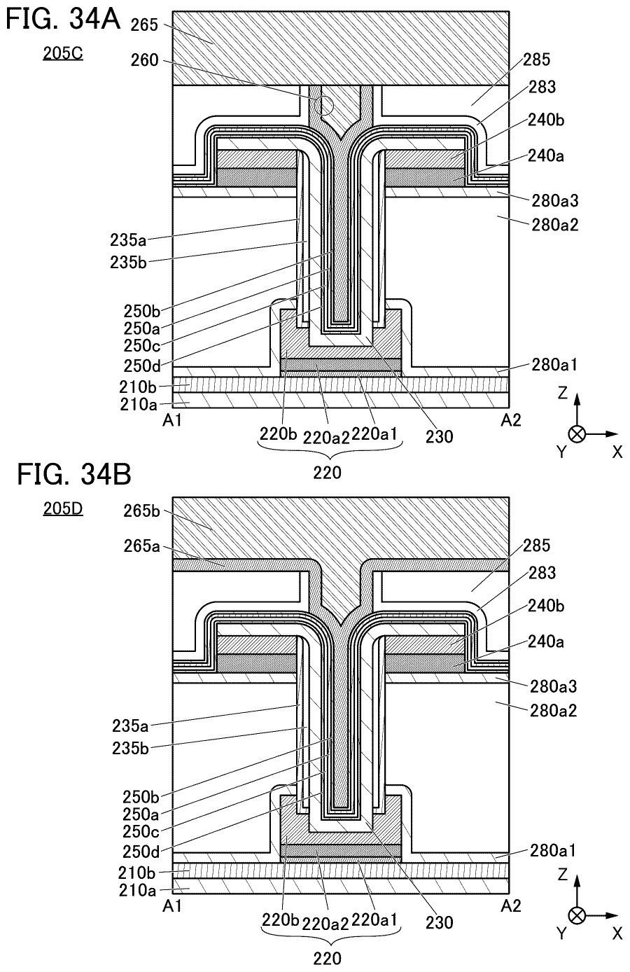

FIG. 34A is a cross-sectional view of a semiconductor device including a transistor 205C.

The transistor 205C is different from the transistor 201 mainly in that the insulating layer 235 has a two-layer structure and the insulating layer 280a is provided instead of the insulating layer 280. FIG. 34A illustrates a structure in which the insulating layer 280a has a three-layer structure of the insulating layer 280al to the insulating layer 280a3. For the details of the insulating layer 235 and the insulating layer 280a illustrated in FIG. 34A, the description of the transistor 205 (FIG. 29A1 to FIG. 30B) can be referred to.

### [Transistor 205D]

FIG. 34B is a cross-sectional view of a semiconductor device including a transistor 205D.

The transistor 205D is different from the transistor 202 mainly in that the insulating layer 235 has a two-layer structure and the insulating layer 280a is provided instead of the insulating layer 280. FIG. 34B illustrates a structure in which the insulating layer 280a has a three-layer structure of the insulating layer 280al to the insulating layer 280a3. For the details of the insulating layer 235 and the insulating layer 280a illustrated in FIG. 34B, the description of the transistor 205 (FIG. 29A1 to FIG. 30B) can be referred to.

### [Transistor 205E]

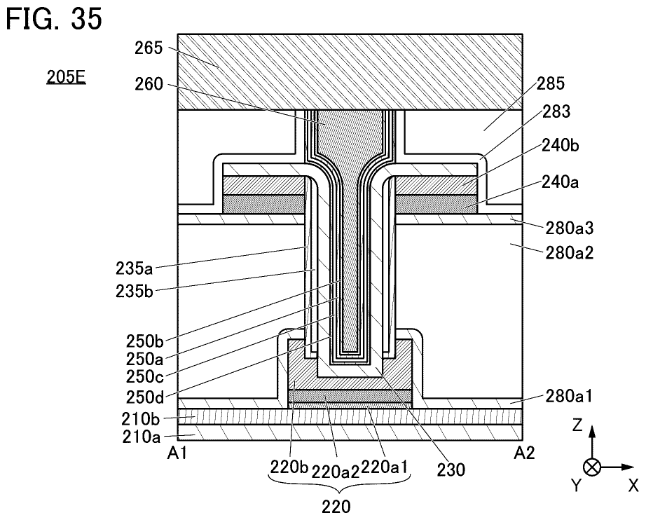

FIG. 35 is a cross-sectional view of a semiconductor device including a transistor 205E.

The transistor 205E is different from the transistor 203 mainly in that the insulating layer 235 has a two-layer structure and the insulating layer 280a is provided instead of the insulating layer 280. FIG. 35 illustrates a structure in which the insulating layer 280a has a three-layer structure of the insulating layer 280al to the insulating layer 280a3. For the details of the insulating layer 235 and the insulating layer 280a illustrated in FIG. 35, the description of the transistor 205 (FIG. 29A1 to FIG. 30B) can be referred to.

The mode and details of the transistor 205 can be modified as in the case of the transistor 200. Specifically, the transistor 205 can have a structure similar to that of any of the transistor 200A to the transistor 200G. The transistor 205 can also have a structure similar to that of any of the transistor 201 to the transistor 203.

In the semiconductor device of one embodiment of the present invention, the barrier insulating layer against hydrogen encloses the periphery of the oxide semiconductor layer, and one or both of an insulating layer having a function of capturing or fixing hydrogen and an insulating layer including a region containing excess oxygen are provided in the vicinity of the oxide semiconductor layer, in which case one or both of oxygen vacancies and impurities in the oxide semiconductor layer can be reduced. Thus, the transistor can have favorable electrical characteristics and higher reliability.

The semiconductor device of one embodiment of the present invention has a structure where the parasitic capacitance generated between the gate electrode and the source electrode or the drain electrode and the parasitic capacitance generated between the gate wiring and the source electrode or the drain electrode are reduced. Accordingly, the frequency characteristics of a circuit using the semiconductor device can be increased.

This embodiment can be combined with any of the other embodiments as appropriate. In this specification, in the case where a plurality of structure examples are shown in one embodiment, the structure examples can be combined as appropriate.

### Embodiment 2

In this embodiment, an oxide semiconductor layer that can be used as a semiconductor layer of a transistor will be described.

### [Oxide Semiconductor Layer]

An oxide semiconductor layer of one embodiment of the present invention preferably includes a metal oxide layer having crystallinity. Examples of the structure of a metal oxide having crystallinity include a c-axis aligned crystalline (CAAC) structure, a polycrystalline structure, and a nano-crystal (nc) structure. By using a metal oxide having crystallinity for the oxide semiconductor layer, the density of defect states in the oxide semiconductor layer can be reduced. This can improve the reliability of a transistor including the oxide semiconductor layer of one embodiment of the present invention, thereby improving the reliability of a semiconductor device including the transistor.

It is particularly preferable that the oxide semiconductor layer of one embodiment of the present invention include a metal oxide having a CAAC structure. The CAAC structure is a crystal structure where a plurality of microcrystals (typically a plurality of microcrystals having a hexagonal crystal structure) have c-axis alignment and are connected in the a-b plane without alignment. Furthermore, in a cross-sectional image of an oxide semiconductor layer having the CAAC structure observed with a high-resolution transmission electron microscope (TEM) (also referred to as a multi-wavelength interference image), metal atoms are observed to be arranged in a layered manner in a crystal part. Thus, it can be said that the oxide semiconductor layer having the CAAC structure includes a layered crystal part. In the case where metal atoms are arranged in a layered manner in the crystal part, a group of bright spots (specifically, bright spots arranged in a layered manner) reflecting a layered arrangement of metal atoms is observed in a cross-sectional TEM image of the oxide semiconductor layer.

The CAAC structure is formed such that the c-axis is perpendicular or substantially perpendicular to a formation surface, for example. In the CAAC structure, metal atoms are arranged in a layered manner in a direction parallel or substantially parallel to the formation surface. In a region having the CAAC structure, an angle formed by the c-axis and the formation surface is preferably within 90°+20° (greater than or equal to 70° and less than or equal to) 110°, further preferably within 90°+15° (greater than or equal to 75° and less than or equal to) 105°, still further preferably within 90°+10° (greater than or equal to 80° and less than or equal to) 100°, yet still further preferably within 90°+5° (greater than or equal to 85° and less than or equal to) 95°.

The crystallinity of the oxide semiconductor layer can be analyzed by X-ray diffraction (XRD), TEM, or electron diffraction (ED), for example. Alternatively, these methods may be combined as appropriate to be employed for analysis.

When the oxide semiconductor layer having the CAAC structure is subjected to electron diffraction, spots indicating c-axis alignment (bright spots) are observed in the electron diffraction pattern. The c-axes of the CAAC structure are preferably aligned in a direction parallel to the normal vector of the formation surface of the oxide semiconductor layer or the normal vector of a surface of the oxide semiconductor layer.

A fast Fourier transform (FFT) pattern obtained by FFT processing on a TEM image reflects reciprocal lattice space information similar to that of an electron diffraction pattern.

When the cross-sectional TEM image of the oxide semiconductor layer having the CAAC structure is obtained and each region in the cross-sectional TEM image is subjected to FFT processing to form the FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle formed by the crystal axis direction calculated from the FFT pattern and the formation surface is preferably greater than or equal to 70° and less than or equal to 110° (within 90°+) 20°, further preferably greater than or equal to 75° and less than or equal to 105° (within 90°+) 15°, still further preferably greater than or equal to 80° and less than or equal to 100° (within 90°+) 10°, and yet still further preferably greater than or equal to 85° and less than or equal to 95° (within 90°+) 5° can be regarded as having the CAAC structure.

When the oxide semiconductor layer having the CAAC structure is observed from the direction perpendicular to the formation surface using the TEM image, a triangular or hexagonal atomic arrangement and crystallinity are observed in the a-b plane. In a Voronoi diagram formed by analysis of the TEM image of the oxide semiconductor layer having the CAAC structure observed from the direction perpendicular to the formation surface, pentagonal, hexagonal, and heptagonal Voronoi regions are mainly observed, typically hexagonal Voronoi regions are observed. For example, the hexagonal Voronoi regions account for higher than or equal to 30% and lower than 100% of the Voronoi regions observed in the Voronoi diagram.

A method for creating a Voronoi diagram is described. First, in TEM image analysis, FFT processing is performed, only information within a certain range is left by filtering, and then reverse fast Fourier transform is performed to create an FFT filtering image. Lattice points are extracted from the created FFT filtering image, and perpendicular bisectors of line segments each connecting adjacent lattice points are formed. A point at which three perpendicular bisectors intersect with each other is referred to as a Voronoi point, and a polygonal region surrounded by line segments connecting the Voronoi points is referred to as a Voronoi region. In the above manner, a Voronoi diagram can be formed.

Note that as the TEM observation range for creating a Voronoi diagram, a rectangular region that is 50 nm wide and 50 nm long can be observed, for example. Note that the observation range is not limited to this range.

In addition, when distribution of hexagonal lattice orientations is analyzed using lattice points extracted by analysis of a plan-view TEM image, at a boundary between two structures with different hexagonal lattice orientations, the difference in hexagonal lattice orientation is small, the boundary is blurred, and the two structures are connected in a way that they interpenetrate each other. That is, no clear boundary portion is observed in the CAAC structure.

Note that as the hexagonal lattice orientation, the orientation of a hexagon formed by six lattice points closest to each other can be calculated.

Note that there is no particular limitation on the crystallinity of a semiconductor material contained in the oxide semiconductor layer. For example, the oxide semiconductor layer sometimes includes one or more of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including a crystal region). When the oxide semiconductor layer has crystallinity, degradation of the transistor characteristics can be inhibited in some cases.

The metal oxide of one embodiment of the present invention preferably includes at least indium (In) or zinc (Zn), particularly preferably includes indium as its main component. Here, the metal oxide includes indium as its main component, and can further contain an element M. The metal oxide preferably includes two or three selected from indium, the element M, and zinc, and particularly preferably includes indium and zinc as its main components. Here, the metal oxide includes indium and zinc as its main components, and can further contain the element M. The element M is a metal element or metalloid element that has a high bonding energy with oxygen, e.g., a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from aluminum, gallium, tin, and yttrium, still further preferably one or more selected from gallium and tin. When the element M contained in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may refer to a metalloid element.

In the cross section of the oxide semiconductor layer observed using the TEM image, metal atoms arranged in a layered manner in a direction parallel or substantially parallel to the formation surface are observed. For example, in a metal oxide containing indium, indium atoms arranged in a layered manner are observed. As another example, in a metal oxide containing indium and zinc, indium atoms and zinc atoms arranged in a layered manner are observed.

As the metal oxide of one embodiment of the present invention, for example, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga-A1 oxide), an indium gallium tin oxide (also referred to as In—Ga—Sn oxide or IGTO), a gallium zinc oxide (also referred to as Ga—Zn oxide or GZO), an aluminum zinc oxide (also referred to as A1-Zn oxide or AZO), an indium aluminum zinc oxide (also referred to as In-A1-Zn oxide or IAZO), an indium tin zinc oxide (In—Sn—Zn oxide also referred to as ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga-A1-Zn oxide, IGAZO, or IAGZO) can be used. Alternatively, ITSO, a gallium tin oxide (Ga—Sn oxide), an aluminum tin oxide (A1-Sn oxide), or the like can be used. As the metal oxide of one embodiment of the present invention, an indium oxide can be used. Alternatively, as the metal oxide of one embodiment of the present invention, a gallium oxide, a zinc oxide, or the like can be used.

By increasing the proportion of the number of indium atoms in the total number of atoms of all the metal elements contained in the metal oxide, a high on-state current and high frequency characteristics of the transistor can be achieved.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, changes in electrical characteristics of the transistor are reduced and the transistor can have high reliability.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor are reduced and the transistor can have high reliability.

In the description of this embodiment, an In—Ga—Zn oxide is sometimes taken as an example of the metal oxide.

The oxide semiconductor layer of one embodiment of the present invention can be formed by forming metal oxides using two kinds of film formation methods. For example, the oxide semiconductor layer of one embodiment of the present invention can be formed by forming metal oxides by a first film formation method and a second film formation method. Note that the oxide semiconductor layer formed by two kinds of film formation methods may be referred to as a hybrid OS.

The oxide semiconductor layer of one embodiment of the present invention has crystallinity. The oxide semiconductor layer of one embodiment of the present invention preferably has the CAAC structure.

In the formation of the oxide semiconductor layer of one embodiment of the present invention, a metal oxide having crystallinity is formed by the first film formation method. The metal oxide formed at this time particularly preferably has the CAAC structure. A metal oxide formed by, for example, a sputtering method, is likely to have crystallinity.

In the case where a metal oxide is formed by the first film formation method, a mixed layer is sometimes formed at the interface between the metal oxide and a formation surface. For example, in the case where a sputtering method is used as the first film formation method, the mixed layer is sometimes formed by particles ejected from a target or the like (also referred to as sputtered particles) or energy applied to the substrate side by sputtered particles or the like, for example. There is a concern that the mixed layer may hinder crystallization of the metal oxide.

For example, in the case where an insulating layer including silicon, e.g., silicon oxide, is used as the formation surface and a metal oxide is formed over the silicon oxide by the first film formation method, silicon might enter the metal oxide. There is a concern that the entry of impurities such as silicon into the metal oxide may hinder crystallization of the metal oxide.

In view of the above, in one embodiment of the present invention, a metal oxide is formed by the second film formation method before a metal oxide is formed by the first film formation method. In other words, a metal oxide is formed by the second film formation method as a first layer, and then a metal oxide is formed by the first film formation method as a second layer over the first layer. In that case, the second film formation method preferably causes less damage to a formation surface than the first film formation method. When a film formation method that causes less damage to a formation surface is used as the second film formation method, formation of a mixed layer at an interface between the oxide semiconductor layer and a layer serving as the formation surface of the oxide semiconductor layer can be inhibited. Moreover, entry of impurities such as silicon into the second layer can be inhibited, which can increase the crystallinity. For example, an ALD method and a CVD method are suitable as the second film formation method because they can reduce damages to a formation surface as compared with a sputtering method.

In addition, for example, a metal oxide having a microcrystalline structure or an amorphous structure that has lower crystallinity than the CAAC structure is sometimes formed as the first layer. Formation of the second layer having high crystallinity over the first layer having low crystallinity or the formation of the second layer followed by heat treatment can increase the crystallinity of the first layer with the second layer as a nucleus in some cases. Accordingly, the crystallinity can be increased in the whole oxide semiconductor layer including the vicinity of the interface with the formation surface in some cases.

In the oxide semiconductor layer of one embodiment of the present invention, preferably, a metal oxide is formed over the formation surface by the second film formation method, and then a metal oxide is formed thereover by the first film formation method.

Examples of the first film formation method include a sputtering method and a PLD method.

Examples of the second film formation method include an ALD method, a plasma CVD method, a thermal CVD method, a photo CVD method, a metal organic CVD method, and an MBE method. The MBE method is a film formation method in which a thin film having a crystal structure reflecting a crystal system of a substrate is grown, and is one of film formation methods that cause less damage to a formation surface. A wet method can be used as the second film formation method. The wet method is one of film formation methods that cause less damage to a formation surface. An example of the wet method is a spray coating method.

For example, the oxide semiconductor layer of one embodiment of the present invention can be formed in the following manner: a metal oxide is formed as the first layer by the second film formation method, and then a metal oxide is formed as the second layer by the first film formation method. Specifically, an ALD method can be used as the second film formation method, and a sputtering method can be used as the first film formation method. The metal oxide formed by the first film formation method preferably has the CAAC structure.

Furthermore, a third layer can be formed over the second layer. Since the second layer has high crystallinity, a crystal of the third layer can grow with a crystal of the second layer as a nucleus or a seed. Thus, the third layer can be crystallized even when a film formation method that easily gives crystallinity is not used as the film formation method of the third layer. Here, for example, when a film formation method that gives higher coverage than that of the second layer is used for formation of the third layer, the whole oxide semiconductor layer can have both high crystallinity and high coverage.

Furthermore, when influence of the formation surface on the second layer is reduced by forming the first layer, the crystallinity of the second layer is increased to an extremely high level. Thus, the third layer whose crystal is grown with the second layer as a nucleus or a seed is also expected to have extremely high crystallinity.

Note that the third layer is the uppermost layer of the oxide semiconductor layer. In the case where the oxide semiconductor layer is used as a semiconductor layer of a transistor, the third layer is, for example, a layer in contact with a gate insulating layer. Increasing the crystallinity of the layer in contact with the gate insulating layer can increase the carrier mobility in an on state of the transistor.

The oxide semiconductor layer of one embodiment of the present invention can be formed in the following manner, for example: a metal oxide is formed as the first layer by the second film formation method, a metal oxide is formed as the second layer by the first film formation method, and a metal oxide is formed as the third layer by the second film formation method. Specifically, an ALD method can be used as the second film formation method, and a sputtering method can be used as the first film formation method. The metal oxide formed by the first film formation method preferably has the CAAC structure. The ALD method is a film formation method that gives higher coverage than a sputtering method, and when the ALD method is used as the film formation methods of the first layer and the third layer, the coverage with the oxide semiconductor layer can be improved. Thus, the oxide semiconductor layer can be formed to favorably cover a step, an opening portion, or the like with a high aspect ratio.

### [Formation Method of Oxide Semiconductor Layer]

The oxide semiconductor layer 230 can be formed in the following manner, for example: an oxide semiconductor 230a is formed over a layer 229 serving as the formation surface by an ALD method, an oxide semiconductor 230b is formed over the oxide semiconductor 230a by a sputtering method, and an oxide semiconductor 230c is formed over the oxide semiconductor 230b by an ALD Furthermore, heat treatment is preferably performed after formation of the oxide method. semiconductor layer 230. The heat treatment can increase the crystallinity of the oxide semiconductor layer 230. The heat treatment here is not limited to heating treatment. For example, heat applied in the formation process may be regarded as the heat treatment. The layer 229 is an insulating film and is, for example, a silicon oxide film, a silicon oxynitride film, a silicon nitride film, a silicon nitride oxide film, an aluminum oxide film, or a hafnium oxide film.

The oxide semiconductor layer 230 can be used as the oxide semiconductor layer 230 or the like included in each of the transistors described in Embodiment 1. The layer 229 corresponds to one or more of the conductive layer 220, the insulating layer 235, the conductive layer 240, and the like described in Embodiment 1. That is, in Embodiment 1, the formation surface of the oxide semiconductor layer 230 refers to the side surface of the insulating layer 235 in the opening portion 290.

The layer 229 does not necessarily have crystallinity. In the case where the layer 229 has crystallinity, the crystal structures of the layer 229 and the metal oxide included in the oxide semiconductor 230 may have poor lattice match.

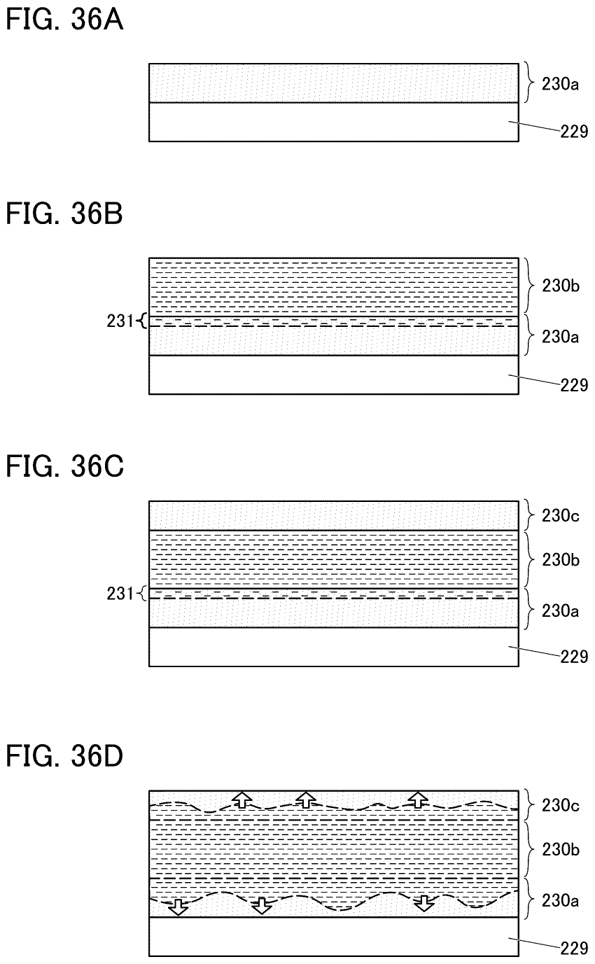

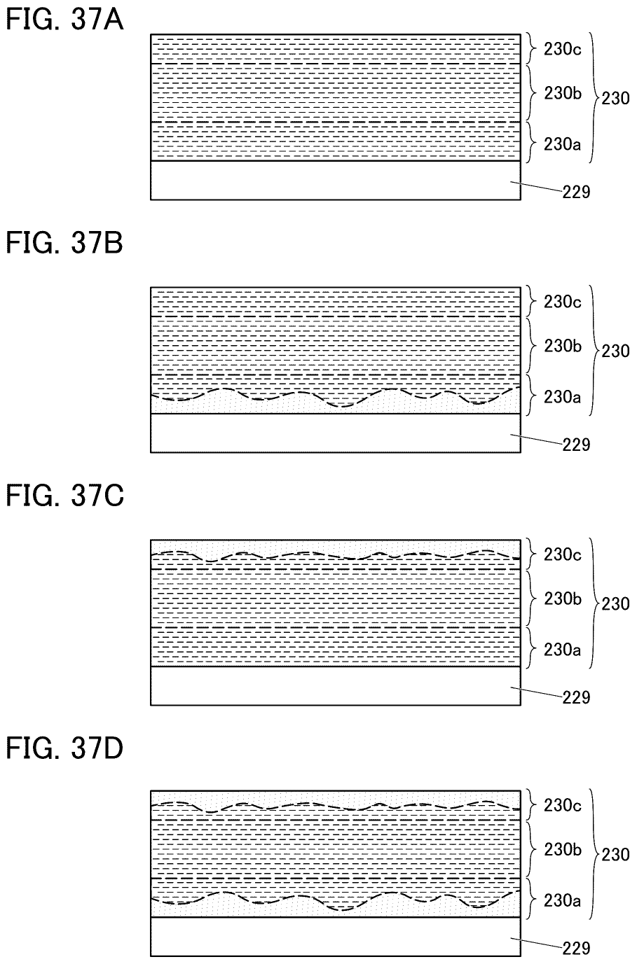

An example of the formation method of the oxide semiconductor layer 230 is described with reference to FIG. 36A to FIG. 37D.

First, the oxide semiconductor 230a is formed over the layer 229 (FIG. 36A). Next, the oxide semiconductor 230b is formed over the oxide semiconductor 230a (FIG. 36B).

The oxide semiconductor 230b is preferably formed by a sputtering method. In addition, the oxide semiconductor 230b preferably has a composition suitable for forming the CAAC structure.

The oxide semiconductor 230a is preferably formed by a film formation method that causes less damage to the formation surface than the film formation method of the oxide semiconductor 230b. Here, the oxide semiconductor 230a is formed by an ALD method.

In the case where a metal oxide film is formed by a sputtering method, damage to a formation surface might cause alloying of a component contained in the metal oxide film with a component contained in a layer serving as the formation surface. In the case where alloying is caused, it is difficult to increase the crystallinity of the alloyed region even when heat treatment described later is performed. When an oxide semiconductor layer including the alloyed region is used for a transistor, the initial characteristics or reliability of the transistor might be adversely affected. Thus, it is preferable to inhibit alloying of the component contained in the metal oxide film with the component contained in the layer serving as the formation surface.

In the formation method of the oxide semiconductor layer of one embodiment of the present invention, the oxide semiconductor 230a is formed over the layer 229, and then the oxide semiconductor 230b is formed thereover by a sputtering method. At this time, the oxide semiconductor 230a is preferably formed by a film formation method that causes less damage to a formation surface. The oxide semiconductor 230a is formed between the oxide semiconductor 230b and the layer 229 by a film formation method that causes less damage to a formation surface, thereby inhibiting alloying of the component contained in the oxide semiconductor layer 230 with the component contained in the layer 229 and further increasing the crystallinity of the oxide semiconductor layer 230.

The above structure enables the alloyed region to be thin or thin enough not to be observed. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIG. 36A and FIG. 36B each illustrate an example where the alloyed region is not formed between the layer 229 and the oxide semiconductor 230a.

Note that the thickness of the alloyed region can sometimes be calculated by performing SIMS or composition line analysis by energy dispersive X-ray spectroscopy (EDX) on the region and its vicinity.

For example, EDX line analysis is performed on the region and its vicinity with the direction perpendicular to the formation surface of the oxide semiconductor 230a regarded as the depth direction. Next, in profiles of quantitative values of elements in the depth direction obtained by the analysis, the depth at which the quantitative value of a metal that is the main component of the oxide semiconductor 230a and is not the main component of a layer (here, the layer 229) serving as the formation surface (the metal is In when the oxide semiconductor 230a contains In) becomes half is defined as a depth (position) of the interface between the region and the oxide semiconductor 230a. Furthermore, the depth at which the quantitative value of an element (e.g., Si) that is the main component of the layer serving as the formation surface and is not the main component of the oxide semiconductor 230a becomes half is defined as a depth (position) of the interface between the region and the layer serving as the formation surface. In the above manner, the thickness of the alloyed region can be calculated.

In the case where the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where SIMS analysis is performed on the oxide semiconductor layer 230 formed over the layer 229 that is formed using a silicon oxide layer, the depth at which the silicon concentration is an intensity at 50% of the maximum silicon concentration in the layer 229 is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

Reducing the thickness of the alloyed region enables the thickness t_s2 to be within the above range.

Note that reducing the thickness of the alloyed region enables formation of the CAAC structure in the vicinity of the formation surface. Here, the vicinity of the formation surface refers to, for example, a region from the formation surface of the oxide semiconductor layer 230 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the oxide semiconductor layer 230.

Note that the CAAC structure in the vicinity of the formation surface can be confirmed in TEM observation in some cases. For example, in cross-sectional observation of the oxide semiconductor 230 with a high-resolution TEM, bright spots arranged in a layered manner in a direction parallel to the formation surface are observed in the vicinity of the formation surface.

Note that when the oxide semiconductor 230a is formed by an ALD method, an oxide semiconductor layer having a microcrystalline structure or an amorphous structure that has lower crystallinity than the CAAC structure may be formed. That is, in the formation step illustrated in FIG. 36A, the oxide semiconductor 230a sometimes includes a region having lower crystallinity than the oxide semiconductor 230b.

After formation of the oxide semiconductor 230a, microwave plasma treatment is preferably performed.

In this specification and the like, a microwave refers to an electromagnetic wave having a frequency greater than or equal to 300 MHz and less than or equal to 300 GHz. The microwave plasma treatment refers to, for example, treatment using an apparatus including a power source that generates high-density plasma with the use of a microwave. The microwave plasma treatment can also be referred to as microwave excitation high-density plasma treatment.

By performing microwave plasma treatment in an oxygen-containing atmosphere, the impurity concentration in the oxide semiconductor layer 230 can be reduced. Specific examples of the impurity include hydrogen and carbon. The above-described example in which the microwave plasma treatment in an oxygen-containing atmosphere is performed on the metal oxide is a non-limiting example. For example, the microwave plasma treatment in an oxygen-containing atmosphere may be performed on an insulating film, specifically a silicon oxide film, which is provided in the vicinity of the metal oxide. Furthermore, the crystallinity of the oxide semiconductor layer is sometimes increased by heat in the microwave plasma treatment.

The microwave plasma treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably higher than or equal to room temperature (25 °C) and lower than or equal to 750 °C, further preferably higher than or equal to 300 °C and lower than or equal to 500 °C, and can be higher than or equal to 400 °C and lower than or equal to 450 °C.

In the microwave plasma treatment, substrate heating may be performed. The substrate heating temperature is preferably higher than or equal to a room temperature (e.g., 25 °C or higher), higher than or equal to 100 °C, higher than or equal to 200 °C, higher than or equal to 300 °C, or higher than or equal to 400 °C, and lower than or equal to 500 °C or lower than or equal to 450 °C.

The microwave plasma treatment can be followed successively by heat treatment without exposure to air. The temperature of the heat treatment is preferably higher than or equal to 100 °C and lower than or equal to 750 °C, further preferably higher than or equal to 300 °C and lower than or equal to 500 °C, still further preferably higher than or equal to 400 °C and lower than or equal to 450 °C, for example.

The microwave plasma treatment can be performed using an oxygen gas and an argon gas, for example. The microwave plasma treatment in an oxygen-containing atmosphere can convert an oxygen gas into plasma using a high-frequency wave such as a microwave or RF and an oxygen radical generated by converting the oxygen gas into plasma can act on the oxide semiconductor layer. By the effect of the plasma, the microwave, the oxygen radical or the like, VoH in the oxide semiconductor layer can be divided into an oxygen vacancy and hydrogen, and hydrogen that is an impurity can be removed from the oxide semiconductor layer. In this manner, VoH contained in the oxide semiconductor layer can be reduced. At this time, carbon bonded to oxygen, hydrogen, or the like can also be removed in some cases. Performing the microwave plasma treatment in this manner can reduce impurities such as carbon and hydrogen. In addition, the oxygen radicals described above can be supplied to oxygen vacancies formed in the oxide semiconductor layer, thereby further reducing oxygen vacancies in the oxide semiconductor layer.

The microwave plasma treatment can increase the crystallinity of the oxide semiconductor 230a in some cases. Here, the principles of improving the crystallinity of oxide semiconductor by the microwave plasma treatment will be described. First, active species excited by a microwave, such as oxygen radicals, reach the surface of the oxide semiconductor, and a substitution reaction between the active species and oxygen in the oxide semiconductor occurs. At this time, a nucleus or a seed is formed. In addition, lateral growth of the nucleus or the seed is caused. The active species excited by the microwave preferably contain oxygen (typically, oxygen ions) that is likely to be adsorbed onto a side surface of the nucleus or the seed, in which case the lateral growth is promoted. The microwave plasma treatment causes formation of a nucleus or a seed or lateral growth of the nucleus or the seed, so that the crystallinity of the oxide semiconductor layer is improved.

Meanwhile, when part of oxygen that has been present in the oxide semiconductor before the microwave plasma treatment reacts with hydrogen in the oxide semiconductor, i.e., a reaction “2H+O→H₂O↑” occurs, the hydrogen can be removed as H₂O (also referred to as dehydration or dehydrogenation). H₂O is a limiting factor in improving crystallinity and thus is preferably removed from the oxide semiconductor. Hydrogen in the oxide semiconductor is removed in the form of H₂O to reduce the hydrogen concentration in the oxide semiconductor, whereby an improvement in crystallinity can be promoted. When the temperature of the microwave plasma treatment is increased, the hydrogen concentration in the oxide semiconductor can be further reduced.

Note that the crystallinity can also be improved by performing plasma treatment using an oxygen gas, instead of the microwave plasma treatment.

The increase in the crystallinity of the oxide semiconductor 230a can further increase the crystallinity of the oxide semiconductor 230b formed over the oxide semiconductor 230a. This can increase the crystallinity of the whole oxide semiconductor layer.

The oxygen supplied to the oxide semiconductor layer is in any of a variety of forms such as an oxygen atom, an oxygen molecule, an oxygen ion (a charged oxygen atom or a charged oxygen molecule), and an oxygen radical (an oxygen atom, an oxygen molecule, or an oxygen ion having an unpaired electron). Note that the oxygen that is supplied into the oxide semiconductor layer is preferably in any one or more of the above forms; an oxygen radical is particularly preferable.

After the oxide semiconductor 230a is formed by an ALD method, an In-M-Zn oxide is formed as the oxide semiconductor 230b over the oxide semiconductor 230a by a sputtering method.

When the oxide semiconductor 230b is formed by a sputtering method, a mixed layer 231 is formed on the surface of the oxide semiconductor 230a or in the vicinity of the surface. A fine crystal region is sometimes formed in the mixed layer 231 by, for example, sputtered particles or energy applied to the substrate side by sputtered particles or the like at the time of forming the oxide semiconductor 230b. In the subsequent heat treatment step, at least part of the oxide semiconductor 230a is crystallized with the mixed layer 231 or the fine crystal region formed in the mixed layer 231 as a nucleus in some cases.

As a target used in a sputtering method, an In-M-Zn oxide can be used. In the case where a metal oxide is formed by a sputtering method, oxygen or a mixed gas of oxygen and a noble gas can be used as a sputtering gas. An increase in the proportion of oxygen in the sputtering gas can increase the amount of excess oxygen contained in the oxide film to be formed.

In some cases, the crystallinity of the metal oxide layer can be increased as the proportion of a flow rate of an oxygen gas in the whole deposition gas (also referred to as oxygen flow rate ratio) used in formation is higher.

In the case where a metal oxide is formed by a sputtering method and the proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess oxide semiconductor layer in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient metal oxide is formed. A transistor including an oxygen-deficient metal oxide in a channel formation region can have relatively high field-effect mobility.

In the formation of the oxide semiconductor 230b by a sputtering method, substrate heating is preferably performed. When the substrate temperature (stage temperature) at the time of forming the metal oxide is increased, the metal oxide having high crystallinity can be formed in some cases. In the formation of the oxide semiconductor 230b by a sputtering method, the substrate heating temperature is preferably higher than or equal to 100 °C and lower than or equal to 400 °C, further preferably higher than or equal to 200 °C and lower than or equal to 300 °C, for example.

In the above manner, as illustrated in FIG. 36B, the oxide semiconductor 230a and the oxide semiconductor 230b over the oxide semiconductor 230a can be formed over the layer 229.

Next, the oxide semiconductor 230c is formed over the oxide semiconductor 230b (FIG. 36C). Here, the oxide semiconductor 230c is formed by an ALD method. For the formation of the oxide semiconductor 230c by an ALD method, the formation method of the oxide semiconductor 230a can be referred to.

When the oxide semiconductor 230c is formed over the oxide semiconductor 230b having the CAAC structure by an ALD method, the oxide semiconductor 230c may epitaxially grow with the oxide semiconductor 230b as a nucleus. Thus, at the time of forming the oxide semiconductor 230c, the oxide semiconductor 230c may include a region having the CAAC structure. The region having the CAAC structure is preferably formed throughout the oxide semiconductor 230c.

Next, a heat treatment step may be performed.

The heat treatment temperature can be higher than or equal to 100 °C and lower than or equal to 800 °C, preferably higher than or equal to 250 °C and lower than or equal to 650 °C, further preferably higher than or equal to 350 °C and lower than or equal to 550 °C, for example. Typically, the temperature can be set to 400 °C+25 °C (greater than or equal to 375 °C and lower than or equal to 425 °C). The treatment time can be shorter than or equal to 10 hours, longer than or equal to 1 minute and shorter than or equal to 5 hours, or longer than or equal to 1 minute and shorter than or equal to 2 hours. In the case of using an RTA apparatus, the treatment time can be longer than or equal to 1 second and shorter than or equal to 5 minutes, for example. By the heat treatment, the oxide semiconductor 230c is expected to repair the atomic-level space between crystal parts of the CAAC structure of the oxide semiconductor 230b.

There is no particular limitation on a heat treatment apparatus used for the heat treatment, and the apparatus may be provided with a device for heating an object by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

The heat treatment step increases the crystallinity of the region having the CAAC structure in the oxide semiconductor 230c in some cases. When the region having the CAAC structure is formed only below the oxide semiconductor 230c after the formation by an ALD method, the region having the CAAC structure may extend upward by the heat treatment step (FIG. 36D). That is, by the heat treatment, the region having the CAAC structure is formed throughout the oxide semiconductor 230c in some cases.

At least part of the oxide semiconductor 230a preferably has the CAAC structure by the heat treatment step (FIG. 36D). The CAAC structure is expected to be easily formed when the mixed layer 231 formed in the oxide semiconductor 230a in the formation of the oxide semiconductor 230b becomes a nucleus or a seed. The oxide semiconductor 230a preferably has a large CAAC region, and the CAAC region preferably extends to the vicinity of the layer 229.

Since the CAAC region extends from the upper portion to the lower portion of the oxide semiconductor 230a, the CAAC region can extend to the vicinity of the layer 229, regardless of the material and crystallinity of the layer 229. For example, even when the layer 229 has an amorphous structure, the oxide semiconductor 230a having high crystallinity can be formed. Thus, the formation method of the oxide semiconductor layer of one embodiment of the present invention is suitable for the case where a layer serving as the formation surface has an amorphous structure, in particular.

After the formation of the oxide semiconductor 230c, microwave plasma treatment may be performed.

When one or both of the above microwave plasma treatment and the above heat treatment are performed, the crystallinity of the whole oxide semiconductor layer can be increased.

In the above manner, impurities in the oxide semiconductor layer can be reduced. Thus, crystal growth can occur with the impurity concentration in the oxide semiconductor layer being low, which can further improve the crystallinity.

Note that one or both of the heat treatment and the microwave plasma treatment may be performed directly on the oxide semiconductor layer or performed after an insulating film or the like is formed over the oxide semiconductor layer.

FIG. 36A to FIG. 36D are cross-sectional views illustrating the formation method of a metal oxide of one embodiment of the present invention. FIG. 36A to FIG. 36D can also be regarded as conceptual diagrams illustrating a formation model of the metal oxide of one embodiment of the present invention. As illustrated in FIG. 36A to FIG. 36D, the crystallinity of each of the oxide semiconductor 230a and the oxide semiconductor 230c is increased with the oxide semiconductor 230b having high crystallinity as a nucleus or a seed. Specifically, the crystallinity of the oxide semiconductor 230a may be increased at the time of forming the oxide semiconductor 230b or by heat treatment after the formation of the oxide semiconductor 230c. In addition, the crystallinity of the oxide semiconductor 230c may be increased at the time of forming the oxide semiconductor 230c or by heat treatment after the formation of the oxide semiconductor 230c. Note that the heat treatment has an assisting function of increasing the crystallinity.

As described above, in the formation method of a metal oxide of one embodiment of the present invention, the crystallinity of the oxide semiconductors (here, the oxide semiconductor 230a and the oxide semiconductor 230c) above and below the oxide semiconductor 230b can be increased with the oxide semiconductor 230b (i.e., CAAC) having high crystallinity as a nucleus or a seed. This can increase the crystallinity of the whole oxide semiconductor layer. In other words, the oxide semiconductor 230b serves as a nucleus or a seed to cause solid-phase growths of the oxide semiconductors above and below the oxide semiconductor 230b, so that the oxide semiconductor layer with high crystallinity can be formed. An oxide semiconductor formed by such a film formation method, here, a CAAC film, may be referred to as an axial growth CAAC (AG CAAC).

It is preferable that the region having the CAAC structure be formed widely throughout the oxide semiconductor layer 230. FIG. 37A illustrates a state where the oxide semiconductor 230a, the oxide semiconductor 230b, and the oxide semiconductor 230c are each crystallized. Crystals in the region having the CAAC structure in the oxide semiconductor 230a are connected to crystals in the region having the CAAC structure in the oxide semiconductor 230b. Crystals in the region having the CAAC structure in the oxide semiconductor 230c are connected to the crystals in the region having the CAAC structure in the oxide semiconductor 230b. As a result, a boundary between the oxide semiconductor 230a and the oxide semiconductor 230b is not observed in some cases. In addition, a boundary between the oxide semiconductor 230b and the oxide semiconductor 230c is not observed in some cases. The oxide semiconductor layer 230 may be expressed as one layer where the interfaces are not clearly observed. The oxide semiconductor layer 230 may be expressed as a single layer in some cases.

In cross-sectional observation with a high-resolution TEM, for example, bright spots arranged parallel or substantially parallel to the formation surface are observed in the region having the CAAC structure in each of the oxide semiconductor 230a, the oxide semiconductor 230b, and the oxide semiconductor 230c. The c-axis of the CAAC structure included in each of the oxide semiconductor 230a, the oxide semiconductor 230b, and the oxide semiconductor 230c is preferably substantially parallel to the normal direction of the formation surface of the oxide semiconductor layer 230.

Part of the oxide semiconductor 230a or part of the oxide semiconductor 230c is not crystallized in some cases. In addition, a region having crystallinity lower than that of the CAAC structure may be present in part of the oxide semiconductor 230a or part of the oxide semiconductor 230c. An example illustrated in FIG. 37B illustrates a state where the vicinity of the interface between the oxide semiconductor 230a and the layer 229 is not crystallized or a region having crystallinity lower than that of the CAAC structure is present in the vicinity of the interface. FIG. 37C illustrates a state where the vicinity of the surface of the oxide semiconductor 230c is not crystallized or a region having crystallinity lower than that of the CAAC structure is present in the vicinity of the surface. FIG. 37D illustrates a state where the vicinity of the interface between the oxide semiconductor 230a and the layer 229 and the vicinity of the surface of the oxide semiconductor 230c are not crystallized or regions having crystallinity lower than that of the CAAC structure are present in the vicinity of the interface between the oxide semiconductor 230a and the layer 229 and in the vicinity of the surface of the oxide semiconductor 230c.

Increasing the crystallinity of the oxide semiconductor layer can suppress an increase in electric resistance of the oxide semiconductor layer used as the semiconductor layer of the transistor or increase the initial characteristics (in particular, the on-state current) of the transistor; thus, the transistor can be expected to be suitable for high-speed driving. In addition, the transistor can have higher reliability and a higher on-state current.

The whole oxide semiconductor layer of one embodiment of the present invention has high crystallinity. Thus, the boundaries between the stacked films of the oxide semiconductor 230a, the oxide semiconductor 230b, and the oxide semiconductor 230c in the oxide semiconductor layer 230 are not observed in some cases. In particular, it is sometimes difficult to observe the boundaries between the stacked films after heat treatment. Whether the boundaries between the stacked films are present can be checked with a cross-sectional TEM or a cross-sectional STEM (scanning transmission electron microscope), for example.

As described above, a transistor including a metal oxide with a high In content percentage can have higher field-effect mobility. Meanwhile, an oxide semiconductor with a high In content percentage tends to be polycrystallized. The use of a metal oxide having a polycrystalline structure for a transistor adversely affects the initial characteristics or reliability of the transistor. In view of this, when an oxide semiconductor with a high In content percentage is used as one or both of the oxide semiconductor 230a and the oxide semiconductor 230c, crystals reflecting the orientation of crystals included in the oxide semiconductor 230b are formed, so that polycrystallization can be inhibited.

It is preferable that crystals included in the oxide semiconductor 230b and crystals included in the oxide semiconductor 230a or the oxide semiconductor 230c have a small lattice mismatch. Thus, the oxide semiconductor 230a or the oxide semiconductor 230c can form crystals reflecting the orientation of crystals included in the oxide semiconductor 230b. In this case, for example, in high-resolution TEM cross-sectional observation of the oxide semiconductor layer 230, bright spots arranged in a layered manner in a direction parallel to the formation surface are observed in the oxide semiconductor 230a or the oxide semiconductor 230c.

As long as crystals included in the oxide semiconductor 230b and crystals included in the oxide semiconductor 230a or the oxide semiconductor 230c have a small lattice mismatch, there is no particular limitation on the crystal structure of the oxide semiconductor 230a or the oxide semiconductor 230c. The oxide semiconductor 230a or the oxide semiconductor 230c may have any of cubic, tetragonal, orthorhombic, hexagonal, monoclinic, and trigonal crystal structures.

In the case where one or both of microwave plasma treatment and heat treatment are performed in the step of forming the oxide semiconductor layer 230, the oxide semiconductor 230b is not necessarily formed in some cases. For example, when one or both of microwave plasma treatment and heat treatment are performed after the oxide semiconductor 230a is formed as described above, the crystallinity of the oxide semiconductor 230a can be increased, and the crystallinity of the oxide semiconductor 230c can be increased using the oxide semiconductor 230a as a nucleus or a seed. When one or both of microwave plasma treatment and heat treatment are performed after the oxide semiconductor 230c is formed, the crystallinity of the oxide semiconductor layer 230 can be increased. Accordingly, the CAAC structure can be formed in the oxide semiconductor layer 230.

For example, when the metal oxide layer 227 described in Embodiment 1 is provided as the layer 229, the crystallinity of the oxide semiconductor 230a can be increased using the metal oxide layer 227 as a nucleus or a seed. When one or both of microwave plasma treatment and heat treatment are performed after the oxide semiconductor 230a is formed and/or after the oxide semiconductor 230c is formed, the crystallinity of the oxide semiconductor layer 230 can be increased. Accordingly, the CAAC structure can be formed in the oxide semiconductor layer 230.

As described above, even when the oxide semiconductor 230b is not provided, the layer 229 (specifically, the metal oxide layer 227) or the oxide semiconductor 230a can be used as a nucleus or a seed for solid-phase growth of the upper oxide semiconductor, thereby forming a highly crystalline oxide semiconductor. An oxide semiconductor formed by such a formation method can also be referred to as an AG CAAC. That is, the AG CAAC can be formed without the use of the first film formation method. In other words, the AG CAAC can be formed also by the second film formation method (e.g., an ALD method or a CVD method) and one or both of microwave plasma treatment and heat treatment.

### [Composition of Oxide Semiconductor Layer]

The oxide semiconductor 230a preferably has a composition different from that of the oxide semiconductor 230b. The oxide semiconductor 230c preferably has a composition different from that of the oxide semiconductor 230b. The oxide semiconductor 230a can have the same composition as the oxide semiconductor 230c. Alternatively, the oxide semiconductor 230a and the oxide semiconductor 230c can have different compositions.

As described above, the oxide semiconductor 230b preferably has a composition suitable for forming the CAAC structure. The oxide semiconductor 230b can be formed by a sputtering method, for example. The oxide semiconductor 230b preferably includes zinc, for example. The oxide semiconductor 230b including zinc can be a metal oxide having high crystallinity. The oxide semiconductor 230b preferably includes the element M in addition to zinc. When the oxide semiconductor 230b includes the element M, formation of oxygen vacancies in the metal oxide can be inhibited, for example. Thus, a transistor including the oxide semiconductor layer can have high reliability. As the oxide semiconductor 230b, it is possible to use, specifically, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof. Note that a composition in the neighborhood includes the range of +30% of an intended atomic ratio. One or more of gallium, aluminum, and tin is preferably used as the element M.

The oxide semiconductor 230b may not necessarily include the element M. For example, an In—Zn oxide may be used. Specifically, an In—Zn oxide having a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, an indium oxide may be used. Furthermore, a slight amount of the element M may be included. For example, a composition of In:Ga:Zn=4:0.1:1 [atomic ratio] or in the neighborhood thereof or a composition of In:Ga:Zn=2:0.1:1 [atomic ratio] or in the neighborhood thereof can be employed. As another example, a composition of In:Sn:Zn=4:0.1:1 [atomic ratio] or in the neighborhood thereof or a composition of In:Sn:Zn=2:0.1:1 [atomic ratio] or in the neighborhood thereof can be employed.

The oxide semiconductor 230a and the oxide semiconductor 230c can each be a metal oxide with a high In proportion. For example, the oxide semiconductor 230a and the oxide semiconductor 230c are each preferably a metal oxide having a higher proportion of In than that of the oxide semiconductor 230b. The oxide semiconductor 230a and the oxide semiconductor 230c can each be formed by an ALD method, for example. It is particularly preferable to use a metal oxide in which the In proportion is higher than the element M proportion. Using a metal oxide with a high In proportion for an oxide semiconductor layer of a transistor can achieve a high on-state current and high frequency characteristics of the transistor.

Alternatively, the oxide semiconductor 230a and the oxide semiconductor 230c do not necessarily contain the element M. For example, an In—Zn oxide may be used. Specifically, an In—Zn oxide having a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, an indium oxide may be used. Furthermore, the oxide semiconductor 230a and the oxide semiconductor 230c may contain a slight amount of the element M. Specifically, a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, or a composition of In:Sn:Zn=2:0.1:1 [atomic ratio] or in the neighborhood thereof can be employed.

The oxide semiconductor 230a and the oxide semiconductor 230c can each be a metal oxide with a higher In proportion than the oxide semiconductor 230b.

For example, as each of the oxide semiconductor 230a and the oxide semiconductor 230c, a metal oxide with a higher Ga proportion than the oxide semiconductor 230b can also be used. For example, as each of the oxide semiconductor 230a and the oxide semiconductor 230c, a metal oxide having a composition of In:Ga:Zn=1:1:1 [atomic ratio] or in the neighborhood thereof, a metal oxide having a composition of In:Ga:Zn=1:3:2 [atomic ratio] or in the neighborhood thereof, or a metal oxide having a composition of In:Ga:Zn=1:3:4 [atomic ratio] or in the neighborhood thereof is preferably used. When the Ga proportion is increased, the band gap of each of the oxide semiconductor 230a and the oxide semiconductor 230c can be larger than that of the oxide semiconductor 230b in some cases, for example. Accordingly, the oxide semiconductor 230b is interposed between the oxide semiconductor 230a and the oxide semiconductor 230c each having a large band gap, and the oxide semiconductor 230b mainly functions as a current path (channel). When the oxide semiconductor 230b is interposed between the oxide semiconductor 230a and the oxide semiconductor 230c, trap states at and near the interfaces with the oxide semiconductor 230b can be reduced. Accordingly, a buried-channel transistor where a channel is away from the interface with an insulating layer can be obtained, whereby the field-effect mobility can be increased. Furthermore, the influence of interface states that might be formed on the back channel side is reduced, so that light deterioration (e.g., light negative bias deterioration) of the transistor can be inhibited and the reliability of the transistor can be improved.

Alternatively, one of the oxide semiconductor 230a and the oxide semiconductor 230c can be a metal oxide with a higher In proportion than the oxide semiconductor 230b, and the other can be a metal oxide with a higher Ga proportion than the oxide semiconductor 230b.

The oxide semiconductor 230a, the oxide semiconductor 230b, and the oxide semiconductor 230c may each include a stack of layers having the above compositions. For example, the oxide semiconductor 230c may have a structure where a metal oxide with a high Ga proportion is stacked over a metal oxide with a high In proportion.

Even when each of the oxide semiconductor 230a and the oxide semiconductor 230c as a single layer has a composition that does not easily form the CAAC structure, the whole oxide semiconductor layer of one embodiment of the present invention, including the oxide semiconductor 230a and the oxide semiconductor 230c, can have the CAAC structure owing to crystal growth caused with the oxide semiconductor 230b as a nucleus. Alternatively, the CAAC structure can be formed in a region including the whole oxide semiconductor 230b and at least part of the oxide semiconductor 230a and at least part of the oxide semiconductor 230c.

In particular, even when the oxide semiconductor 230a and the oxide semiconductor 230c each have a composition with a high In proportion, the oxide semiconductor layer can have crystallinity suitable as the semiconductor layer of the transistor. The oxide semiconductor layer of one embodiment of the present invention enables both high on-state characteristics of a transistor by having the high In proportion and high reliability by having the CAAC structure with high crystallinity.

A metal oxide having the same composition as the oxide semiconductor 230b may be used as the oxide semiconductor 230a and the oxide semiconductor 230c. By using the same composition, the oxide semiconductors easily have the CAAC structure after heat treatment in some cases.

The oxide semiconductor layer having the CAAC structure formed by the two kinds of film formation methods sometimes has one or more of a higher relative permittivity of a film, higher film density, and higher film hardness than the oxide semiconductor layer having the CAAC structure formed by one kind of film formation method.

With the use of the oxide semiconductor layer having the CAAC structure formed by the above two kinds of film formation methods for a channel formation region of a transistor, the transistor can have excellent characteristics (e.g., a high on-state current, high field-effect mobility, a low S value, high frequency characteristics (also referred to as f characteristics), or high reliability).

Analysis of the composition of the metal oxide used for the oxide semiconductor layer 230 can be performed by EDX, XPS, inductively coupled plasma-mass spectrometry (ICP-MS), or inductively coupled plasma-atomic emission spectrometry (ICP-AES). Alternatively, some of these methods may be combined as appropriate to be employed for analysis. As for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage of the element M. [Oxide semiconductor layer of transistor] The oxide semiconductor layer of one embodiment of the present invention can be used as a semiconductor layer of a transistor.

The oxide semiconductor layer of one embodiment of the present invention has the CAAC structure. In an oxide semiconductor layer having the CAAC structure, metal atoms are arranged in a crystal part in a layered manner in a direction parallel or substantially parallel to the formation surface.

In the oxide semiconductor layer 230 of the semiconductor device of one embodiment of the present invention, metal atoms are arranged in a layered manner in a direction parallel or substantially parallel to the formation surface. This can also be expressed that “the a-b plane of the CAAC structure is provided to be parallel or substantially parallel to the formation surface”. Here, the oxide semiconductor layer 230 is provided along the sidewall of the opening portion 290 with the insulating layer 235, which is part of the formation surface, therebetween. Thus, in the oxide semiconductor layer 230, metal atoms are arranged in a layered manner in a direction parallel or substantially parallel to the sidewall of the opening portion 290. With such a structure, the a-b plane of the CAAC structure can be provided along a current flow direction in a channel of the transistor. Accordingly, the transistor can have a high on-state current.

In the case where the oxide semiconductor layer 230 is used as a semiconductor layer of a transistor, the thickness of the oxide semiconductor layer 230 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, and yet still further preferably greater than or equal to 20 nm and less than or equal to 50 nm. In a transistor used for a miniaturized semiconductor device, the thickness of the oxide semiconductor layer 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm. The average thickness of the oxide semiconductor layer 230 in the channel formation region of the transistor is particularly preferably greater than or equal to 2 nm and less than or equal to 15 nm, for example.

The thickness of the oxide semiconductor 230b is preferably less than or equal to 200 nm, for example. When having a layer form, the oxide semiconductor 230b preferably has a thickness greater than or equal to 1 nm and less than or equal to 200 nm, further preferably greater than or equal to 1 nm and less than or equal to 100 nm, still further preferably greater than or equal to 2 nm and less than or equal to 100 nm.

Alternatively, when the oxide semiconductor 230b can function as a crystal nucleus, the oxide semiconductor 230b does not have a layer form but may be an aggregate of island-shaped regions. In such a case, for example, the island-shaped regions in the oxide semiconductor 230b are discretely located.

The thickness of each of the oxide semiconductor 230a and the oxide semiconductor 230c is preferably greater than or equal to 0.5 nm and less than or equal to 50 nm, further preferably greater than or equal to 0.5 nm and less than or equal to 30 nm, still further preferably greater than or equal to 0.5 nm and less than or equal to 20 nm, yet still further preferably greater than or equal to 1 nm and less than or equal to 50 nm, yet still further preferably greater than or equal to 1 nm and less than or equal to 30 nm, yet still further preferably greater than or equal to 1 nm and less than or equal to nm, and yet still further preferably greater than or equal to 2 nm and less than or equal to 20 nm. The thickness of the oxide semiconductor 230a is further preferably greater than or equal to 0.5 nm and less than or equal to 3 nm.

### [Impurities in Oxide Semiconductor]

The influence of impurities in the oxide semiconductor will be described here.

It is preferable that the channel formation region of the transistor including an oxide semiconductor in the semiconductor layer contain less oxygen vacancies or have a lower concentration of impurities such as hydrogen, nitrogen, or a metal element than the source region and the drain region. When oxygen vacancies (Vo) and impurities are contained in a channel formation region of an oxide semiconductor, the electrical characteristics easily vary and the reliability might worsen. In some cases, hydrogen in the vicinity of the oxygen vacancies forms VoH and generates an electron serving as a carrier. Thus, when the channel formation region of the oxide semiconductor includes oxygen vacancies, the transistor tends to have normally on characteristics. Thus, VoH is also preferably reduced in the channel formation region. Thus, the channel formation region of the transistor is a high-resistance region having a low carrier concentration. Accordingly, the channel formation region of the transistor can be regarded as an i-type (intrinsic) or substantially i-type region.

In order to obtain stable electrical characteristics of the transistor, reducing the impurity concentration in the oxide semiconductor is effective. In order to reduce the impurity concentration in the oxide semiconductor, the impurity concentration in a film that is adjacent to the oxide semiconductor is preferably reduced. Examples of the impurity include hydrogen, carbon, and nitrogen. Note that an impurity in an oxide semiconductor refers to, for example, elements other than the main components of the oxide semiconductor. For example, an element with a concentration of lower than 0.1 atomic % is an impurity.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally on characteristics. When nitrogen is contained in the oxide semiconductor, a trap state is sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to become water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier in some cases. Thus, a transistor including an oxide semiconductor that contains hydrogen tends to have normally on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

[c-Axis Alignment Proportion]

The oxide semiconductor layer of one embodiment of the present invention has the CAAC structure. The crystallinity degree of the oxide semiconductor layer of one embodiment of the present invention can be evaluated with the use of crystal orientation, for example.

The crystal orientation can be obtained from an FFT pattern obtained by performing FFT processing on a TEM image. Specifically, the crystal axis direction can be obtained using the FFT pattern. The FFT pattern obtained by the FFT processing reflects reciprocal lattice space information like an electron diffraction pattern.

When FFT processing is performed on each region in the TEM image of the oxide semiconductor layer, crystal orientation in each region can be obtained. For example, crystal orientation is obtained in each region in a certain area range, so that a map indicating crystal orientation can be formed. Specifically, two spots with high intensity are observed in the FFT pattern of the region including a layered crystal part. The crystal axis direction in the region can be obtained from the angle of a line segment connecting the two spots.

When the proportion of regions having c-axis alignment is calculated from the map indicating the crystal orientation, the c-axis alignment proportion can be calculated. Note that the region having c-axis alignment here is a region where the orientation is aligned with the c-axis or a region where the orientation is deviated from the c-axis by less than or equal to 20°, further preferably less than or equal to 15°, still further preferably less than or equal to 10°, yet still further preferably less than or equal to 5°. Here, the angle of the c-axis refers to an angle with respect to the formation surface.

In the oxide semiconductor layer of one embodiment of the present invention, the c-axis alignment proportion can be calculated using, for example, the above-described map indicating crystal orientation obtained through cross-sectional or plan-view TEM observation of the oxide semiconductor layer. A region subjected to FFT (also referred to as FFT window) can be a circle with a diameter of 1.0 nm, for example. Note that the region subjected to FFT is not limited to a circle.

In the case where analysis is performed using a cross-sectional TEM image, the cross-sectional TEM image observation range can be, for example, a region having a width of 100 nm in the horizontal direction with a direction perpendicular to the formation surface regarded as the vertical direction. Note that the observation range is not limited to this.

In the oxide semiconductor layer of one embodiment of the present invention, the c-axis alignment proportion is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Here, the c-axis alignment proportion is preferably calculated as the proportion of regions where the orientation is deviated from the c-axis by less than or equal to 20°, for example.

The c-axis alignment proportions of a region formed as the oxide semiconductor 230a, a region formed as the oxide semiconductor 230b, and a region formed as the oxide semiconductor 230c are Rc1, Rc2, and Rc3, respectively. Rc2 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Furthermore, Rc3 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Rc3/Rc1 is preferably greater than one. Furthermore, Rc2/Rc1 is preferably greater than one. Here, the c-axis alignment proportion is preferably calculated as the proportion of regions where the orientation is deviated from the c-axis by less than or equal to 20°, for example.

Note that boundaries between the oxide semiconductors 230a, 230b, and 230c are not clearly observed in some cases after the formation of the oxide semiconductor layer 230.

The oxide semiconductor layer 230 of one embodiment of the present invention can be divided into three regions that are a first region, a second region, and a third region in this order from the layer 229. Each of the regions has a layer form.

Each of the first region, the second region, and the third region has the CAAC structure. In addition, the c-axis alignment proportion of the third region is preferably higher than that of the first region. The c-axis alignment proportion of the second region is preferably higher than that of the first region. The c-axis alignment proportion of the third region is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. The c-axis alignment proportion of the second region is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Here, the c-axis alignment proportion is preferably calculated as the proportion of regions where the orientation is deviated from the c-axis by less than or equal to 20°, for example.

The first region is a region from the top surface of the layer 229 to greater than or equal to 0 nm and less than or equal to 3 nm, and the third region is a region from the top surface of the oxide semiconductor layer 230 to greater than or equal to 0 nm and less than or equal to 3 nm.

The layers of the regions have substantially the same thickness, for example.

This embodiment can be combined with any of the other embodiments as appropriate.

### Embodiment 3

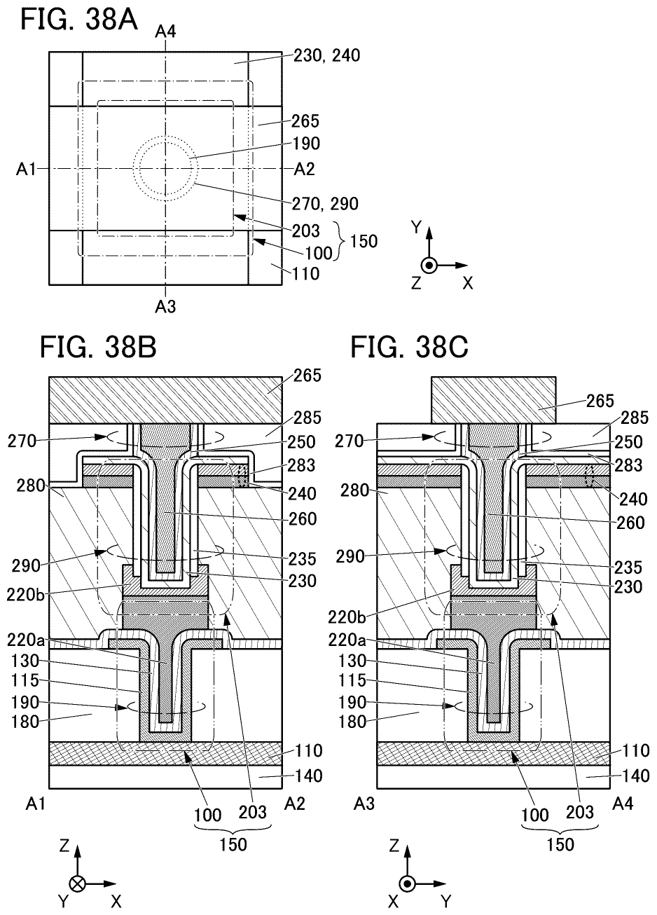

In this embodiment, a memory device of one embodiment of the present invention will be described with reference to FIG. 38 to FIG. 42. The memory device of one embodiment of the present invention includes a memory cell. The memory cell includes a transistor and a capacitor.

### Structure Example 1 of Memory Device

A structure of a memory device including a transistor and a capacitor will be described with reference to FIG. 38A to FIG. 38C. FIG. 38A is a plan view of the memory device including the transistor 203 and a capacitor 100. FIG. 38B is a cross-sectional view along the dashed-dotted line A1-A2 in FIG. 38A. FIG. 38C is a cross-sectional view along the dashed-dotted line A3-A4 in FIG. 38A.

The memory device illustrated in FIG. 38A to FIG. 38C includes an insulating layer 140 over a substrate (not illustrated), a conductive layer 110 over the insulating layer 140, a memory cell 150 over the conductive layer 110, an insulating layer 180 over the conductive layer 110, the insulating layer 280, the insulating layer 283, the insulating layer 285, and the conductive layer 265 over the insulating layer 285. The insulating layer 140, the insulating layer 180, the insulating layer 280, the insulating layer 283, and the insulating layer 285 each function as an interlayer film. The conductive layer 110 and the conductive layer 265 function as wirings.

The memory cell 150 includes the capacitor 100 over the conductive layer 110 and the transistor 203 over the capacitor 100.

The capacitor 100 includes a conductive layer 115 over the conductive layer 110, the insulating layer 130 over the conductive layer 115, and the conductive layer 220a over the insulating layer 130. The conductive layer 220a functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 forms a MIM (Metal-Insulating layer-Metal) capacitor. Note that the conductive layer 220b can be regarded as part of the upper electrode of the capacitor 100.

As illustrated in FIG. 38B and FIG. 38C, an opening portion 190 reaching the conductive layer 110 is provided in the insulating layer 180. At least part of the conductive layer 115 is placed in the opening portion 190. Note that the conductive layer 115 includes a region in contact with the top surface of the conductive layer 110 in the opening portion 190, a region in contact with the side surface of the insulating layer 180 in the opening portion 190, and a region in contact with at least part of the top surface of the insulating layer 180. At least part of the insulating layer 130 is placed so as to be positioned in the opening portion 190. At least part of the conductive layer 220a is placed so as to be positioned in the opening portion 190. Note that the conductive layer 220a is preferably provided to fill the opening portion 190 as illustrated in FIG. 38B and FIG. 38C. Note that the films provided in the opening portion 190 are each preferably formed by an ALD method. Thus, the coverage with the films can be favorable. For example, the conductive layer 115, the insulating layer 130, and the conductive layer 220a are each preferably formed by an ALD method.

The capacitor 100 has a structure in which the upper electrode and the lower electrode face each other with the dielectric therebetween on the side surface as well as the bottom surface in the opening portion 190; thus, the capacitance per unit area can be increased. Thus, the deeper the opening portion 190 is, the higher the capacitance of the capacitor 100 can be. Increasing the capacitance per unit area of the capacitor 100 in this manner enables a stable read operation of the memory device. This also allows further miniaturization or high integration of the memory device. FIG. 38B and FIG. 38C illustrate an example in which the sidewall of the opening portion 190 is perpendicular to the top surface of the conductive layer 110. In that case, the opening portion 190 has a cylindrical shape. With the structure, the memory device can be miniaturized or highly integrated.

The conductive layer 115 and the insulating layer 130 are stacked along the sidewall of the opening portion 190 and the top surface of the conductive layer 110. The conductive layer 220a is provided over the insulating layer 130 to fill the opening portion 190. The capacitor 100 having such a structure may be referred to as a trench-type capacitor or a trench capacitor.

The insulating layer 280 is placed over the capacitor 100. The insulating layer 280 includes a portion positioned over the insulating layer 130 and a portion positioned over the conductive layer 220b.

The transistor 203 includes the conductive layer 220a, the conductive layer 220b over the conductive layer 220a, the conductive layer 240 over the insulating layer 280, the oxide semiconductor layer 230, the insulating layer 235 between the insulating layer 280 and the oxide semiconductor layer 230, the insulating layer 250 over the oxide semiconductor layer 230, and the conductive layer 260 over the insulating layer 250. The oxide semiconductor layer 230 functions as a semiconductor layer, the conductive layer 260 functions as a gate electrode, the insulating layer 250 functions as a gate insulating layer, the conductive layer 220a and the conductive layer 220b function as one of a source electrode and a drain electrode, and the conductive layer 240 functions as the other of the source electrode and the drain electrode.

The description in Embodiment 1 (FIG. 15) can be referred to for the transistor 203; thus, the detailed description thereof is omitted. The transistor included in the memory cell 150 is not limited to the transistor 203, and any of the transistors described as examples in Embodiment 1 can be used.

As illustrated in FIG. 38A to FIG. 38C, the transistor 203 is provided to overlap with the capacitor 100. The opening portion 290 and the opening portion 270 where part of the structure of the transistor 203 is provided includes a region overlapping with the opening portion 190 where part of the structure of the capacitor 100 is provided. Specifically, since the conductive layer 220a (and the conductive layer 220b) has a function of one of the source electrode and the drain electrode of the transistor 203 and a function of the upper electrode of the capacitor 100, the transistor 203 and the capacitor 100 share part of the structure. With such a structure, the transistor 203 and the capacitor 100 can be provided without a great increase in the occupation area in a plan view. Thus, the occupation area of the memory cell 150 can be reduced, so that the memory cells 150 can be arranged densely and the memory capacity of the memory device can be increased. In other words, the memory device can be highly integrated. FIG. 38B and FIG. 38C illustrate an example where the width of the opening portion 190 is smaller than the width of the opening portion 290 and the width of the opening portion 270. There is no particular limitation on the magnitude relation between the width of the opening portion 190 and the width of the opening portion 290 or the width of the opening portion 270. In view of miniaturization, the width of the opening portion 190 is preferably smaller than or equal to the width of the opening portion 290. Similarly, the width of the opening portion 190 is preferably smaller than or equal to the width of the opening portion 270.

When the transistor 203 is provided above the capacitor 100, the transistor 203 is not affected by heat treatment in fabricating the capacitor 100. Thus, in the transistor 203, degradation of the electrical characteristics such as a variation in threshold voltage or an increase in parasitic resistance, an increase in variation in electrical characteristics due to the degradation of the electrical characteristics, and the like can be inhibited.

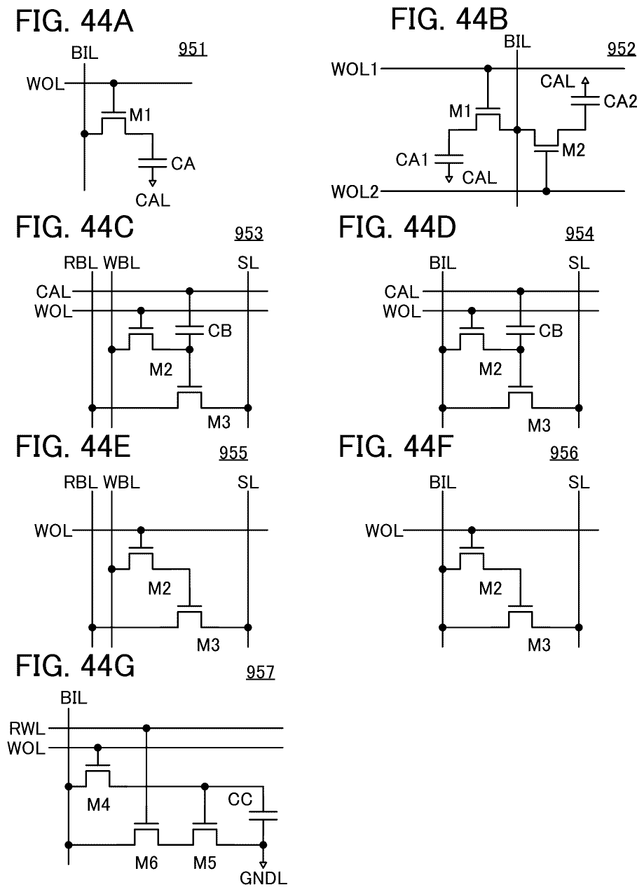

FIG. 44A is a circuit diagram of the memory device described in this embodiment. As illustrated in FIG. 44A, the structure illustrated in FIG. 38A to FIG. 38C functions as a memory cell. A memory cell 951 includes a transistor M1 and a capacitor CA. Here, the transistor M1 corresponds to the transistor 203, and the capacitor CA corresponds to the capacitor 100.

One of a source and a drain of the transistor M1 is connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to a wiring CAL.

Here, the wiring BIL corresponds to the conductive layer 240, the wiring WOL corresponds to the conductive layer 265, and the wiring CAL corresponds to the conductive layer 110. As illustrated in FIG. 38A to FIG. 38C, it is preferable that the conductive layer 265 be provided to extend in the X direction and the conductive layer 240 be provided to extend in the Y direction. In this structure, the wiring BIL and the wiring WOL are provided to intersect with each other. Although the wiring CAL (the conductive layer 110) is provided in a planar shape in FIG. 38A, the present invention is not limited thereto. For example, the wiring CAL may be provided parallel to the wiring WOL (the conductive layer 265) or may be provided parallel to the wiring BIL (the conductive layer 240).

The memory cell will be described in detail in a later embodiment.

### [Capacitor 100]

The capacitor 100 includes the conductive layer 115, the insulating layer 130, and the conductive layer 220a. The conductive layer 110 is provided below the conductive layer 115. The conductive layer 115 includes a region in contact with the conductive layer 110.

The conductive layer 110 is provided over the insulating layer 140. The conductive layer 110 functions as the wiring CAL and can be provided in a planar shape, for example. The conductive layer 110 can be formed as a single layer or stacked layers using any of the conductive materials described in the section [Conductive layer] in Embodiment 1. For example, a conductive material with high conductivity such as tungsten can be used for the conductive layer 110. With use of such a conductive material with high conductivity, the conductive layer 110 can have improved conductivity and can work well as the wiring CAL.

A single layer or stacked-layer including a conductive material that is not easily oxidized, a conductive material having a function of inhibiting diffusion of oxygen, or the like is preferably used for the conductive layer 115. For example, titanium nitride, indium tin oxide to which silicon is added, or the like may be used. For another example, a structure where titanium nitride is stacked over tungsten may be employed. For another example, a structure where tungsten is stacked over first titanium nitride and second titanium nitride is stacked over the tungsten may be employed. With such a structure, when an oxide is used for the insulating layer 130, oxidation of the conductive layer 110 due to the insulating layer 130 can be inhibited. In the case of using an oxide for the insulating layer 180, oxidation of the conductive layer 110 due to the insulating layer 180 can be inhibited.

The insulating layer 130 is provided over the conductive layer 115. The insulating layer 130 is provided to be in contact with the top surface and the side surface of the conductive layer 115. That is, the insulating layer 130 preferably covers the side end portion of the conductive layer 110. This can prevent a short circuit between the conductive layer 115 and the conductive layer 220a.

In addition, a structure may be employed in which the side end portion of the insulating layer 130 and the side end portion of the conductive layer 115 are aligned with each other. In this structure, the insulating layer 130 and the conductive layer 115 can be formed using the same mask, so that the manufacturing process of the memory device can be simplified.

The insulating layer 130 is preferably formed using a high-relative-permittivity (high-k) material. Using such a high-k material for the insulating layer 130 allows the insulating layer 130 to be thick enough to inhibit a leakage current and the capacitor 100 to have a sufficiently high capacitance.

It is preferable to use stacked insulating layers formed of any of the high-k materials, for the insulating layer 130, and it is preferable to use a stacked-layer structure of a high-relative-permittivity material (high-k material) and a material having a higher dielectric strength than the high-k material. For the insulating layer 130, an insulating film in which zirconium oxide, aluminum oxide, and zirconium oxide are stacked in this order can be used, for example. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The use of stacked insulating layers with relatively high dielectric strength, such as aluminum oxide, can increase the dielectric strength and inhibit electrostatic breakdown of the capacitor 100.

Alternatively, a material that can have ferroelectricity may be used for the insulating layer 130. Description in Embodiment 1 can also be referred to for the details of the material that can have ferroelectricity.

A metal oxide containing one or both of hafnium and zirconium is preferable for the insulating layer 130 because the metal oxide can have ferroelectricity even when being a thin film of several nanometers. The thickness of the insulating layer 130 is preferably less than or equal to 100 nm, further preferably less than or equal to 50 nm, still further preferably less than or equal to 20 nm, yet still further preferably less than or equal to 10 nm (typically, greater than or equal to 2 nm and less than or equal to 9 nm). The film thickness is preferably greater than or equal to 8 nm and less than or equal to 12 nm, for example. When a ferroelectric layer that can be thinned is used, the capacitor 100 can be combined with a semiconductor element such as a miniaturized transistor to form a semiconductor device.

A metal oxide containing one or both of hafnium and zirconium can have ferroelectricity even with a minute area and is thus preferable for the insulating layer 130. For example, the metal oxide can have ferroelectricity even with an area (occupation area) in a plan view of 100 μm² or less, 10 μm² or less, 1 μm² or less, or 0.1 μm² or less. Furthermore, even with an area of 10000 nm² or less or 1000 nm² or less, the metal oxide has ferroelectricity in some cases. With a small-area ferroelectric layer, the occupation area of the capacitor 100 can be reduced.

The ferroelectric is an insulator and has a property of causing internal polarization by application of an electric field from the outside and maintaining the polarization even after the electric field is made zero. Thus, by using a capacitor including this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is connected to one terminal of the ferroelectric capacitor. Thus, in the case of using a ferroelectric capacitor as the capacitor 100, the memory device described in this embodiment functions as a ferroelectric memory.

The conductive layer 220a is provided in contact with part of the top surface of the insulating layer 130. The side end portion of the conductive layer 220a is preferably positioned inward from the side end portion of the conductive layer 115 in both the X direction and the Y direction. In the structure where the insulating layer 130 covers the side end portion of the conductive layer 115, the side end portion of the conductive layer 220a may be positioned outward from the side end portion of the conductive layer 115.

The insulating layer 180, which functions as an interlayer film, preferably has a low relative permittivity. When a low-relative-permittivity material is used for an interlayer film, parasitic capacitance generated between wirings can be reduced. As the insulating layer 180, a single layer or stacked layers of insulating layers containing a low-relative-permittivity material can be used. Silicon oxide and silicon oxynitride are preferable because they are thermally stable.

Although FIG. 38B and FIG. 38C illustrate the insulating layer 180 having a single-layer structure, the present invention is not limited thereto. The insulating layer 180 may have a stacked-layer structure of two layers or a stacked-layer structure of three or more layers.

### Structure Example 2 of Memory Device

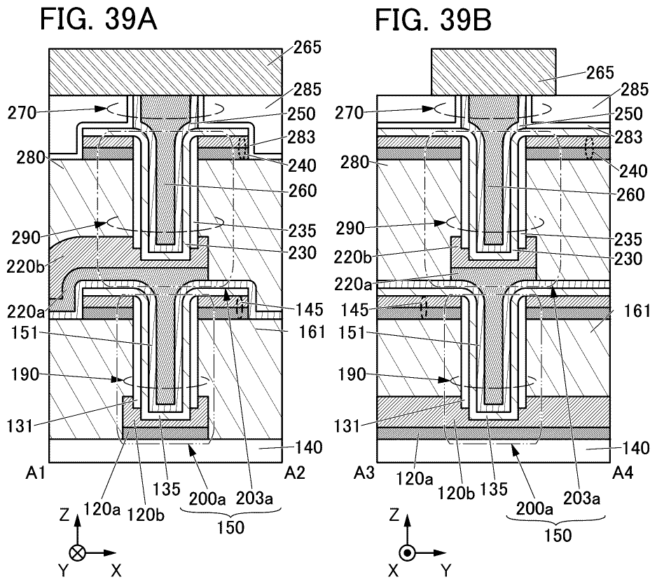

FIG. 39A and FIG. 39B are cross-sectional views of a memory device including a transistor 200a and a transistor 203a.

The memory device illustrated in FIG. 39A and FIG. 39B includes the insulating layer 140 over a substrate (not illustrated), the memory cell 150 over the insulating layer 140, the insulating layer 161 over the insulating layer 140, the insulating layer 280, the insulating layer 283, the insulating layer 285, and the conductive layer 265 over the insulating layer 285. The insulating layer 140, the insulating layer 161, the insulating layer 280, the insulating layer 283, and the insulating layer 285 each function as an interlayer film. The conductive layer 265 functions as a wiring.

The memory cell 150 includes the transistor 200a over the insulating layer 140 and the transistor 203a over the transistor 200a.

The description of the transistor 200 in Embodiment 1 (FIG. 2) can be referred to for the transistor 200a; thus, the detailed description thereof is omitted. The description of the transistor 203 in Embodiment 1 (FIG. 15) can be referred to for the transistor 203a; thus, the detailed description thereof is omitted. The transistors included in the memory cell 150 are not limited to the combination of the transistor 200 and the transistor 203, and one or more kinds of the transistors described in Embodiment 1 can be used.

A conductive layer 120a and a conductive layer 120b included in the transistor 200a can have structures similar to those usable for the conductive layer 220a and the conductive layer 220b, respectively. A conductive layer 145 can have a structure similar to that usable for the conductive layer 240. An insulating layer 131 can have a structure similar to that usable for the insulating layer 235. An oxide semiconductor layer 135 can have a structure similar to that usable for the oxide semiconductor layer 230. An insulating layer 151 can have a structure similar to that usable for the insulating layer 250.

In the memory cell 150 illustrated in FIG. 39A and FIG. 39B, the capacitance generated between the conductive layer 220a and the conductive layer 145 can be used; thus, data can be retained without forming of an additional capacitor. The shortest distance from the top surface of the conductive layer 145 to the conductive layer 220a is preferably shorter than the shortest distance from the top surface of the conductive layer 240 to the conductive layer 265. Accordingly, the capacitance generated between the conductive layer 220a and the conductive layer 145 can be increased. Thus, parasitic capacitance generated between the conductive layer 240 and the conductive layer 265 can be reduced.

As illustrated in FIG. 39A and FIG. 39B, the transistor 203a is provided to overlap with the transistor 200a. The opening portion 290 and the opening portion 270 where part of the structure of the transistor 203a is provided include a region overlapping with the opening portion 190 where part of the structure of the transistor 200a is provided. Specifically, since the conductive layer 220a and the conductive layer 220b have a function of one of a source electrode and a drain electrode of the transistor 203a and a function of a gate electrode of the transistor 200a, the transistor 203a and the transistor 200a share part of the structure. With this structure, the transistor 203a and the transistor 200a can be provided without a great increase in the occupation area in the plan view. Thus, the occupation area of the memory cell 150 can be reduced, so that the memory cells 150 can be arranged densely and the memory capacity of the memory device can be increased. In other words, high integration of the memory device can be achieved.

FIG. 44E is a circuit diagram of the memory device described in this embodiment. As illustrated in FIG. 44E, the structure illustrated in FIG. 39A and FIG. 39B functions as a memory cell. A memory cell 955 includes a transistor M2 and a transistor M3. Here, the transistor M2 corresponds to the transistor 203a, and the transistor M3 corresponds to the transistor 200a.

One of a source and a drain of the transistor M2 is connected to a gate of the transistor M3. The other of the source and the drain of the transistor M1 is connected to a wiring WBL. A gate of the transistor M2 is connected to the wiring WOL. One of a source and a drain of the transistor M3 is connected to a wiring RBL. The other of the source and the drain of the transistor M3 is connected to a wiring SL.

Here, the wiring WBL corresponds to the conductive layer 240 and the wiring WOL corresponds to the conductive layer 265. As illustrated in FIG. 39A and FIG. 39B, it is preferable that the conductive layer 265 be provided to extend in the X direction and the conductive layer 240 be provided to extend in the Y direction. In this structure, the wiring WBL and the wiring WOL are provided to intersect with each other.

Moreover, the transistor M2 may include a back gate. Similarly, the transistor M3 may include a back gate.

### Structure Example 3 of Memory Device

The memory cell 150 with the transistor 203 and the capacitor 100 described in this embodiment can be used as a memory cell of a memory device. The transistor 203 is a transistor whose channel is formed in a semiconductor layer including an oxide semiconductor. Since the transistor 203 has a low off-state current, a memory device including the transistor 203 can retain stored data for a long time. In other words, such a memory device does not require refresh operation or has an extremely low frequency of refresh operation, which leads to a sufficient reduction in power consumption of the memory device. The transistor 203 has high frequency characteristics and thus enables the memory device to perform reading and writing at high speed.

The memory cells 150 can be arranged in a matrix three-dimensionally to form a memory cell array.

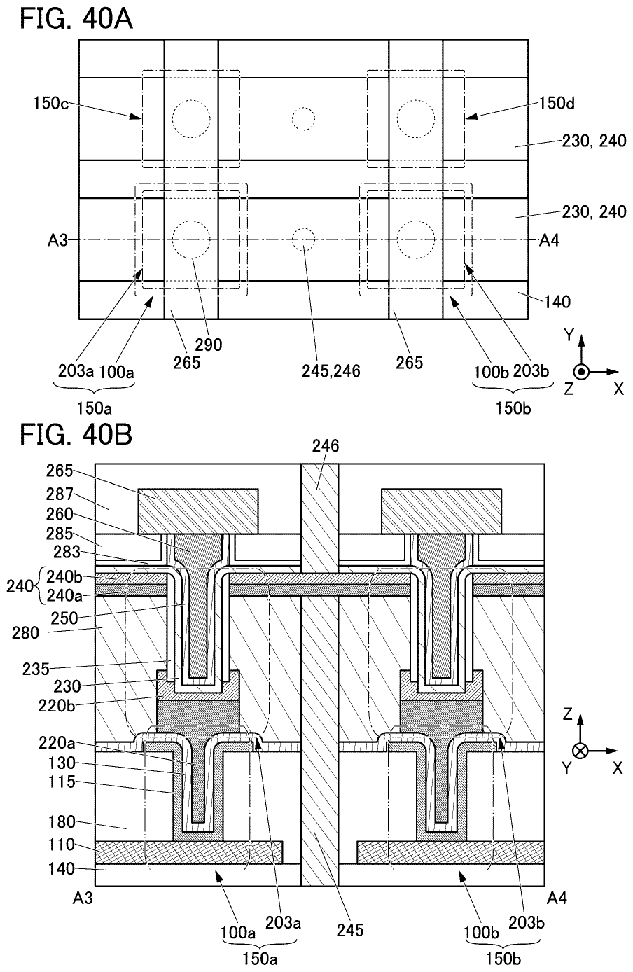

FIG. 40A is a plan view of the memory device. FIG. 40A illustrates an example where 2×2 memory cells (a memory cell 150a to a memory cell 150d) are arranged in the X direction and the Y direction.

FIG. 40B is a cross-sectional view taken along the dashed-dotted line A3-A4 in FIG. 40A. In FIG. 40A and FIG. 40B, two memory cells (the memory cell 150a and the memory cell 150b in FIG. 40B) are connected to a common wiring (a conductive layer 246).

FIG. 44B is a circuit diagram corresponding to the two memory cells. As illustrated in FIG. 44B, a memory device 952 includes two memory cells; one of the memory cells includes the transistor M1 and a capacitor CA1, and the other of the memory cells includes the transistor M2 and a capacitor CA2. For example, in the case where FIG. 44B corresponds to FIG. 40B, the transistor M1 corresponds to the transistor 203a, the capacitor CA1 corresponds to a capacitor 100a, the transistor M2 corresponds to a transistor 203b, and the capacitor CA2 corresponds to a capacitor 100b.

One of the source and the drain of the transistor M1 is connected to one of a pair of electrodes of the capacitor CA1. The other of the source and the drain of the transistor M1 is connected to the wiring BIL. The gate of the transistor M1 is connected to a wiring WOL1. The other of the pair of electrodes of the capacitor CA1 is connected to the wiring CAL. One of the source and the drain of the transistor M2 is connected to one of a pair of electrodes of the capacitor CA2. The other of the source and the drain of the transistor M2 is connected to the wiring BIL. The gate of the transistor M2 is connected to a wiring WOL2. The other of the pair of electrodes of the capacitor CA2 is connected to the wiring CAL.

Here, the wiring BIL corresponds to the conductive layer 240, the wiring WOL1 corresponds to one conductive layer 265, the wiring WOL2 corresponds to another conductive layer 265, and the wiring CAL corresponds to the conductive layer 110.

Here, the memory cell 150a and the memory cell 150b illustrated in FIG. 40A and FIG. 40B each have a structure similar to that of the memory cell 150. The memory cell 150a includes the capacitor 100a and the transistor 203a, and the memory cell 150b includes the capacitor 100b and the transistor 203b. The memory cell 150c and the memory cell 150d illustrated in FIG. 40A each have a structure similar to that of the memory cell 150. Thus, in the memory device illustrated in FIG. 40A and FIG. 40B, components having the same functions as the components of the memory device illustrated in FIG. 38 are denoted by the same reference numerals. The description of the memory cell 150 in <Structure example 1 of memory device>can be referred to for the details of the memory cell 150a to the memory cell 150d.

As illustrated in FIG. 40A and FIG. 40B, the conductive layer 265 functioning as the wiring WOL is provided in each of the memory cell 150a and the memory cell 150b. As illustrated in FIG. 40A, one conductive layer 265 is provided to be shared by the memory cell 150a and the memory cell 150c, and another conductive layer 265 is provided to be shared by the memory cell 150b and the memory cell 150d. One conductive layer 240 functioning as part of the wiring BIL is provided to be shared by the memory cell 150a and the memory cell 150b. That is, the conductive layer 240 is in contact with the oxide semiconductor layer 230 of the memory cell 150a and the oxide semiconductor layer 230 of the memory cell 150b. Another conductive layer 240 is provided to be shared by the memory cell 150c and the memory cell 150d.

FIG. 40B illustrates an example where the conductive layer 240 has a two-layer structure of the conductive layer 240a and the conductive layer 240b over the conductive layer 240a.

Here, the memory device illustrated in FIG. 40A and FIG. 40B includes a conductive layer 245 and the conductive layer 246 functioning as plugs (which also can be referred to as connection electrodes) connected to the memory cell 150a and the memory cell 150b. The conductive layer 245 is placed in an opening portion formed in the insulating layer 140, the insulating layer 180, the insulating layer 130, and the insulating layer 280, and is in contact with the bottom surface of the conductive layer 240a. The conductive layer 246 is placed in an opening portion formed in an insulating layer 287, the insulating layer 285, the insulating layer 283, and the oxide semiconductor layer 230 and is in contact with the top surface of the conductive layer 240b. Note that a conductive material or the like that can be used for the conductive layer 240 can be used for the conductive layer 245 and the conductive layer 246.

The conductive layer 246 can be in contact with the top surface of the conductive layer 240a. Alternatively, the conductive layer 246 can be in contact with the top surface of the oxide semiconductor layer 230. That is, the conductive layer 240b may include an opening portion at a position overlapping with the conductive layer 246. In addition, the oxide semiconductor layer 230 does not necessarily have an opening portion at a position overlapping with the conductive layer 246. As a connection portion between the memory cell and the plug, a layer having a low contact resistance with the conductive layer 246 among the layers included in the conductive layer 240 and the oxide semiconductor layer 230 is preferably in contact with the conductive layer 246.

Similarly, the conductive layer 245 can be in contact with the bottom surface of the conductive layer 240b or the bottom surface of the oxide semiconductor layer 230. That is, the conductive layer 240a may include an opening portion at a position overlapping with the conductive layer 246. Among the layers included in the conductive layer 240 and the oxide semiconductor layer 230, a layer having a low contact resistance with the conductive layer 245 is preferably in contact with the conductive layer 245.

Among the layers included in the conductive layer 240 and the oxide semiconductor layer 230, a layer with a low wiring resistance is preferably in contact with the conductive layer 245 and the conductive layer 246.

The insulating layer 287 functions as an interlayer film and thus preferably has a low relative permittivity. When a low-relative-permittivity material is used for an interlayer film, parasitic capacitance generated between wirings can be reduced.

The concentration of impurities such as water and hydrogen in the insulating layer 287 is preferably reduced. This can inhibit entry of impurities such as water and hydrogen into the channel formation region of the oxide semiconductor layer 230.

The conductive layer 245 and the conductive layer 246 function as plugs or wirings for connecting the memory cell 150a and the memory cell 150b to a circuit element such as a switch, a transistor, a capacitor, an inductor, a resistor, or a diode, a wiring, an electrode, or a terminal. For example, the conductive layer 245 can be connected to a sense amplifier (not illustrated) provided below the memory device illustrated in FIG. 40B, and the conductive layer 246 can be connected to a similar memory device (not illustrated) provided above the memory device illustrated in FIG. 40B. In that case, the conductive layer 245 and the conductive layer 246 function as part of the wiring BIL. When the memory device or the like is provided above or below the memory device illustrated in FIG. 40B in this manner, the memory capacity per unit area can be increased.

The memory cell 150a and the memory cell 150b are line-symmetrical to each other with a perpendicular bisector of the dashed-dotted line A3-A4 as the symmetric axis. Thus, the transistor 203a and the transistor 203b are also placed symmetrically with the conductive layer 245 and the conductive layer 246 therebetween. Here, the conductive layer 240 has a function of the other of the source electrode and the drain electrode of the transistor 203a and a function of the other of the source electrode and the drain electrode of the transistor 203b. The transistor 203a and the transistor 203b share the conductive layer 245 and the conductive layer 246 functioning as plugs. Accordingly, when the two transistors and the plugs are connected as described above, the memory device that can be miniaturized or highly integrated can be provided.

Note that the conductive layer 110 functioning as the wiring CAL may be provided in each of the memory cell 150a and the memory cell 150b or may be provided to be shared by the memory cell 150a and the memory cell 150b. However, as illustrated in FIG. 40B, the conductive layer 110 is provided to be apart from the conductive layer 245 so that the conductive layer 110 and the conductive layer 245 are not short-circuited.

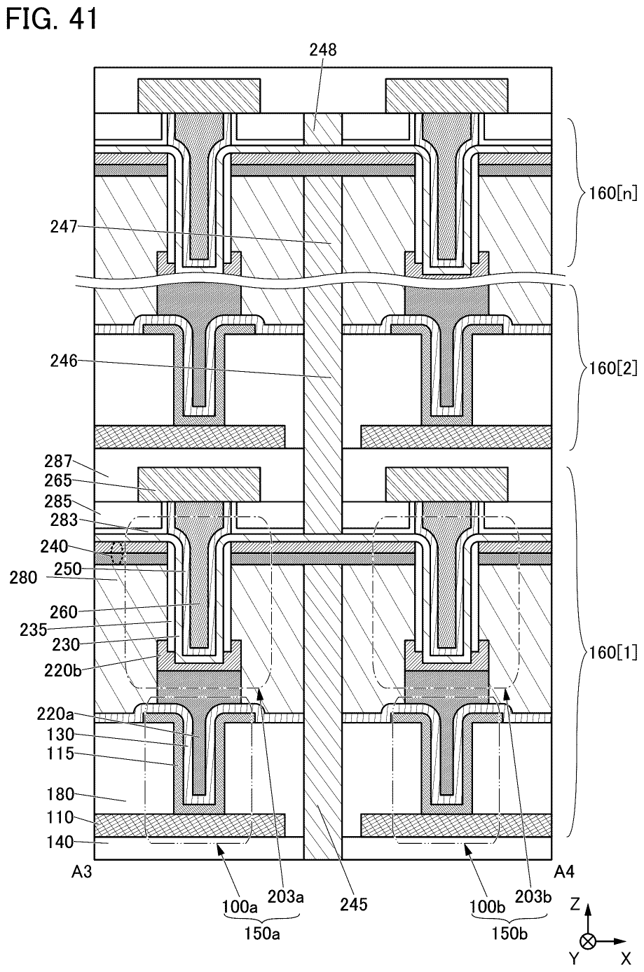

FIG. 41 illustrates an example where the four memory cells illustrated in FIG. 40A are stacked in n layers (n is an integer greater than or equal to 3) in the Z direction. FIG. 41 is a cross-sectional view taken along the dashed-dotted line A3-A4 in FIG. 40A.

The memory device illustrated in FIG. 41 includes n memory layers 160. Specifically, a memory layer 160[2] is provided over a memory layer 160[1], (n-2) memory layers are provided over the memory layer 160[2], and a memory layer 160[n] is provided at the uppermost level. There is no particular limitation on the number of memory cells included in one memory layer 160, and two or more memory cells can be included. Through the conductive layer 245, the conductive layer 246, a conductive layer 247, a conductive layer 248, and the like, memory cells included in the n memory layers 160 are connected to a sense amplifier (not illustrated) provided below the n memory layers 160.

FIG. 41 illustrates an example where the conductive layer 245 is in contact with the bottom surface of the conductive layer 240 and the conductive layer 246 is in contact with the top surface of the oxide semiconductor layer 230. As described above, connection portions between the plugs such as the conductive layer 245 and the conductive layer 246 and the memory cells can have any of a variety of modes and are not limited to the structure in FIG. 41.

When a plurality of memory cells are stacked as illustrated in FIG. 41, cells can be integrated without increasing the occupation area of the memory cell array. In other words, a 3D memory cell array can be formed.

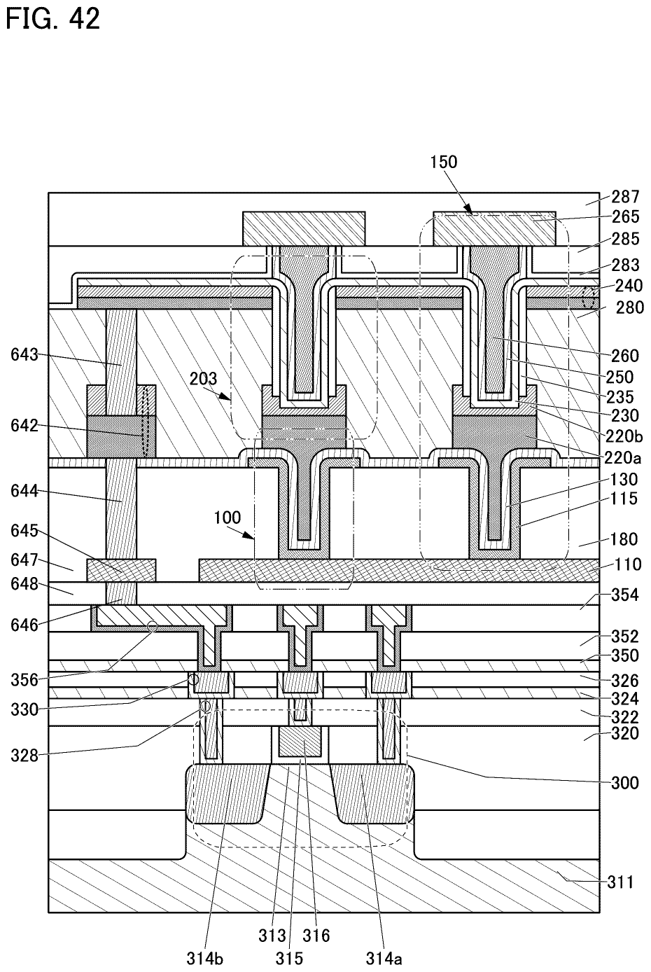

FIG. 42 illustrates a cross-sectional structure example of a memory device in which a layer including a memory cell is stacked over a layer including a driver circuit provided with a sense amplifier.

In FIG. 42, the memory cell 150 (the transistor 203 and the capacitor 100) is provided above a transistor 300.

The transistor 300 is one of the transistors included in the sense amplifier.

For the memory cell 150 illustrated in FIG. 42, the description of the memory cell 150 in <Structure example 1 of memory device>can be referred to.

When the sense amplifier is provided to overlap with the memory cell 150 as illustrated in FIG. 42, a bit line can be shortened. Accordingly, the bit line capacitance can be reduced and the memory device can be driven at high speed.

The memory device illustrated in FIG. 42 can correspond to a semiconductor device 900 described in Embodiment 4. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 formed of part of the substrate 311, and a low-resistance region 314a and a low-resistance region 314b functioning as a source region and a drain region. The transistor 300 may be a p-channel transistor or an n-channel transistor. The substrate 311 preferably includes a silicon-based semiconductor, specifically, preferably includes single crystal silicon.

Here, in the transistor 300 illustrated in FIG. 42, the semiconductor region 313 (part of the substrate 311) in which a channel is formed has a projecting shape. In addition, the conductive layer 316 is provided to cover the side surface and the top surface of the semiconductor region 313 with the insulating layer 315 therebetween. Note that a material for adjusting the work function may be used for the conductive layer 316. The transistor 300 is also referred to as a FIN-type transistor because it utilizes the projecting portion of the semiconductor substrate. Note that an insulating layer functioning as a mask for forming the projecting portion may be provided in contact with an upper portion of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 42 is an example and is not limited to the structure; an appropriate transistor can be used in accordance with a circuit structure or a driving method.

A wiring layer provided with an interlayer film, a wiring, a plug, and the like may be provided between the components. A plurality of wiring layers can be provided in accordance with the design. Here, a plurality of conductive layers functioning as a plug or a wiring are collectively denoted by the same reference numeral in some cases. Furthermore, in this specification and the like, a wiring and a plug connected to the wiring may be a single component. That is, part of a conductive layer serves as a wiring in some cases and part of the conductive layer serves as a plug in other cases.

For example, an insulating layer 320, an insulating layer 322, an insulating layer 324, and an insulating layer 326 are sequentially stacked over the transistor 300 as interlayer films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 function as a plug or a wiring.

The insulating layers functioning as interlayer films may also function as planarization films that cover uneven shapes therebelow. For example, the top surface of the insulating layer 322 may be planarized by planarization treatment using a CMP method or the like to increase the planarity.

A wiring layer may be provided over the insulating layer 326 and the conductive layer 330. For example, in FIG. 42, an insulating layer 350, an insulating layer 352, and an insulating layer 354 are stacked sequentially. Furthermore, a conductive layer 356 is formed in the insulating layer 350, the insulating layer 352, and the insulating layer 354. The conductive layer 356 functions as a plug or a wiring.

As the insulating layer 352, the insulating layer 354, and the like functioning as interlayer films, any of the above-described insulating layers that can be used for the semiconductor device or the memory device can be used.

As each of the conductive layers functioning as plugs or wirings, such as the conductive layer 328, the conductive layer 330, and the conductive layer 356, a conductive material that can be used for the conductive layer 240 can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

The conductive layer 240 included in the transistor 203 is connected to the low-resistance region 314b functioning as a source region or a drain region of the transistor 300 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 642 is provided over the insulating layer 130 and is embedded in the insulating layer 280. The conductive layer 642 can be formed using the same material in the same step as the conductive layer 220a and the conductive layer 220b. The conductive layer 644 is embedded in the insulating layer 180 and the insulating layer 130. The conductive layer 645 is embedded in the insulating layer 647. The conductive layer 645 and the conductive layer 110 can be formed using the same material in the same step. The conductive layer 646 is embedded in an insulating layer 648. The transistor 300 and the conductive layer 110 are insulated from each other by the insulating layer 648.

This embodiment can be combined with any of the other embodiments as appropriate.

### Embodiment 4

The semiconductor device 900 of one embodiment of the present invention will be described in this embodiment. The semiconductor device 900 can function as a memory device.

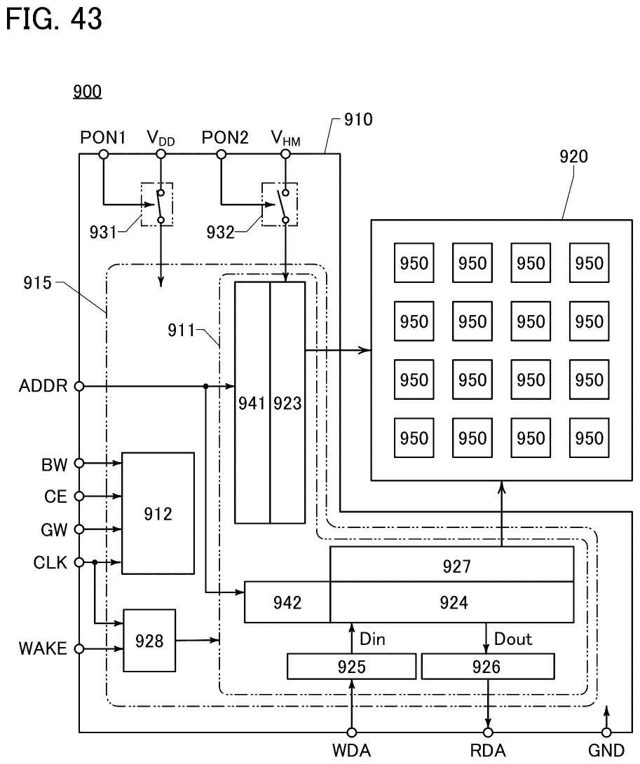

FIG. 43 illustrates a block diagram illustrating a structure example of the semiconductor device 900. The semiconductor device 900 illustrated in FIG. 43 includes a driver circuit 910 and a memory array 920. The memory array 920 includes at least one memory cell 950. FIG. 43 illustrates an example in which the memory array 920 includes a plurality of memory cells 950 placed in a matrix.

The memory device (e.g., the memory cell 150) described in Embodiment 3 can be used for the memory cell 950.

The driver circuit 910 includes a PSW 931 (power switch), a PSW 932, and a peripheral circuit 915. The peripheral circuit 915 includes a peripheral circuit 911, a control circuit 912, and a voltage generation circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating a negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and the sense amplifier 927.

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained by the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of VDD to the peripheral circuit 915. The PSW 932 has a function of controlling supply of VHM to the row driver 923. Here, in the semiconductor device 900, a high power supply voltage is VDD and a low power supply voltage is GND (a ground potential). In addition, VHM is a high power supply voltage used to set a word line at a high level and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 43 but can be more than one. In that case, a power switch may be provided for each power domain.

A structure example of a memory cell that can be used for the memory cell 950 will be described with reference to FIG. 44A to FIG. 44G.

### [DOSRAM]

FIG. 44A illustrates a circuit structure example of a memory cell of DRAM. In this specification and the like, a DRAM using an OS transistor is referred to as a DOSRAM (Dynamic Oxide Semiconductor Random Access Memory). The memory cell 951 includes the transistor M1 and the capacitor CA.

Note that the transistor M1 may include a front gate (sometimes simply referred to as a gate) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to the wiring BIL. The gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. In data writing and reading, a low-level potential (referred to as a reference potential in some cases) is preferably applied to the wiring CAL.

Data writing and reading are performed in such a manner that a high-level potential is applied to the wiring WOL to turn on the transistor M1 so that electrical continuity (a state where current can flow) is established between the wiring BIL and the first terminal of the capacitor CA.

The memory cell that can be used as the memory cell 950 is not limited to the memory cell 951, and the circuit structure can be changed. For example, the memory cell 951 does not necessarily include the capacitor CA or the wiring CAL, and the first terminal of the transistor M1 may be in an electrically floating state.

Note that an OS transistor is preferably used as the transistor M1. OS transistors have a characteristic of extremely low off-state current. The use of an OS transistor as the transistor M1 enables an extremely low leakage current of the transistor M1. That is, with the use of the transistor M1, written data can be retained for a long time, and thus the frequency of the refresh operation for the memory cell can be decreased. Alternatively, refresh operation for the memory cell can be unnecessary. In addition, the extremely low leakage current allows multi-level data or analog data to be retained in the memory cell 951.

As illustrated in FIG. 44B, one wiring BIL can be provided to be shared by two or more memory cells of DRAM.

### [NOSRAM]

FIG. 44C illustrates a circuit structure example of a gain memory cell including two transistors and one capacitor. A memory cell 953 includes the transistor M2, the transistor M3, and a capacitor CB. In this specification and the like, a memory device including a gain memory cell using an OS transistor as the transistor M2 is referred to as a NOSRAM (Nonvolatile Oxide Semiconductor RAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. The gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In data writing, data retention, and data reading, a low-level potential (referred to as a reference potential in some cases) is preferably applied to the wiring CAL.

Data writing is performed in such a manner that a high-level potential is applied to the wiring WOL to turn on the transistor M2 so that electrical continuity is established between the wiring WBL and the first terminal of the capacitor CB. Specifically, when the transistor M2 is in an on state, a potential corresponding to information stored in the wiring WBL is applied, whereby the potential is written to the first terminal of the capacitor CB and the gate of the transistor M3. After that, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. The current flowing between a source and a drain of the transistor M3 and the potential of the first terminal of the transistor M3 are determined by the potential of the gate of the transistor M3 and the potential of the second terminal of the transistor M3; therefore, the potential of the wiring RBL electrically connected to the first terminal of the transistor M3 is read out, so that the potential retained at the first terminal of the capacitor CB (or the gate of the transistor M3) can be read out. In other words, information written into this memory cell can be read out from the potential retained at the first terminal of the capacitor CB (or the gate of the transistor M3).

Alternatively, for example, the wiring WBL and the wiring RBL may be combined into one wiring BIL. FIG. 44D illustrates a circuit structure example of the memory cell. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, the memory cell 954 has a structure in which one wiring BIL operates as a write bit line and a read bit line.

A memory cell 955 illustrated in FIG. 44E is an example in which the capacitor CB and the wiring CAL in the memory cell 953 are omitted. A memory cell 956 illustrated in FIG. 44F is an example in which the capacitor CB and the wiring CAL in the memory cell 954 are omitted. With such structures, the integration degree of the memory cells can be increased.

Note that it is preferable to use an OS transistor as at least the transistor M2. It is particularly preferable to use OS transistors as the transistor M2 and the transistor M3.

Since an OS transistor has a characteristic of extremely low off-state current, written data can be retained for a long time with the transistor M2, and thus the frequency of refresh operation for the memory cell can be decreased. Alternatively, refresh operation for the memory cell can be unnecessary. In addition, the extremely low leakage current allows multi-level data or analog data to be retained in the memory cell 953, the memory cell 954, the memory cell 955, and the memory cell 956.

The memory cell 953, the memory cell 954, the memory cell 955, and the memory cell 956 each using an OS transistor as the transistor M2 are embodiments of NOSRAM.

Note that a Si transistor may be used as the transistor M3. A Si transistor can have high field-effect mobility and can be a p-channel transistor, so that circuit design flexibility can be increased.

In the case where an OS transistor is used as the transistor M3, the memory cell can be formed using only n-channel transistors.

FIG. 44G illustrates a gain memory cell 957 including three transistors and one capacitor. The memory cell 957 includes a transistor M4 to a transistor M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line, the wiring WOL functions as a write word line, and the wiring RWL functions as a read word line. The wiring GNDL is a wiring for applying a low-level potential.

Data writing is performed in such a manner that a high-level potential is applied to the wiring WOL to turn on the transistor M4 so that electrical continuity is established between the wiring BIL and the first terminal of the capacitor CC. Specifically, when the transistor M4 is in an on state, a potential corresponding to information stored in the wiring BIL is applied, whereby the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed in such a manner that after the wiring BIL is precharged with a predetermined potential, the wiring BIL is brought into an electrically floating state and a high-level potential is applied to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL are changed in accordance with the potential retained at the first terminal of the capacitor CC (or the gate of the transistor M5). Here, by reading out the potential of the wiring BIL, the potential retained at the first terminal of the capacitor CC (or the gate of the transistor M5) can be read out. In other words, information written into the memory cell can be read out from the potential retained at the first terminal of the capacitor CC (or the gate of the transistor M5).

Note that it is preferable to use an OS transistor as at least the transistor M4.

Note that the transistors M5 and M6 may be Si transistors. As described above, a Si transistor has a higher field-effect mobility than an OS transistor in some cases depending on the crystal state of silicon used in a semiconductor layer, for example.

In the case where OS transistors are used as the transistors M5 and M6, the memory cell can be formed using only n-channel transistors.

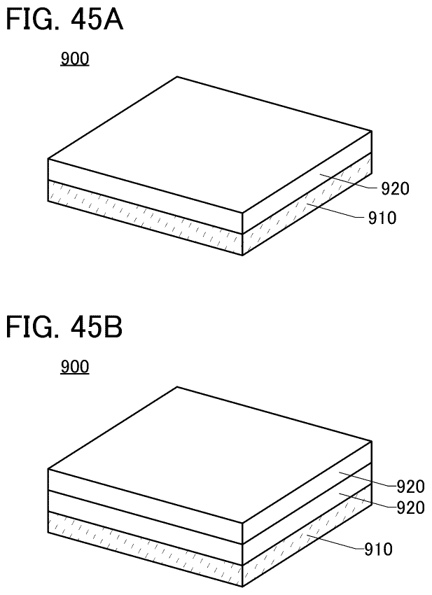

The driver circuit 910 and the memory array 920 that are included in the semiconductor device 900 may be provided on the same plane. Alternatively, the driver circuit 910 and the memory array 920 may be provided so as to overlap with each other as illustrated in FIG. 45A. When the driver circuit 910 and the memory array 920 are provided to overlap with each other, the signal transmission distance can be shortened. Alternatively, a plurality of memory arrays 920 may be provided to overlap with each other over the driver circuit 910 as illustrated in FIG. 45B.

Next, an example of an arithmetic processing device that can include the semiconductor device such as the memory device described above will be described.

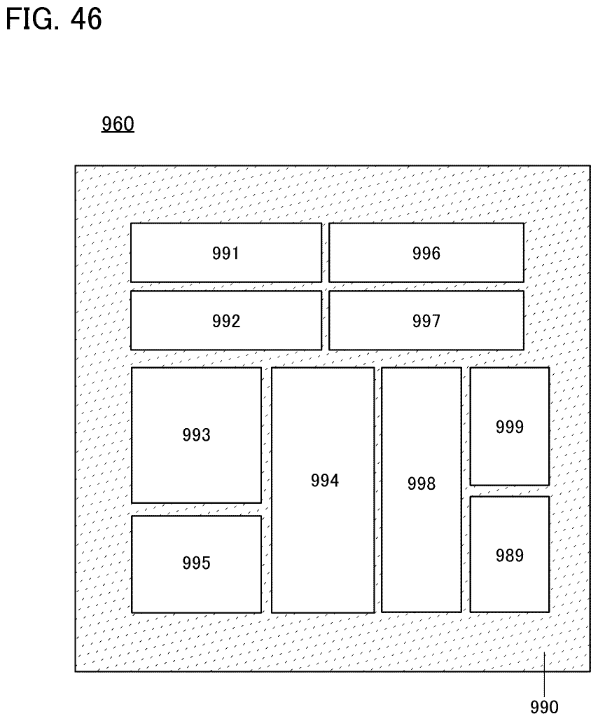

FIG. 46 is a block diagram of an arithmetic device 960. The arithmetic device 960 illustrated in FIG. 46 can be used for a CPU, for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic device 960 illustrated in FIG. 46 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may include a rewritable ROM and a ROM interface. In addition, the cache 999 and the cache interface 989 may be provided in a separate chip.

The cache 999 is connected to a main memory provided in separate chip via the cache interface 989. The cache interface 989 has a function of supplying part of data retained in the main memory to the cache 999. The cache interface 989 has a function of outputting part of data retained in the cache 999 to the ALU 991, the register 996, or the like via the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also acceptable that the cache 999 is not provided and only the memory array 920 is used as a cache.

The arithmetic device 960 illustrated in FIG. 46 is only an example with a simplified structure, and the actual arithmetic device 960 has a variety of structures depending on the application. For example, what is called a multicore structure is preferably employed in which a plurality of cores each including the arithmetic device 960 in FIG. 46 operate in parallel. A larger number of cores can further enhance the arithmetic performance. The number of cores is preferably larger; for example, the number is preferably 2, further preferably 4, still further preferably 8, yet further preferably 12, still yet further preferably 16 or more. For application requiring extremely high arithmetic performance, e.g., a server, it is preferable to employ the multicore structure including 16 or more cores, preferably 32 or more cores, or further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, which is then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 assesses an interrupt request from an external input/output device, a peripheral circuit, or the like based on its priority, a mask state, or the like, and handles the request. The register controller 997 generates the address of the register 996, and reads and writes data from and to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 in FIG. 46, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

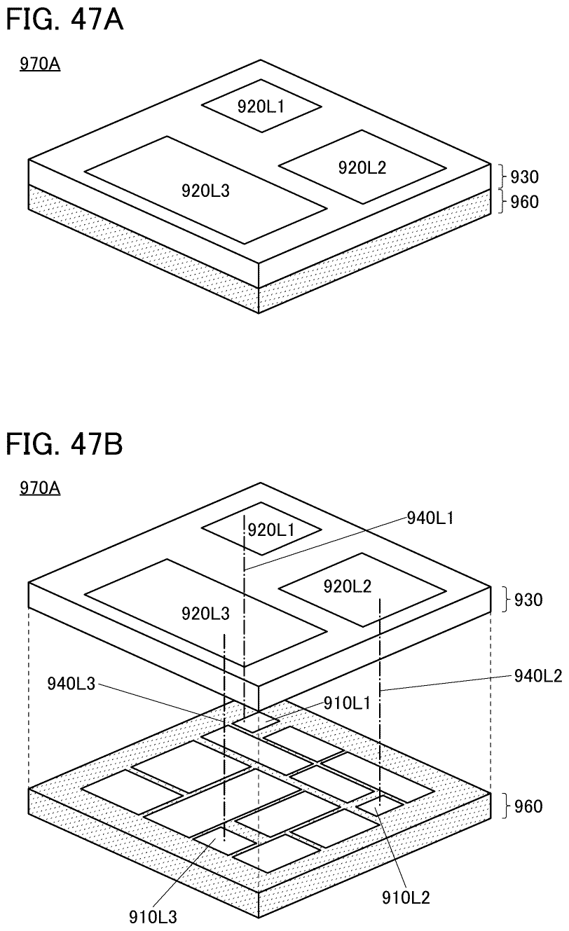

The memory array 920 and the arithmetic device 960 can be provided to overlap with each other. FIG. 47A and FIG. 47B illustrate perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 has an overlapping region with each of the memory arrays. For easy understanding of the structure of the semiconductor device 970A, the arithmetic device 960 and the layer 930 are separately illustrated in FIG. 47B.

Providing the arithmetic device 960 and the layer 930 including the memory arrays to overlap with each other can shorten the connection distance therebetween. Thus, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking), and a method in which the arithmetic device 960 and the layer 930 are formed over two different substrates, the substrates are bonded to each other, and the arithmetic device 960 and the layer 930 are connected to each other with a through via or by a technique for bonding conductive films (e.g., Cu-Cu bonding). The former method does not require consideration of misalignment in bonding; thus, not only the chip size but also the manufacturing cost can be reduced.

Here, in the arithmetic device 960, the memory arrays 920L1, 920L2, and 920L3 provided in the layer 930 are each used as a cache without including the cache 999. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

In the case where the cache 999 provided in the arithmetic device 960 is used as the L1 cache, the memory arrays provided in the layer 930 can each be used as the lower-level cache or the main memory. The main memory has a higher capacity and a lower access frequency than the cache.

As illustrated in FIG. 47B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may be configured to function as part of the cache interface 989 or be connected to the cache interface 989. Similarly, each of the driver circuit 910L2 and the driver circuit 910L3 may be configured to function as part of the cache interface 989 or be connected thereto.

Whether the memory array 920 functions as the cache or the main memory is determined by the control circuit 912 included in each of the driver circuits 910. The control circuit 912 allows some of the plurality of memory cells 950 included in the semiconductor device 900 to function as RAM in accordance with a signal supplied from the arithmetic device 960.

In the semiconductor device 900, some of the plurality of memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

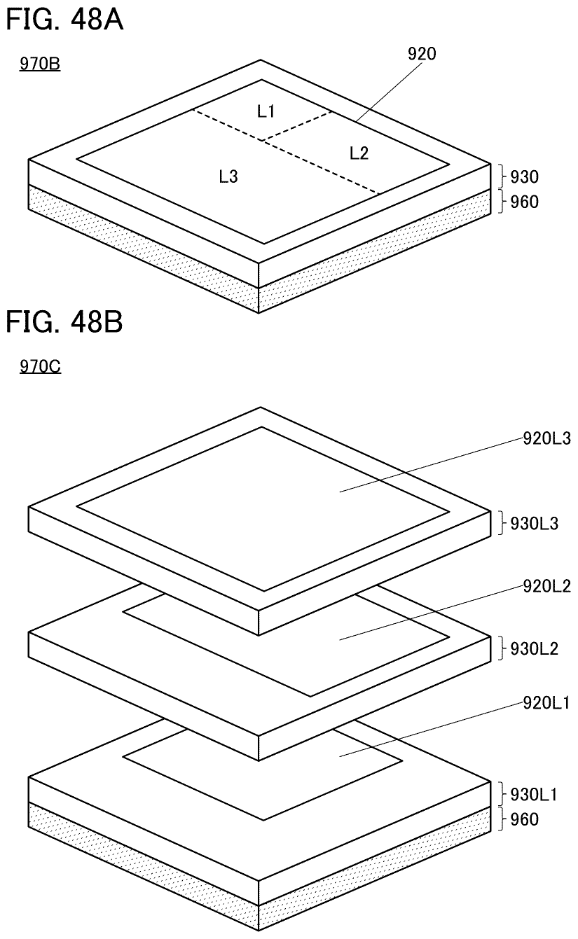

The layer 930 including one memory array 920 may be provided to overlap with the arithmetic device 960. FIG. 48A illustrates a perspective view of a semiconductor device 970B.

In the semiconductor device 970B, one memory array 920 can be divided into a plurality of areas having different functions. FIG. 48A illustrates an example in which a region L1, a region L2, and a region L3 are used as the L1 cache, the L2 cache, and the L3 cache, respectively.

In the semiconductor device 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 48B illustrates a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. This structure can increase the capacity of each memory array, leading to higher processing capability.

This embodiment can be combined with any of the other embodiments as appropriate.

### Embodiment 5

In this embodiment, application examples of the memory device of one embodiment of the present invention will be described.

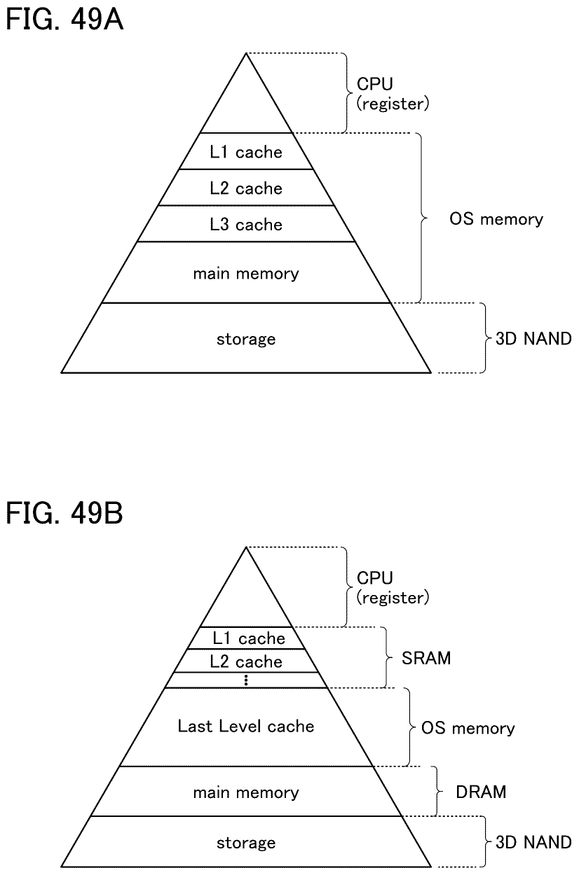

In general, a variety of memory devices are used in semiconductor devices such as computers in accordance with the intended use. FIG. 49A illustrates the hierarchy of various memory devices used in a semiconductor device. The memory devices at the upper levels require higher operating speed, whereas the memory devices at the lower levels require larger memory capacity and higher memory density. FIG. 49A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may further be included.

A memory included as a register in an arithmetic processing unit such as a CPU is used for temporary storage of arithmetic operation results, for example, and thus is frequently accessed by the arithmetic processing unit. Accordingly, high operation speed is required rather than memory capacity. In addition, the register also has a function of retaining settings information of the arithmetic processing unit, for example.

The cache has a function of duplicating and retaining part of data retained in a main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and various kinds of programs used in an arithmetic processing device, for example. Therefore, a storage needs to have high memory capacity and high memory density rather than operating speed. For example, a high-capacity nonvolatile memory device such as a 3D NAND can be used.

The memory device including an oxide semiconductor (the OS memory) of one embodiment of the present invention operates at high speed and can retain data for a long time. For example, the OS memory has features shown in Table 1.

TABLE 1

| | |
|---|---|
| Power consumption | Reduced to 1/10 to 1/100 as compared with Si LSI DRAMs and L3 caches used |
| | in current servers or supercomputers |
| Switching speed | 10 or more times faster than the speed of current 2.5 V DRAMs |
| | (<1.7 nsec at 1.8 V, −40 °C to +110 °C) |
| Memory retention time | 10 to 100 times the retention time of current DRAMs |
| | (in the operation temperature range of −40 °C to 110 °C, which is the harsher |
| | condition than the range of −20 °C to 85 °C) |

Utilizing the characteristics of the OS memory shown in Table 1, as illustrated in FIG. 49A, the memory device of one embodiment of the present invention can be suitably used at both the level where the cache is positioned and the level where the main memory is positioned. The memory device of one embodiment of the present invention can also be used at the level where the storage is positioned.

FIG. 49B illustrates an example in which an SRAM (Static Random Access Memory) is used as some of the cache memories and the OS memory of one embodiment of the present invention is used as the other cache memory.

Among the caches, the lowest-level cache can be referred to as an LLC (Last Level cache). The LLC does not require a higher operating speed than a higher-level cache, but desirably has a large memory capacity. The OS memory of one embodiment of the present invention operates at high speed and can retain data for a long time, and thus can be suitably used as the LLC. Note that the OS memory of one embodiment of the present invention can also be used as an FLC (Final Level cache).

For example, as illustrated in FIG. 49B, a structure can be employed in which an SRAM is used as the higher-level caches (the L1 cache, the L2 cache, and the like) and the OS memory of one embodiment of the present invention is used as the LLC. Moreover, instead of the OS memory, a DRAM can be used as the main memory as illustrated in FIG. 49B.

Note that in a supercomputer, a server using a supercomputer, or the like, the L3 cache and the DRAM that is a main memory consume a large amount of power, which is one factor of global warming. In FIG. 49A, OS memories are used as both the L3 cache and the main memory. In FIG. 49B, an OS memory is used as the LLC. With use of the oxide semiconductor of one embodiment of the present invention for a memory device, the power consumption of a supercomputer can be reduced to be equivalent to that of a personal computer.

This embodiment can be combined with any of the other embodiments as appropriate.

### Embodiment 6

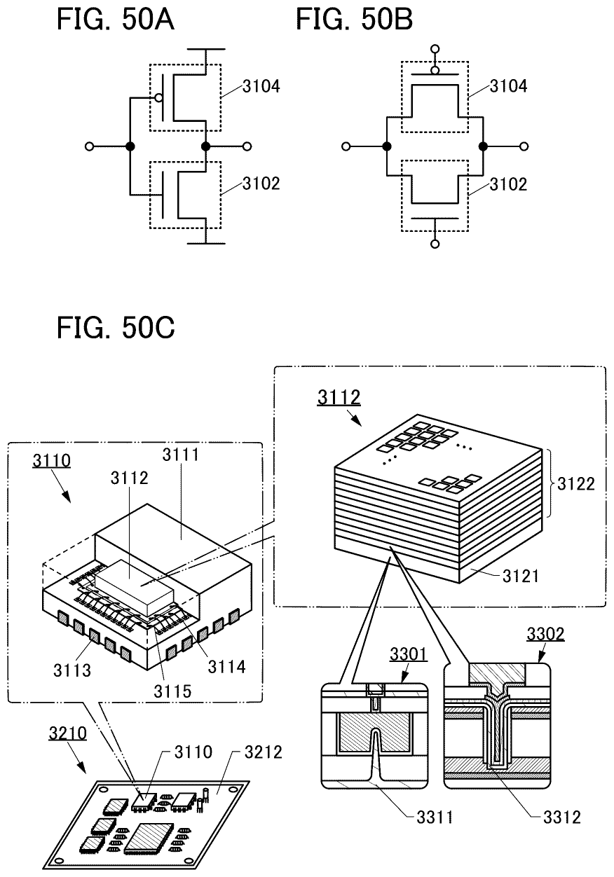

In this embodiment, examples of a circuit structure including the OS transistor of one embodiment of the present invention and examples of electronic components using the semiconductor device of one embodiment of the present invention will be described with reference to FIG. 50A to FIG. 50C.

### Circuit Structure Example

FIG. 50A and FIG. 50B each illustrate an example of a circuit structure including the OS transistor of one embodiment of the present invention. The circuit diagram in FIG. 50A illustrates a structure of an inverter circuit formed of what is called a complementary metal oxide semiconductor (CMOS) circuit in which an n-channel transistor 3102 and a p-channel transistor 3104 are connected in series and their gates are connected. The circuit diagram in FIG. 50B illustrates a structure of a circuit that functions as what is called an analog switch, in which sources of the n-channel transistor 3102 and the p-channel transistor 3104 are connected to each other and drains of the n-channel transistor 3102 and the p-channel transistor 3104 are connected to each other.

### <Transistor Structure>

Any of various types of transistors can be used as the n-channel transistor 3102 and the p-channel transistor 3104 illustrated in FIG. 50A and FIG. 50B. Specifically, a planar transistor, a vertical field effect transistor (VFET), a Fin-type transistor, a gate all around (GAA) transistor, or the like can be used as the n-channel transistor 3102 and the p-channel transistor 3104. A complementary field effect transistor (CFET) in which the n-channel transistor 3102 and the p-channel transistor 3104 are combined may be used.

In this specification and the like, a planar transistor has a structure where a source electrode and a drain electrode are positioned at the same or substantially the same height and a current flowing through a semiconductor contains a lateral-direction component. In this specification and the like, a VFET has a structure where a source electrode and a drain electrode are positioned at different heights and a current flowing through a semiconductor contains a vertical-direction component. Since two or more of the source electrode, the semiconductor, and the drain electrode of the VFET can be provided to overlap with each other, the area occupied by the VFET can be much smaller than the area occupied by the planar transistor.

In this specification and the like, a Fin-type transistor has a structure where two or more surfaces of a channel are covered with a gate electrode with a gate insulating film therebetween in a cross-sectional view in the channel width direction. In particular, the channel height (H) is preferably larger than the channel width (W) in the cross-sectional view in the channel width direction, in which case the channel width per unit area can be increased. In this specification and the like, a GA-A transistor has a structure where a gate electrode covers four surfaces of a channel with a gate insulating film therebetween in a cross-sectional view in the channel width direction.

### <N-Channel Transistor>

An OS transistor of one embodiment of the present invention can be used as the n-channel transistor 3102 illustrated in FIG. 50A and FIG. 50B. The OS transistor has an extremely low off-state current, and thus the leakage current of the n-channel transistor 3102 can be extremely low. As a semiconductor material of the n-channel transistor 3102, a single element semiconductor such as silicon or germanium, a compound semiconductor such as gallium arsenide, a layered material functioning as a semiconductor, or the like can be used. In particular, a layered material functioning as a semiconductor is preferably used as the semiconductor material.

In this specification and the like, the layered material is a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

In this specification and the like, the above-described layered material is sometimes referred to as a two-dimensional material. Examples of the two-dimensional material that can be used in one embodiment of the present invention include graphene, silicene (a substance in which a carbon atom of graphene is replaced with a silicon atom), germanene (a substance in which a carbon atom of graphene is replaced with a germanium atom), transition metal chalcogenides (Transition Metal Dichalcogenides (TMDs)), boron nitride (BN), and black phosphorus, which can be used for the n-channel transistor 3102 and the p-channel transistor 3104. Using the above-described two-dimensional material can improve one or more physical properties of electron mobility, mechanical strength, and thermal conductivity, compared with the case of using a single element semiconductor such as silicon or germanium. The above-described two-dimensional material has excellent physical properties compared with a single element semiconductor such as silicon; thus, the two-dimensional material may be referred to as an NMC (New Material Channel).

Examples of the layered material include chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

As a material that can be used for the transistor 3102, a transition metal chalcogenide functioning as a semiconductor is preferably used, for example. Specific examples of the transition metal chalcogenide include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### <P-Channel Transistor>

As a semiconductor material of the p-channel transistor 3104 illustrated in FIG. 50A and FIG. 50B, a single element semiconductor such as silicon or germanium, a compound semiconductor such as gallium arsenide, a layered material functioning as a semiconductor, or the like can be used. In particular, a layered material functioning as a semiconductor is preferably used as the semiconductor material.

As a material that can be used for the p-channel transistor 3104, a transition metal chalcogenide functioning as a semiconductor is preferably used, for example. Specific examples of the transition metal chalcogenide include molybdenum sulfide (typically MoS₂), molybdenum selenide (typically MoSe₂), tungsten sulfide (typically WS₂), and tungsten selenide (typically WSe₂).

As the material that can be used for the transistor 3104, other than the above-described two-dimensional material, a Group III-V compound semiconductor (typically, a gallium-arsenic compound semiconductor, an indium-phosphorus compound semiconductor, an indium-gallium-arsenic compound semiconductor, an indium-arsenic compound semiconductor, or the like), a carbon nanotube (CNT), tin sulfide (typically, SnS), tin selenide (typically, SnSe), or the like can be used. Note that a Group III-V compound semiconductor may be used for the transistor 3102.

### Example of Electronic Component

FIG. 50C illustrates an example of an electronic component including the semiconductor device of one embodiment of the present invention. An electronic component including the semiconductor device of one embodiment of the present invention is effective in reducing power consumption and improving performance.

FIG. 50C is a perspective view of a substrate (a circuit board 3210) provided with an electronic component 3110. The electronic component 3110 illustrated in FIG. 50C includes a memory device 3112 in a mold 3111. FIG. 50C omits some components to show the inside of the electronic component 3110. The electronic component 3110 includes a land 3113 outside the mold 3111. The land 3113 is connected to an electrode pad 3114, and the electrode pad 3114 is connected to the memory device 3112 through a wire 3115. The electronic component 3110 is mounted on a printed circuit board 3212, for example. A plurality of such electronic components are combined and electrically connected to each other on the printed circuit board 3212, which forms the circuit board 3210.

The memory device 3112 includes a layer 3121 including an arithmetic core and a layer 3122 including a memory. For example, the above-described n-channel transistor and p-channel transistor can be used for both the layer 3121 and the layer 3122. It is particularly preferable that a p-channel transistor be used for the layer 3121 and an n-channel transistor be used for the layer 3122 to form a CMOS circuit. However, one embodiment of the present invention is not limited thereto, and both an n-channel transistor and a p-channel transistor may be included in the layer 3121 and an n-channel transistor may be used in the layer 3122.

Specifically, it is preferable that the layer 3121 include a p-channel transistor 3301 and the layer 3122 include an n-channel transistor 3302. In FIG. 50C, when a semiconductor layer 3311 included in the transistor 3301 is p-channel silicon and a semiconductor layer 3312 included in the transistor 3302 is an n-channel oxide semiconductor, a stacked-layer structure of a Si transistor and an OS transistor can be obtained.

Alternatively, in FIG. 50C, when the semiconductor layer 3311 included in the transistor 3301 is a p-channel two-dimensional material (e.g., WS₂) and the semiconductor layer 3312 included in the transistor 3302 is an n-channel oxide semiconductor, a stacked-layer structure of the WS2 transistor and the OS transistor can be obtained. With such a stacked-layer structure, a memory device with low power consumption and high performance can be provided.

Stacking the two kinds of transistors reduces the area occupied by the circuit, allowing a plurality of circuits to be arranged at higher density. Although FIG. 50C illustrates a structure example where the transistor 3301 is a Fin-type transistor and the transistor 3302 is a VFET, one embodiment of the present invention is not limited thereto; a Fin-type transistor may be used as the transistor 3301 and a Fin-type transistor may be used as the transistor 3302. When the transistor 3301 and the transistor 3302 have different structures, characteristics according to the respective transistor structures can be obtained, which is preferable. The structures of the transistor 3301 and the transistor 3302 are preferably the same, in which case some manufacturing apparatuses can be used in common.

The layer 3122 including the memory has a structure where a plurality of memory cell arrays are stacked. The layer 3121 including the arithmetic core and the layer 3122 including the memory can be stacked monolithically. In the monolithic stacked-layer structure, layers can be connected to each other without using a through electrode technique such as a through silicon via (TSV) technique and a bonding technique such as Cu-Cu direct bonding. The monolithic stacked-layer structure of the layer 3121 including the arithmetic core and the layer 3122 including the memory enables, for example, what is called an on-chip memory structure where a memory is directly formed on a processor. The on-chip memory structure allows an interface portion between the processor and the memory to operate at high speed. Note that part of the function (part of the arithmetic function) of the layer 3121 including the arithmetic core may be provided in part of the layer 3122 including the memory.

With the on-chip memory structure, the sizes of a connection wiring and the like can be smaller than those in the case where the through electrode technique such as TSV is employed; thus, the number of connection pins can be increased. The increase in the number of connection pins enables parallel operations, which can improve the bandwidth of the memory (also referred to as a memory bandwidth).

It is preferable that the plurality of memory cell arrays included in the layer 3122 including the memory be formed with OS transistors and be monolithically stacked. The monolithic stacked-layer structure of the plurality of memory cell arrays can improve the bandwidth of the memory and/or the access latency of the memory. Note that the bandwidth refers to the data transfer volume per unit time, and the access latency refers to a period of time from data access to the start of data transmission. Furthermore, it is more difficult to form the monolithic stacked-layer structure in the case where the layer 3122 including the memory is formed with Si transistors than in the case where the layer 3122 including the memory is formed with OS transistors. Therefore, an OS transistor is superior to a Si transistor in the monolithic stacked-layer structure.

This embodiment can be combined with any of the other embodiments as appropriate. In this specification, in the case where a plurality of structure examples are shown in one embodiment, the structure examples can be combined as appropriate.

### Embodiment 7

In this embodiment, a display device of one embodiment of the present invention will be described.

The semiconductor device of one embodiment of the present invention can be used for a display device or a module including the display device. Examples of the module including the display device include a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

The display device in this embodiment may have a function of a touch panel. The display device can employ any of a variety of sensing elements (also referred to as sensor elements) that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be sensed simultaneously.

Examples of a touch panel include an out-cell touch panel, an on-cell touch panel, and an in-cell touch panel. Note that an in-cell touch panel has a structure in which an electrode included in a sensing element is provided on one or both of a substrate supporting a display element and a counter substrate.

### [Display Module]

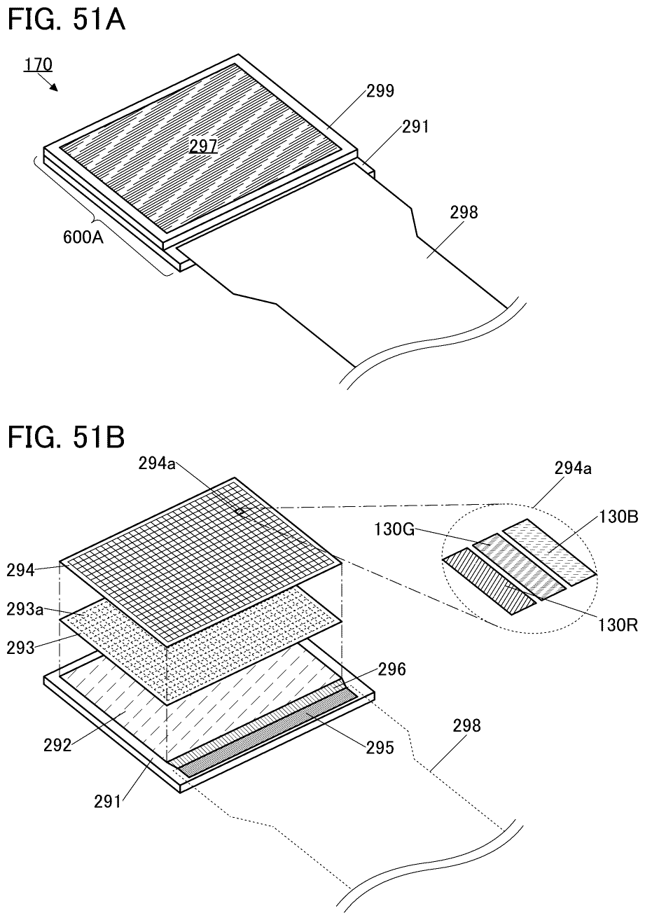

FIG. 51A illustrates a perspective view of a display module 170. The display module 170 includes a display device 600A and an FPC 298. Note that the display device included in the display module 170 is not limited to the display device 600A and may be a display device 600B described later.

The display module 170 includes a substrate 291 and a substrate 299. The display module 170 includes a display portion 297. The display portion 297 is a region of the display module 170 where an image is displayed, and is a region where light from pixels provided in a pixel portion 294 described later can be seen.

FIG. 51B illustrates a schematic perspective view of the structure on the substrate 291 side. Over the substrate 291, a circuit portion 292, a pixel circuit portion 293 over the circuit portion 292, and the pixel portion 294 over the pixel circuit portion 293 are stacked. In addition, a terminal portion 295 for connection to the FPC 298 is provided in a portion over the substrate 291 that does not overlap with the pixel portion 294. The terminal portion 295 and the circuit portion 292 are connected to each other through a wiring portion 296 formed of a plurality of wirings.

The semiconductor device of one embodiment of the present invention can be used for one or both of the circuit portion 292 and the pixel circuit portion 293.

The pixel portion 294 includes a plurality of pixels 294a arranged periodically. An enlarged view of one pixel 294a is illustrated on the right side in FIG. 51B. FIG. 51B illustrates an example where one pixel 294a includes a subpixel 130R emitting red light, a subpixel 130G emitting green light, and a subpixel 130B emitting blue light.

The subpixels include display elements. Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

Examples of light-emitting elements are self-luminous type light-emitting elements such as an LED (Light Emitting Diode), an OLED (Organic LED), and a semiconductor laser. As the LED, for example, a mini LED, a micro LED, or the like can be used.

There is no particular limitation on the arrangement of the pixels in the display device of this embodiment, and any of a variety of methods can be employed. Examples of the arrangement of pixels include stripe arrangement, S-stripe arrangement, matrix arrangement, delta arrangement, Bayer arrangement, and PenTile arrangement. FIG. 51B illustrates an example where stripe arrangement is employed as the pixel arrangement.

The pixel circuit portion 293 includes a plurality of pixel circuits 293a arranged periodically.

One pixel circuit 293a is a circuit that controls driving of a plurality of elements included in one pixel 294a. One pixel circuit 293a can be provided with three circuits each controlling light emission of one light-emitting element. For example, a structure can be employed in which the pixel circuit 293a includes at least one selection transistor, one current control transistor (driving transistor), and a capacitor for one light-emitting element. In that case, a gate signal is input to a gate of the selection transistor, and a source signal is input to a source of the selection transistor. Thus, an active-matrix display device is obtained.

The circuit portion 292 includes a circuit for driving the pixel circuits 293a in the pixel circuit portion 293. For example, the circuit portion 292 preferably includes one or both of a gate line driver circuit and a source line driver circuit. The circuit portion 292 may also include at least one of an arithmetic circuit, a memory circuit, a power supply circuit, and the like.

The FPC 298 functions as a wiring for supplying a video signal, a power supply potential, or the like to the circuit portion 292 from the outside. An IC may be mounted on the FPC 298.

The display module 170 can have a structure in which one or both of the pixel circuit portion 293 and the circuit portion 292 are stacked below the pixel portion 294; hence, the aperture ratio (effective display area ratio) of the display portion 297 can be significantly high. Furthermore, the pixels 294a can be placed extremely densely and thus the display portion 297 can have an extremely high resolution.

Such a display module 170 has an extremely high resolution, and thus can be suitably used for a VR device such as an HMD or a glasses-type AR device. For example, even in the case of a structure in which the display portion of the display module 170 is seen through a lens, pixels of the extremely-high-resolution display portion 297 included in the display module 170 are not recognized when the display portion is enlarged by the lens, and thus display providing a high sense of immersion can be performed. Without being limited thereto, the display module 170 can be suitably used for electronic appliances including a relatively small display portion. For example, the display module 170 can be suitably used for a display portion of a wearable electronic appliance, such as a wrist watch.

### Structure Example 1 of Display Device

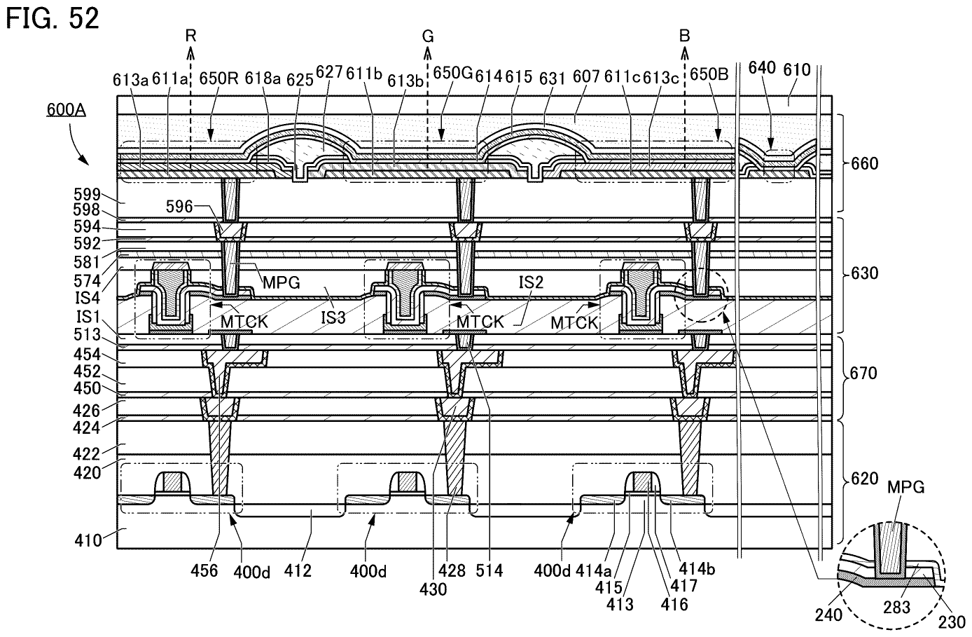

FIG. 52 illustrates a cross-sectional view of the display device 600A. The display device 600A is an example of a display device having an MML (metal maskless) structure. In other words, the display device 600A includes a light-emitting element that is formed without using a fine metal mask.

An island-shaped light-emitting layer of the light-emitting element included in the display device having the MML structure is formed in the following manner: a light-emitting layer is formed on the entire surface, and then, the light-emitting layer is processed by a photolithography method. Accordingly, a high-resolution display device or a display device with a high aperture ratio, which has been difficult to achieve, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

A device having an MML structure can be manufactured without using a metal mask, and thus can break through the resolution limit due to alignment accuracy of the metal mask. Furthermore, manufacturing a device without using a metal mask can eliminate the need for the equipment for manufacturing a metal mask and the step of cleaning the metal mask. Furthermore, for processing by photolithography, an apparatus that is the same as or similar to that used for manufacturing a transistor can be used; thus, there is no need to introduce a special apparatus to manufacture the device having an MML structure. An MML structure can reduce the manufacturing cost as described above, and thus is suitable for mass production of the device.

It is not necessary to conduct a pseudo improvement in resolution by employing a unique pixel arrangement such as a PenTile arrangement in a display device having an MML structure; thus, the display device can achieve high resolution (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

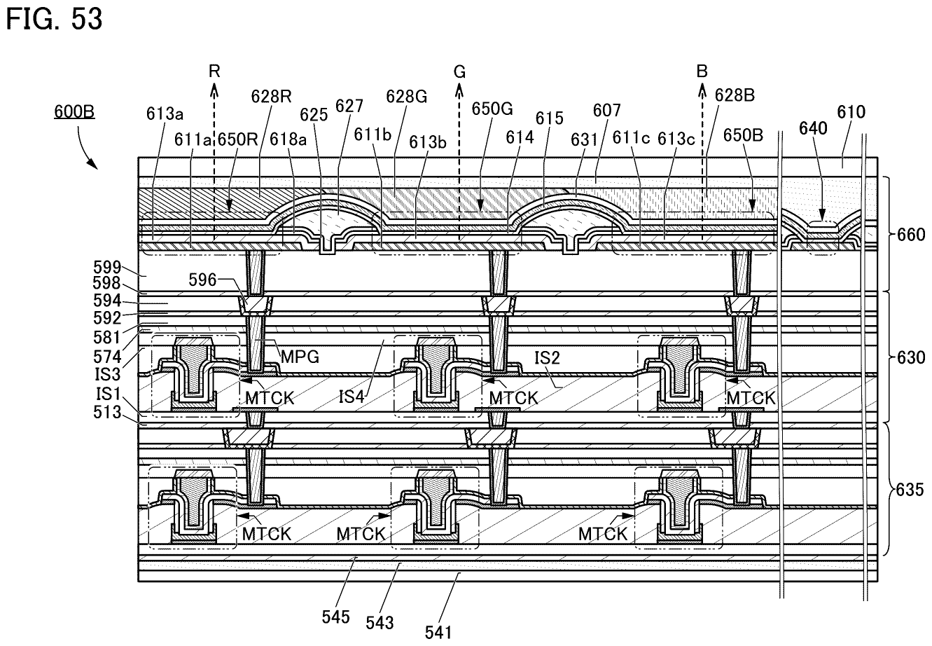

Moreover, providing a sacrificial layer over the light-emitting layer can reduce damage to the light-emitting layer in the manufacturing process of the display device, resulting in an increase in reliability of the light-emitting element. Note that the sacrificial layer may remain in the completed display device or may be removed in the manufacturing process. For example, a sacrificial layer 618a illustrated in FIG. 52 and FIG. 53 is part of the sacrificial layer provided over the light-emitting layer.

Furthermore, employing a film formation step using an area mask and a processing step using a resist mask enables a light-emitting element to be manufactured by a relatively easy process.

FIG. 52 is a schematic cross-sectional view of the display device 600A that is a display device (a semiconductor device) of one embodiment of the present invention. The display device 600A has a structure including a pixel circuit, a driver circuit, and the like provided over a substrate 410. Note that in the display device 600A in FIG. 52, a wiring layer 670 is illustrated in addition to an element layer 620, an element layer 630, and an element layer 660. The wiring layer 670 is a layer provided with a wiring.

A pixel circuit of the display device is preferably provided in the element layer 630. A driver circuit (one or both of a gate driver and a source driver) of the display device is preferably provided in the element layer 620. One or more of a variety of circuits such as an arithmetic circuit and a memory circuit may be provided in the element layer 620.

The element layer 620 includes the substrate 410, for example, and a transistor 400d is formed over the substrate 410. The wiring layer 670 is provided above the transistor 400d, and a wiring for electrically connecting the transistor 400d to a conductive layer, a transistor, or the like provided in the element layer 630 (a conductive layer 514 in FIG. 52) is provided in the wiring layer 670. The element layer 630 and the element layer 660 are provided above the wiring layer 670, and the element layer 630 includes a transistor MTCK and the like, for example. The element layer 660 includes a light-emitting element 650 (a light-emitting element 650R, a light-emitting element 650G, and a light-emitting element 650B in FIG. 5₂) and the like.

The transistor 400d is an example of a transistor included in the element layer 620. The transistor MTCK is an example of a transistor included in the element layer 630. The light-emitting element (the light-emitting element 650R, the light-emitting element 650G, and the light-emitting element 650B) is an example of a light-emitting element included in the element layer 660.

As the substrate 410, a semiconductor substrate (e.g., a single crystal substrate containing silicon or germanium as a material) can be used, for example. Besides the semiconductor substrate, for example, an SOI substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, a laminate film, or paper or a base material film including a fibrous material can be used as the substrate 410. In description of this embodiment, the substrate 410 is a semiconductor substrate containing silicon as a material. Therefore, a transistor included in the element layer 620 can be a Si transistor.

The transistor 400d includes an element isolation layer 412, a conductive layer 416, an insulating layer 415, an insulating layer 417, a semiconductor region 413 that is part of the substrate 410, and a low-resistance region 414a and a low-resistance region 414b that function as a source region and a drain region. Thus, the transistor 400d is a Si transistor. Although FIG. 52 illustrates a structure in which one of a source and a drain of the transistor 400d is connected to the conductive layer 514 provided in the element layer 630 through a conductive layer 428, a conductive layer 430, and a conductive layer 456, the connection structure in the display device of one embodiment of the present invention is not limited thereto.

The transistor 400d can be a Fin type when, for example, the top surface of the semiconductor region 413 and the side surface thereof in the channel width direction are covered with the conductive layer 416 with the insulating layer 415 functioning as a gate insulating layer therebetween. The effective channel width can be increased in the Fin-type transistor 400d, so that the on-state characteristics of the transistor 400d can be improved. In addition, since contribution of an electric field of a gate electrode can be increased, the off-state characteristics of the transistor 400d can be improved. Alternatively, the transistor 400d may have a planar structure instead of a Fin-type structure.

Note that the transistor 400d can be either a p-channel transistor or an n-channel transistor. Alternatively, a plurality of the transistors 400d may be provided and both the p-channel transistor and the n-channel transistor may be used.

A region of the semiconductor region 413 where a channel is formed, a region in the vicinity thereof, and the low-resistance region 414a and the low-resistance region 414b that function as the source region and the drain region preferably include a silicon-based semiconductor, specifically, preferably include single crystal silicon. Alternatively, each of the above-described regions may be formed using germanium, silicon germanium, gallium arsenide, aluminum gallium arsenide, or gallium nitride, for example. A structure using silicon whose effective mass is controlled by applying stress to a crystal lattice and changing lattice spacing may be employed. Alternatively, the transistor 400d may be a HEMT (High Electron Mobility Transistor) using gallium arsenide and aluminum gallium arsenide, for example.

For the conductive layer 416 functioning as a gate electrode, a semiconductor material such as silicon containing an element that imparts n-type conductivity, such as arsenic or phosphorus, or an element that imparts p-type conductivity, such as boron or aluminum, can be used. Alternatively, for the conductive layer 416, a conductive material such as a metal material, an alloy material, or a metal oxide material can be used, for example.

Note that since a work function depends on the material for the conductive layer, the threshold voltage of the transistor can be adjusted by selecting the material for the conductive layer. Specifically, it is preferable to use one or both of titanium nitride and tantalum nitride as the material for the conductive layer. Moreover, for both conductivity and embeddability, it is preferable to use stacked layers of metal materials of one or both of tungsten and aluminum as the conductive layer, and it is particularly preferable to use tungsten in terms of heat resistance.

The element isolation layer 412 is provided to separate a plurality of transistors formed on the substrate 410 from each other. The element isolation layer can be formed by, for example, a LOCOS (Local Oxidation of Silicon) method, an STI (Shallow Trench Isolation) method, or a mesa isolation method.

Over the transistor 400d illustrated in FIG. 52, an insulating layer 420 and an insulating layer 422 are sequentially stacked from the substrate 410 side.

For each of the insulating layer 420 and the insulating layer 422, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 422 may have a function of a planarization film for eliminating a level difference caused by the transistor 400d or the like covered with the insulating layer 420 and the insulating layer 422. For example, the top surface of the insulating layer 422 may be planarized through planarization treatment using a CMP method or the like to increase the planarity.

The conductive layer 428 connected to the transistor MTCK and the like provided above the insulating layer 422 is embedded in the insulating layer 420 and the insulating layer 422. Note that the conductive layer 428 has a function of a plug or a wiring.

In the display device 600A, the wiring layer 670 is provided over the transistor 400d. The wiring layer 670 includes, for example, an insulating layer 424, an insulating layer 426, the conductive layer 430, an insulating layer 450, an insulating layer 452, an insulating layer 454, and the conductive layer 456.

Over the insulating layer 422 and the conductive layer 428, the insulating layer 424 and the insulating layer 426 are sequentially stacked. An opening portion is formed in the insulating layer 424 and the insulating layer 426 in a region overlapping with the conductive layer 428. In addition, the conductive layer 430 is embedded in the opening portion.

The insulating layer 450, the insulating layer 452, and the insulating layer 454 are sequentially stacked over the insulating layer 426 and the conductive layer 430. An opening portion is formed in the insulating layer 450, the insulating layer 452, and the insulating layer 454 in a region overlapping with the conductive layer 430. The conductive layer 456 is embedded in the opening portion.

The conductive layer 430 and the conductive layer 456 have a function of a plug or a wiring that is connected to the transistor 400d.

Note that like an insulating layer 592 described later, for example, the insulating layer 424 and the insulating layer 450 are each preferably formed using an insulating layer having a barrier property against one or more selected from hydrogen, oxygen, and water. Like an insulating layer 594 described later, the insulating layer 426, the insulating layer 452, and the insulating layer 454 are each preferably formed using an insulating layer having a relatively low relative permittivity to reduce parasitic capacitance generated between wirings. The insulating layer 426, the insulating layer 452, and the insulating layer 454 have functions of an interlayer insulating film and a planarization film.

Furthermore, the conductive layer 456 preferably includes a conductive layer having a barrier property against one or more selected from hydrogen, oxygen, and water.

For the conductive layer having a barrier property against hydrogen, tantalum nitride is preferably used, for example. In addition, using a stack of tantalum nitride and tungsten, which has high conductivity, can inhibit diffusion of hydrogen from the transistor 400d while the conductivity of a wiring is kept. In that case, the tantalum nitride layer having a barrier property against hydrogen is preferably in contact with the insulating layer 450 having a barrier property against hydrogen.

An insulating layer 513 is provided above the insulating layer 454 and the conductive layer 456. An insulating layer ISI is provided over the insulating layer 513. The conductive layer functioning as a plug or a wiring is embedded in the insulating layer IS1 and the insulating layer 513. Thus, the transistor 400d can be connected to the conductive layer 514 provided in the element layer 630. Alternatively, one of a source and a drain of the transistor MTCK and one of the source and the drain of the transistor 400d may be connected to each other.

The transistor MTCK is provided over the insulating layer IS1. An insulating layer IS4, an insulating layer 574, and an insulating layer 581 are stacked in this order over the transistor MTCK. A conductive layer MPG functioning as a plug or a wiring is embedded in an insulating layer IS3, the insulating layer IS4, the insulating layer 574, and the insulating layer 581. As illustrated in an enlarged view of a region surrounded by a dashed line in FIG. 52, the conductive layer MPG is preferably in direct contact with the conductive layer 240 through an opening portion provided in the insulating layer 283 and the oxide semiconductor layer 230. The direct contact between the conductive layer MPG and the conductive layer 240 is preferable because the contact resistance therebetween can be reduced. Alternatively, the conductive layer MPG and the oxide semiconductor layer 230 may be in contact with each other and the conductive layer MPG and the conductive layer 240 may be connected to each other through the oxide semiconductor layer 230.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits the entry of the impurities into the transistor MTCK. Moreover, the insulating layer 574 preferably has a function of inhibiting diffusion of oxygen (e.g., one or both of an oxygen atom and an oxygen molecule). For example, the insulating layer 574 preferably has a lower oxygen permeability than each of an insulating layer IS2, the insulating layer IS3, and the insulating layer IS4.

Thus, the insulating layer 574 preferably functions as a barrier insulating film that inhibits diffusion of impurities such as water and hydrogen. Accordingly, it is preferable to use, for the insulating layer 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are less likely to pass). Alternatively, it is preferable to use an insulating material having a function of inhibiting diffusion of oxygen (e.g., one or both of an oxygen atom and an oxygen molecule) (an insulating material through which the oxygen is less likely to pass).

For the insulating layer having a function of inhibiting passage of oxygen and impurities such as water and hydrogen, it is possible to use any of the materials that can be used for the insulating layer having a function of inhibiting passage of oxygen and impurities described as examples in Embodiment 1.

In particular, aluminum oxide or silicon nitride is preferably used for the insulating layer 574. Accordingly, it is possible to inhibit diffusion of impurities such as water and hydrogen into the transistor MTCK from above the insulating layer 574. Alternatively, it is possible to inhibit diffusion of oxygen contained in the insulating layer IS3 or the like to above the insulating layer 574.

The insulating layer 581 is preferably a film functioning as an interlayer film and having a lower permittivity than the insulating layer 574. When a material with a lower permittivity is used for an interlayer film, parasitic capacitance generated between wirings can be reduced. The relative permittivity of the insulating layer 581 is preferably lower than 4, further preferably lower than 3, for example. The relative permittivity of the insulating layer 581 is, for example, preferably 0.7 times or less, further preferably 0.6 times or less the relative permittivity of the insulating layer 574. When a material with a lower permittivity is used for the insulating layer 581, parasitic capacitance generated between wirings can be reduced.

The concentration of impurities such as water and hydrogen in the insulating layer 581 is preferably reduced. In that case, for the insulating layer 581, silicon oxide, silicon oxynitride, silicon nitride oxide, or silicon nitride can be used, for example. Alternatively, for the insulating layer 581, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulating layer 581, a resin can be used. A material that can be used for the insulating layer 581 may be an appropriate combination of the above-described materials.

The insulating layer 592 and the insulating layer 594 are stacked in this order over the insulating layer 574 and the insulating layer 581.

For the insulating layer 592, it is preferable to use a barrier insulating layer which can prevent diffusion of impurities such as water and hydrogen from the substrate 410 or the transistor MTCK to a region above the insulating layer 592 (e.g., the region where the light-emitting element 650R, the light-emitting element 650G, the light-emitting element 650B, and the like are provided). Accordingly, for the insulating layer 592, it is preferable to use an insulating material that has a function of inhibiting diffusion of impurities such as a hydrogen atom, a hydrogen molecule, and a water molecule (an insulating material through which the above impurities are less likely to pass). Furthermore, depending on the situation, it is preferable to use, for the insulating layer 592, an insulating material having a function of inhibiting diffusion of impurities such as a nitrogen atom, a nitrogen molecule, a nitrogen oxide molecule (e.g., N₂O, NO, or NO₂), and a copper atom (an insulating material through which the above impurities are less likely to pass). Alternatively, it is preferable that the insulating layer 592 have a function of inhibiting diffusion of oxygen (e.g., one or both of an oxygen atom and an oxygen molecule).

For the film having a barrier property against hydrogen, silicon nitride formed by a CVD method can be used, for example.

Like the insulating layer 581, the insulating layer 594 is preferably an interlayer film with a low permittivity. Thus, for the insulating layer 594, a material that can be used for the insulating layer 581 can be used.

Note that the insulating layer 594 preferably has a lower permittivity than the insulating layer 592. The relative permittivity of the insulating layer 594 is preferably lower than 4, further preferably lower than 3, for example. The relative permittivity of the insulating layer 594 is, for example, preferably 0.7 times or less, further preferably 0.6 times or less the relative permittivity of the insulating layer 592. When a material with a lower permittivity is used for the insulating layer 594, parasitic capacitance generated between wirings can be reduced.

The conductive layer MPG functioning as a plug or a wiring is embedded in the insulating layer IS3, the insulating layer IS4, the insulating layer 574, and the insulating layer 581, and a conductive layer 596 functioning as a plug or a wiring is embedded in the insulating layer 592 and the insulating layer 594. In particular, the conductive layer MPG and the conductive layer 596 are connected to the light-emitting element or the like provided above the insulating layer 594. A plurality of conductive layers functioning as plugs or wirings are collectively denoted by the same reference numeral in some cases. In this specification and the like, a wiring and a plug connected to the wiring may be a single component. That is, part of a conductive layer serves as a wiring in some cases and part of the conductive layer serves as a plug in other cases.

As a material for each of plugs and wirings (e.g., the conductive layer MPG, the conductive layer 428, the conductive layer 430, the conductive layer 456, the conductive layer 514, and the conductive layer 596), a single layer or stacked layers of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

An insulating layer 598 and an insulating layer 599 are sequentially formed over the insulating layer 594 and the conductive layer 596.

Like the insulating layer 592, for example, the insulating layer 598 is preferably formed using an insulating layer having a barrier property against one or more selected from hydrogen, oxygen, and water. Like the insulating layer 594, the insulating layer 599 is preferably formed using an insulating layer having relatively low relative permittivity to reduce parasitic capacitance generated between wirings. The insulating layer 599 has functions of an interlayer insulating film and a planarization film.

The light-emitting element 650 and a connection portion 640 are formed over the insulating layer 599.

The connection portion 640 is referred to as a cathode contact portion in some cases, and is connected to cathode electrodes of the light-emitting element 650R, the light-emitting element 650G, and the light-emitting element 650B. In the connection portion 640 illustrated in FIG. 52, a conductive layer formed using the same material in the same step as a conductive layer 611a to a conductive layer 611c is connected to a common electrode 615 described later. Although FIG. 52 illustrates an example in which the conductive layer is connected to the common electrode 615 through a common layer 614 described later, the conductive layer and the common electrode 615 may be in direct contact with each other.

In addition, the connection portion 640 may be provided to surround four sides of the display portion in the plan view, or may be provided in the display portion (e.g., between adjacent light-emitting elements 650) (not illustrated).

The light-emitting element 650R includes the conductive layer 611a as a pixel electrode. Similarly, the light-emitting element 650G includes the conductive layer 611b as a pixel electrode, and the light-emitting element 650B includes the conductive layer 611c as a pixel electrode.

The conductive layer 611a, the conductive layer 611b, and the conductive layer 611c are connected to the conductive layer 596 embedded in the insulating layer 594 through a conductive layer (plug) embedded in the insulating layer 599.

The light-emitting element 650R includes a layer 613a, the common layer 614 over the layer 613a, and the common electrode 615 over the common layer 614. The light-emitting element 650G includes a layer 613b, the common layer 614 over the layer 613b, and the common electrode 615 over the common layer 614. The light-emitting element 650B includes a layer 613c, the common layer 614 over the layer 613c, and the common electrode 615 over the common layer 614.

As a material that forms the pair of electrodes (the pixel electrode and the common electrode) of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include ITO, ITSO, indium zinc oxide (In—Zn oxide), and In—W—Zn oxide. Other examples of the material include an alloy containing aluminum (aluminum alloy), such as an alloy of aluminum, nickel, and lanthanum (A1-Ni—La), and an alloy containing silver, such as an alloy of silver and magnesium and an alloy of silver, palladium, and copper (Ag—Pd—Cu, also referred to as APC). Other examples of the material include an element belonging to Group 1 or Group 2 of the periodic table of the elements (e.g., lithium, cesium, calcium, or strontium), which is not given as examples above, a rare earth metal such as europium or ytterbium, an alloy containing an appropriate combination of any of these elements, and graphene.

The display device 600A employs an SBS structure. The SBS structure can optimize materials and structures of light-emitting elements and thus can extend the freedom of choices of materials and structures, whereby the luminance and the reliability can be easily improved.

The display device 600A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

Note that the layer 613a is formed to cover the top surface and the side surface of the conductive layer 611a. Similarly, the layer 613b is formed to cover the top surface and the side surface of the conductive layer 611b. Similarly, the layer 613c is formed to cover the top surface and the side surface of the conductive layer 611c. Accordingly, regions provided with the conductive layer 611a, the conductive layer 611b, and the conductive layer 611c can be entirely used as the light-emitting regions of the light-emitting element 650R, the light-emitting element 650G, and the light-emitting element 650B, respectively, thereby increasing the aperture ratio of the pixels.

In the light-emitting element 650R, the layer 613a and the common layer 614 can be collectively referred to as an EL layer. Similarly, in the light-emitting element 650G, the layer 613b and the common layer 614 can be collectively referred to as an EL layer. Similarly, in the light-emitting element 650B, the layer 613c and the common layer 614 can be collectively referred to as an EL layer.

The EL layer includes at least a light-emitting layer. The light-emitting layer includes one or more kinds of light-emitting substances. As the light-emitting substance, a substance emitting light of emission color of blue, violet, bluish violet, green, yellowish green, yellow, orange, red, or the like is appropriately used. Alternatively, as the light-emitting substance, a substance that emits near-infrared light can be used.

Examples of the light-emitting substance included in the light-emitting element include a substance that emits fluorescent light (a fluorescent material), a substance that emits phosphorescent light (a phosphorescent material), a substance that exhibits thermally activated delayed fluorescence (a TADF material), and an inorganic compound (e.g., a quantum dot material).

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a substance with a bipolar property and a TADF material.

Either a low molecular compound or a high molecular compound can be used in the light-emitting element, and an inorganic compound may also be included. Each layer included in the light-emitting element can be formed by a method such as an evaporation method (including a vacuum evaporation method), a transfer method, a printing method, an inkjet method, or a coating method.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when voltage is applied between the pair of electrodes. A tandem structure enables a light-emitting element capable of emitting light with high luminance. Furthermore, the amount of current needed for obtaining the same luminance can be smaller in a tandem structure than in a single structure; thus, a tandem structure enables higher reliability. Note that a tandem structure may also be referred to as a stack structure.

When the light-emitting element has a microcavity structure, higher color purity can be achieved.

The layer 613a, the layer 613b, and the layer 613c are each processed into an island shape by a photolithography method. At each of end portions of the layer 613a, the layer 613b, and the layer 613c, an angle between the top surface and side surface is approximately 90°. By contrast, for example, an organic film formed using an FMM (Fine Metal Mask) tends to have a thickness that gradually decreases with decreasing distance to an end portion, and has a sloped top surface toward the end portion in the range of 1 μm to 10 μm, both inclusive, for example; thus, such an organic film has a shape whose top surface and side surface are difficult to distinguish from each other.

The top surface and the side surface of each of the layer 613a, the layer 613b, and the layer 613c are clearly distinguished from one another. Accordingly, regarding the layer 613a and the layer 613b which are adjacent to each other, one of the side surfaces of the layer 613a and one of the side surfaces of the layer 613b are placed to face each other. This applies to any combination of the layer 613a, the layer 613b, and the layer 613c.

The layer 613a, the layer 613b, and the layer 613c each include at least a light-emitting layer. It is preferable that the layer 613a include a red-light-emitting layer, the layer 613b include a green-light-emitting layer, and the layer 613c include a blue-light-emitting layer, for example. Other than the above colors, cyan, magenta, yellow, or white can be employed for the light-emitting layers.

The layer 613a, the layer 613b, and the layer 613c each preferably include a light-emitting layer and a carrier-transport layer (an electron-transport layer or a hole-transport layer) over the light-emitting layer. Since the surfaces of the layer 613a, the layer 613b, and the layer 613c are exposed in the manufacturing process of the display device in some cases, providing the carrier-transport layer over the light-emitting layer inhibits the light-emitting layer from being exposed on the outermost surface, so that damage to the light-emitting layer can be reduced. This can improve the reliability of the light-emitting element.

The common layer 614 includes, for example, an electron-injection layer or a hole-injection layer. Alternatively, the common layer 614 may include a stack of an electron-transport layer and an electron-injection layer, or may include a stack of a hole-transport layer and a hole-injection layer. The common layer 614 is shared by the light-emitting element 650R, the light-emitting element 650G, and the light-emitting element 650B. Note that the common layer 614 is not necessarily provided, and the whole EL layer included in the light-emitting element may be provided in an island shape like the layer 613a, the layer 613b, and the layer 613c.

The common electrode 615 is shared by the light-emitting element 650R, the light-emitting element 650G, and the light-emitting element 650B. As illustrated in FIG. 52, the common electrode 615 shared by the plurality of light-emitting elements is connected to a conductive layer included in the connection portion 640.

An insulating layer 625 preferably has a function of a barrier insulating layer against one or both of water and oxygen. Alternatively, the insulating layer 625 preferably has a function of inhibiting diffusion of one or both of water and oxygen. Alternatively, the insulating layer 625 preferably has a function of capturing or fixing (also referred to as gettering) one or both of water and oxygen. When the insulating layer 625 has at least one of these functions, entry of impurities (typically, one or both of water and oxygen) that would be diffused into the light-emitting elements from the outside can be inhibited. With this structure, a highly reliable light-emitting element and a highly reliable display device can be provided.

As the insulating layer 625, the above-described barrier insulating layer against oxygen can be used, and aluminum oxide or silicon nitride is preferably used.

The insulating layer 625 preferably has a low impurity concentration. Accordingly, degradation of the EL layer, which is caused by entry of impurities into the EL layer from the insulating layer 625, can be inhibited. In addition, when the impurity concentration is reduced in the insulating layer 625, a barrier property against one or both of water and oxygen can be increased. For example, it is desirable that one or both of the hydrogen concentration and the carbon concentration in the insulating layer 625 be sufficiently low.

As an insulating layer 627, an insulating layer containing an organic material can be favorably used. As the organic material, a photosensitive resin is preferably used; for example, a photosensitive resin composition containing an acrylic resin can be used. Note that in this specification and the like, an acrylic resin refers to not only a polymethacrylic acid ester or a methacrylic resin, but also a broader range of acrylic-based polymers in some cases.

The organic material that can be used for the insulating layer 627 is not limited to the materials given above. For the insulating layer 627, an acrylic resin, a polyimide resin, an epoxy resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used for the insulating layer 627 in some cases. For the insulating layer 627, for example, a photoresist can be used as the photosensitive resin in some cases. Note that as the photosensitive resin, a positive material or a negative material can be used.

The insulating layer 627 may be formed using a material absorbing visible light. When the insulating layer 627 absorbs light emitted from the light-emitting element, light leakage (stray light) from the light-emitting element to the adjacent light-emitting element through the insulating layer 627 can be inhibited. This can improve the display quality of the display device. Since the display quality of the display device can be improved without using a polarizing plate, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable because the effect of blocking visible light can be enhanced. In particular, mixing color filter materials of three or more colors enables the formation of a black or nearly black resin layer.

For example, the insulating layer 627 can be formed by a wet film formation method such as spin coating, dipping, spray coating, ink-jetting, dispensing, screen printing, offset printing, a doctor knife method, slit coating, roll coating, curtain coating, or knife coating. Specifically, an organic insulating film to be the insulating layer 627 is preferably formed by spin coating.

The insulating layer 627 is formed at a temperature lower than the heat resistance temperature of the EL layer. The typical substrate temperature in formation of the insulating layer 627 is higher than or equal to room temperature and lower than or equal to 200 °C, preferably lower than or equal to 180 °C, further preferably lower than or equal to 160 °C, still further preferably lower than or equal to 150 °C, yet further preferably lower than or equal to 140 °C.

Note that the insulating layer 627 preferably has a tapered side surface. A forward tapered shape (less than 90°, preferably less than or equal to 60°, further preferably less than or equal to) 45° of the end portion of the side surface of the insulating layer 627 can prevent disconnection, local thinning, or the like from occurring in the common layer 614 and the common electrode 615 which are provided over the end portion of the side surface of the insulating layer 627, leading to film formation with good coverage. Accordingly, the in-plane uniformity of the common layer 614 and the common electrode 615 can be improved, leading to higher display quality of the display device.

The top surface of the insulating layer 627 preferably has a convex shape in a cross-sectional view of the display device. The top surface of the insulating layer 627 preferably has a convex shape that bulges gradually toward the center. When the insulating layer 627 has such a shape, the common layer 614 and the common electrode 615 can be formed with good coverage over the whole insulating layer 627.

The insulating layer 627 is formed in a region between two EL layers (e.g., a region between the layer 613a and the layer 613b). At this time, part of the insulating layer 627 is placed at a position sandwiched between an end portion of the side surface of one of the EL layers (e.g., the layer 613a) and an end portion of the side surface of the other of the EL layers (e.g., the layer 613b).

One end portion of the insulating layer 627 preferably overlaps with the conductive layer 611a functioning as a pixel electrode, and the other end portion of the insulating layer 627 preferably overlaps with the conductive layer 611b functioning as a pixel electrode. Such a structure enables the end portion of the insulating layer 627 to be formed over a flat or substantially flat region of the layer 613a (the layer 613b). This makes it relatively easy to process the insulating layer 627 into a tapered shape as described above.

By providing the insulating layer 627 and the like in the above manner, a disconnected portion and a locally thinned portion can be prevented from being formed in the common layer 614 and the common electrode 615 from a flat or substantially flat region of the layer 613a to a flat or substantially flat region of the layer 613b. Thus, between the light-emitting elements, a connection defect caused by the disconnected portion and an increase in electrical resistance caused by the locally thinned portion can be inhibited from occurring in the common layer 614 and the common electrode 615.

In the display device of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device of this embodiment includes a region where a distance between two adjacent island-shaped EL layers is less than or equal to 1 μm, preferably less than or equal to 0.5 μm (500 nm), further preferably less than or equal to 100 nm. The distance between the light-emitting elements is shortened in this manner, whereby a display device with a high resolution and a high aperture ratio can be provided.

A protective layer 631 is provided over the light-emitting element 650. The protective layer 631 is a film functioning as a passivation film for protecting the light-emitting element 650. Forming the protective layer 631 covering the light-emitting element can inhibit impurities such as water and oxygen from entering the light-emitting element, and improve the reliability of the light-emitting element 650. The protective layer 631 preferably has a single-layer structure or a stacked-layer structure including at least an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide (IGZO) may be used for the protective layer 631. Note that the protective layer 631 can be formed by an ALD method, a CVD method, a sputtering method, or the like. Although the protective layer 631 includes an inorganic insulating film in this example, one embodiment of the present invention is not limited thereto. For example, the protective layer 631 may have a stacked-layer structure of an inorganic insulating film and an organic insulating film.

The protective layer 631 and a substrate 610 are bonded to each other with an adhesive layer 607. A solid sealing structure, a hollow sealing structure, or the like can be employed to seal in the light-emitting elements. In FIG. 52, a solid sealing structure is employed in which a space between the substrate 410 and the substrate 610 is filled with the adhesive layer 607. Alternatively, a hollow sealing structure may be employed in which the space is filled with an inert gas (e.g., nitrogen or argon). The adhesive layer 607 may be provided not to overlap with the light-emitting element. The space may be filled with a resin different from that of the frame-shaped adhesive layer 607.

For the adhesive layer 607, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component resin may be used. An adhesive sheet may be used.

The display device 600A has a top-emission structure. Light from the light-emitting element is emitted toward the substrate 610. Thus, for the substrate 610, a material having a high visible-light-transmitting property is preferably used. For example, as the substrate 610, a substrate having a high visible-light-transmitting property can be selected from substrates that can be used as the substrate 410. The pixel electrode includes a material that reflects visible light, and the counter electrode (the common electrode 615) includes a material that transmits visible light.

Note that the display device of one embodiment of the present invention may be not a top-emission display device but a bottom-emission display device where light from the light-emitting element is emitted to the substrate 410 side. In that case, a substrate having a high visible-light-transmitting property is selected as the substrate 410.

### Structure Example 2 of Display Device

FIG. 53 illustrates a cross-sectional view of the display device 600B.

The display device 600B can be a display device having flexibility (also referred to as a flexible display device) when a substrate having flexibility is used as each of a substrate 541 and the substrate 610. The substrate 541 is bonded to an insulating layer 545 with an adhesive layer 543. The substrate 610 is bonded to the protective layer 631 with the adhesive layer 607.

The element layer 660 of the display device 600B is different from the element layer 660 of the display device 600A mainly in that the layer 613a, the layer 613b, and the layer 613c have the same structure and that a coloring layer 628R, a coloring layer 628G, and a coloring layer 628B are provided.

The layer 613a, the layer 613b, and the layer 613c are formed using the same material in the same step. The layer 613a, the layer 613b, and the layer 613c are separated from one another. When the EL layer is provided in an island shape for each light-emitting element, leakage current between adjacent light-emitting elements (sometimes referred to as horizontal-direction leakage current, horizontal leakage current, or lateral leakage current) can be inhibited. Accordingly, unintentional light emission due to crosstalk can be prevented, and color mixture between adjacent light-emitting elements can be inhibited, so that a display device with extremely high contrast can be obtained.

The light-emitting elements 650R, 650G, and 650B illustrated in FIG. 53 emit white light, for example. White light emitted from the light-emitting elements 650R, 650G, and 650B passes through the coloring layer 628R, the coloring layer 628G, and the coloring layer 628B, whereby light of a desired color can be obtained.

In the case where the light-emitting element configured to emit white light has a microcavity structure, light with a specific wavelength such as red, green, or blue is sometimes intensified and emitted.

Light emitted by the light-emitting element 650R is extracted as red light to the outside of the display device 600B through the coloring layer 628R. Similarly, light emitted by the light-emitting element 650G is extracted as green light to the outside of the display device 600B through the coloring layer 628G. Light emitted by the light-emitting element 650B is extracted as blue light to the outside of the display device 600B through the coloring layer 628B.

The light-emitting element that emits white light preferably has a tandem structure.

Alternatively, the light-emitting elements 650R, 650G, and 650B illustrated in FIG. 53 emit blue light, for example. In this case, the layer 613a, the layer 613b, and the layer 613c include one or more light-emitting layers that emit blue light. In the subpixel that emits blue light, blue light emitted from the light-emitting element 650B can be extracted. In each of the subpixel emitting red light and the subpixel emitting green light, when a color conversion layer is provided between the light-emitting element 650R and the coloring layer 628R and between the light-emitting element 650G and the coloring layer 628G, blue light emitted from the light-emitting element 650R or the light-emitting element 650G can be converted into light with a longer wavelength and red light or green light can be extracted. When light transmitted through the color conversion layer is extracted through the coloring layer, light other than light of the desired color can be absorbed by the coloring layer, and color purity of light emitted by a subpixel can be improved.

The coloring layer is a colored layer that selectively transmits light in a specific wavelength range and absorbs light in the other wavelength ranges. For example, a red (R) color filter transmitting light in the red wavelength range, a green (G) color filter transmitting light in the green wavelength range, a blue (B) color filter transmitting light in the blue wavelength range, or the like can be used. For each coloring layer, one or more of a metal material, a resin material, a pigment, and a dye can be used. Each coloring layer is formed in a desired position by a printing method, an inkjet method, an etching method using a photolithography method, or the like.

The element layer 630 of the display device 600B has a structure similar to that of the element layer 630 of the display device 600A; thus, the detailed description thereof is omitted.

The display device 600B is different from the display device 600A in not including the element layer 620 but including an element layer 635. The element layer 635 has a structure similar to that of the element layer 630.

At least part of the transistor included in the element layer 635 is connected to a conductive layer or a transistor included in the element layer 630 through a plug, a wiring, and the like. Note that the wiring layer 670 may be provided between the element layer 630 and the element layer 635.

One or both of a pixel circuit and a driver circuit of the display device are preferably provided in the element layer 635.

Although FIG. 53 illustrates an example in which two element layers including OS transistors are stacked (the element layer 630 and the element layer 635), the number of stacked element layers is not limited thereto, and may be three or more. For example, in the case where three or more element layers including OS transistors are stacked, it is preferable that the lowermost layer be used for the driver circuit (one or both of the gate driver and the source driver) of the display device, the uppermost layer be used for the pixel circuit of the display device, and a layer between them be used for the pixel circuit or the driver circuit.

Note that a Si transistor is typically formed on a single crystal Si wafer, and thus has difficulty in having flexibility. Meanwhile, as illustrated in FIG. 53, in the case where the display device is formed using only OS transistors without using a Si transistor, the display device can have flexibility through a relatively simple manufacturing process.

### Structure Example of Light-Emitting Element

Next, light-emitting elements that can be used in the display device of one embodiment of the present invention will be described. Structure examples of light-emitting elements, which are different from the structures illustrated in FIG. 52 and FIG. 53, will be mainly described below.

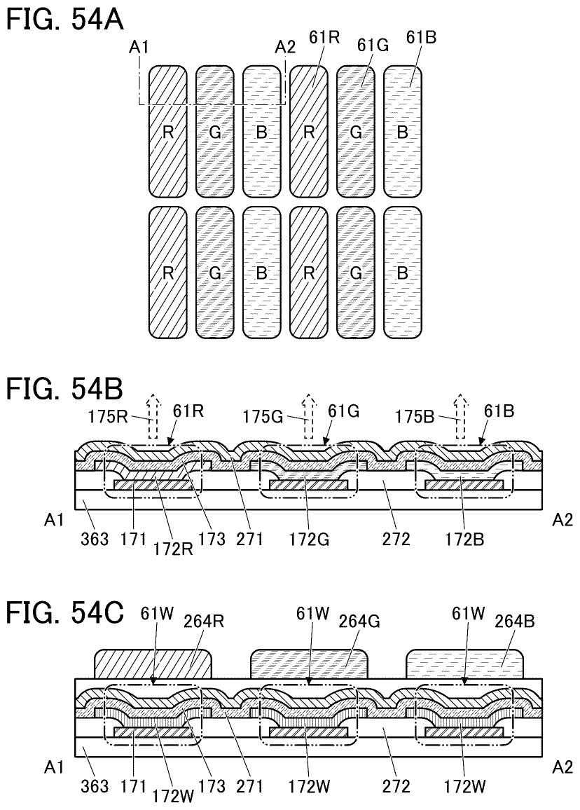

FIG. 54A illustrates a schematic top view of part of a display portion including a plurality of light-emitting elements. The display portion includes a plurality of light-emitting elements 61R emitting red light, a plurality of light-emitting elements 61G emitting green light, and a plurality of light-emitting elements 61B emitting blue light. In FIG. 54A, light-emitting regions of the light-emitting elements are denoted by R, G, and B to easily differentiate the light-emitting elements. Although FIG. 54A illustrates the structure having three emission colors of red (R), green (G), and blue (B), one embodiment of the present invention is not limited thereto. For example, the structure may have four or more colors.

FIG. 54B is a cross-sectional view along the dashed-dotted line A1-A2 in FIG. 54A. The light-emitting element 61R, the light-emitting element 61G, and the light-emitting element 61B illustrated in FIG. 54B are each provided over an insulating layer 363 and include a conductive layer 171 functioning as a pixel electrode and a conductive layer 173 functioning as a common electrode. For the insulating layer 363, one or both of an inorganic insulating film and an organic insulating film can be used.

The light-emitting element 61R includes an EL layer 172R between the conductive layer 171 functioning as a pixel electrode and the conductive layer 173 functioning as a common electrode.

The EL layer 172R includes a light-emitting compound that emits light with a peak in a red wavelength range. An EL layer 172G included in the light-emitting element 61G includes a light-emitting compound that emits light with a peak in a green wavelength range. An EL layer 172B included in the light-emitting element 61B includes a light-emitting compound that emits light with a peak in a blue wavelength range.

The conductive layer 171 functioning as a pixel electrode is provided in each of the light-emitting elements. The conductive layer 173 functioning as a common electrode is provided as a continuous layer shared by the light-emitting elements. A conductive film that has a property of transmitting visible light is used as either the conductive layer 171 functioning as a pixel electrode or the conductive layer 173 functioning as a common electrode, and a reflective conductive film is used as the other.

For example, in the case where the light-emitting element 61R has a top-emission structure, light 175R is emitted from the light-emitting element 61R to the conductive layer 173 side. In the case where the light-emitting element 61G has a top-emission structure, light 175G is emitted from the light-emitting element 61G to the conductive layer 173 side. In the case where the light-emitting element 61B has a top-emission structure, light 175B is emitted from the light-emitting element 61B to the conductive layer 173 side.

An insulating layer 272 is provided to cover end portions of the conductive layer 171 functioning as a pixel electrode. End portions of the insulating layer 272 are preferably tapered. For the insulating layer 272, one or both of an inorganic insulating film and an organic insulating film can be used.

The insulating layer 272 is provided to prevent an unintentional short-circuit between adjacent light-emitting elements and unintended light emission therefrom. In the case where a metal mask is used to form the EL layer, the insulating layer 272 also has a function of avoiding contact of the metal mask with the conductive layer 171.

The EL layer 172R, the EL layer 172G, and the EL layer 172B each include a region in contact with the top surface of the conductive layer 171 functioning as a pixel electrode and a region in contact with the surface of the insulating layer 272. The end portions of the EL layer 172R, the EL layer 172G, and the EL layer 172B are positioned over the insulating layer 272.

As illustrated in FIG. 54B, a gap is provided between two EL layers of light-emitting elements of different emission colors. In this manner, the EL layer 172R, the EL layer 172G, and the EL layer 172B are preferably provided so as not to be in contact with each other. This can favorably prevent unintentional light emission (also referred to as crosstalk) from being caused by current flowing through two adjacent EL layers. As a result, the contrast can be increased, resulting in obtaining a display device with high display quality.

The EL layer 172R, the EL layer 172G, and the EL layer 172B can be formed separately by a vacuum evaporation method or the like using a shadow mask such as a metal mask. Alternatively, these layers may be formed separately by a photolithography method. The use of a photolithography method enables a display device to have a high resolution, which is difficult to obtain in the case of using a metal mask.

A protective layer 271 is provided over the conductive layer 173 functioning as a common electrode so as to cover the light-emitting element 61R, the light-emitting element 61G, and the light-emitting element 61B. The protective layer 271 has a function of preventing diffusion of impurities such as water into the light-emitting elements from above. For the material for the protective layer 271, the above-described material for the protective layer 631 can be referred to.

FIG. 54C illustrates a light-emitting element 61 W that emits white light. The light-emitting element 61 W includes an EL layer 172 W that emits white light between the conductive layer 171 functioning as a pixel electrode and the conductive layer 173 functioning as a common electrode. The EL layer 172 W can have, for example, a stacked structure of two or more light-emitting layers that are selected so that their emission colors have a relationship of complementary colors. It is also possible to use a tandem EL layer in which a charge-generation layer is provided between light-emitting layers.

FIG. 54C illustrates three light-emitting elements 61 W side by side. A coloring layer 264R is provided above the light-emitting element 61 W on the left. The coloring layer 264R functions as a band-pass filter that transmits red light. Similarly, a coloring layer 264G that transmits green light is provided above the light-emitting element 61 W in the middle, and a coloring layer 264B that transmits blue light is provided above the light-emitting element 61 W on the right. Thus, the display device can display a color image.

Here, the EL layer 172 W is separated between two adjacent light-emitting elements 61 W. This can prevent unintentional light emission from being caused by current flowing through the EL layers 172 W of the two adjacent light-emitting elements 61 W. Particularly when a stacked EL layer in which a charge-generation layer is provided between two light-emitting layers is used as the EL layer 172 W, the effect of crosstalk becomes more significant as the resolution increases, i.e., as the distance between adjacent pixels decreases, leading to a lower contrast. Thus, the above structure enables a display device to have both high resolution and high contrast.

A photolithography method is preferably used for the separation of the EL layer 172 W. This can reduce a distance between light-emitting elements, enabling a display device to have a higher aperture ratio than a display device formed using, for example, a shadow mask such as a metal mask.

This embodiment can be combined with any of the other embodiments as appropriate.

### Embodiment 8

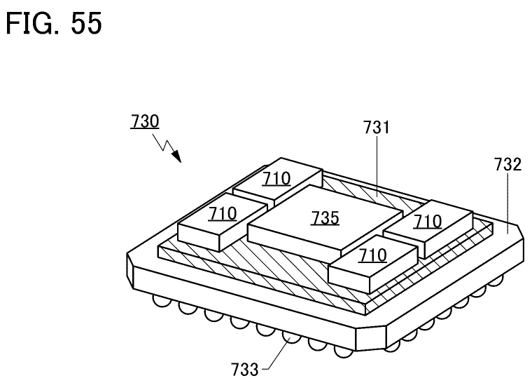

In this embodiment, application examples of the semiconductor device of one embodiment of the present invention will be described with reference to FIG. 55 to FIG. 59.

The semiconductor device of one embodiment of the present invention can be used for an electronic component, a large computer, space equipment, and a data center (also referred to as DC), and a variety of electronic appliances, for example. With the use of the semiconductor device of one embodiment of the present invention, an electronic component, a large computer, space equipment, a data center, and a variety of electronic appliances can have lower power consumption and higher performance.

A display device including the semiconductor device of one embodiment of the present invention can be used for a display portion of a variety of electronic appliances. The display device including the semiconductor device of one embodiment of the present invention can be easily increased in resolution and definition.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook computers, a monitor of a computer and the like, digital signage, and a large game machine such as a pachinko machine.

In particular, the display device of one embodiment of the present invention can have a high resolution, and thus can be favorably used for an electronic appliance having a relatively small display portion. Examples of such an electronic appliance include watch-type and bracelet-type information terminal devices (wearable devices) and wearable devices that can be worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×10⁸⁰), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display device of one embodiment of the present invention is preferably higher than or equal to 100 ppi, higher than or equal to 300 ppi, higher than or equal to 500 ppi, higher than or equal to 1000 ppi, higher than or equal to 2000 ppi, higher than or equal to 3000 ppi, higher than or equal to 5000 ppi, or higher than or equal to 7000 ppi. The use of such a display device having one or both of high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (square), 4:3, 16:9, and 16:10.

The electronic appliance of this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, a gradient, oscillation, odor, or infrared rays).

The electronic appliance in this embodiment can have a variety of functions. For example, the electronic appliance can have a function of displaying a variety of information (e.g., a still image, a moving image, and a text image) on the display portion, a touch panel function, a function of displaying a calendar, date, time, or the like, a function of executing a variety of software (programs), a wireless communication function, or a function of reading out a program or data stored in a recording medium.

### [Electronic Component]

Next, FIG. 55 illustrates a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The memory device 3112 described in Embodiment 6 can be used as the semiconductor device 710.

The electronic component 730 that includes the semiconductor device 710 as a high bandwidth memory (HBM) is illustrated as an example. The semiconductor device 735 can be used for an integrated circuit such as a CPU, a GPU, or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for connecting the integrated circuit and the package substrate 732. Moreover, in the case of using a silicon interposer, a TSV can also be used as the through electrode.

An HBM needs to be connected to many wirings to achieve a wide memory bandwidth.

Therefore, an interposer on which an HBM is mounted requires minute and densely formed wirings.

Thus, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are placed side by side on the interposer.

Meanwhile, in the case where a plurality of integrated circuits with different terminal pitches are connected to each other using a silicon interposer, a TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (a radiator plate) may be provided to overlap with the electronic component 730. In the case of providing a heat sink, the heights of integrated circuits provided on the interposer 731 are preferably equal to each other. In the electronic component 730 of this embodiment, the heights of the semiconductor device 710 and the semiconductor device 735 are preferably equal to each other, for example.

An electrode 733 may be provided on the bottom portion of the package substrate 732 to mount the electronic component 730 on another substrate. FIG. 55 illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

The semiconductor device 710 may be called a die. Note that in this specification and the like, a die refers to a chip piece obtained by forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

### [Large Computer]

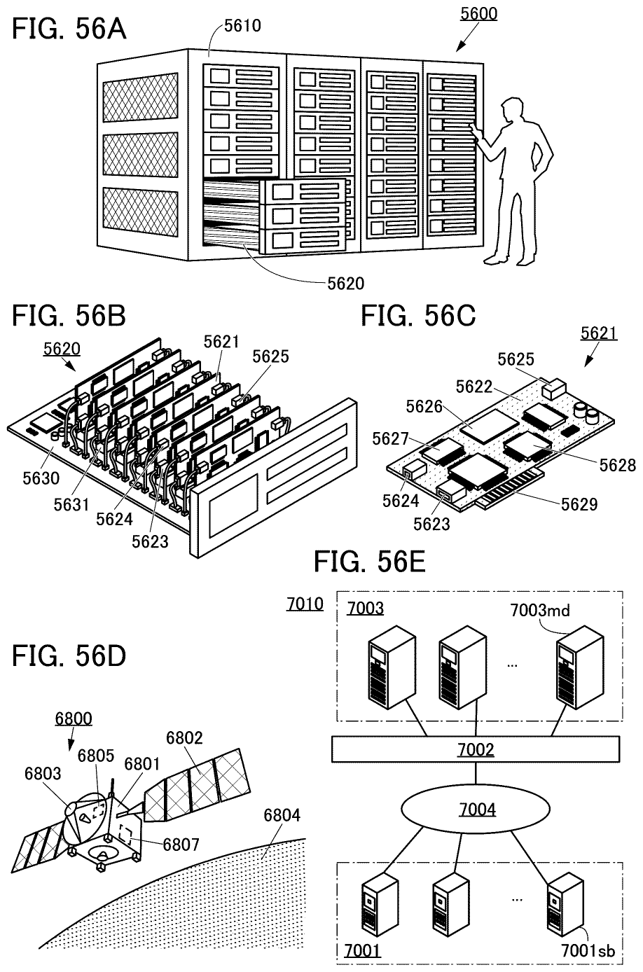

Next, FIG. 56A illustrates a perspective view of a large computer 5600. In the large computer 5600 illustrated in FIG. 56A, a plurality of rack mount computers 5620 are stored in a rack 5610. Note that the large computer 5600 may be referred to as a supercomputer.

The computer 5620 can have a structure in a perspective view illustrated in FIG. 56B, for example. In FIG. 56B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 56C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 56C also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device. As the semiconductor device 5628, the electronic component 3110 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment.

The semiconductor device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space in this specification may also include one or more of thermosphere, mesosphere, and stratosphere.

FIG. 56D illustrates an artificial satellite 6800 as an example of space equipment. The artificial satellite 6800 includes a body 6801, a solar panel 6802, an antenna 6803, a secondary battery 6805, and a control device 6807. Note that FIG. 56D illustrates a planet 6804 in outer space, for example.

Although not illustrated in FIG. 56D, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Thus, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor, which is one embodiment of the present invention, is suitably used for the control device 6807. A change in electrical characteristics of the OS transistor due to exposure to radiation is smaller than that of a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device of one embodiment of the present invention can be suitably used for space equipment such as a spacecraft, a space capsule, or a space probe, for example.

As described above, the OS transistor has excellent effects of achieving a wide memory bandwidth and being highly resistant to radiation as compared with the Si transistor.

### [Data Center]

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With use of the semiconductor device of one embodiment of the present invention for a storage system in a data center, electric power required for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be improved.

FIG. 56E illustrates a storage system that can be used in a data center. A storage system 7010 illustrated in FIG. 56E includes a plurality of servers 7001sb as a host 7001. The storage system 7010 includes a plurality of memory devices 7003md as a storage 7003. In the illustrated example, the host 7001 and the storage 7003 are connected to each other through a storage area network 7004 and a storage control circuit 7002.

The host 7001 corresponds to a computer which accesses data stored in the storage 7003. The host 7001 may be connected to another host 7001 through a network.

The data access speed, i.e., the time taken for storing and outputting data, of the storage 7003 is shortened by using a flash memory, but is still considerably longer than the time required for a DRAM that can be used as a cache memory in the storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on the data can reduce the frequency of refreshing, so that power consumption can be reduced. Furthermore, downscaling is possible by stacking memory cell arrays.

### [Electronic Appliance]

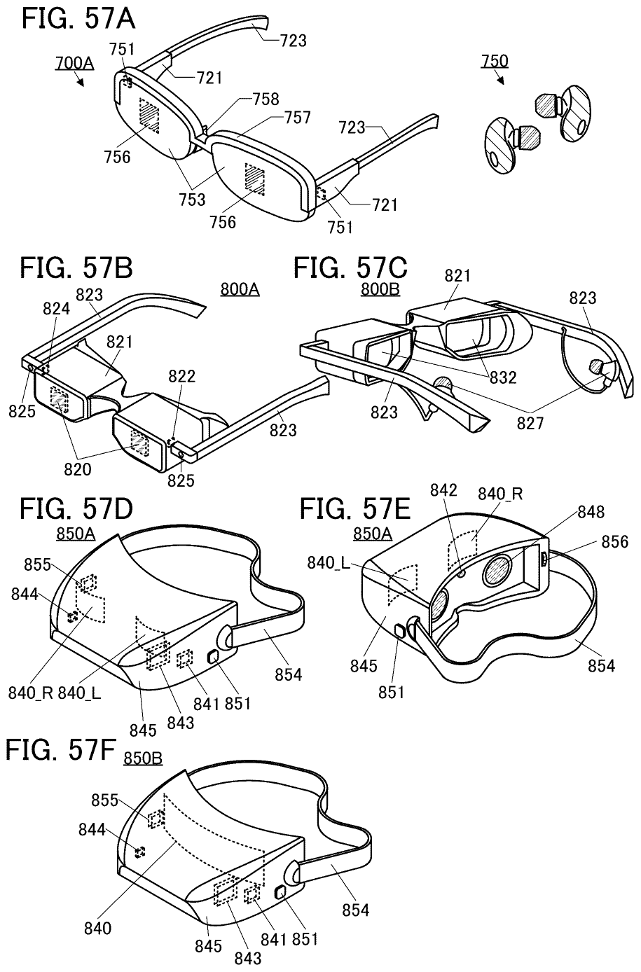

Examples of wearable devices that can be worn on the head will be described with reference to FIG. 57A to FIG. 57F. These wearable devices have at least one of a function of displaying AR content, a function of displaying VR content, a function of displaying SR content, and a function of displaying MR content. The electronic appliance having a function of displaying content of at least one of AR, VR, SR, MR, and the like enables the user to feel a higher sense of immersion. An electronic appliance 700A illustrated in FIG. 57A includes a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic appliance is capable of performing ultrahigh-resolution display. The semiconductor device of one embodiment of the present invention can be used for the control portion (not illustrated). Thus, the power consumption of the electronic appliance can be reduced.

The electronic appliance 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliance 700A is an electronic appliance capable of AR display.

In the electronic appliance 700A, a camera capable of capturing images of the front side may be provided as the image capturing portion. Furthermore, when the electronic appliance 700A is provided with an acceleration sensor such as a gyroscope sensor, the orientation of the user's head can be sensed and an image corresponding to the orientation can be displayed on the display regions 756.

The communication portion includes a wireless communication device, and a video signal or the like can be supplied by the wireless communication device. Instead of or in addition to the wireless communication device, a connector that can be connected to a cable for supplying a video signal and a power supply potential may be provided.

The electronic appliance 700A is provided with a battery, so that it can be charged wirelessly and/or by wire.

A touch sensor module may be provided in the housing 721. The touch sensor module has a function of detecting a touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

An electronic appliance 800A illustrated in FIG. 57B and an electronic appliance 800B illustrated in FIG. 57C each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic appliances are capable of performing ultrahigh-resolution display. This enables a user to feel a high sense of immersion. The semiconductor device of one embodiment of the present invention can be used for the control portion 824. Thus, the power consumption of the electronic appliance can be reduced.

The display portions 820 are positioned inside the housing 821 so as to be seen through the lenses 832. When the pair of display portions 820 display different images, three-dimensional display using parallax can be performed.

The electronic appliance 800A and the electronic appliance 800B can be regarded as electronic appliances for VR. The user who wears the electronic appliance 800A or the electronic appliance 800B can see images displayed on the display portions 820 through the lenses 832.

The electronic appliance 800A and the electronic appliance 800B each preferably include a mechanism for laterally adjusting the positions of the lenses 832 and the display portions 820 so that the lenses 832 and the display portions 820 are positioned optimally in accordance with the positions of the user's eyes. Moreover, the electronic appliance 800A and the electronic appliance 800B each preferably include a mechanism for adjusting focus by changing the distance between the lenses 832 and the display portions 820.

The electronic appliance 800A or the electronic appliance 800B can be worn on the user's head with the wearing portions 823. Note that FIG. 57B and the like illustrate a shape like a temple (also referred to as a joint, for example) of glasses as an example; however, one embodiment of the present invention is not limited thereto. The wearing portion 823 can have any shape with which the user can wear the electronic appliance, for example, a shape of a helmet or a band.

The image capturing portions 825 has a function of obtaining information on the external environment. Data obtained by the image capturing portions 825 can be output to the display portions 820. An image sensor can be used for the image capturing portions 825. Moreover, a plurality of cameras may be provided so as to support a plurality of fields of view, such as a telescope field of view and a wide field of view.

Although an example where the image capturing portions 825 are provided is described here, a range sensor (hereinafter also referred to as a sensing portion) capable of measuring the distance between the user and an object just needs to be provided. In other words, the image capturing portion 825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic appliance 800A.

The electronic appliance 800A and the electronic appliance 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A illustrated in FIG. 57A has a function of transmitting information to the earphones 750 with the wireless communication function.

The electronic appliance may include an earphone portion. The electronic appliance 800B illustrated in FIG. 57C includes earphone portions 827. For example, a structure can be employed in which the earphone portion 827 is connected to the control portion 824 by wire. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of what is called a headset by including the audio input mechanism.

FIG. 57D and FIG. 57E are perspective views of a goggles-type electronic appliance 850A for VR. FIG. 57D and FIG. 57E illustrate an example where a pair of curved display devices 840 (a display device 840_R and a display device 840_L) is included in a housing 845. The electronic appliance 850A includes a motion detection portion 841, an eye-gaze detection portion 842, an arithmetic portion 843, a communication portion 844, lenses 848, an operation button 851, a wearing tool 854, a sensor 855, a dial 856, and the like.

Since the two display devices 840 are included, the user's eyes can see their respective display devices. This allows a high-definition image to be displayed even when three-dimensional display using parallax is performed. In addition, the display device 840 is curved around an arc with the user's eye as an approximate center. This allows a uniform distance between the user's eye and the display surface of the display device 840; thus, the user can see a more natural image. Even when having what is called viewing angle dependence where the luminance or chromaticity of light changes depending on a viewing angle, the display device 840 can have a structure in which the user's eye is positioned in the normal direction of the display surface of the display device 840; accordingly, the influence of the viewing angle dependence particularly in the horizontal direction can be practically ignored, enabling display of a more realistic image.

As illustrated in FIG. 57E, the lenses 848 are positioned between the display devices 840 and the user's eyes. FIG. 57E illustrates an example where the dial 856 for changing the positions of the lenses for visibility adjustment is provided. In the case where the electronic appliance 850A has an autofocus function, the dial 856 for visibility adjustment is not necessarily provided. FIG. 57F illustrates a goggles-type electronic appliance 850B including one display device 840. Such a structure can reduce the number of components.

The display device 840 can display an image for the right eye and an image for the left eye side by side on a right region and a left region, respectively. Thus, a three-dimensional image using binocular parallax can be displayed. Note that the display device 840 may display two different images side by side using parallax, or may display two same images side by side without using parallax.

One image that can be seen by both eyes may be displayed on the entire display device 840. A panorama image can thus be displayed from end to end of the field of view, which can provide a stronger sense of reality.

The display device of one embodiment of the present invention can be used as the display device 840. Since the display device of one embodiment of the present invention has an extremely high resolution, even when an image is magnified using the lens 848, the pixels are not perceived by the user, and thus a more realistic image can be displayed.

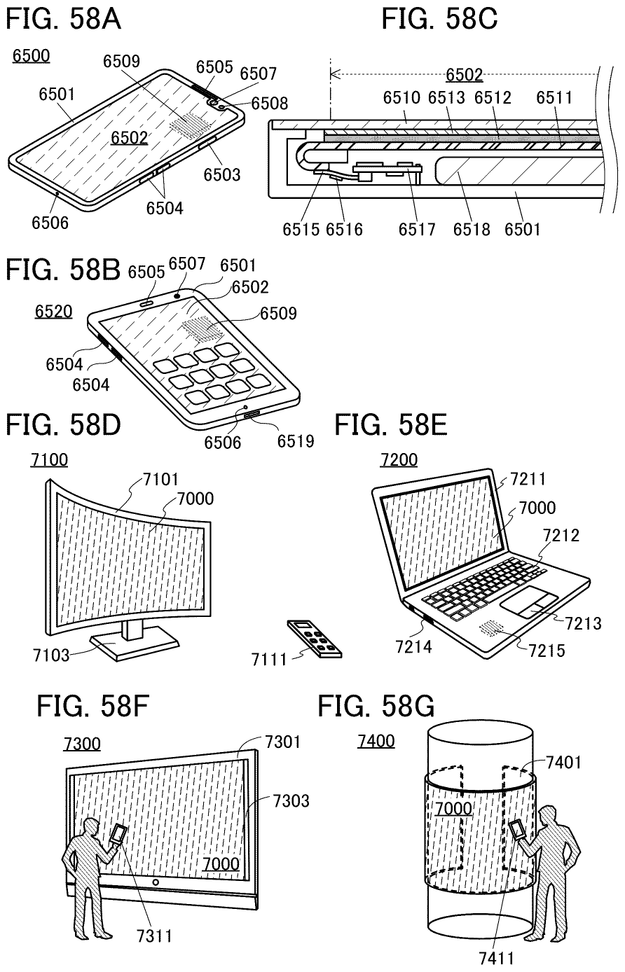

An electronic appliance 6500 illustrated in FIG. 58A is a portable information terminal device that can be used as a smartphone.

The electronic appliance 6500 includes a housing 6501, a display portion 6502, a power button 6503, buttons 6504, a speaker 6505, a microphone 6506, a camera 6507, a light source 6508, a control device 6509, and the like.

An electronic appliance 6520 illustrated in FIG. 58B is a portable information terminal device that can be used as a tablet terminal.

The electronic appliance 6520 includes the housing 6501, the display portion 6502, the buttons 6504, the speaker 6505, the microphone 6506, the camera 6507, the control device 6509, a connection terminal 6519, and the like.

In each of the electronic appliance 6500 and the electronic appliance 6520, the display portion 6502 has a touch panel function. In addition, one or more selected from a CPU, a GPU, and a memory device are included as the control device 6509, for example. The semiconductor device of one embodiment of the present invention can be used for one or both of the display portion 6502 and the control device 6509.

FIG. 58C is a schematic cross-sectional view including an end portion of the housing 6501 included in the electronic appliance 6500 or the electronic appliance 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used as the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back such that a connection portion with the FPC 6515 is provided on the back side of a pixel portion, whereby an electronic appliance with a narrow bezel can be obtained.

FIG. 58D illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used for the display portion 7000.

Operation of the television device 7100 illustrated in FIG. 58D can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 58E illustrates an example of a laptop computer. A laptop computer 7200 includes a housing 7211, a keyboard 7212, a pointing device 7213, an external connection port 7214, a control device 7215, and the like. The display portion 7000 is incorporated in the housing 7211. As the control device 7215, for example, one or more selected from a CPU, a GPU, and a memory device are included. The semiconductor device of one embodiment of the present invention can be used for one or both of the display portion 7000 and the control device 7215.

FIG. 58F and FIG. 58G illustrate examples of digital signage.

Digital signage 7300 illustrated in FIG. 58F includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 58G illustrates digital signage 7400 attached to a cylindrical pillar 7401. The digital signage 7400 includes the display portion 7000 provided along a curved surface of the pillar 7401.

In FIG. 58F and FIG. 58G, the display device of one embodiment of the present invention can be used for the display portions 7000.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 58F and FIG. 58G, it is preferable that the digital signage 7300 or the digital signage 7400 can work with an information terminal device 7311 or an information terminal device 7411, such as a smartphone that a user has, through wireless communication. For example, information of an advertisement displayed on the display portion 7000 can be displayed on a screen of the information terminal device 7311 or the information terminal device 7411. By operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

The semiconductor device or the display device of one embodiment of the present invention can also be used around a driver's seat in a car, which is a vehicle.

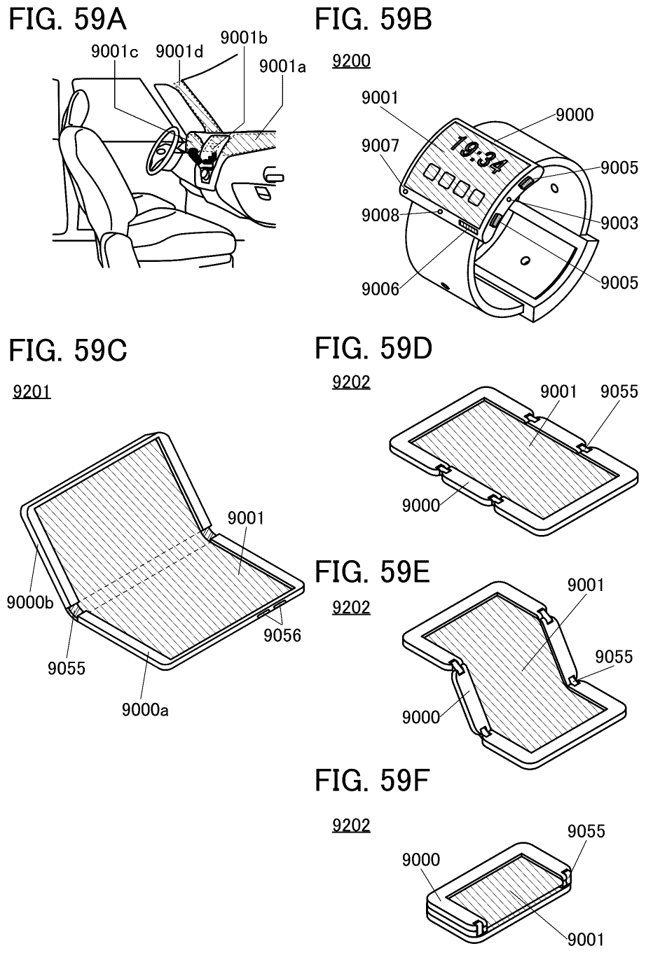

FIG. 59A is a diagram illustrating an area around a windshield inside an automobile. FIG. 59A illustrates a display panel 9001a, a display panel 9001b, and a display panel 9001c attached to a dashboard and a display panel 9001d attached to a pillar.

The display panel 9001a to the display panel 9001c can provide a variety of kinds of information by displaying navigation information, a speedometer, a tachometer, a mileage, a fuel meter, a gearshift indicator, air-condition settings, and the like. In addition, the content, layout, or the like of the display on the display panels can be changed as appropriate to suit the user's preference, so that the design quality can be increased. The display panel 9001a to the display panel 9001c can also be used as lighting devices.

The display panel 9001d can compensate for the view obstructed by the pillar (blind areas) by showing an image taken by an image capturing unit provided for the car body. That is, displaying an image taken by the image capturing unit provided outside the automobile leads to compensation for the blind spot and an increase in safety. In addition, displaying an image to compensate for a portion that cannot be seen makes it possible for the driver to confirm the safety more naturally and comfortably. The display panel 9001d can also be used as a lighting device.

FIG. 59B is a perspective view illustrating a watch-type portable information terminal 9200. The portable information terminal 9200 can be used as a Smartwatch (registered trademark), for example. The display surface of a display portion 9001 is curved, and display can be performed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 59B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

FIG. 59C is a perspective view illustrating a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows a bi-fold.

The display portion 9001 of the portable information terminal 9201 is supported by two housings (the housing 9000a and the housing 9000b) joined together by the hinge 9055.

FIG. 59D to FIG. 59F are perspective views illustrating a foldable portable information terminal 9202. FIG. 59D is a perspective view of an opened state of the portable information terminal 9202, FIG. 59F is a perspective view of a folded state thereof, and FIG. 59E is a perspective view of a state in the middle of change from one of FIG. 59D and FIG. 59F to the other. In this manner, the portable information terminal 9202 can be folded in three.

The display portion 9001 of the portable information terminal 9202 is supported by three housings 9000 joined together by hinges 9055.

The display device of one embodiment of the present invention can be used for the display portion 9001 in FIG. 59C to FIG. 59F. The display portion 9001 can be folded with a radius of curvature of greater than or equal to 0.1 mm and less than or equal to 150 mm, for example.

The portable information terminal 9201 and the portable information terminal 9202 are each highly portable in the folded state and are highly browsable in the opened state because of a seamless large display region.

Note that the use of the semiconductor device of one embodiment of the present invention for one or more selected from an electronic component, a large computer, space equipment, a data center, and an electronic appliance can reduce power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

This embodiment can be combined with any of the other embodiments as appropriate.

### Example

In this example, samples were fabricated and SIMS analysis was performed on the samples. Other samples were fabricated, and thermal desorption spectrometry (TDS) analysis was performed on each sample.

### [SIMS Analysis]

First, eight samples (Sample 1A, Sample 1B, Sample 2A, Sample 2B, Sample 3A, Sample 3B, Sample 4A, and Sample 4B) used for the SIMS analysis are described.

For all the eight samples, a first silicon oxide film having a thickness of 100 nm was formed on a silicon substrate by thermal oxidation treatment. Note that the first silicon oxide film is an oxide film formed using hydrogen chloride; thus, the first silicon oxide film is sometimes referred to as HCl-SiOx.

Next, a second silicon oxide film having a thickness of 20 nm (referred to as PEALD-SiOx) was deposited over the first silicon oxide film by a PEALD method.

Next, in Sample 2A, Sample 2B, Sample 3A, Sample 3B, Sample 4A, and Sample 4B, a first oxide film having a thickness of 2 nm was formed over the second silicon oxide film by an ALD method. Precursors used for forming the first oxide film were triethylindium (TEI) and diethylzinc (DEZ). As an oxidizer, a mixed gas of ozone (03) and oxygen (O₂) was used. That is, the first oxide film was an In—Zn oxide film.

Next, in each of Sample 3A, Sample 3B, Sample 4A, and Sample 4B, a second oxide film was formed over the first oxide film by a sputtering method. As a sputtering target, an ITZO sputtering target in which the atomic ratio of metal elements is In:Sn:Zn=40:1:10 (4:0.1:1) was used. Note that in each of Sample 3A and Sample 3B, the second oxide film was formed to a thickness of 1.5 nm, and in each of Sample 4A and Sample 4B, the second oxide film was formed to a thickness of 5 nm.

The first oxide film in each of Sample 2A and Sample 2B is referred to as OS in some cases. The stack of the first oxide film and the second oxide film in each of Sample 3A, Sample 3B, Sample 4A, and Sample 4B is referred to as OS in some cases.

Next, microwave plasma treatment was performed on Sample 1B, Sample 2B, Sample 3B, and Sample 4B for 10 minutes. In the microwave plasma treatment, a mixed gas of an argon gas at 150 sccm and an ¹⁸O₂ gas at 50 sccm was used as a treatment gas, the power was 4000 W, the pressure was 400 Pa, and the treatment temperature was 400 °C. Note that the microwave plasma treatment was not performed on Sample 1A, Sample 2A, Sample 3A, and Sample 4A.

Through the above steps, eight samples (Sample 1A to Sample 4B) were fabricated.

SIMS analysis was performed on each of the eight samples. The analysis direction of the SIMS analysis was a direction from the substrate toward the second silicon oxide film. By the SIMS analysis, ¹⁸O profiles of the eight samples were obtained. Note that SIMS analysis was performed with an ULVAC-PHI quadrupole mass spectrometer (ADEPT1010).

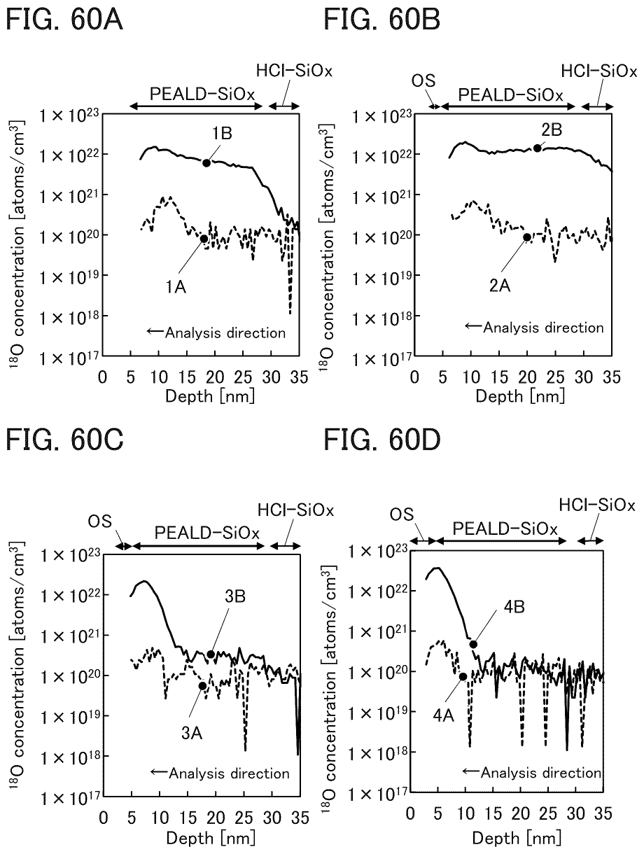

FIG. 60A to FIG. 60D show the 180 profiles results of the samples. In FIG. 60A to FIG. 60D, the vertical axis represents the 180 concentration [atoms/cm³] and the horizontal axis represents the depth [nm] in the film thickness direction. As the quantitative layer, the second silicon oxide film (PEALD-SiOx) was used.

The dashed line in FIG. 60A shows the 180 profile of Sample 1A, and the solid line in FIG. 60A shows the 180 profile of Sample 1B. The dashed line in FIG. 60B shows the 180 profile of Sample 2A and the solid line in FIG. 60B shows the 180 profile of Sample 2B. The dashed line in FIG. 60C shows the 180 profile of Sample 3A and the solid line in FIG. 60C shows the 180 profile of Sample 3B. The dashed line in FIG. 60D shows the 180 profile of Sample 4A and the solid line in FIG. 60D shows the 180 profile of Sample 4B.

As shown in FIG. 60A, the microwave plasma treatment was found to increase the 180 concentration in the second silicon oxide film. Thus, it was found that active species excited by the microwave, such as oxygen radicals, were injected into the second silicon oxide film. Note that similar results were observed also in FIG. 60B. Thus, it was found that the active species excited by the microwave, such as oxygen radicals, were injected into the first oxide film and the second silicon oxide film.

As shown in FIG. 60C and FIG. 60D, when the microwave plasma treatment was performed on the sample provided with the second oxide film, an increase in the 180 concentration of the second silicon oxide film was inhibited as compared with the sample not provided with the second oxide film. Thus, it was found that oxygen was injected into the silicon oxide film by performing microwave plasma treatment after formation of the silicon oxide film as a base film. Moreover, it was found that oxygen was injected into the base film also by performing microwave plasma treatment after the formation of the oxide film over the base film by an ALD method.

Thus, microwave plasma treatment is performed after the formation of the insulating layer including silicon oxide, whereby oxygen can be supplied to the insulating layer. As an example of the insulating layer, the insulating layer 235 described in Embodiment 1 is given. In the case where the insulating layer 235 has a stacked-layer structure, the layer of the insulating layer 235 that is in contact with the oxide semiconductor layer 230 (e.g., the insulating layer 235b illustrated in FIG. 22A or the insulating layer 235c illustrated in FIG. 32A) is given as an example of the insulating layer.

When microwave plasma treatment is performed after the formation of the oxide semiconductor layer where the channel is formed, oxygen can be supplied to the insulating layer that includes silicon oxide and serves as the formation surface (base) of the oxide semiconductor layer. In addition, oxygen vacancies in the oxide semiconductor layer can be reduced. The oxide semiconductor 230a described in Embodiment 2 is given as an example of the oxide semiconductor layer, and the insulating layer 235 described in Embodiment 1 is given as an example of the insulating layer. In the case where the insulating layer 235 has a stacked-layer structure, the layer of the insulating layer 235 that is in contact with the oxide semiconductor layer 230 (e.g., the insulating layer 235b illustrated in FIG. 22A or the insulating layer 235c illustrated in FIG. 32A) is given as an example of the insulating layer.

### [TDS Analysis]

Next, samples (Sample 5A and Sample 5B) used for a TDS analysis are described.

For both of Sample 5A and Sample 5B, a first silicon oxide film having a thickness of 100 nm was formed over a silicon substrate by thermal oxidation treatment. Note that the first silicon oxide film was an oxide film formed using hydrogen chloride.

Next, a 10-nm-thick silicon nitride film was formed over the first silicon oxide film by a sputtering method.

Then, the second silicon oxide film having a thickness of 20 nm was formed over the silicon nitride film by a sputtering method. For the formation of the second silicon oxide film, a Si target was used; an oxygen gas at 164 sccm and an Ar gas at 36 sccm were used as deposition gases; the deposition pressure was 0.9 Pa; the deposition power was 200 W; the substrate temperature was 200 °C; and the target-substrate distance was 62 mm.

Next, for Sample 5B, a 2-nm-thick oxide film was formed over the second silicon oxide film by an ALD method. Precursors used for forming the oxide film were triethylindium (TEI) and diethylzinc (DEZ). As an oxidizer, ozone (O₃) and oxygen (O₂) were used. That is, the oxide film was an In—Zn oxide film.

Next, the oxide film in Sample 5B was removed by a wet etching method using a mixed acid aluminum solution. Thus, a surface of the second silicon oxide film was exposed.

Through the above steps, Sample 5A and Sample 5B were fabricated.

For each of Sample 5A and Sample 5B, the amount of oxygen molecules released from the second silicon oxide film was measured by TDS analysis. In the TDS analysis in this example, the amount of a released gas with a mass-to-charge ratio m/z=32, which corresponds to an oxygen molecule, was measured. As a TDS analysis apparatus, ESCO TDS1200 II was used. The stage temperature was controlled such that the substrate temperature in the TDS analysis was higher than or equal to 50 °C and lower than or equal to 600 °C, and the temperature rising rate at that time was °C/min.

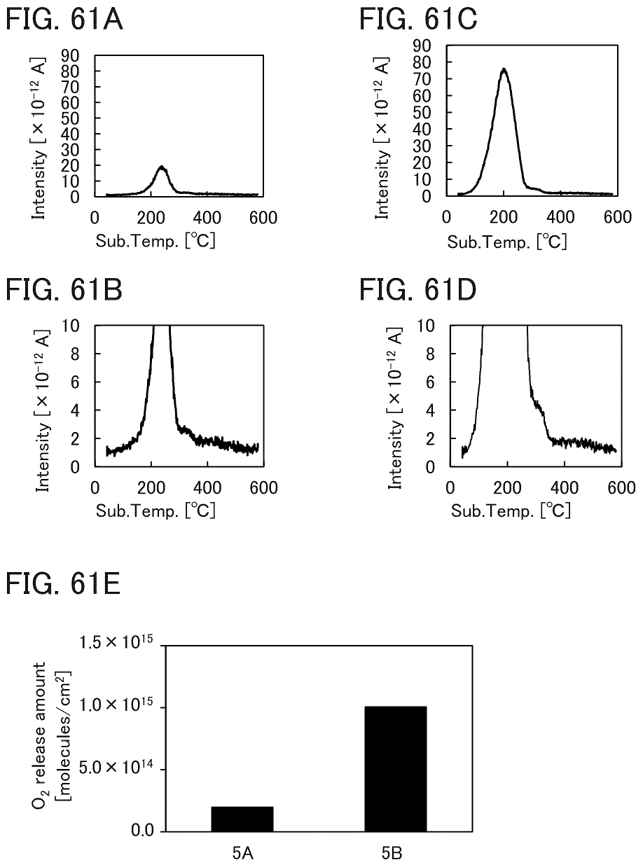

FIG. 61A to FIG. 61E show the TDS analysis results. FIG. 61A to FIG. 61D show TDS profiles of oxygen (¹⁶O₂, Mlz=32), and FIG. 61E shows the amount of released oxygen (O₂ release amount) in the entire temperature range measured. Note that in the TDS profiles in FIG. 61A to FIG. 61D, the horizontal axis represents substrate temperature (Sub. Temp.) and the vertical axis represents detection intensity (Intensity) at Mlz=32. FIG. 61A and FIG. 61B show TDS profiles of Sample 5A, and FIG. 61C and FIG. 61D show TDS profiles of Sample 5B. Note that in FIG. 61B and FIG. 61D, the vertical axes in FIG. 61A and FIG. 61C are enlarged. In FIG. 61E, the vertical axis represents the amount of released oxygen molecules (O₂ release amount (molecules/cm²). FIG. 61E shows the amounts of released oxygen molecules of Sample 5A and Sample 5B.

FIG. 61A to FIG. 61E confirm that in Sample 5B in which the oxide film was removed by wet etching after the formation of the oxide film, the amount of oxygen molecules released from the second silicon oxide film was larger than that in Sample 5A. Thus, it was suggested that excess oxygen was injected into the second silicon oxide film by using a mixed gas containing ozone (O₃) at the time of formation of the oxide film by an ALD method.

As described above, when the oxide semiconductor layer where the channel is formed is formed by an ALD method, oxygen can be injected into the insulating layer that is the formation surface (base) of the oxide semiconductor layer. Thus, excess oxygen in the insulating layer can be increased. The oxide semiconductor layer 230 described in Embodiment 1 is given as an example of the oxide semiconductor layer, and the insulating layer 235 described in Embodiment 1 is given as an example of the insulating layer. Note that in the case where the insulating layer 235 has a stacked-layer structure, the layer of the insulating layer 235 that is in contact with the oxide semiconductor layer 230 (e.g., the insulating layer 235b illustrated in FIG. 22A or the insulating layer 235c illustrated in FIG. 32A) is given as an example of the insulating layer.

The configuration, structure, method, or the like described in this example can be used in combination with the configuration, structure, method, or the like described in the other embodiments and the like as appropriate.

### REFERENCE NUMERALS

ADDR: signal, BIL: wiring, BW: signal, CA: capacitor, CAL: wiring, CB: capacitor, CC: capacitor, CE: signal, CLK: signal, GNDL: wiring, GW: signal, MPG: conductive layer, MTCK: transistor, RBL: wiring, RDA: signal, RWL: wiring, SL: wiring, Ta: shortest distance, Tb: shortest distance, Tc: shortest distance, Tsw: width, WAKE: signal, WBL: wiring, WDA: signal, WOL: wiring, 61B: light-emitting element, 61G: light-emitting element, 61R: light-emitting element, 61 W: light-emitting element, 100: capacitor, 100a: capacitor, 100b: capacitor, 110: conductive layer, 115: conductive layer, 120a: conductive layer, 120b: conductive layer, 130: insulating layer, 130B: pixel, 130G: pixel, 130R: pixel, 131: insulating layer, 135: semiconductor layer, 140: insulating layer, 145: conductive layer, 150: memory cell, 150a: memory cell, 150b: memory cell, 150c: memory cell, 150d: memory cell, 151: insulating layer, 160: memory layer, 161: insulating layer, 170: display module, 171: conductive layer, 172B: EL layer, 172G: EL layer, 172R: EL layer, 172 W: EL layer, 173: conductive layer, 175B: light, 175G: light, 175R: light, 180: insulating layer, 190: opening portion, 200: transistor, 200A: transistor, 200a: transistor, 200B: transistor, 200C: transistor, 200D: transistor, 200E: transistor, 200F: transistor, 200G: transistor, 201: transistor, 201A: transistor, 201B: transistor, 202: transistor, 202A: transistor, 203: transistor, 203A: transistor, 203a: transistor, 203b: transistor, 204: transistor, 204A: transistor, 204B: transistor, 204C: transistor, 204D: transistor, 204E: transistor, 204F: transistor, 204G: transistor, 204H: transistor, 205: transistor, 205A: transistor, 205B: transistor, 205C: transistor, 205D: transistor, 205E: transistor, 210: insulating layer, 210a: insulating layer, 210b: insulating layer, 220: conductive layer, 220a: conductive layer, 220b: conductive layer, 227: metal oxide layer, 229: layer, 230: oxide semiconductor layer, 230a: oxide semiconductor, 230b: oxide semiconductor, 230c: oxide semiconductor, 231: mixed layer, 235: insulating layer, 235a: insulating layer, 235b: insulating layer, 235c: insulating layer, 235d: insulating layer, 240: conductive layer, 240a: conductive layer, 240b: conductive layer, 245: conductive layer, 246: conductive layer, 247: conductive layer, 248: conductive layer, 250: insulating layer, 250a: insulating layer, 250b: insulating layer, 250c: insulating layer, 250d: insulating layer, 255: conductive layer, 260: conductive layer, 262: sacrificial layer, 264B: coloring layer, 264G: coloring layer, 264R: coloring layer, 265: conductive layer, 265a: conductive layer, 265b: conductive layer, 270: opening portion, 271: protective layer, 272: insulating layer, 280: insulating layer, 280a: insulating layer, 281: insulating layer, 283: insulating layer, 285: insulating layer, 287: insulating layer, 290: opening portion, 291: substrate, 292: circuit portion, 293: pixel circuit portion, 293a: pixel circuit, 294: pixel portion, 294a: pixel, 295: terminal portion, 296: wiring portion, 297: display portion, 298: FPC, 299: substrate, 300: transistor, 311: substrate, 313: semiconductor region, 314a: resistance region, 314b: resistance region, 315: insulating layer, 316: conductive layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 363: insulating layer, 400d: transistor, 410: substrate, 412: element isolation layer, 413: semiconductor region, 414a: resistance region, 414b: resistance region, 415: insulating layer, 416: conductive layer, 417: insulating layer, 420: insulating layer, 422: insulating layer, 424: insulating layer, 426: insulating layer, 428: conductive layer, 430: conductive layer, 450: insulating layer, 452: insulating layer, 454: insulating layer, 456: conductive layer, 513: insulating layer, 514: conductive layer, 541: substrate, 543: adhesive layer, 545: insulating layer, 574: insulating layer, 581: insulating layer, 592: insulating layer, 594: insulating layer, 596: conductive layer, 598: insulating layer, 599: insulating layer, 600A: display device, 600B: display device, 607: adhesive layer, 610: substrate, 611a: conductive layer, 611b: conductive layer, 611c: conductive layer, 613a: layer, 613b: layer, 613c: layer, 614: common layer, 615: common electrode, 618a: sacrificial layer, 620: element layer, 625: insulating layer, 627: insulating layer, 628B: coloring layer, 628G: coloring layer, 628R: coloring layer, 630: element layer, 631: protective layer, 635: element layer, 640: connection portion, 642: conductive layer, 643: conductive layer, 644: conductive layer, 645: conductive layer, 646: conductive layer, 647: insulating layer, 648: insulating layer, 650: light-emitting element, 650B: light-emitting element, 650G: light-emitting element, 650R: light-emitting element, 660: element layer, 670: wiring layer, 700A: electronic appliance, 710: semiconductor device, 721: housing, 723: wearing portion, 730: electronic component, 731: interposer, 732: package substrate, 733: electrode, 735: semiconductor device, 750: earphone, 751: display panel, 753: optical member, 756: display region, 757: frame, 758: pad, 800A: electronic appliance, 800B: electronic appliance, 820: display portion, 821: housing, 822: communication portion, 823: wearing portion, 824: control portion, 825: image capturing portion, 827: earphone portion, 832: lens, 840: display device, 840_L: display device, 840_R: display device, 841: motion detection portion, 842: eye-gaze detection portion, 843: arithmetic portion, 844: communication portion, 845: housing, 848: lens, 850A: electronic appliance, 850B: electronic appliance, 851: operation button, 854: wearing tool, 855: sensor, 856: dial, 900: semiconductor device, 910: driver circuit, 911: peripheral circuit, 912: control circuit, 915: peripheral circuit, 920: memory array, 923: row driver, 924: column driver, 925: input circuit, 926: output circuit, 927: sense amplifier, 928: voltage generation circuit, 930: layer, 931: PSW, 932: PSW, 941: row decoder, 942: column decoder, 950: memory cell, 951: memory cell, 952: memory device, 953: memory cell, 954: memory cell, 955: memory cell, 956: memory cell, 957: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 3102: transistor, 3104: transistor, 3110: electronic component, 3111: mold, 3112: memory device, 3113: land, 3114: electrode pad, 3115: wire, 3121: layer, 3122: layer, 3210: circuit board, 3212: printed circuit board, 3301: transistor, 3302: transistor, 3311: semiconductor layer, 3312: semiconductor layer, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 6519: connection terminal, 6520: electronic appliance, 6800: artificial satellite, 6801: body, 6802: solar panel, 6803: antenna, 6804: planet, 6805: battery, 6807: control device, 7000: display portion, 7001: host, 7001sb: server, 7002: storage control circuit, 7003: storage, 7003md: memory device, 7010: storage system, 7100: television device, 7101: housing, 7103: stand, 7111: remote controller, 7200: computer, 7211: housing, 7212: keyboard, 7213: pointing device, 7214: external connection port, 7215: control device, 7300: digital signage, 7301: housing, 7303: speaker, 7311: information terminal device, 7400: digital signage, 7401: pillar, 7411: information terminal device, 9000: housing, 9000a: housing, 9000b: housing, 9001: display portion, 9001a: display panel, 9001b: display panel, 9001c: display panel, 9001d: display panel, 9003: speaker, 9005: operation key, 9006: connection terminal, 9007: sensor, 9008: microphone, 9055: hinge, 9056: operation button, 9200: portable information terminal, 9201: portable information terminal, 9202: portable information terminal

1. A semiconductor device comprising:
an oxide semiconductor layer;
a first conductive layer comprising a first depressed portion;
a first insulating layer over the first conductive layer;
a second conductive layer over the first insulating layer;
a third conductive layer;
a second insulating layer; and
a third insulating layer,
wherein the first insulating layer and the second conductive layer have a first opening portion at a position overlapping with the first depressed portion,
wherein the second insulating layer is in contact with at least a side surface of the first insulating layer in the first opening portion,
wherein the oxide semiconductor layer is in contact with a top surface of the second conductive layer and a bottom surface and a side surface of the first depressed portion and is in contact with the second insulating layer in the first opening portion,
wherein the third insulating layer is positioned inward from the oxide semiconductor layer in the first opening portion,
wherein the third conductive layer is positioned inward from the third insulating layer in the first opening portion,
wherein the first insulating layer has a barrier property against hydrogen, and
wherein the second insulating layer is configured to capture or fix hydrogen.

2. The semiconductor device according to claim 1,
wherein the first insulating layer comprises silicon and nitrogen, and
wherein the second insulating layer comprises oxygen and one or both of hafnium and aluminum.

3. The semiconductor device according to claim 1,
wherein the second insulating layer comprises a first layer in contact with the first insulating layer and a second layer positioned between the first layer and the oxide semiconductor layer,
wherein the first layer is configured to capture or fix hydrogen, and
wherein the second layer comprises a region containing excess oxygen.

4. The semiconductor device according to claim 3,
wherein the first insulating layer comprises silicon and nitrogen,
wherein the first layer comprises oxygen and one or both of hafnium and aluminum, and
wherein the second layer comprises oxygen and one or both of silicon and aluminum.

5. The semiconductor device according to claim 1, comprising a fourth insulating layer,
wherein the third insulating layer covers a top surface and a side surface of the oxide semiconductor layer over the first insulating layer,
wherein the fourth insulating layer is positioned over the third insulating layer and comprises a second opening portion at a position overlapping with the first opening portion, and
wherein the third conductive layer comprises a portion facing the oxide semiconductor layer with the third insulating layer therebetween in the first opening portion and a portion positioned in the second opening portion.

6. The semiconductor device according to claim 5,
wherein a width of the second opening portion is smaller than a width of the first opening portion.

7. The semiconductor device according to claim 1,
wherein the first conductive layer comprises a fourth conductive layer and a fifth conductive layer over the fourth conductive layer,
wherein the fifth conductive layer comprises a second depressed portion,
wherein the first opening portion overlaps with the second depressed portion, and
wherein the second insulating layer is in contact with a bottom surface and a side surface of the second depressed portion.

8. The semiconductor device according to claim 1,
wherein the oxide semiconductor layer comprises indium, and
wherein in a cross-sectional observation with a transmission electron microscope of the oxide semiconductor layer, bright spots arranged in a layered manner in a direction parallel to the side surface of the first insulating layer in the first opening portion are observed.

9. The semiconductor device according to claim 1,
wherein the oxide semiconductor layer comprises indium,
wherein the oxide semiconductor layer comprises a first region, a second region in contact with the first region, and a third region in contact with the second region, and
wherein in a cross-sectional observation with a transmission electron microscope of the oxide semiconductor layer, bright spots arranged in a layered manner in a direction parallel to the side surface of the first insulating layer in the first opening portion are observed in each of the first region, the second region, and the third region.

10. The semiconductor device according to claim 9,
wherein a content percentage of indium in the first region is higher than a content percentage of indium in the second region, and
wherein a content percentage of indium in the third region is higher than the content percentage of indium in the second region.

11. A semiconductor device comprising:
an oxide semiconductor layer;
a first conductive layer comprising a first depressed portion;
a first insulating layer over the first conductive layer;
a second conductive layer over the first insulating layer;
a third conductive layer;
a second insulating layer; and
a third insulating layer,
wherein the first insulating layer and the second conductive layer have a first opening portion at a position overlapping with the first depressed portion,
wherein the second insulating layer is in contact with at least a side surface of the first insulating layer in the first opening portion,
wherein the oxide semiconductor layer is in contact with a top surface of the second conductive layer and a bottom surface and a side surface of the first depressed portion and is in contact with the second insulating layer in the first opening portion,
wherein the third insulating layer is positioned inward from the oxide semiconductor layer in the first opening portion,
wherein the third conductive layer is positioned inward from the third insulating layer in the first opening portion,
wherein the first insulating layer comprises silicon and nitrogen,
wherein the second insulating layer comprises oxygen and one or both of hafnium and aluminum,
wherein the oxide semiconductor layer comprises indium, and
wherein in a cross-sectional observation with a transmission electron microscope of the oxide semiconductor layer, bright spots arranged in a layered manner in a direction parallel to the side surface of the first insulating layer in the first opening portion are observed.
